(19) United States
(12) Patent Application Publication
(10) Pub. No.: US 2007/0040164 A1
(43) Pub. Date: Feb. 22, 2007

(54) Polymer complex compound and polymer light emitting device using the same

(75) Inventors: Satoshi Mikami, Tsukuba-shi (JP); Tomoya Nakatani, Tsukuba-shi (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY, LIMITED, Tokyo (JP)

(21) Appl. No.: 10/571,353

(22) PCT Filed: Sep. 10, 2004
(86) PCT No.: PCT/JP04/13586

§ 371 Date: Mar. 10, 2006

(30) Foreign Application Priority Data
Sep. 12, 2003 (JP) 2003-321521
Sep. 12, 2003 (JP) 2003-321518
Jan. 13, 2004 (JP) 2004-005173
Jan. 13, 2004 (JP) 2004-005172

(51) Int. Cl. H01L 29/08; C08L 81/00; C08G 73/02

(52) U.S. Cl. 257/40; 523/161; 525/535; 525/540

(57) ABSTRACT

A polymer complex compound comprising a repeating unit of the following formula (1) and a metal complex structure showing light emission from triplet excited state, having visible light emission in the solid state, and having a polystyrene reduced number-average molecular weight of 10³ to 10⁸: 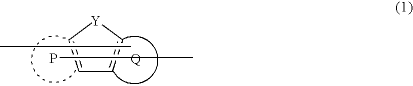 (wherein, Ring P and Ring Q each independently represent an aromatic ring, but Ring P may be either existent or non-existent. When Ring P is existent, two connecting bonds respectively are on Ring P and/or Ring Q, and when Ring P is non-existent, two connecting bonds respectively are on 5 membered ring containing Y, and/or Ring Q. Y represents —O—, —S— and the like).

### TECHNICAL FIELD

The present invention relates to a polymer complex compound and a polymer light emitting device (hereinafter, referred to as polymer LED in some cases).

### BACKGROUND ART

It is known that a device using in a light emitting layer a metal complex showing light emission from triplet excited state (hereinafter, referred to as triplet light emitting complex in some cases) as a light emitting material used in a light emitting layer of a light emitting device shows high light emitting efficiency. Complex compounds containing a structure of a triplet light emitting complex in a polymer have been investigated, and for example, there is known a compound having a partial structure of tri(2-phenylpyridine) iridium complex Ir(ppy)₃ as a triplet light emitting complex in the main chain of a polymer having a fluorene structure, as a repeating unit (Japanese Patent Application Laid-Open (JP-A) No. 2003-73480).

Further, polymer complex compounds containing a structure of a triplet light emitting complex in the side chain of a polymer having an aromatic hydrocarbon ring in the main chain have been investigated, and for example, there is disclosed a compound having a structure of a triplet light emitting complex as shown below in the side chain of a polymer compound having a fluorene structure, as a repeating unit (J. Am. Chem. Soc., 2003, vol. 125, No. 3, 636-637).

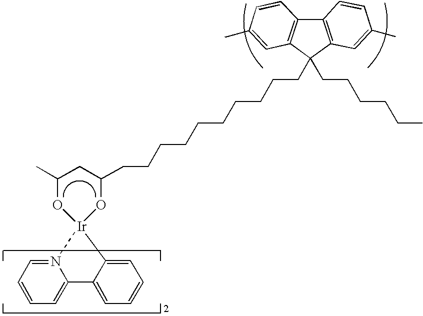

However, in the above-mentioned devices using a complex compound in a light emitting layer, properties of the devices such as light emitting efficiency, half life-time of luminance and the like are yet insufficient.

### DISCLOSURE OF THE INVENTION

The object of the present invention is to provide a complex compound which contains a structure of a triplet light emitting complex in a polymer, and gives, when used in a light emitting layer of a light emitting device, excellent properties of the device.

The present inventors have intensively studied to solve the above-mentioned problem and resultantly found that a polymer complex compound comprising a repeating unit of the following formula (1) and a metal complex structure showing light emission from triplet excited state gives, when used in a light emitting layer of a light emitting device, excellent properties of the device, leading to completion of the present invention.

That is, the present invention provides a polymer complex compound comprising a repeating unit of the following formula (1) and a metal complex structure showing light emission from triplet excited state, having visible light emission in the solid state, and having a polystyrene reduced number-average molecular weight of 10³ to 10⁸: 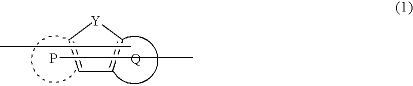
(wherein, Ring P and Ring Q each independently represent an aromatic ring, but Ring P may be either existent or non-existent. When Ring P is existent, two connecting bonds respectively are on Ring P and/or Ring Q, and when Ring P is non-existent, two connecting bonds respectively are on 5 membered ring containing Y, and/or Ring Q. The aromatic ring and/or the 5-membered ring containing Y may carry substituents selected from the group consisting of alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atoms, acyl group, acyloxy group, imine residues, amide group, acid imide group, monovalent heterocyclic group, carboxyl group, substituted carboxyl group and cyano group.

Y represents —O—, —S—, —Se—, —Si(R₁)(R₂)—, —P(R₃)— or —PR₄(═O)—, and R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group or halogen atom).

### BEST MODES FOR CARRYING OUT THE INVENTION

In the present invention, mentioned as the structure of the above-mentioned formula (1) are structures of the following formulae (1-1), (1-2) and (1-3) and structures of the following formulae (1-4) and (1-5): 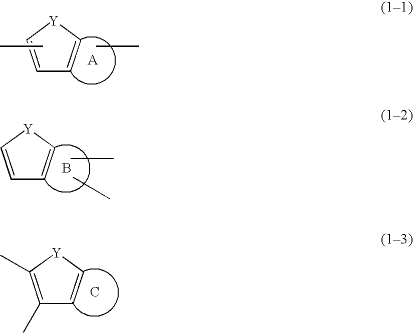
(wherein, Ring A, Ring B and Ring C each independently represent an aromatic ring. The formulae (1-1), (1-2) and (1-3) may each carry substituents selected from the group consisting of alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atoms, acyl group, acyloxy group, imine residues, amide group, acid imide group, monovalent heterocyclic group, carboxyl group, substituted carboxyl group and cyano group. Y represents the same meaning as described above). 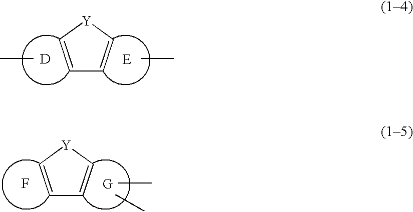
(wherein, Ring D, Ring E, Ring F and Ring G each independently represent an aromatic ring. These repeating units may have substituents selected from the group consisting of alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atoms, acyl group, acyloxy group, imine residues, amide group, acid imide group, monovalent heterocyclic group, carboxyl group, substituted carboxyl group and cyano group. Y represents the same meaning as described above).

In the above-mentioned formulae (1), (1-1), (1-2), (1-3), (1-4) and (1-5), a Ring P, Ring Q, Ring A, Ring B, Ring C, Ring D, Ring E, Ring F and Ring G each independently represent an aromatic ring, and this aromatic ring includes aromatic hydrocarbon rings such as a benzene ring, naphthalene ring, anthracene ring, tetracene ring, pentacene ring, pyrene ring, phenanthrene ring and the like; heteroaromatic rings such as a pyridine ring, bipyridine ring, phenanthroline ring, quinoline ring, isoquinoline ring, thiophenering, furan ring, pyrrole ring and the like.

Specific examples of formula (1-1), shown as unsubstituted structure, include the followings.

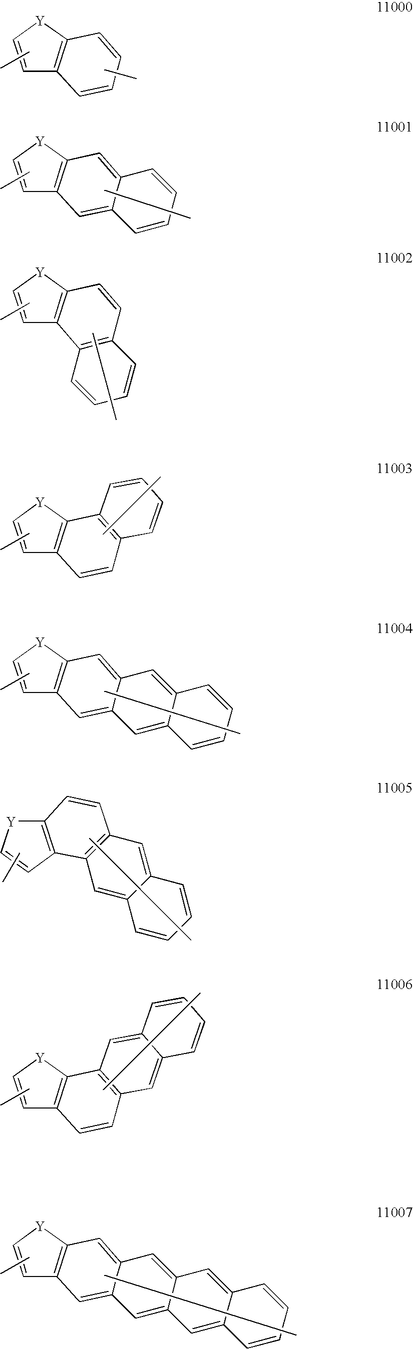

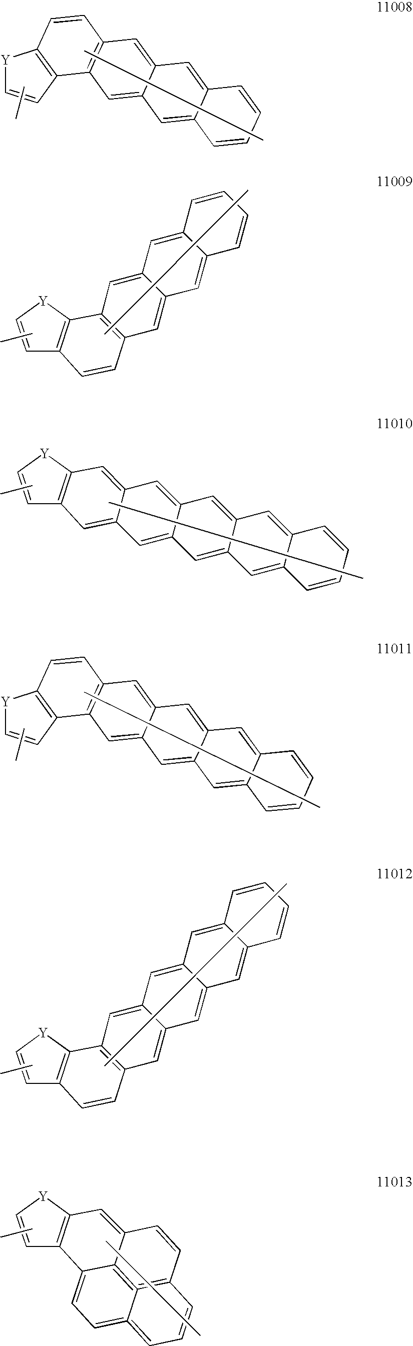

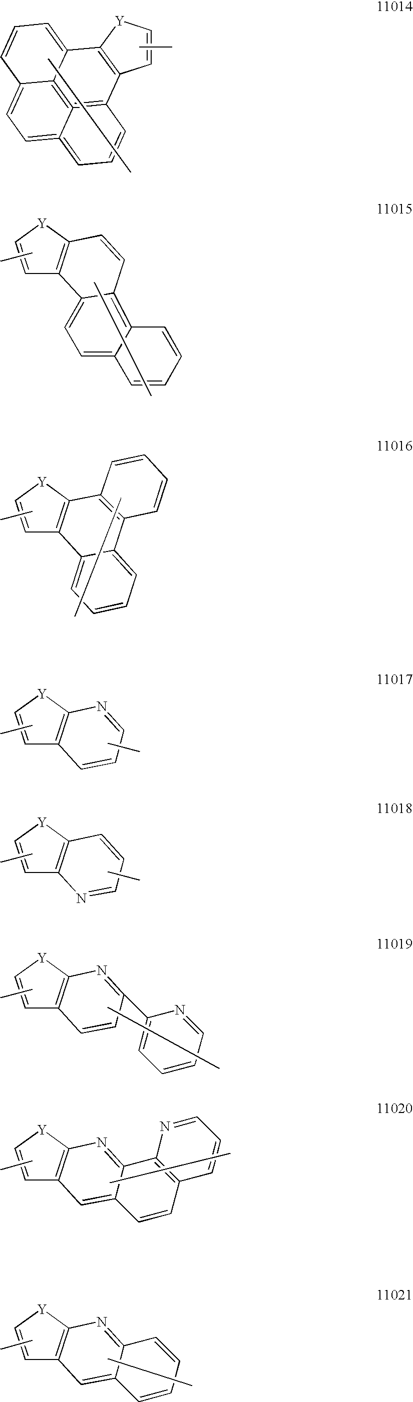

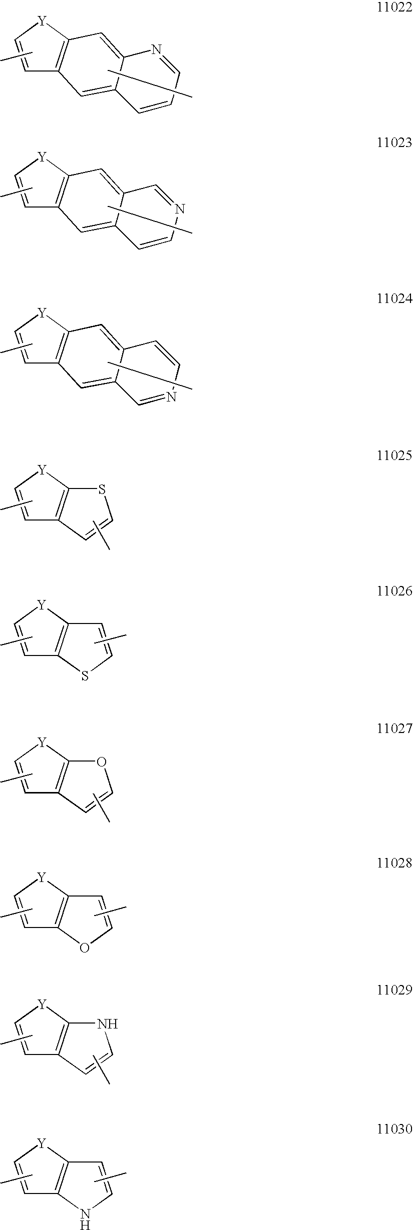

Specific examples of formula (1-2), shown as unsubstituted structure, include the followings.

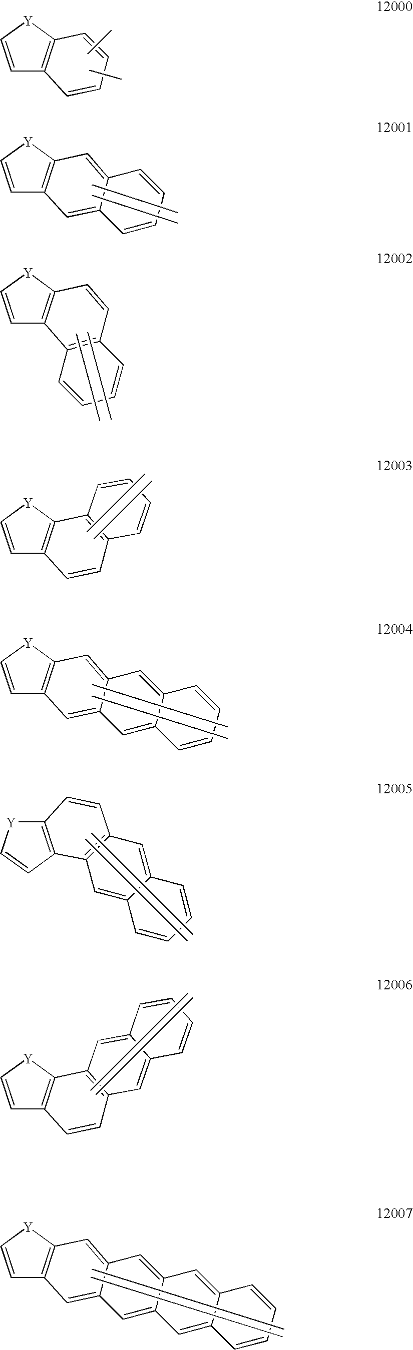

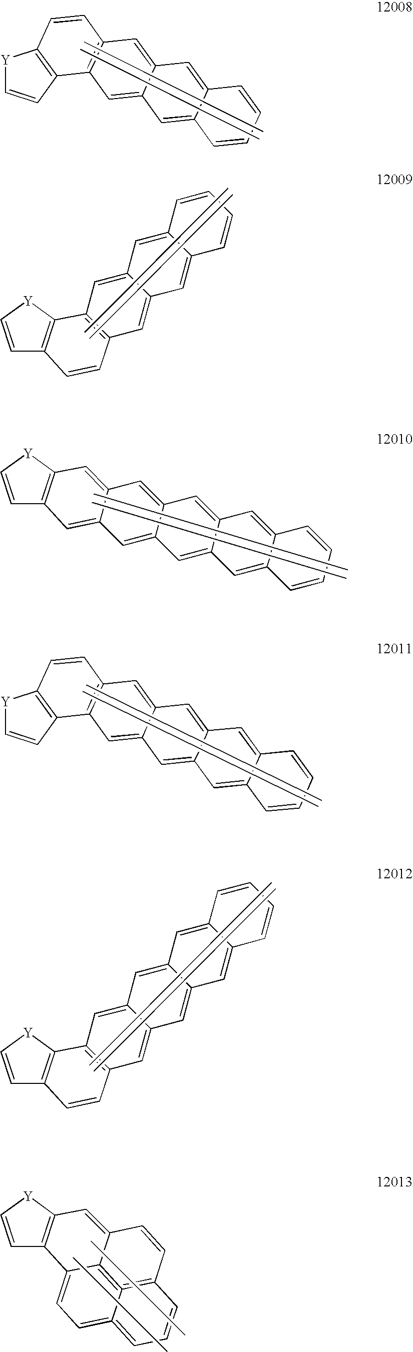

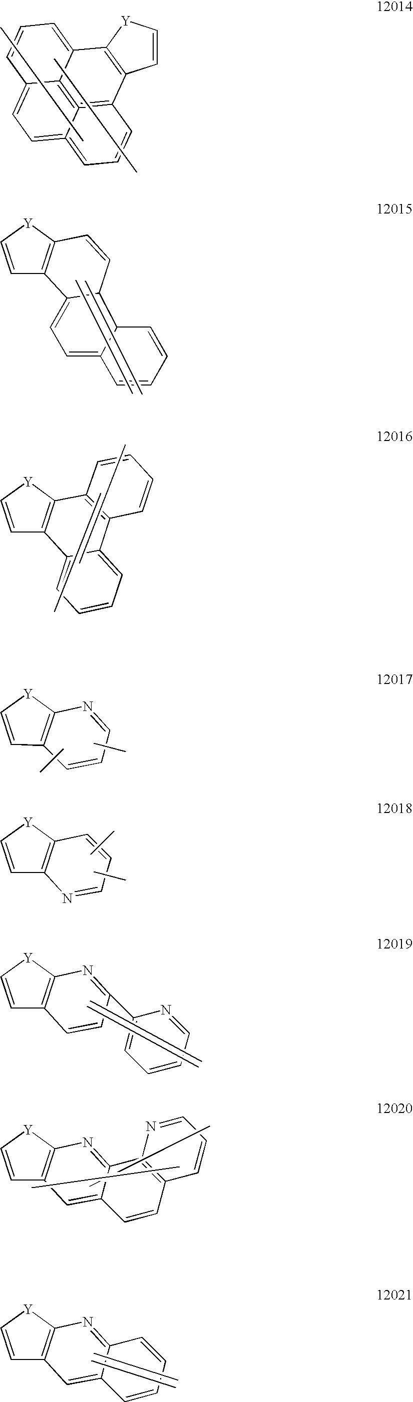

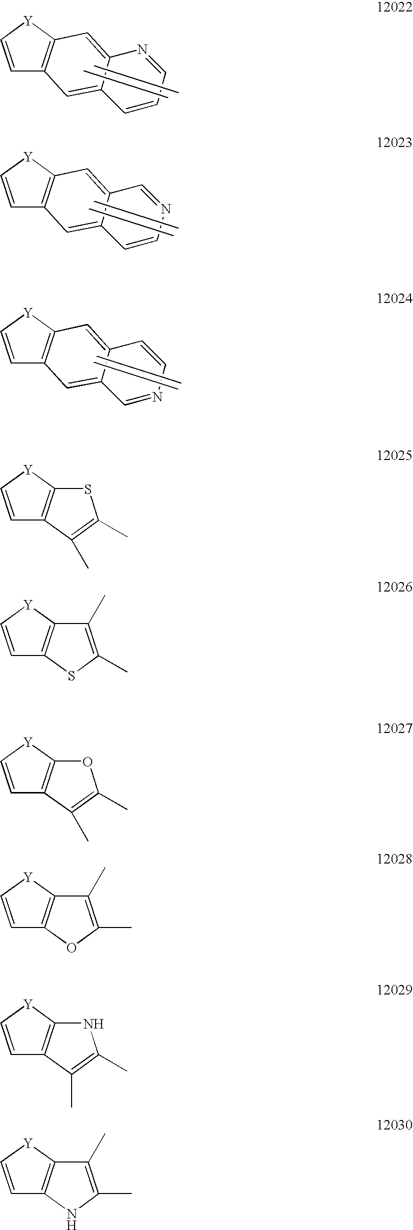

Specific examples of formula (1-3), shown as unsubstituted structure, include the followings.

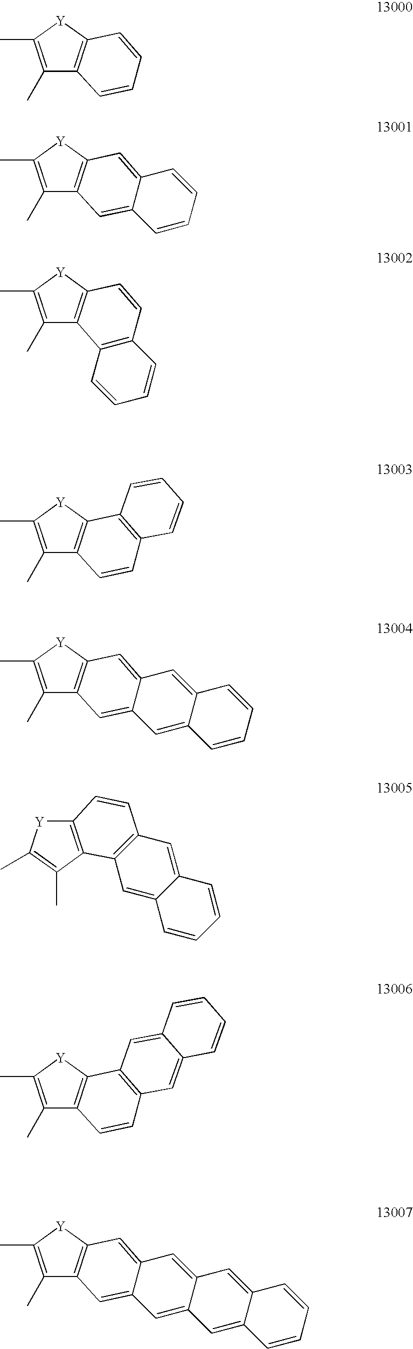

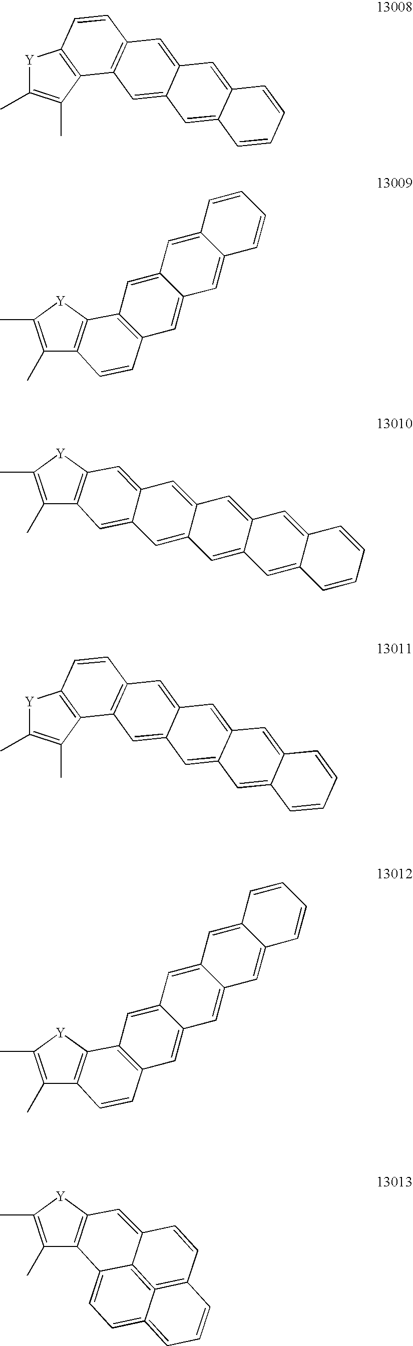

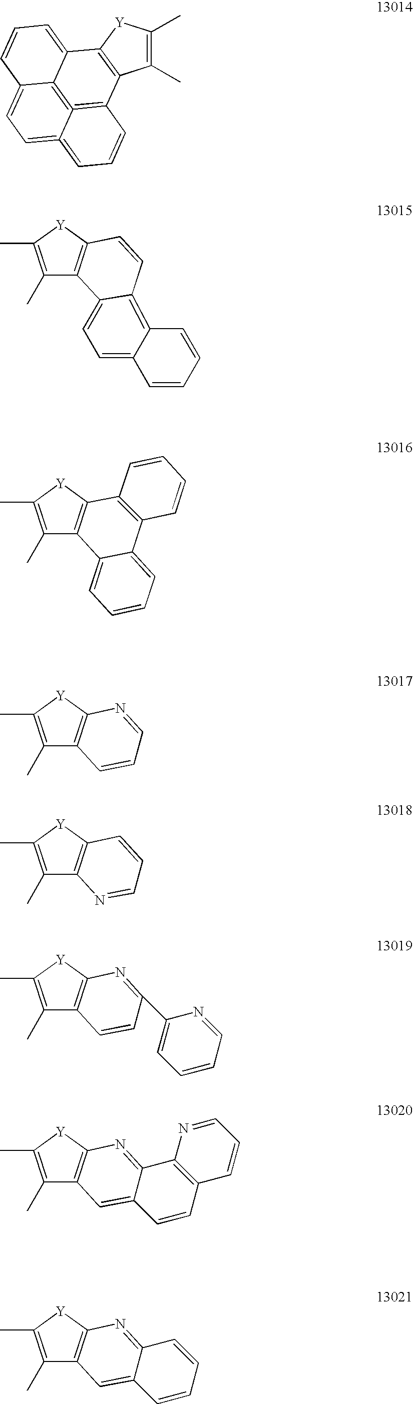

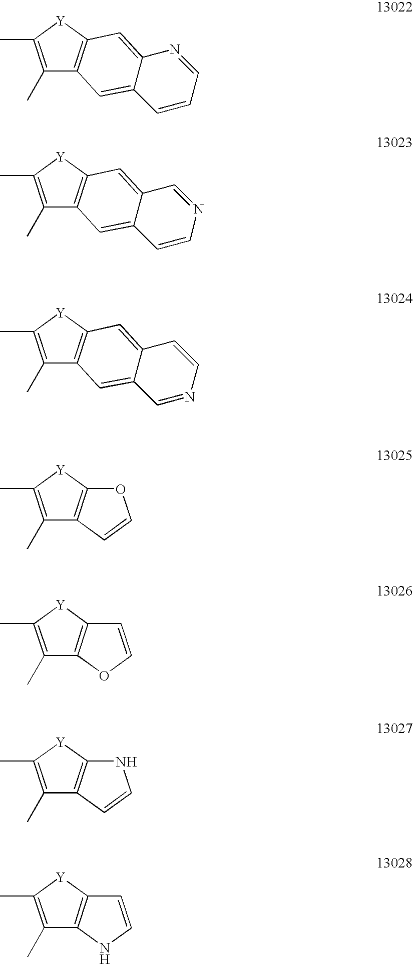

Specific examples of formula (1-4), shown as unsubstituted structure, include the followings.

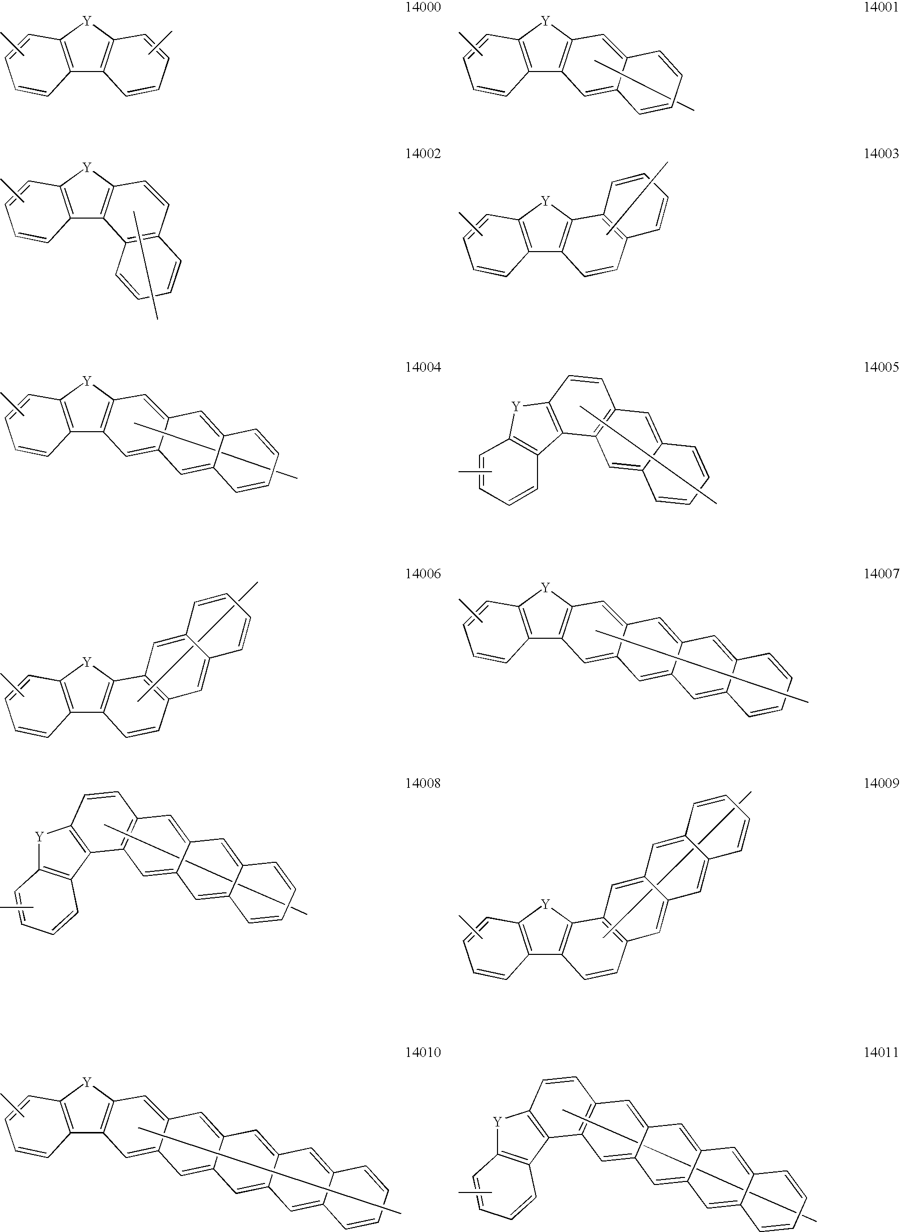

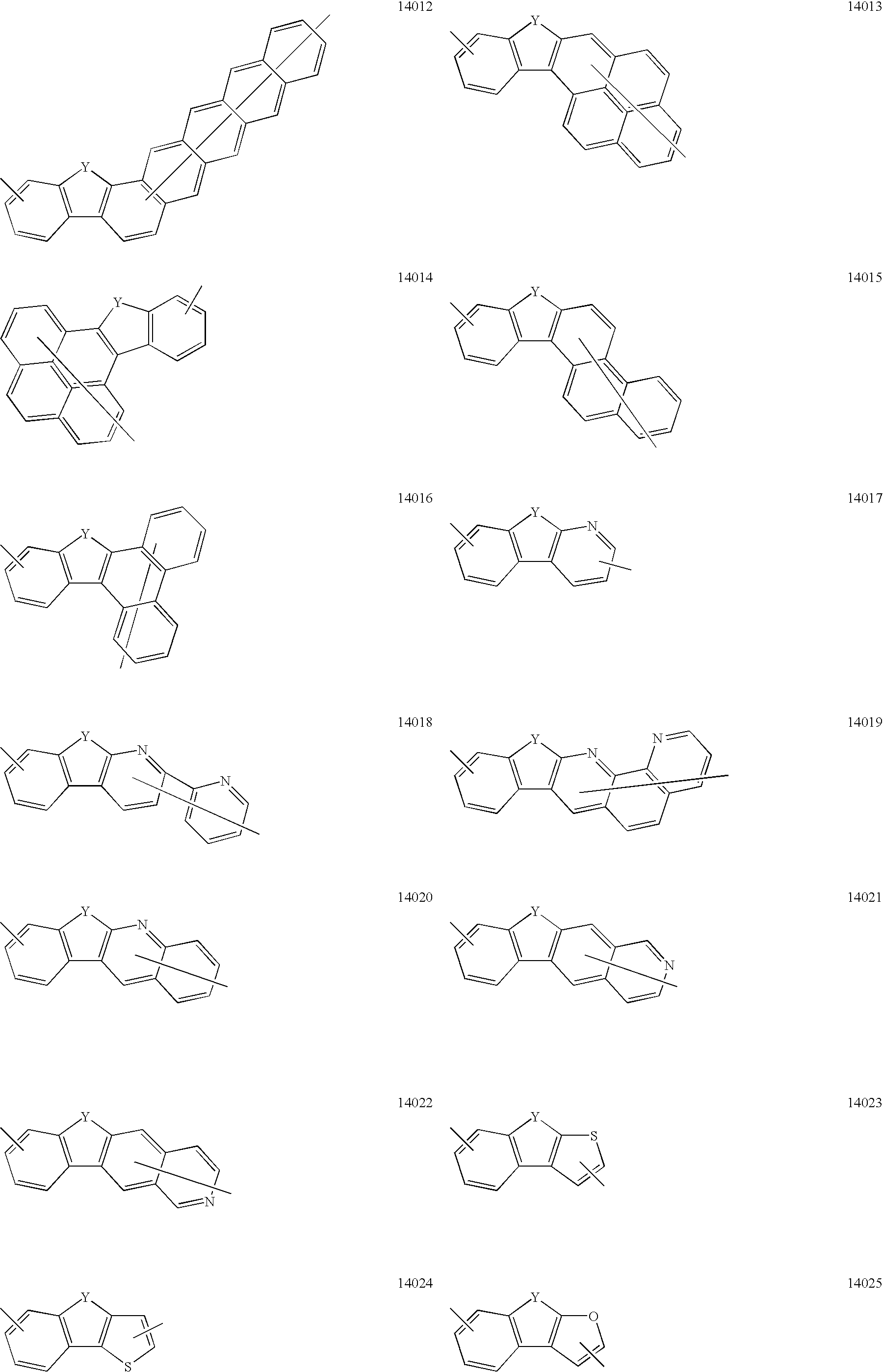

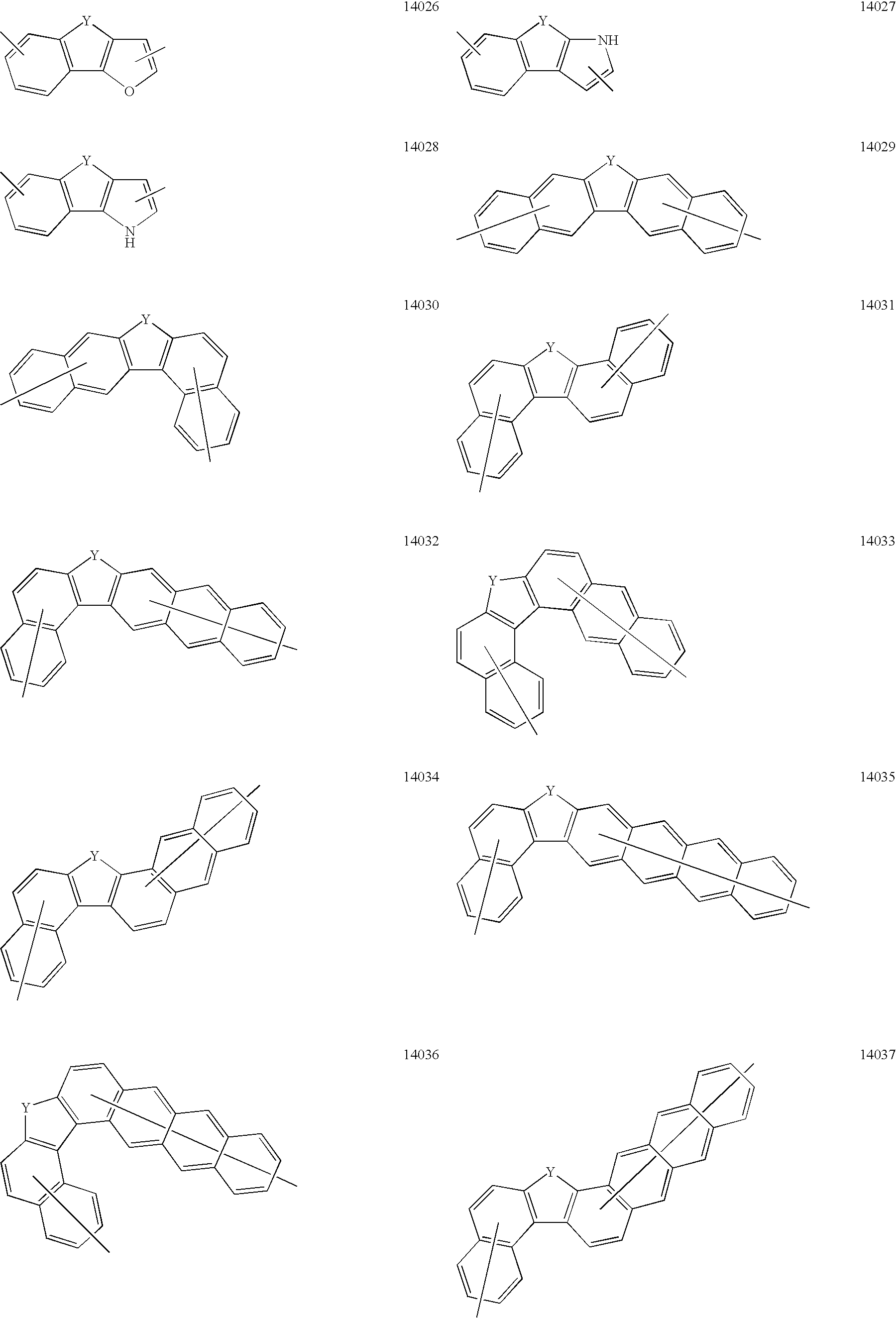

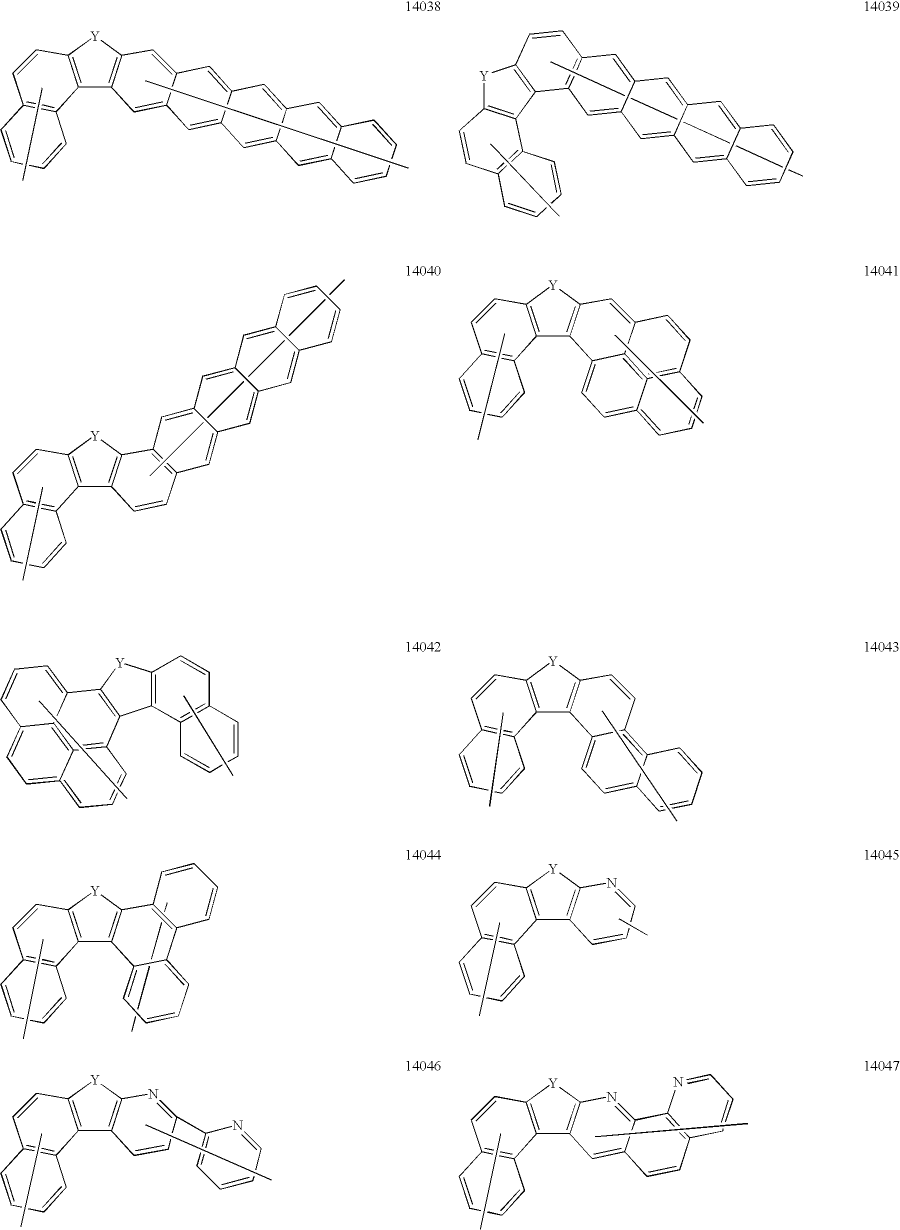

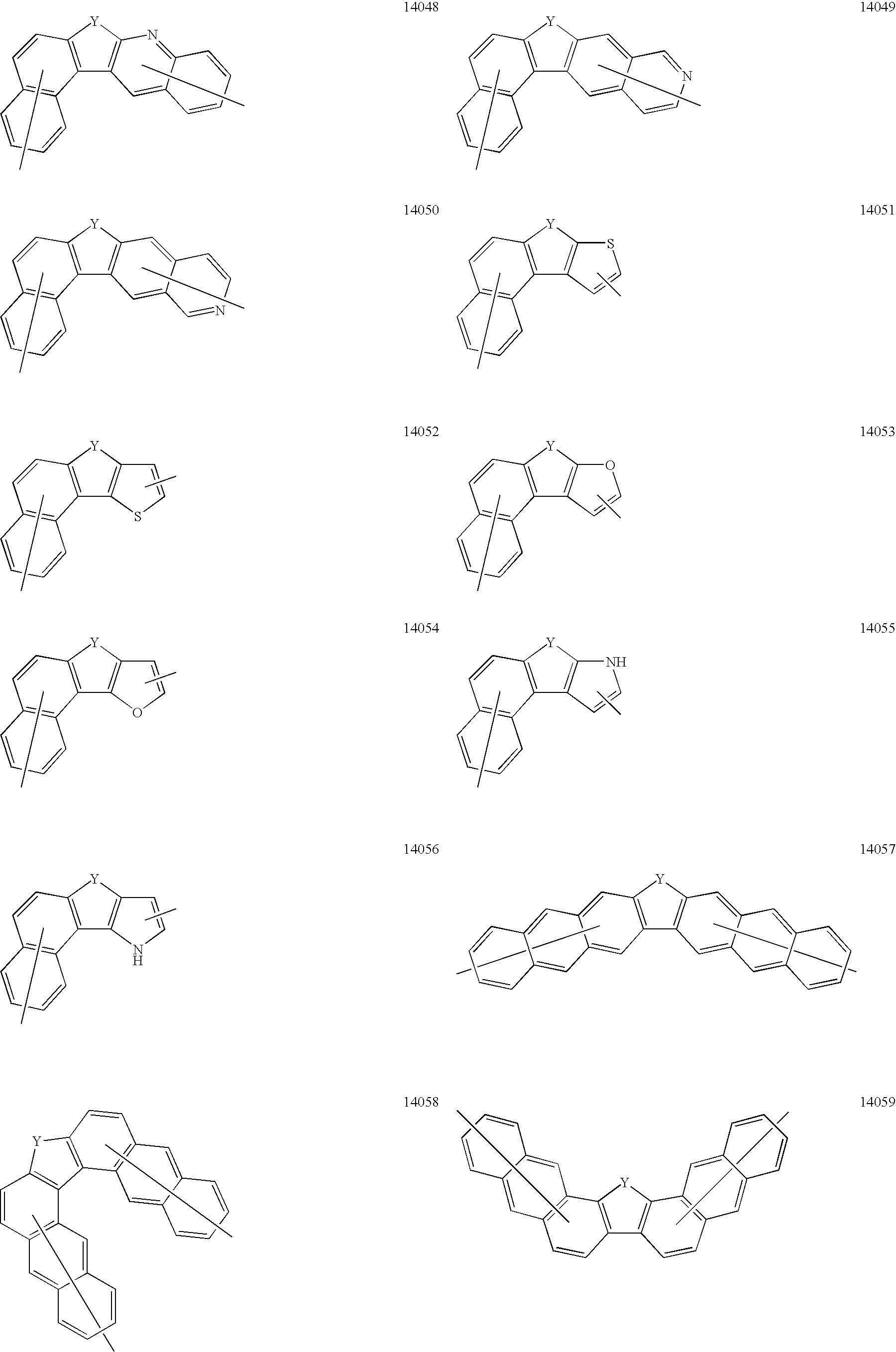

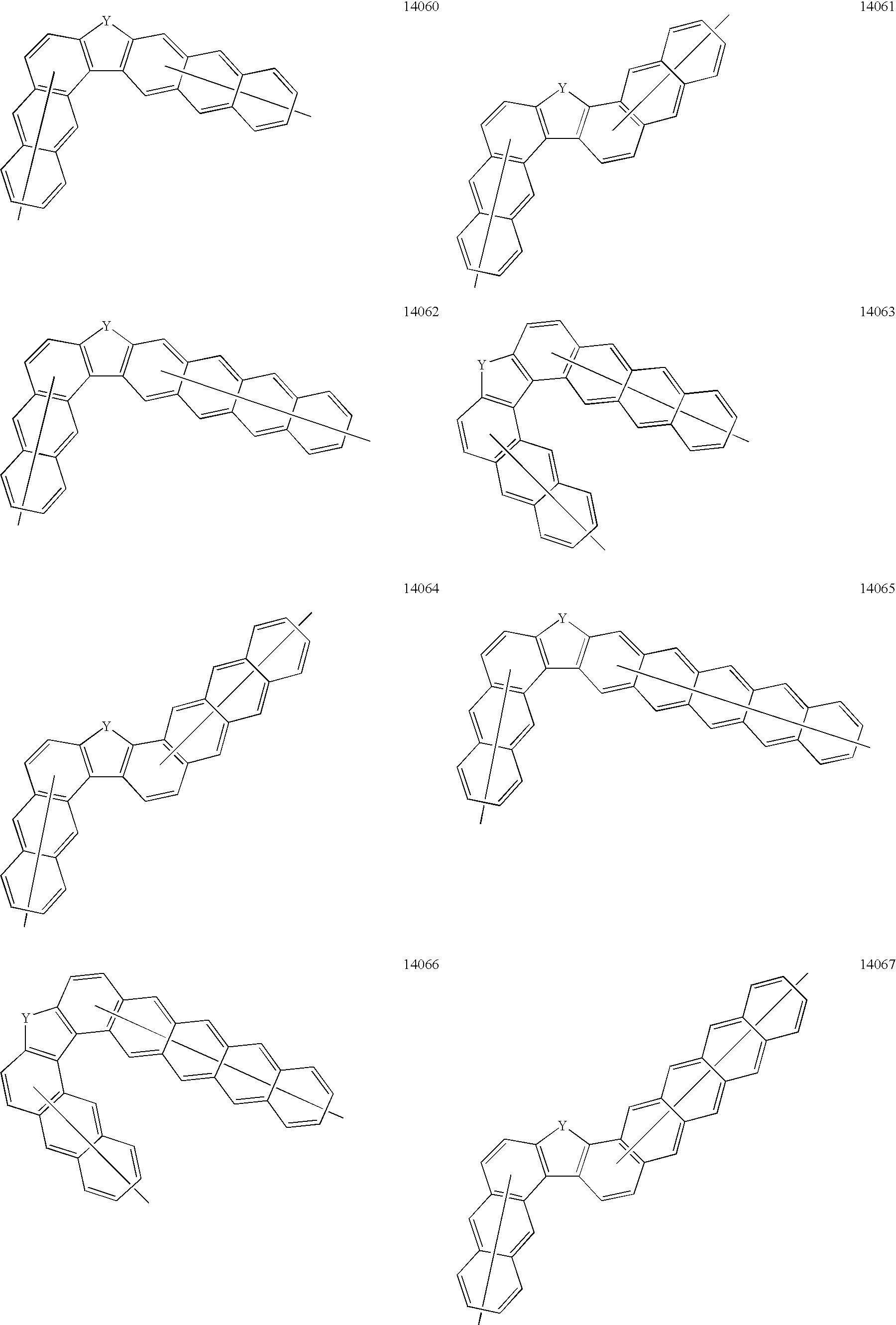

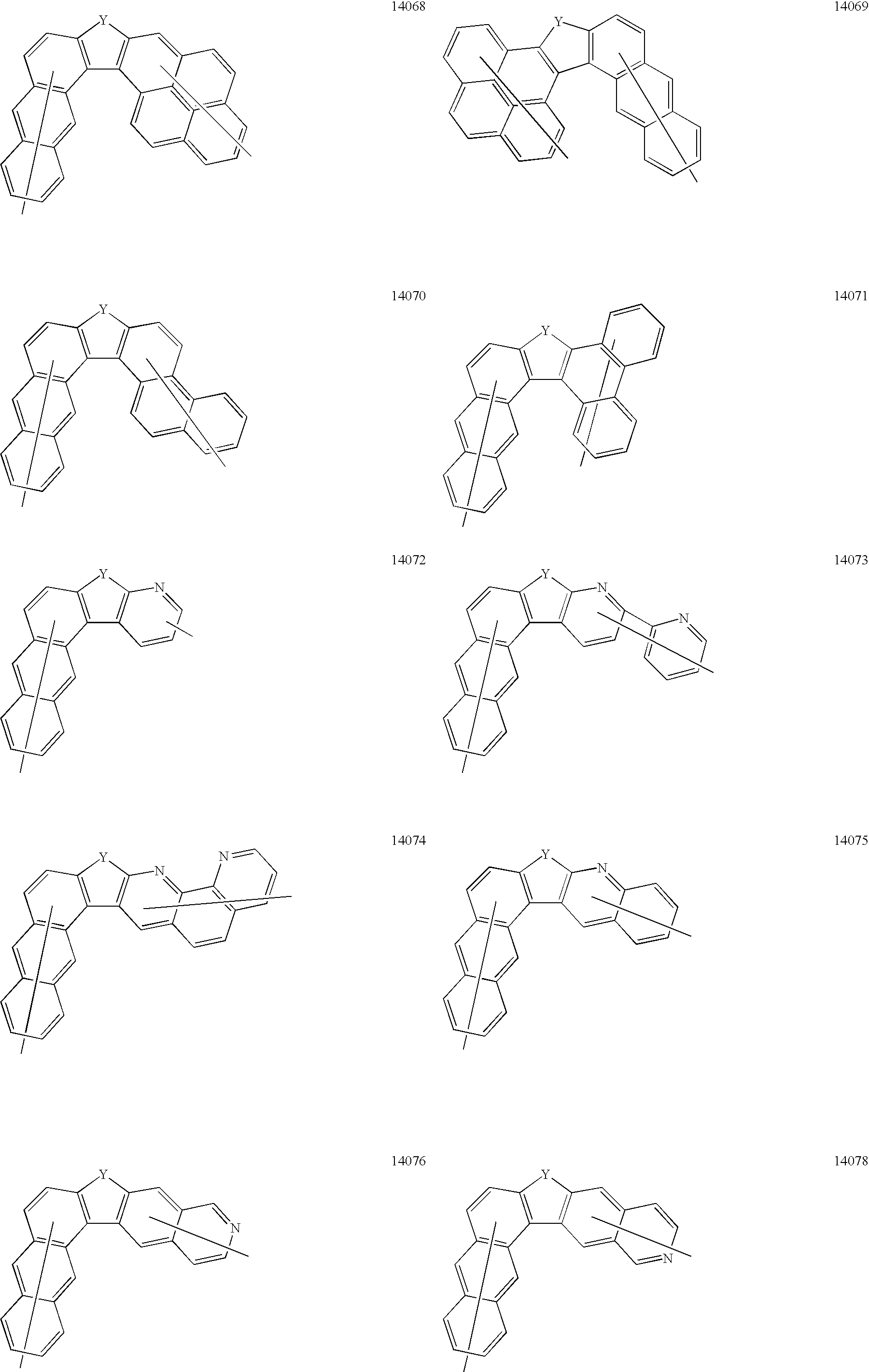

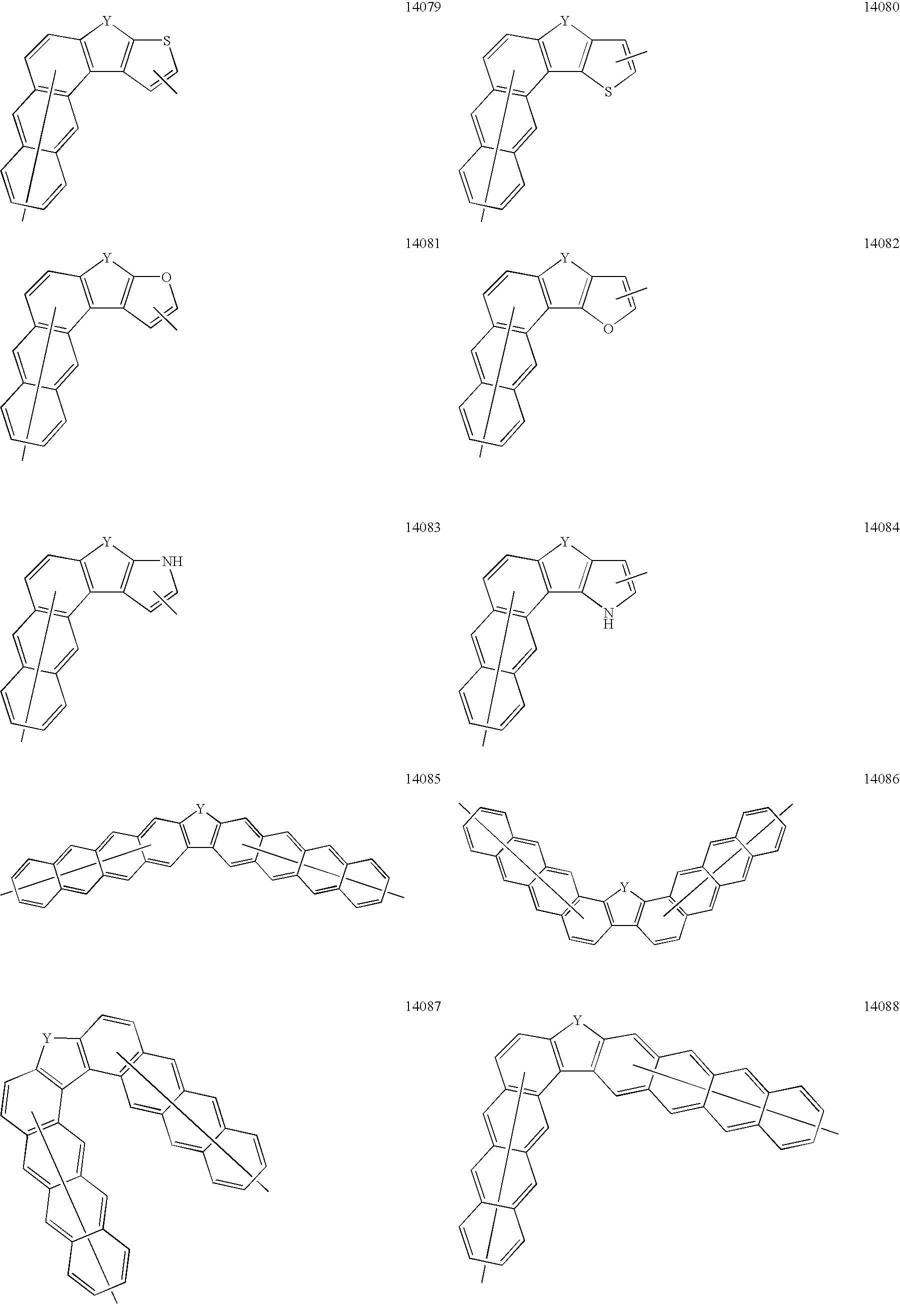

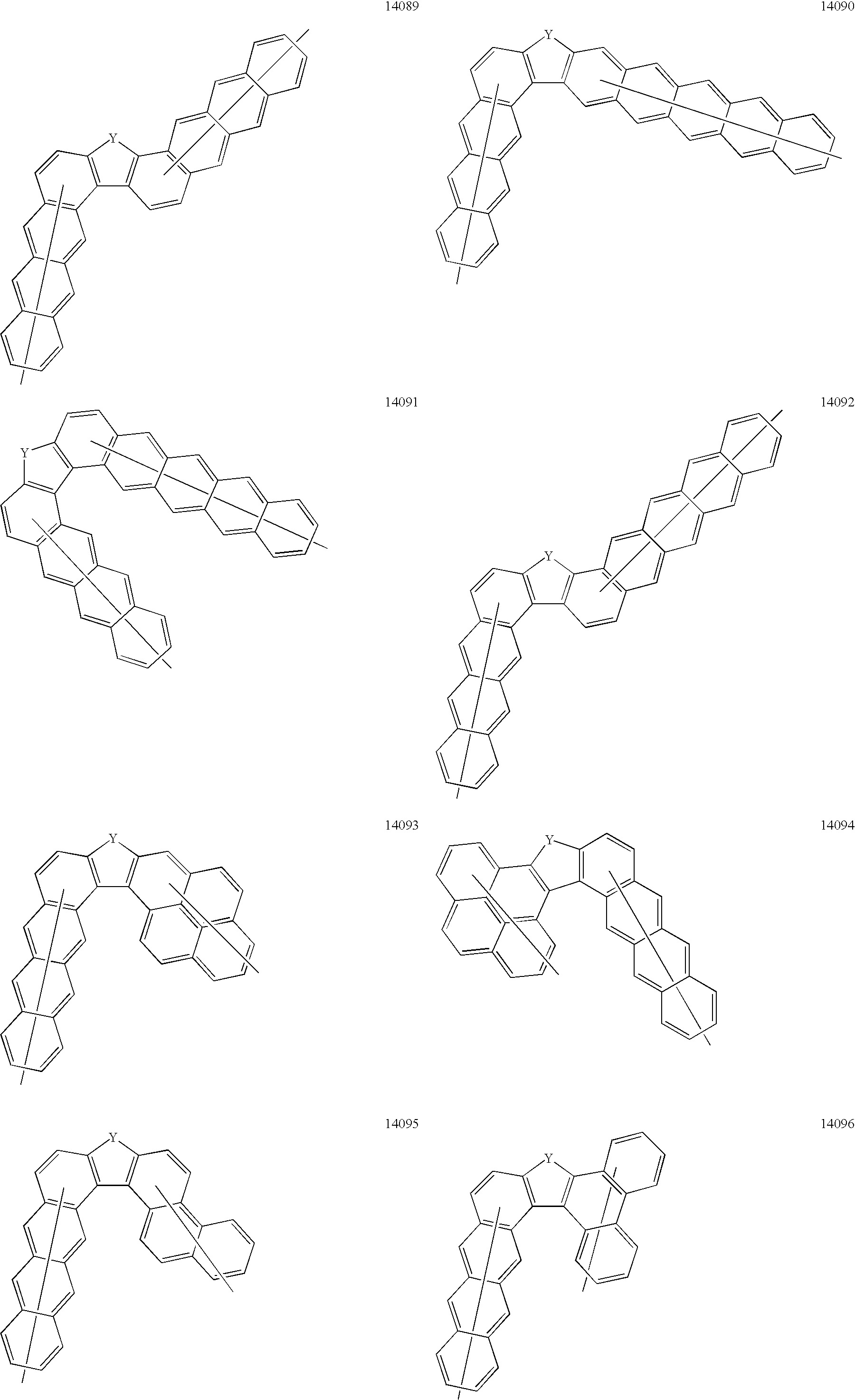

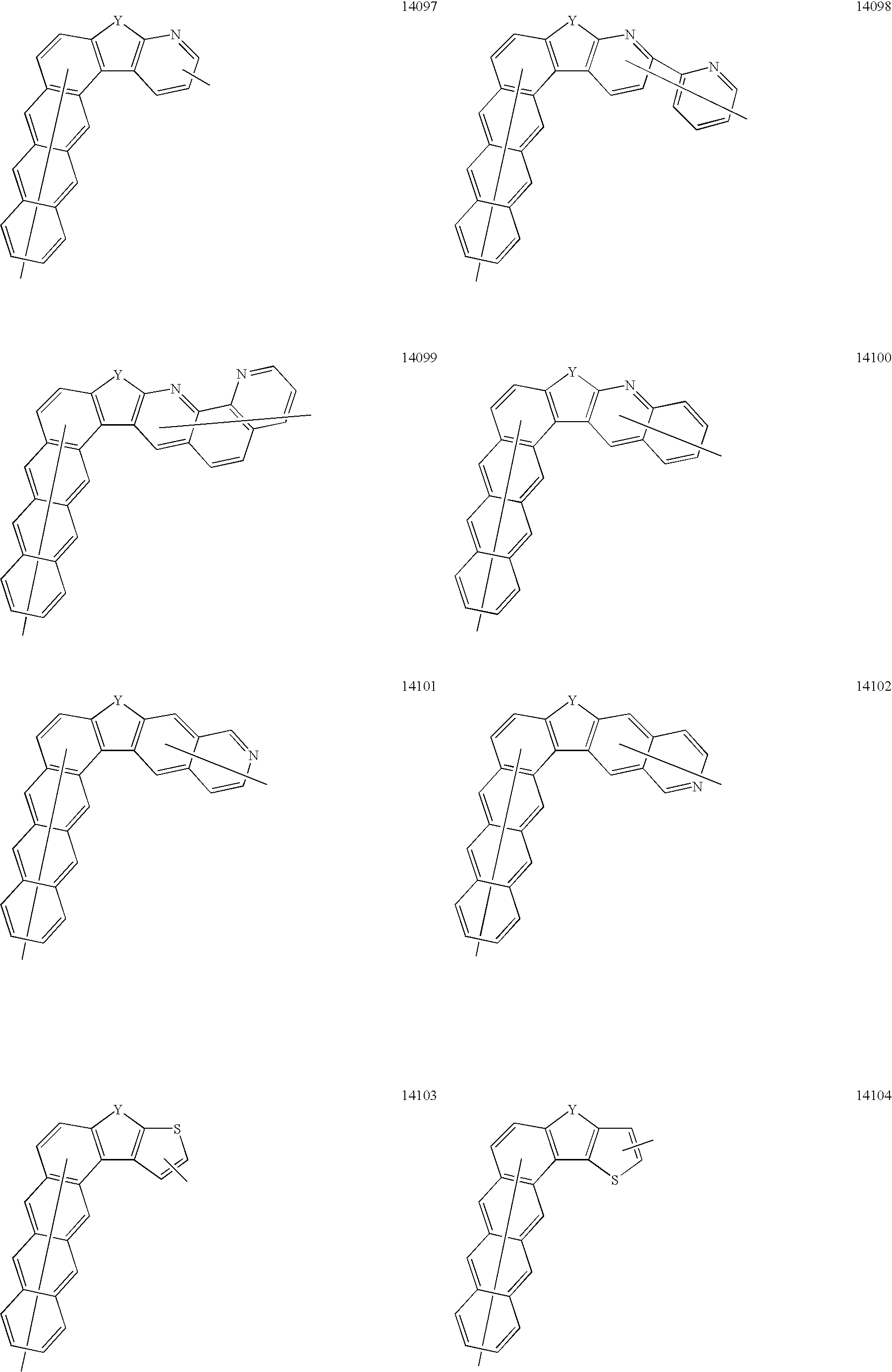

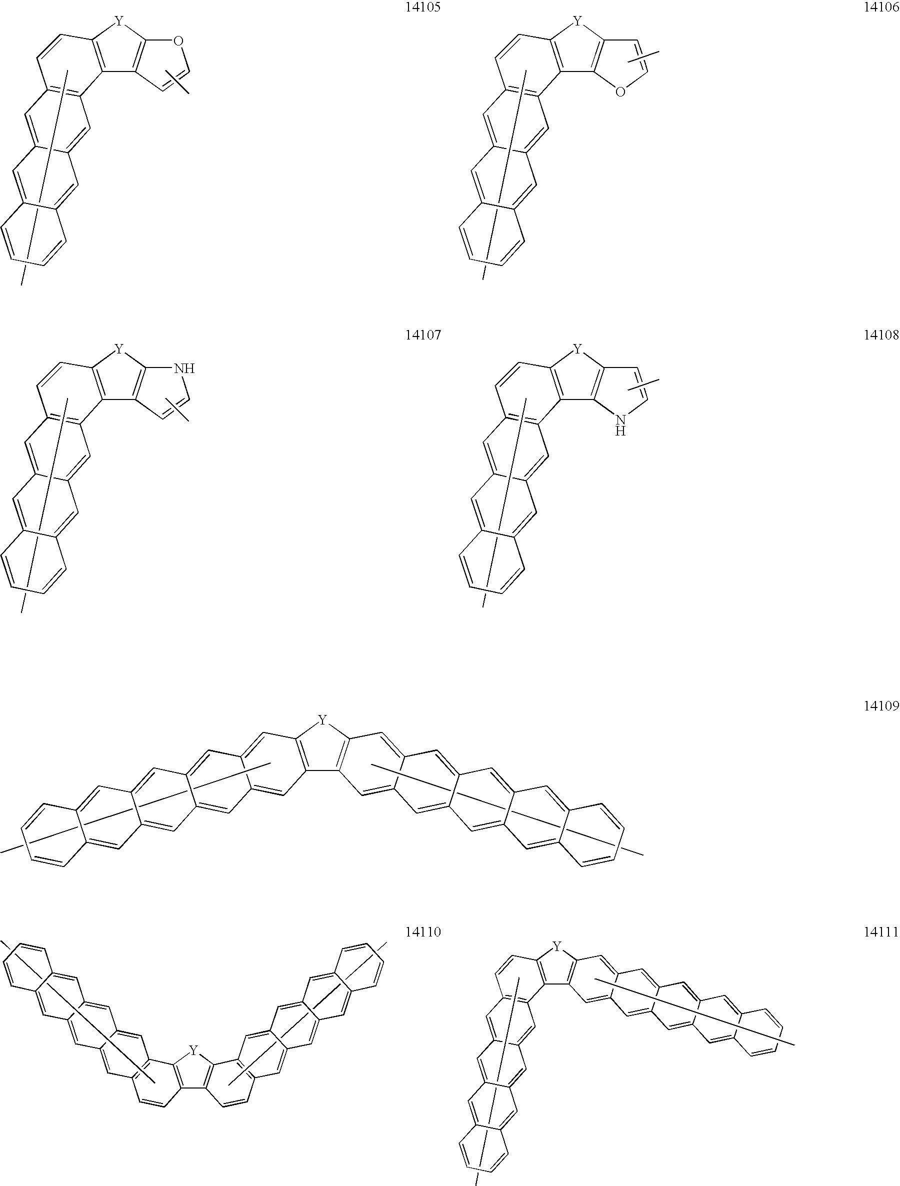

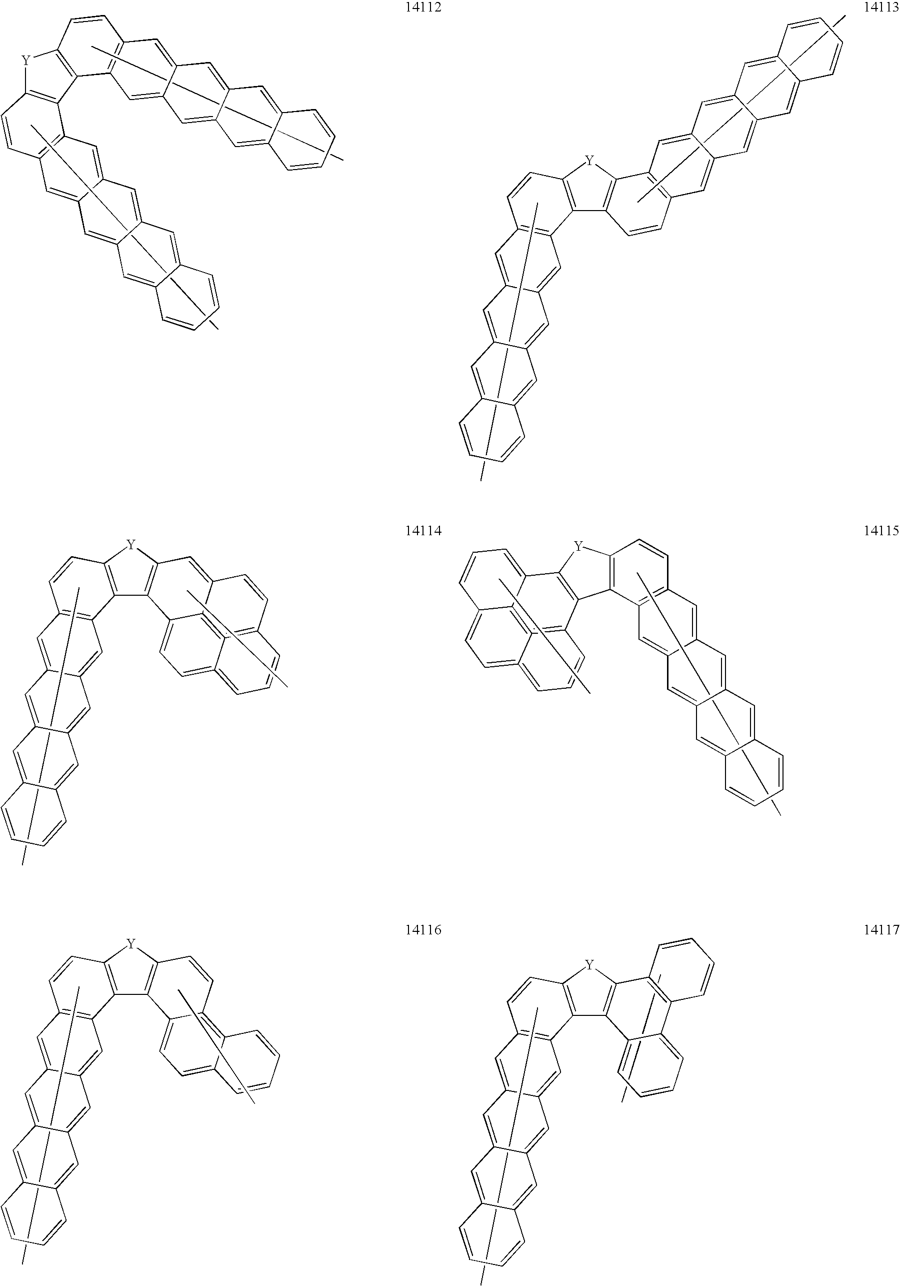

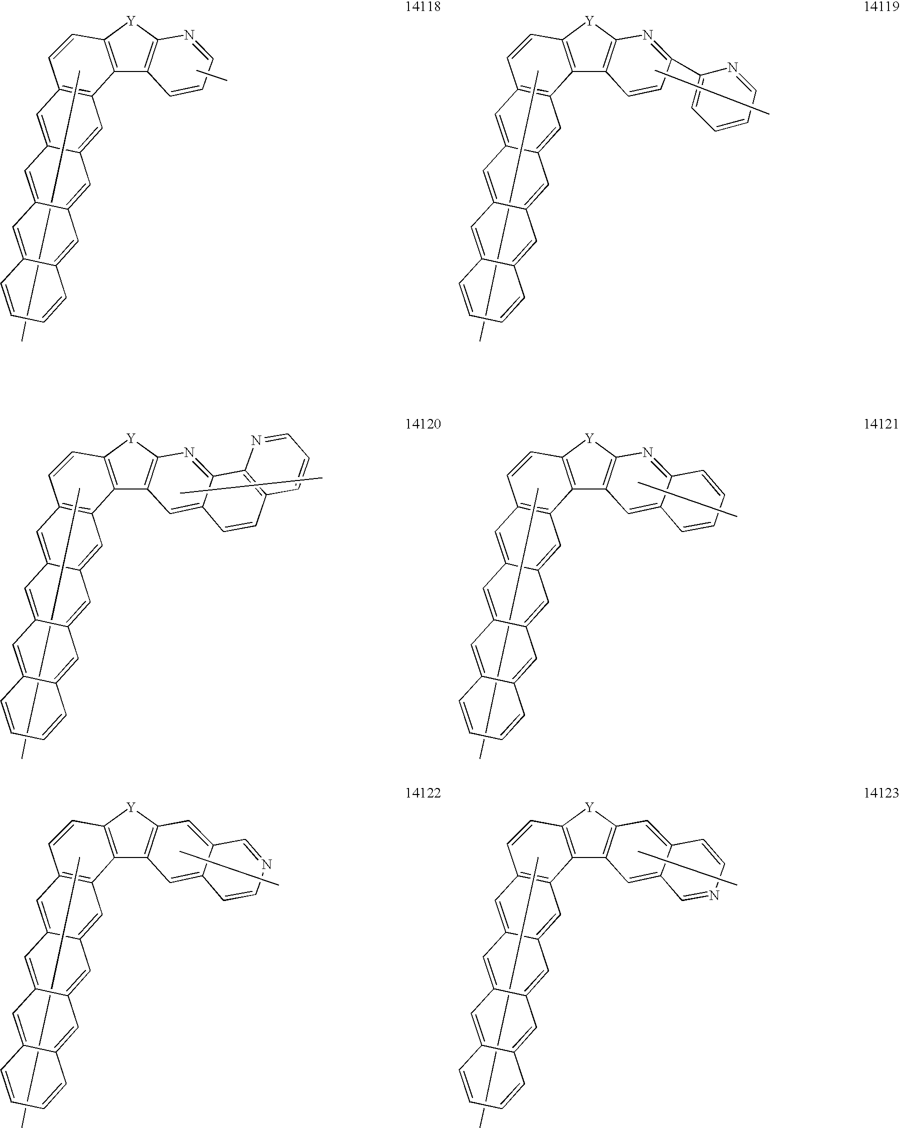

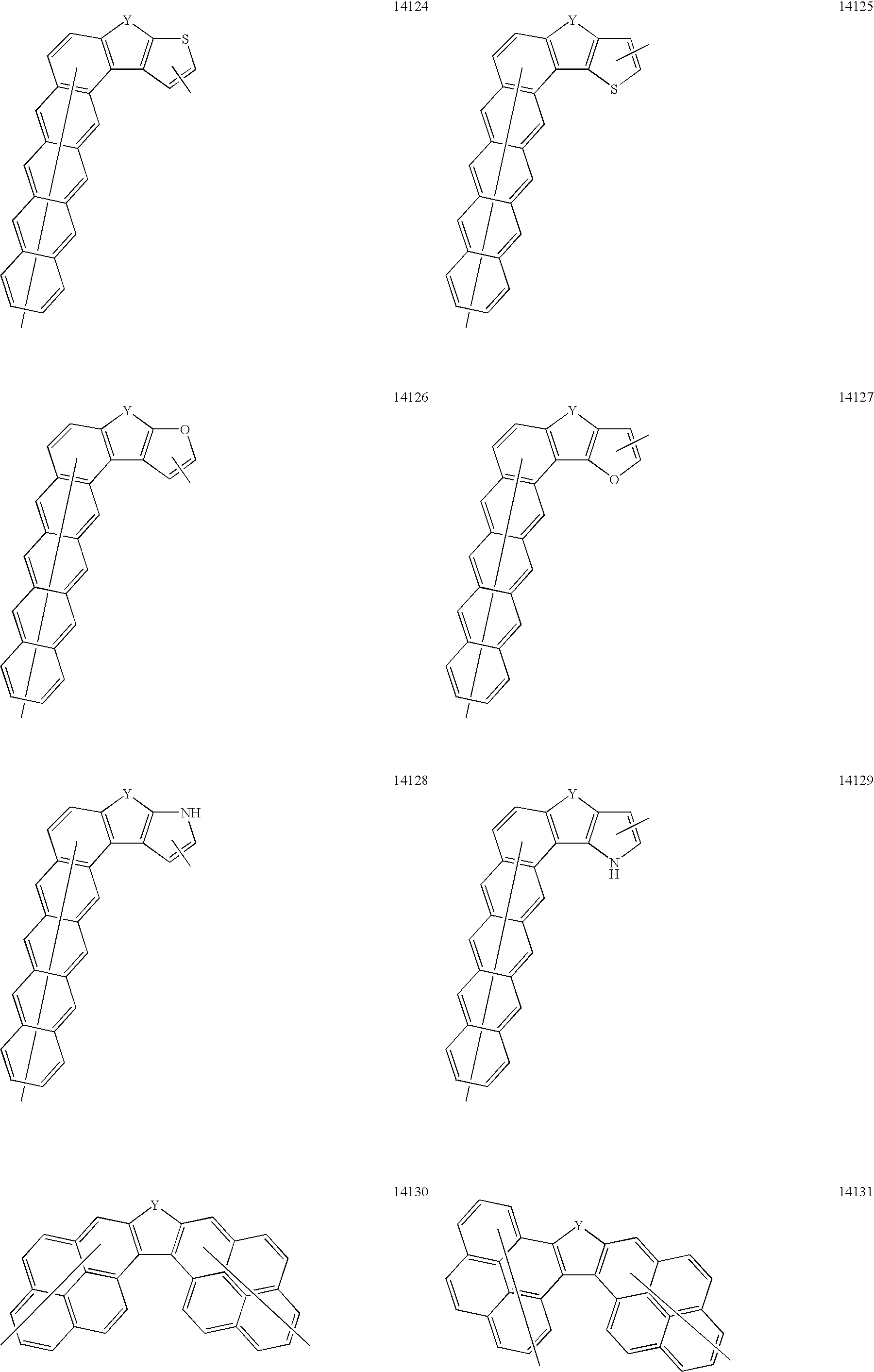

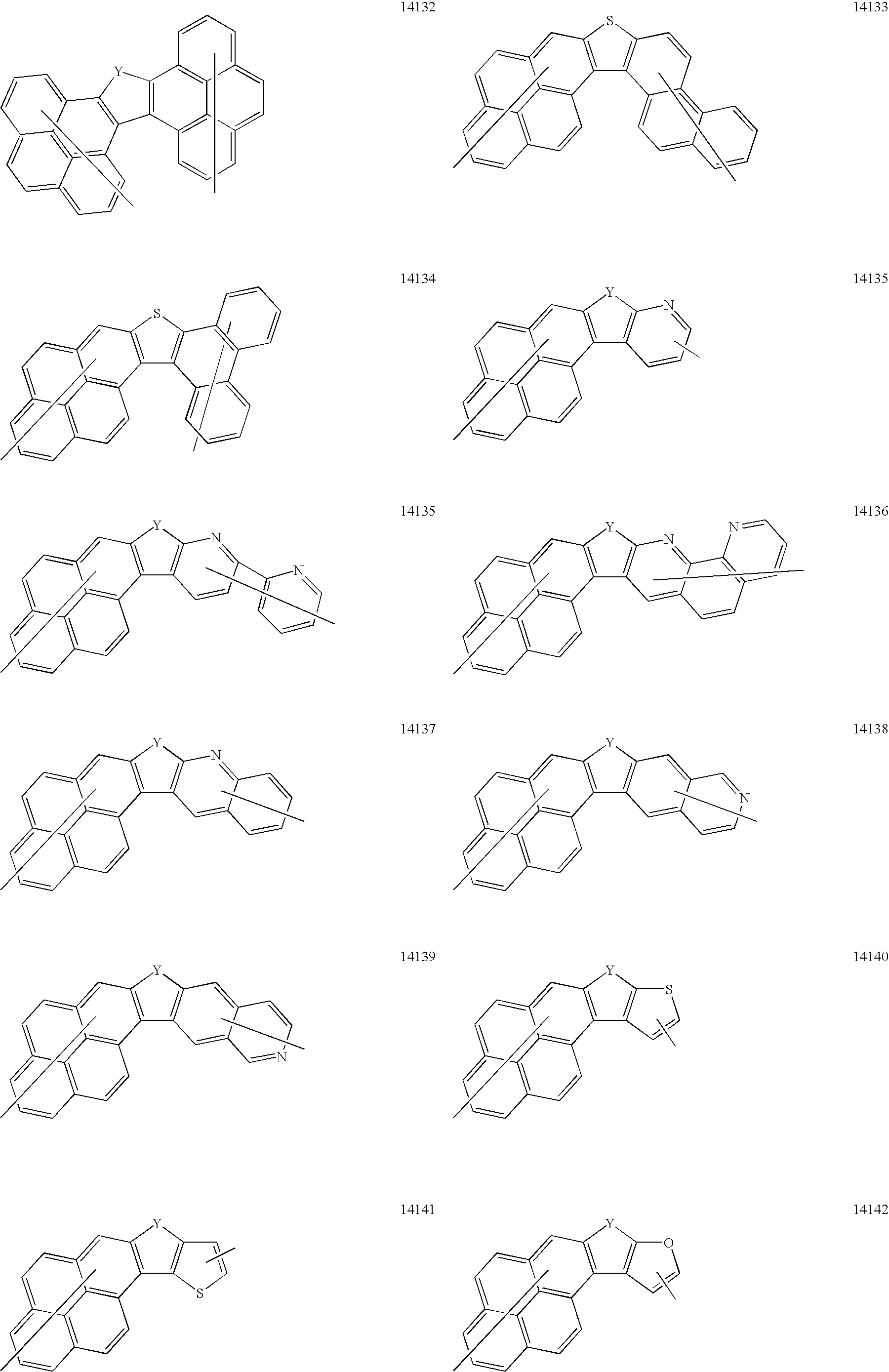

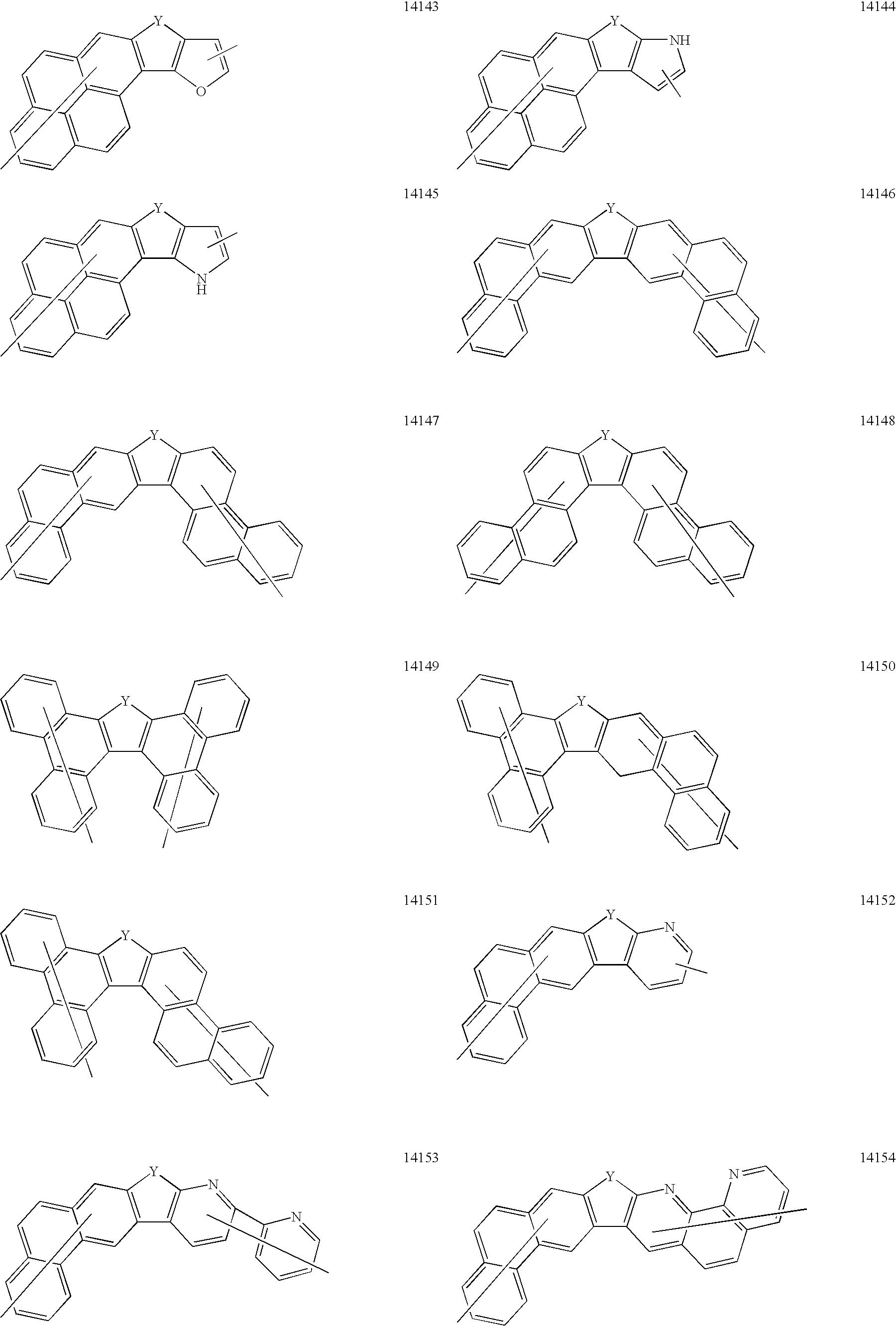

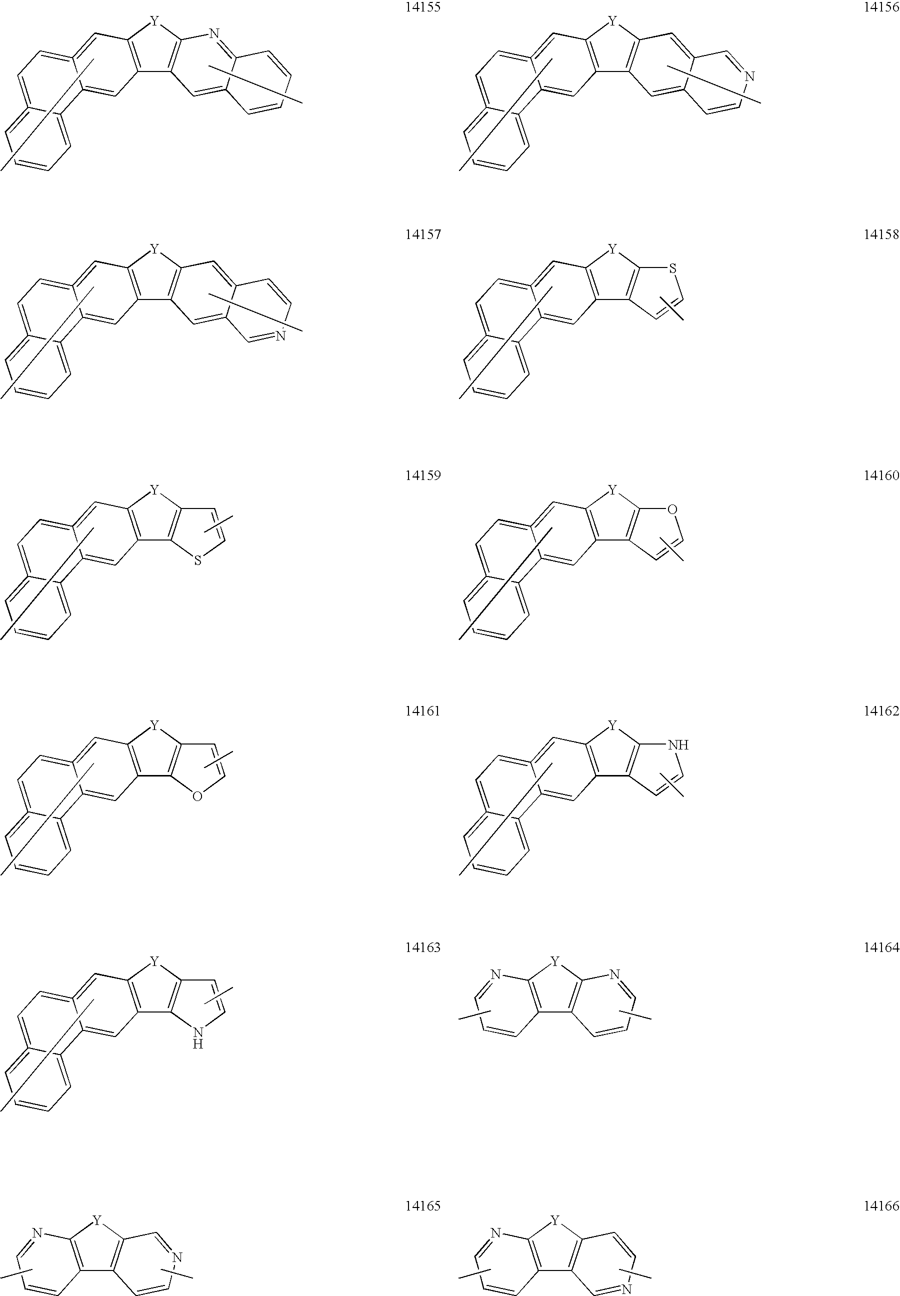

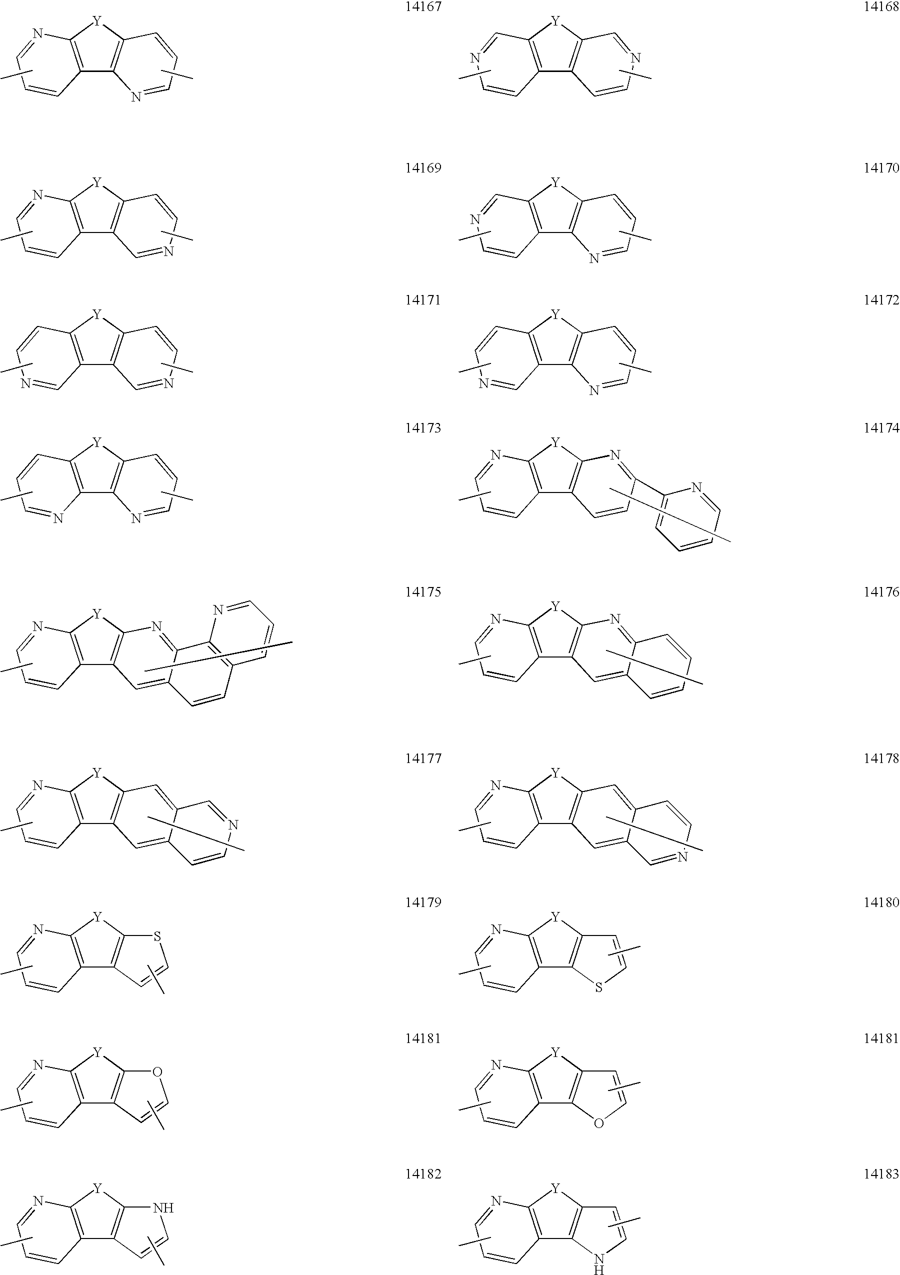

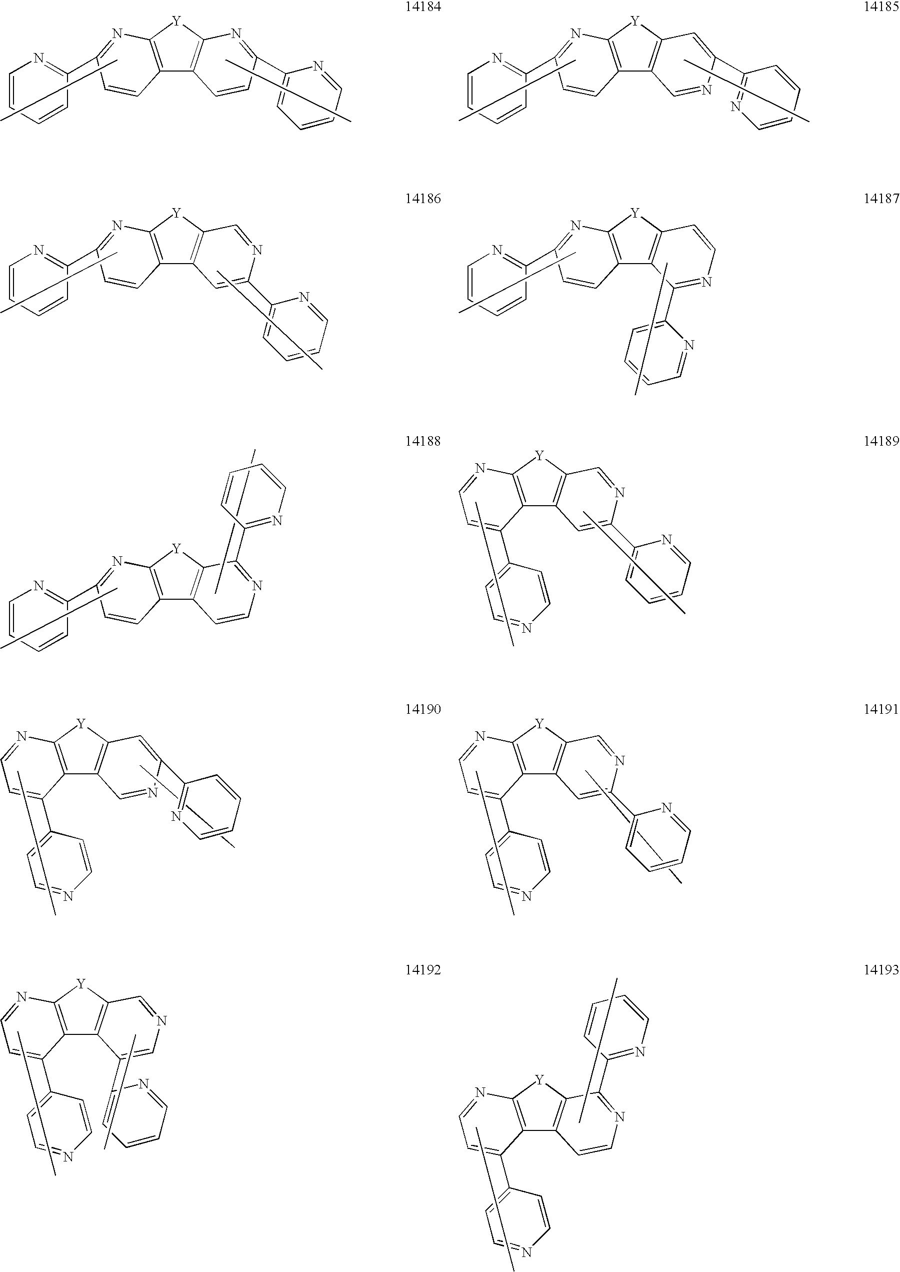

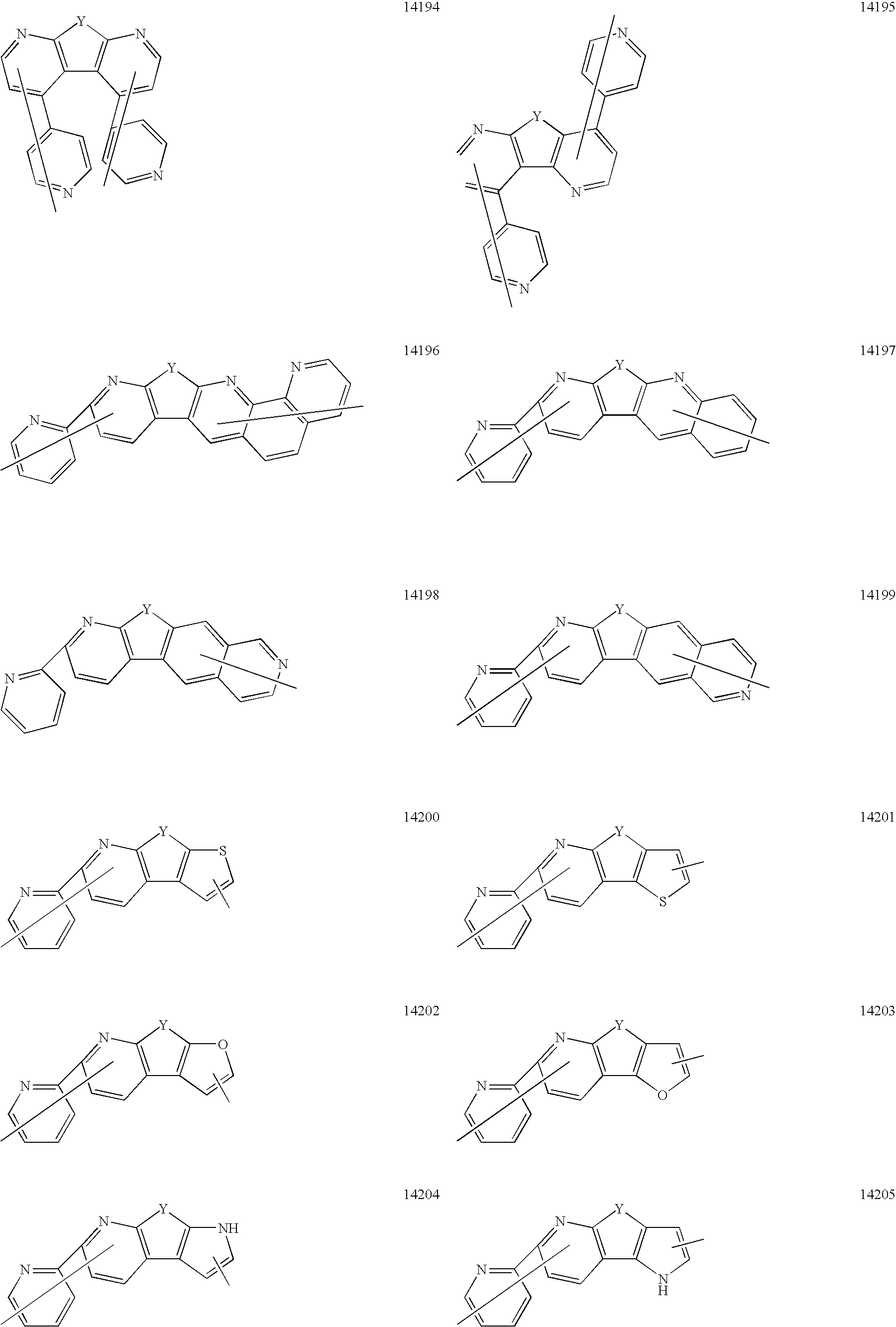

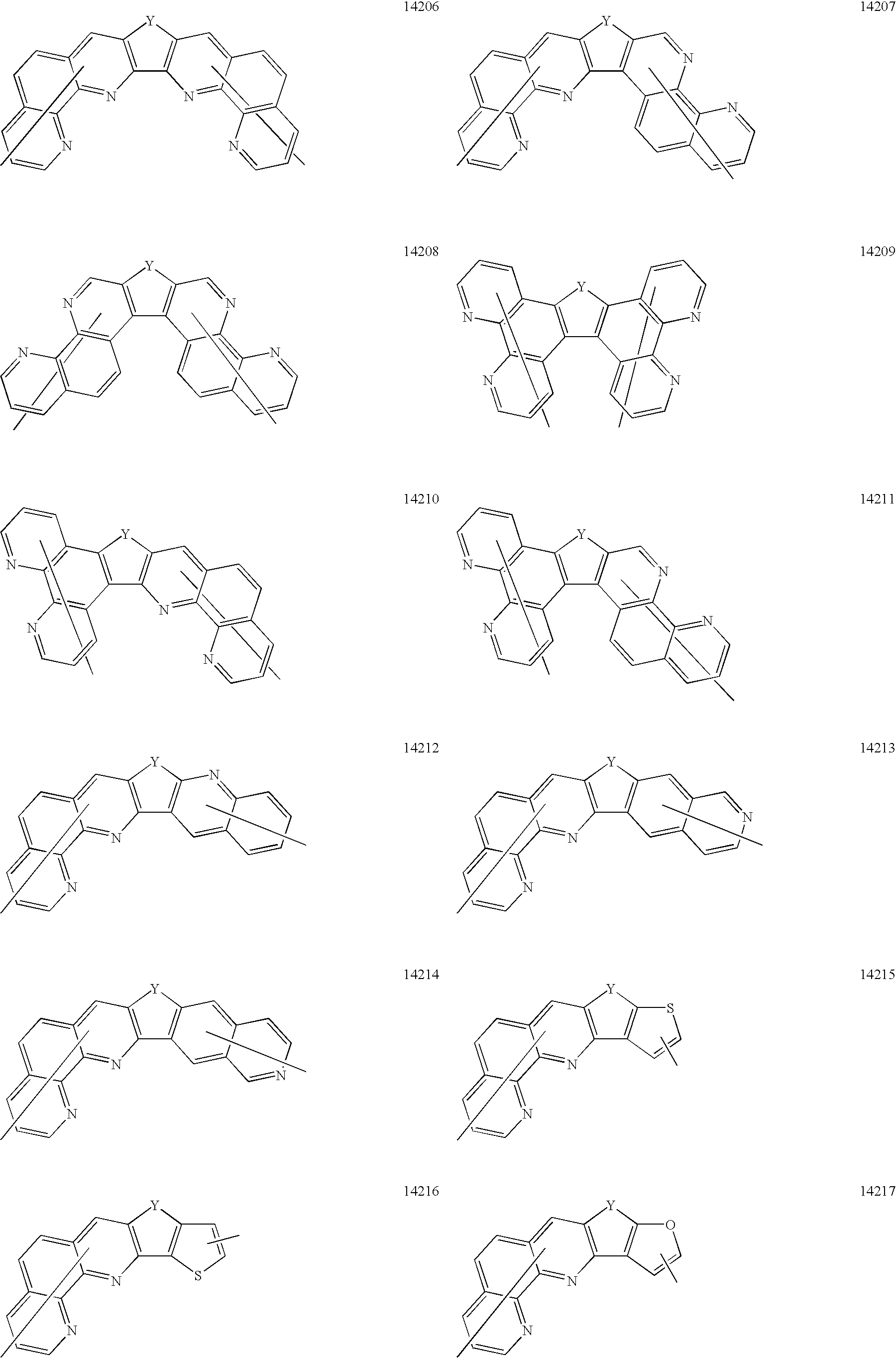

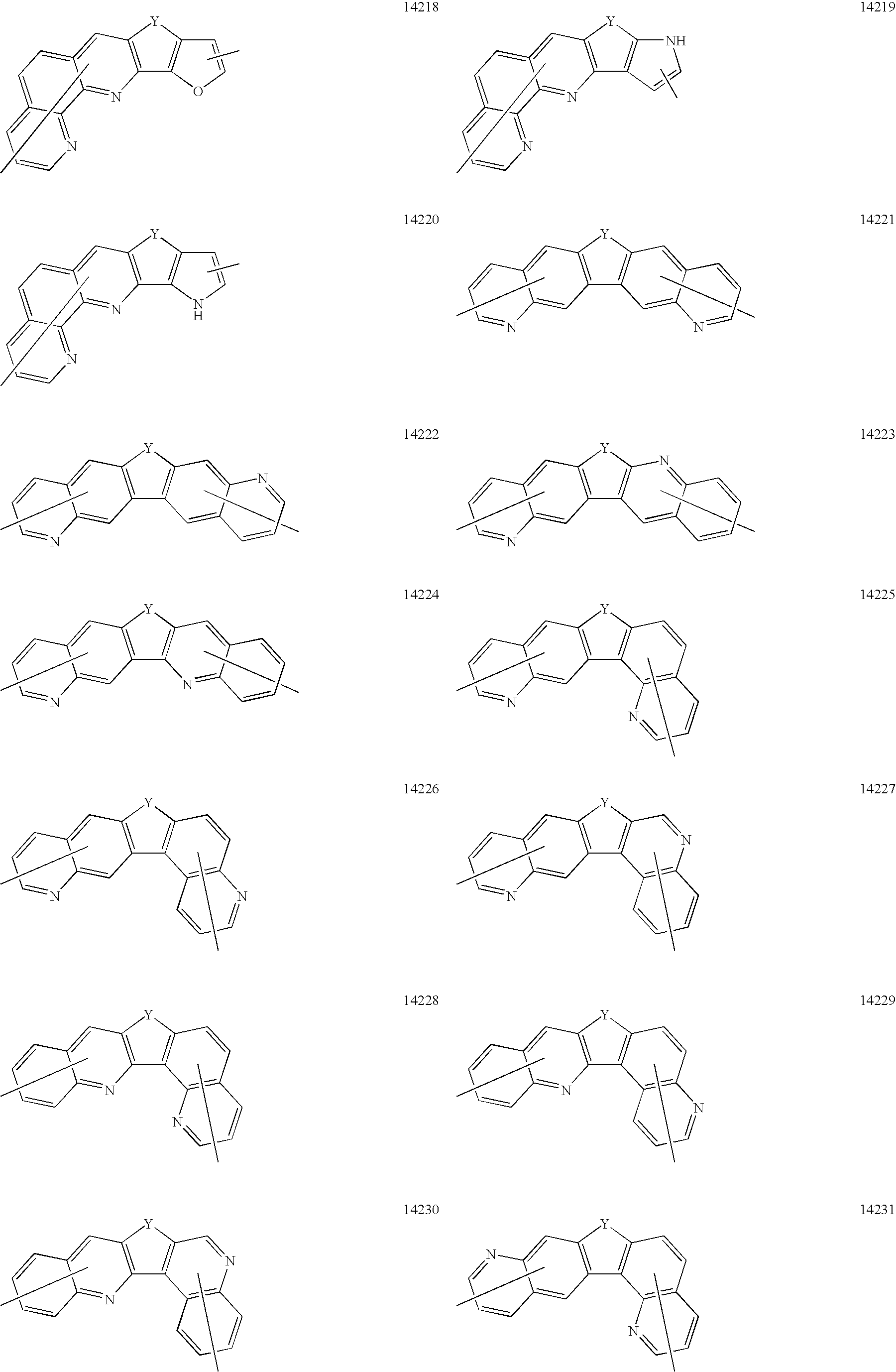

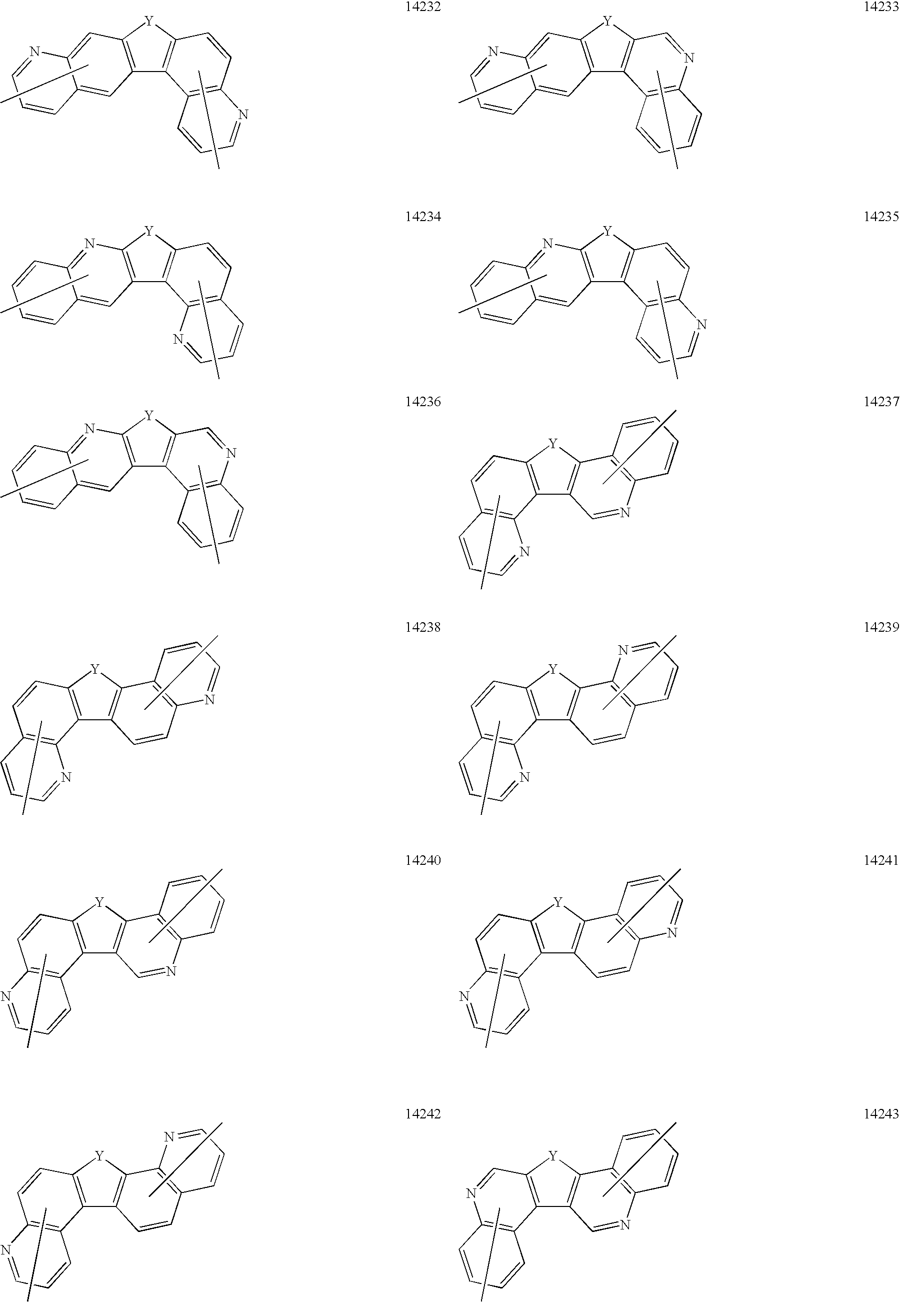

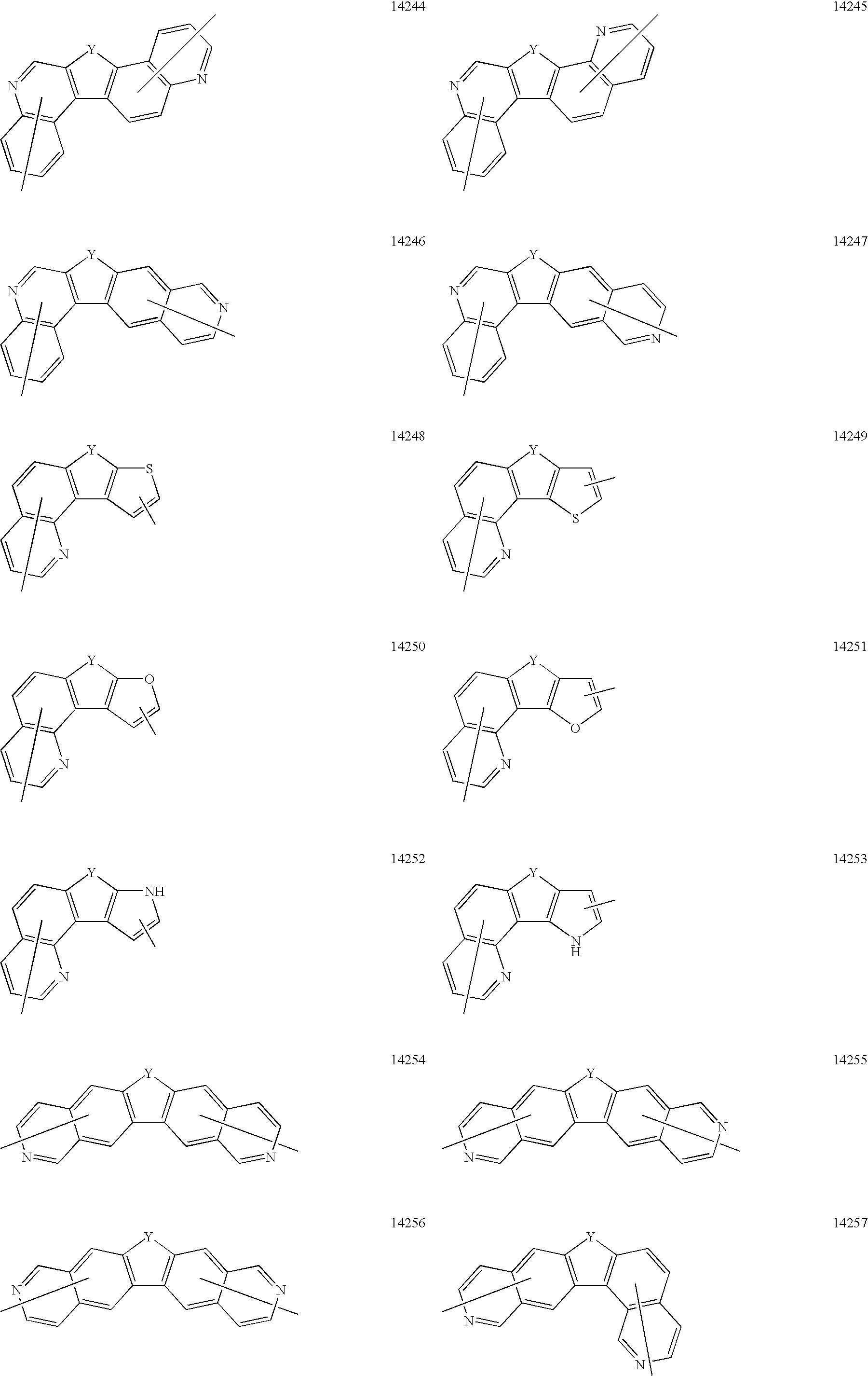

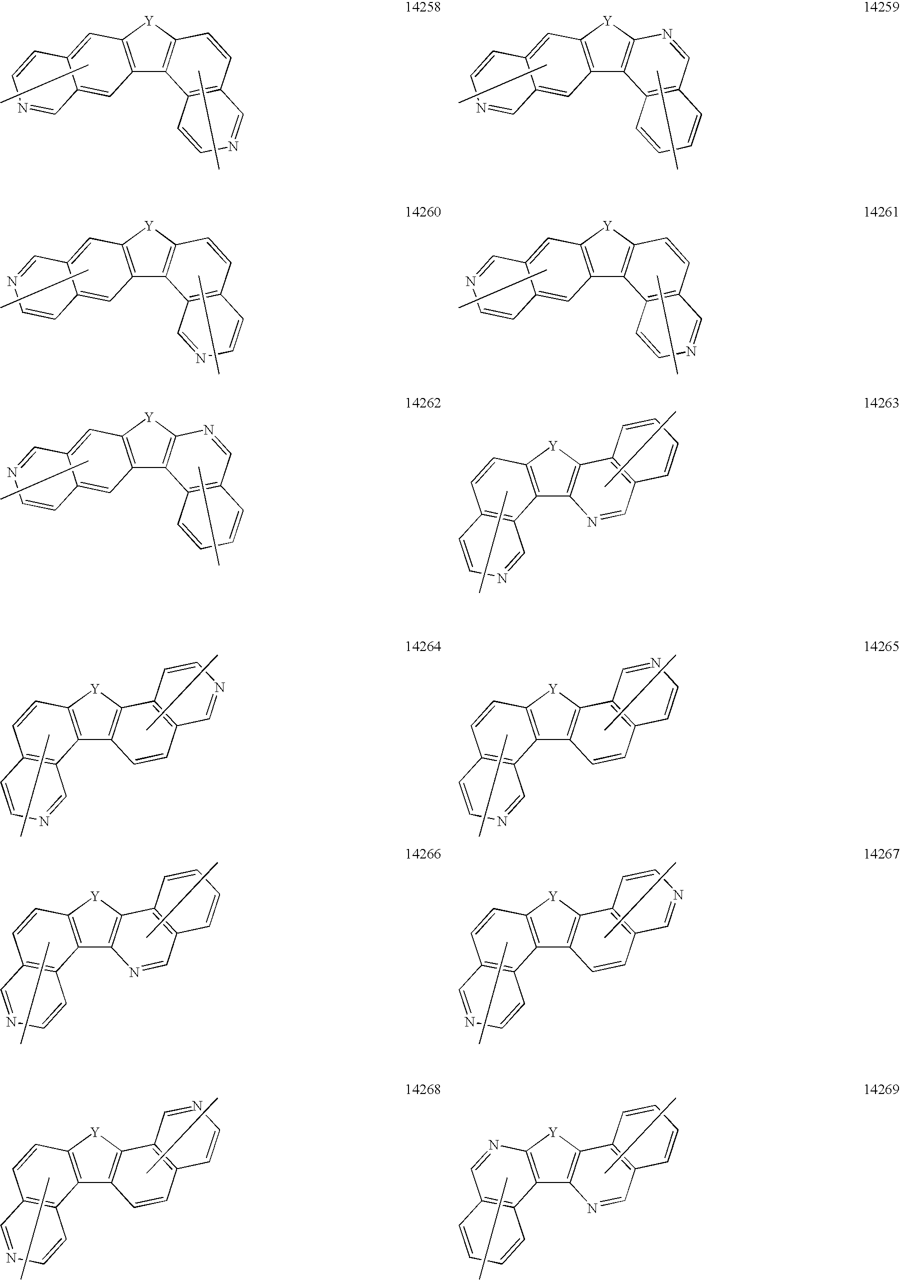

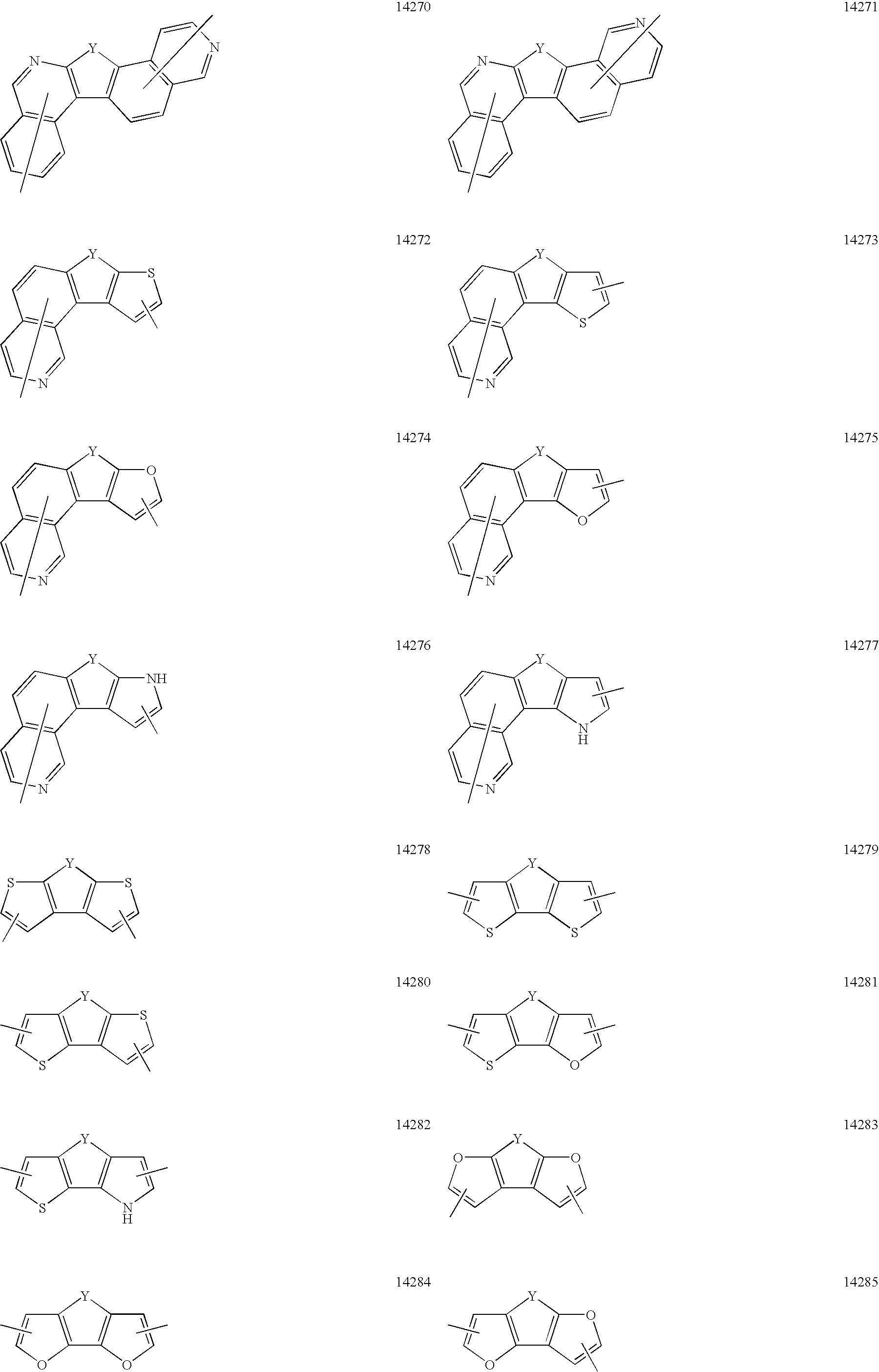

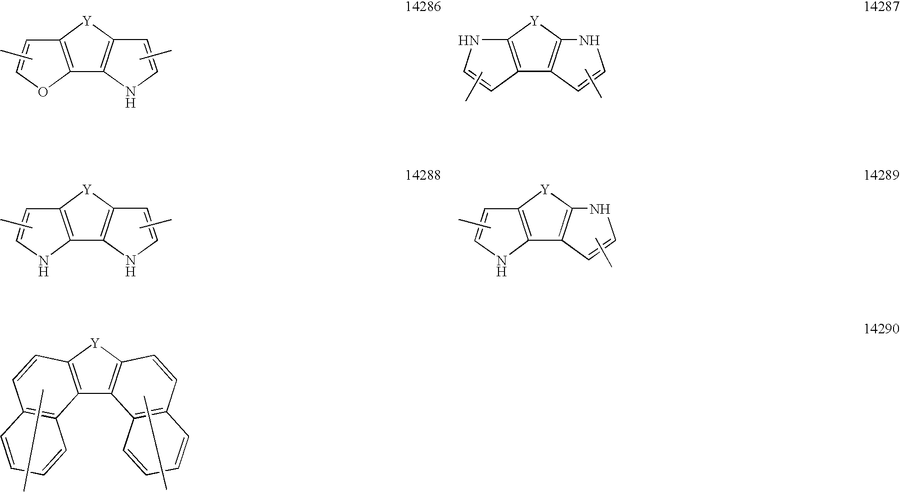

Specific examples of formula (1-5), shown as unsubstituted structure, include the followings.

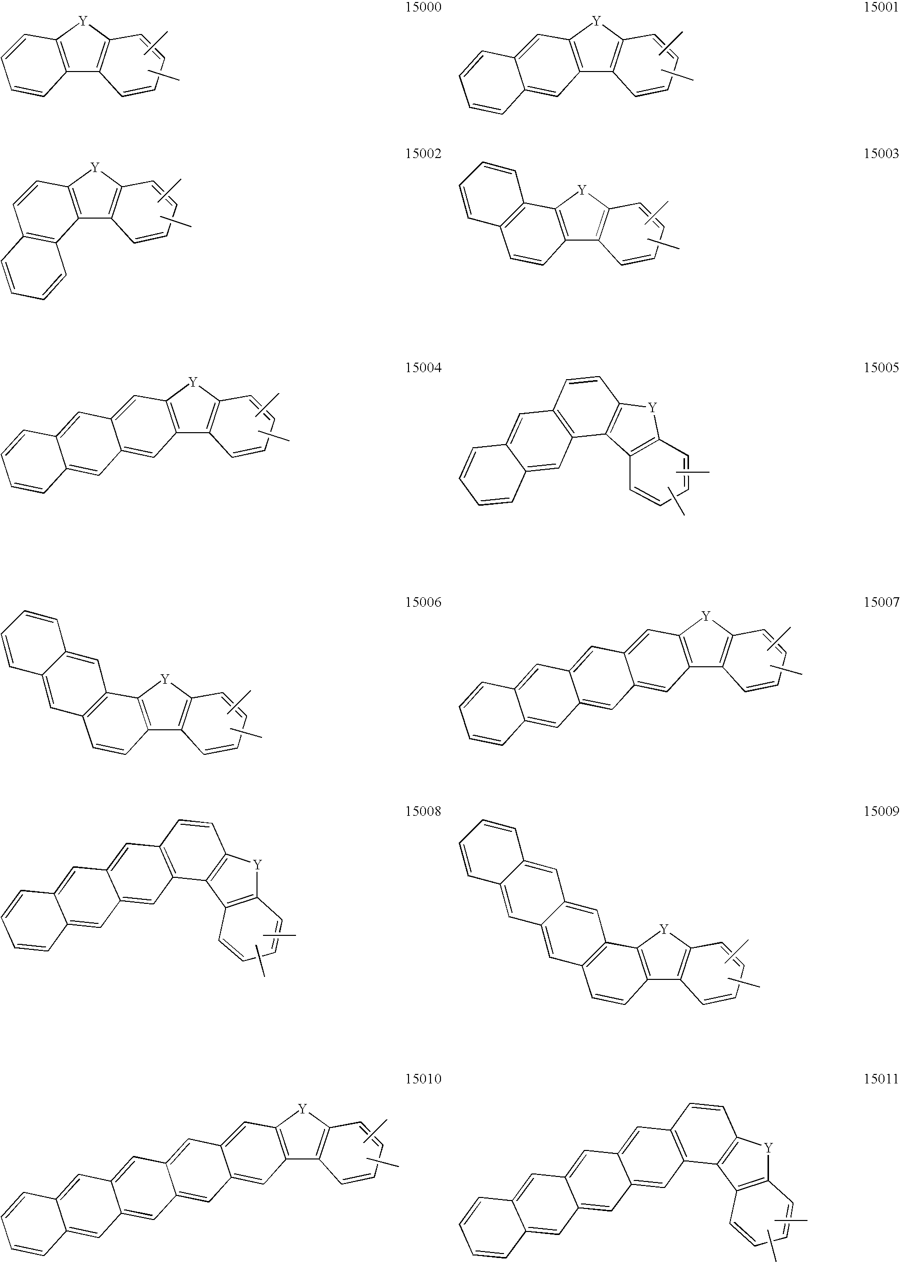

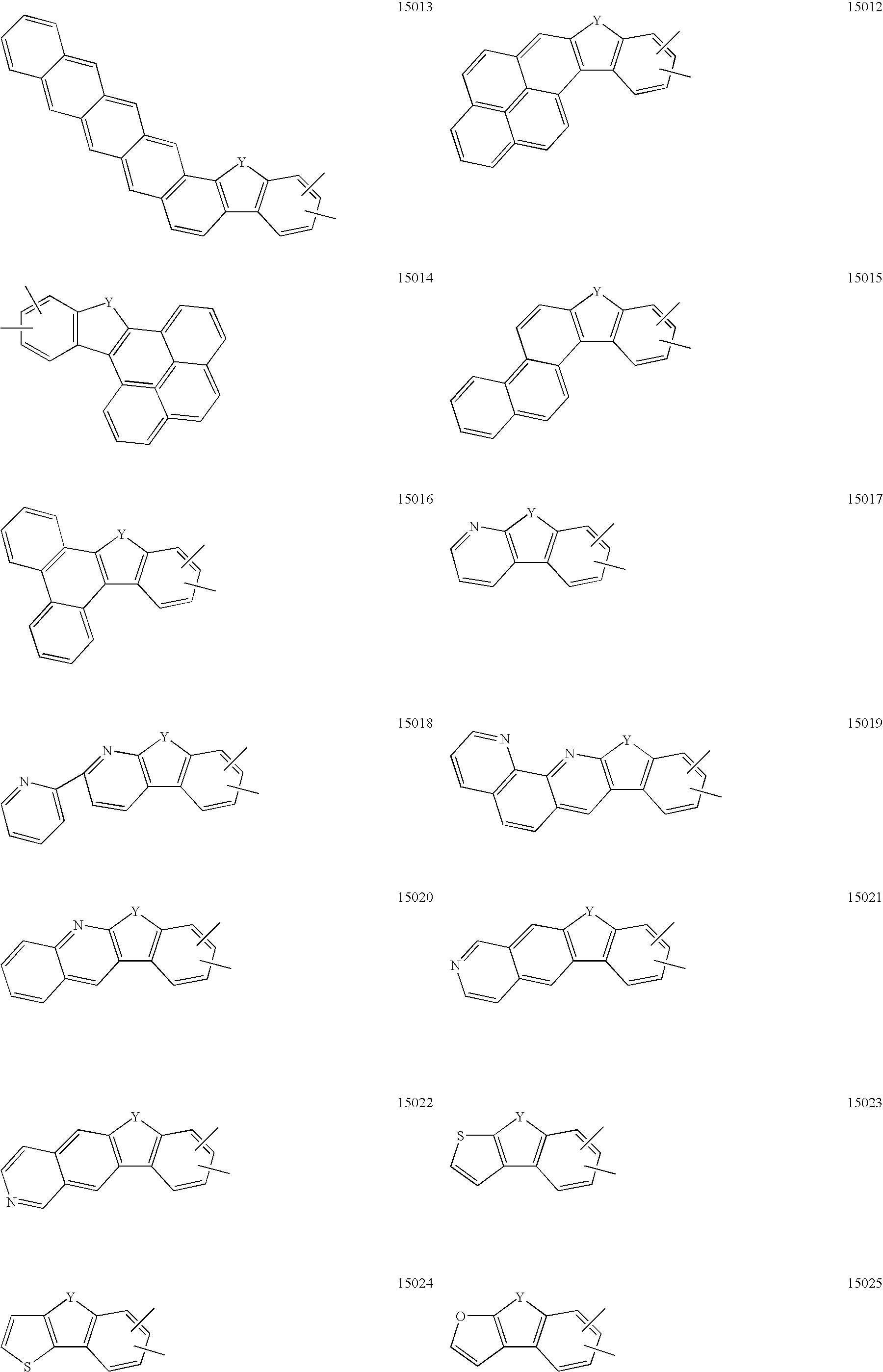

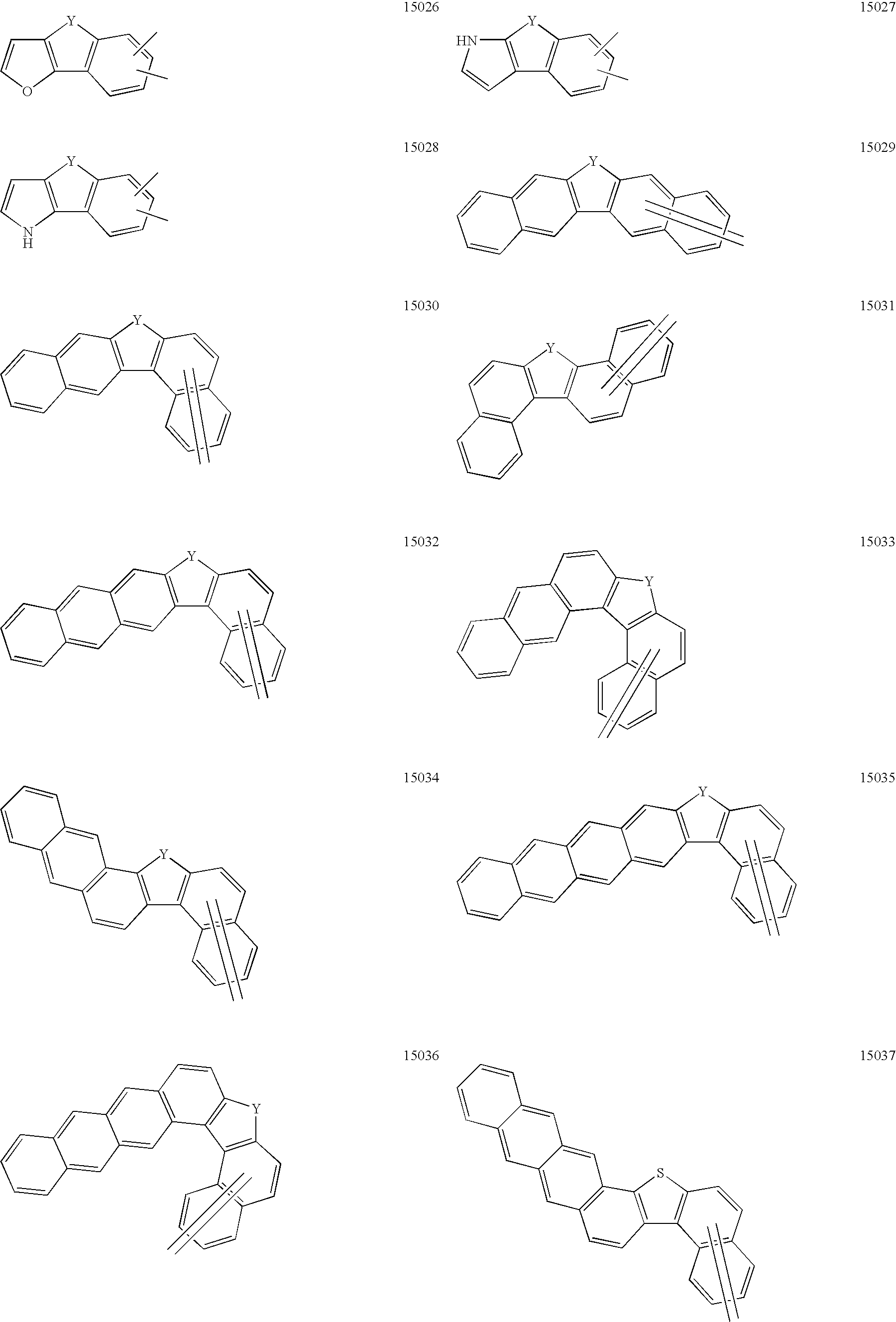

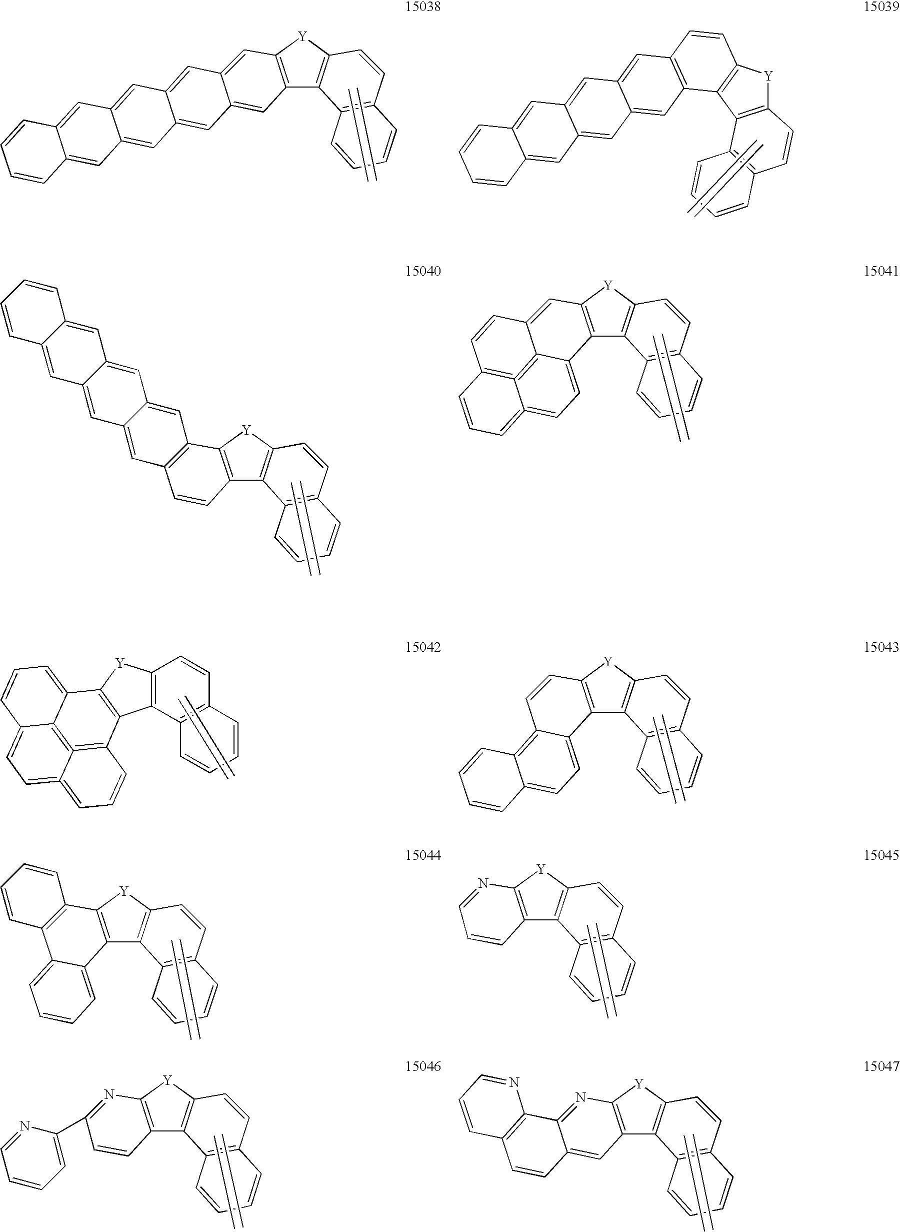

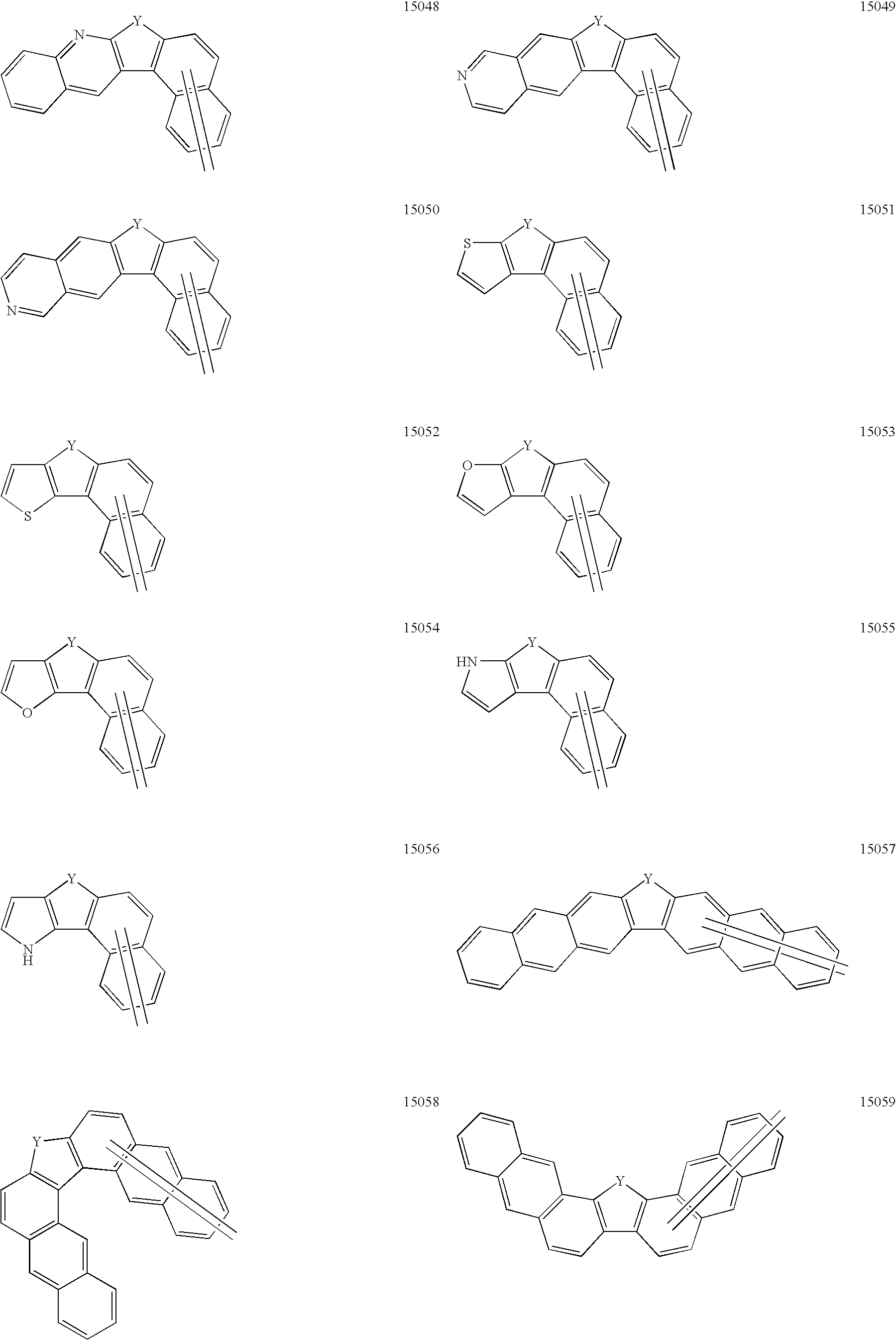

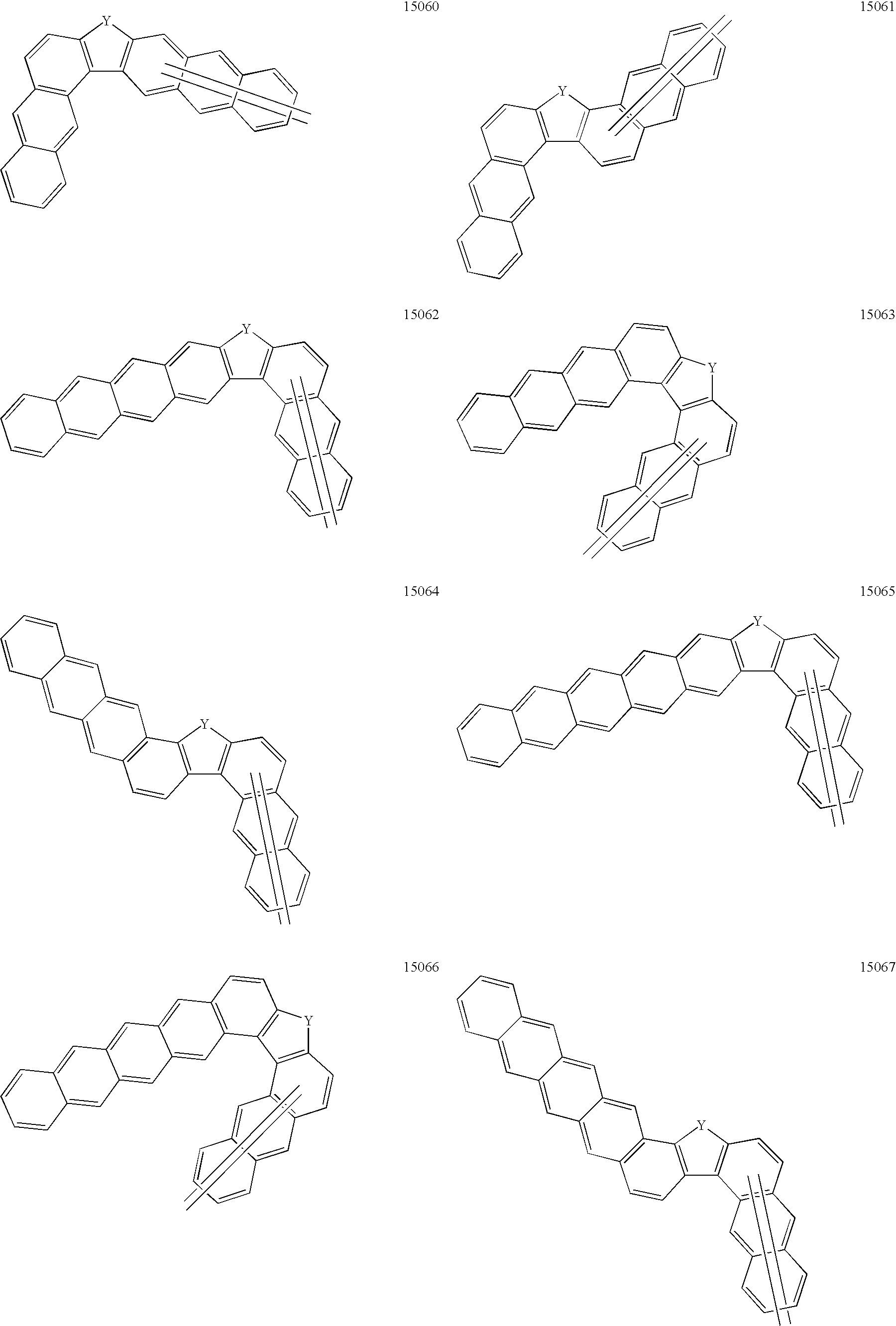

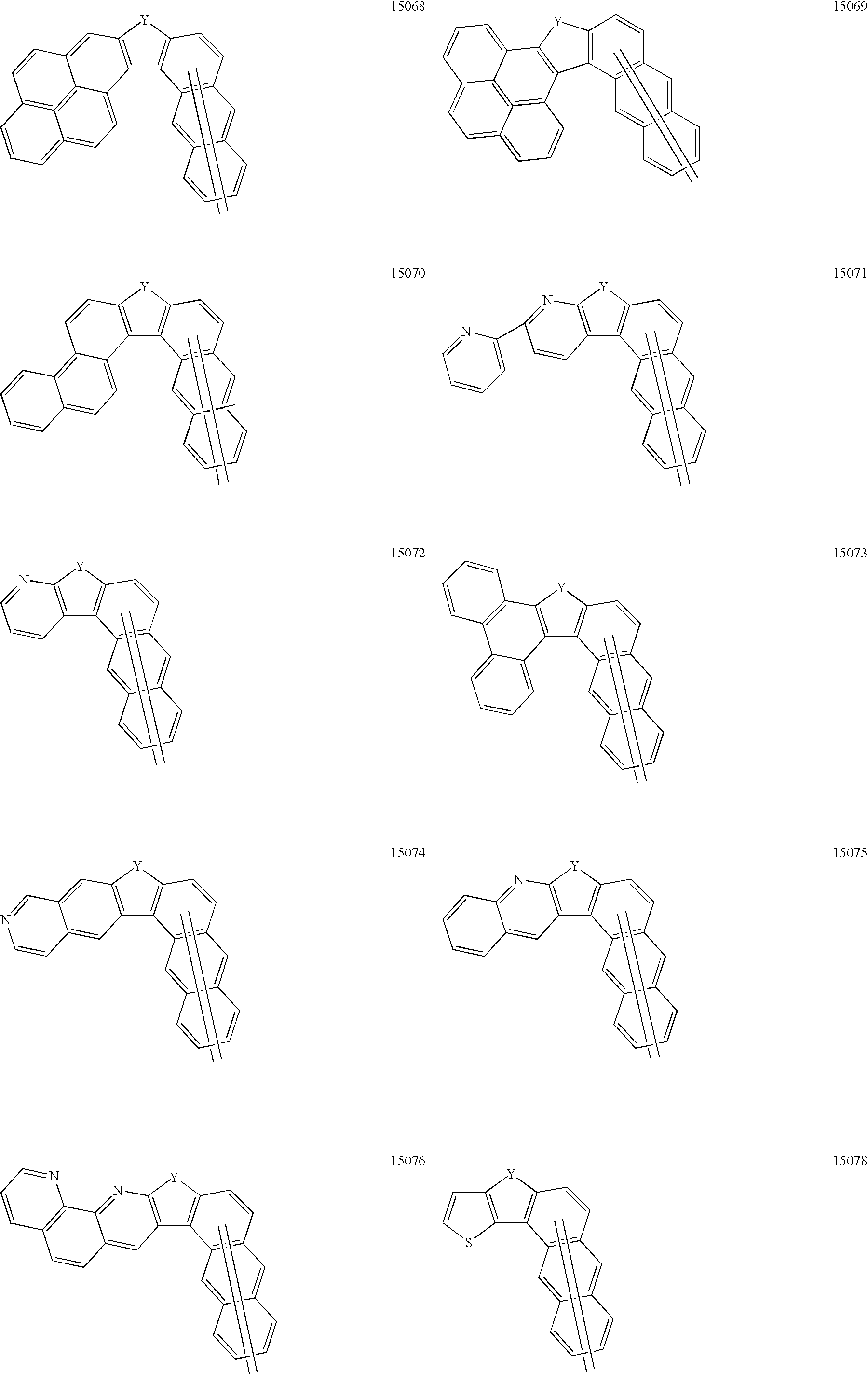

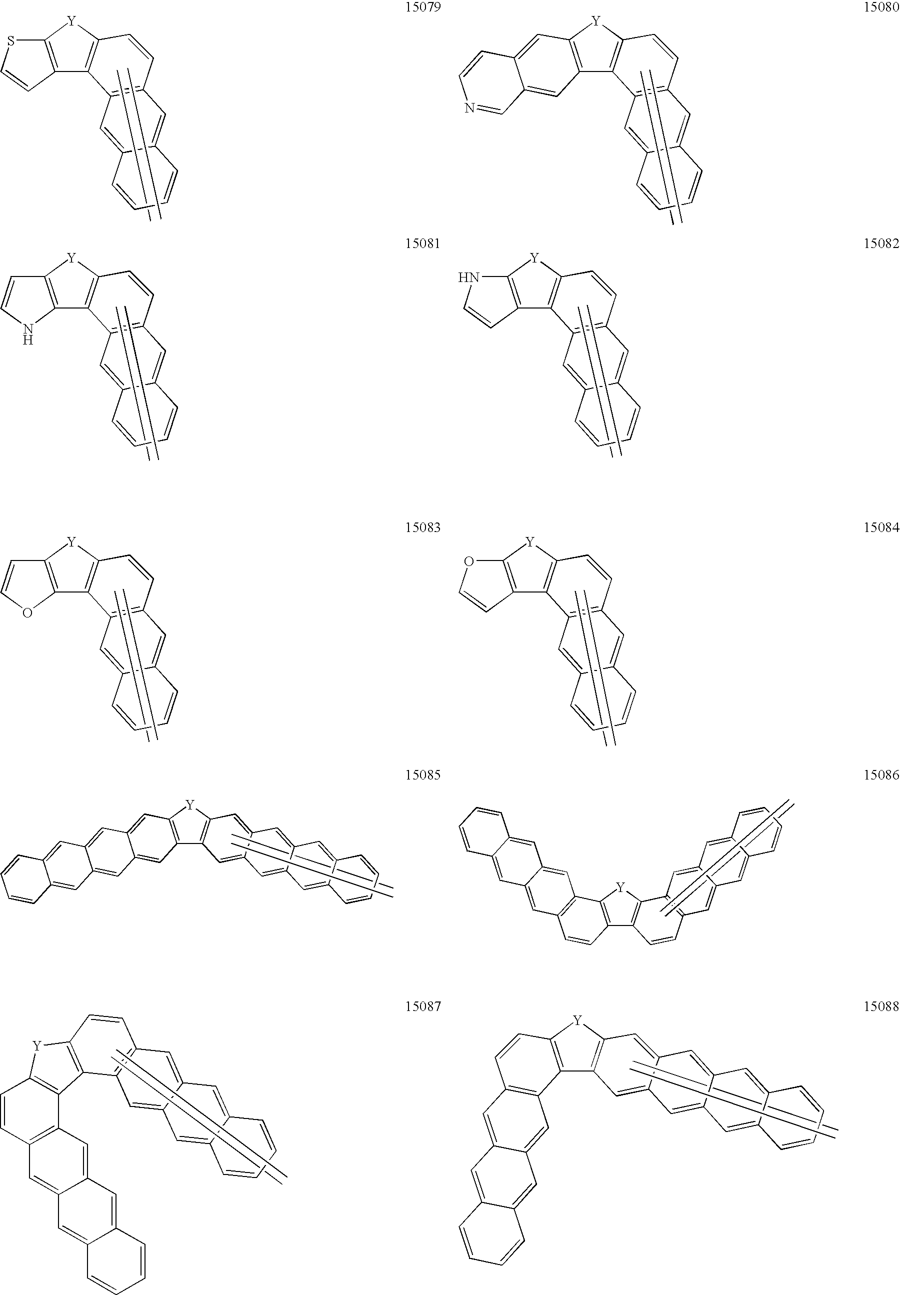

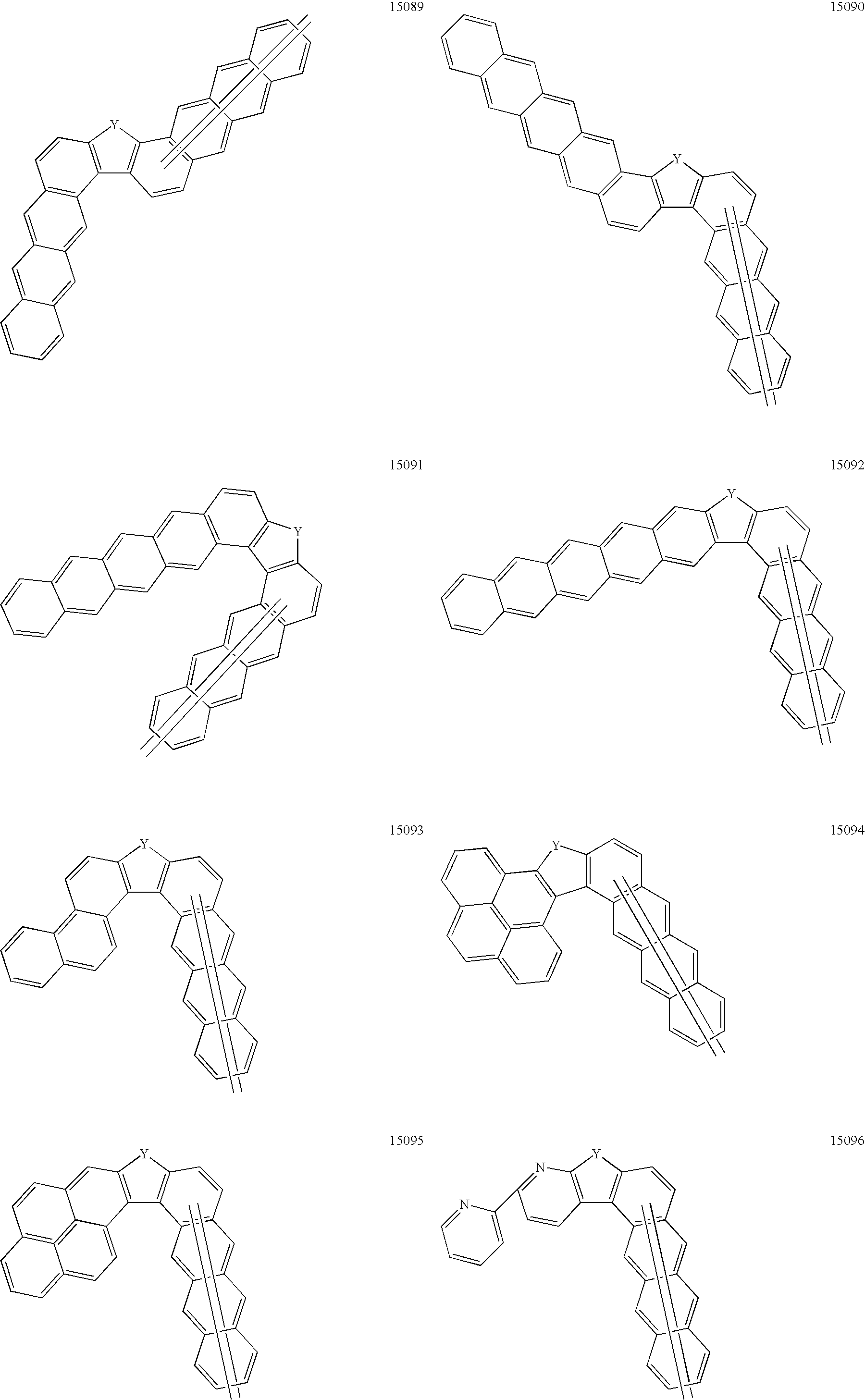

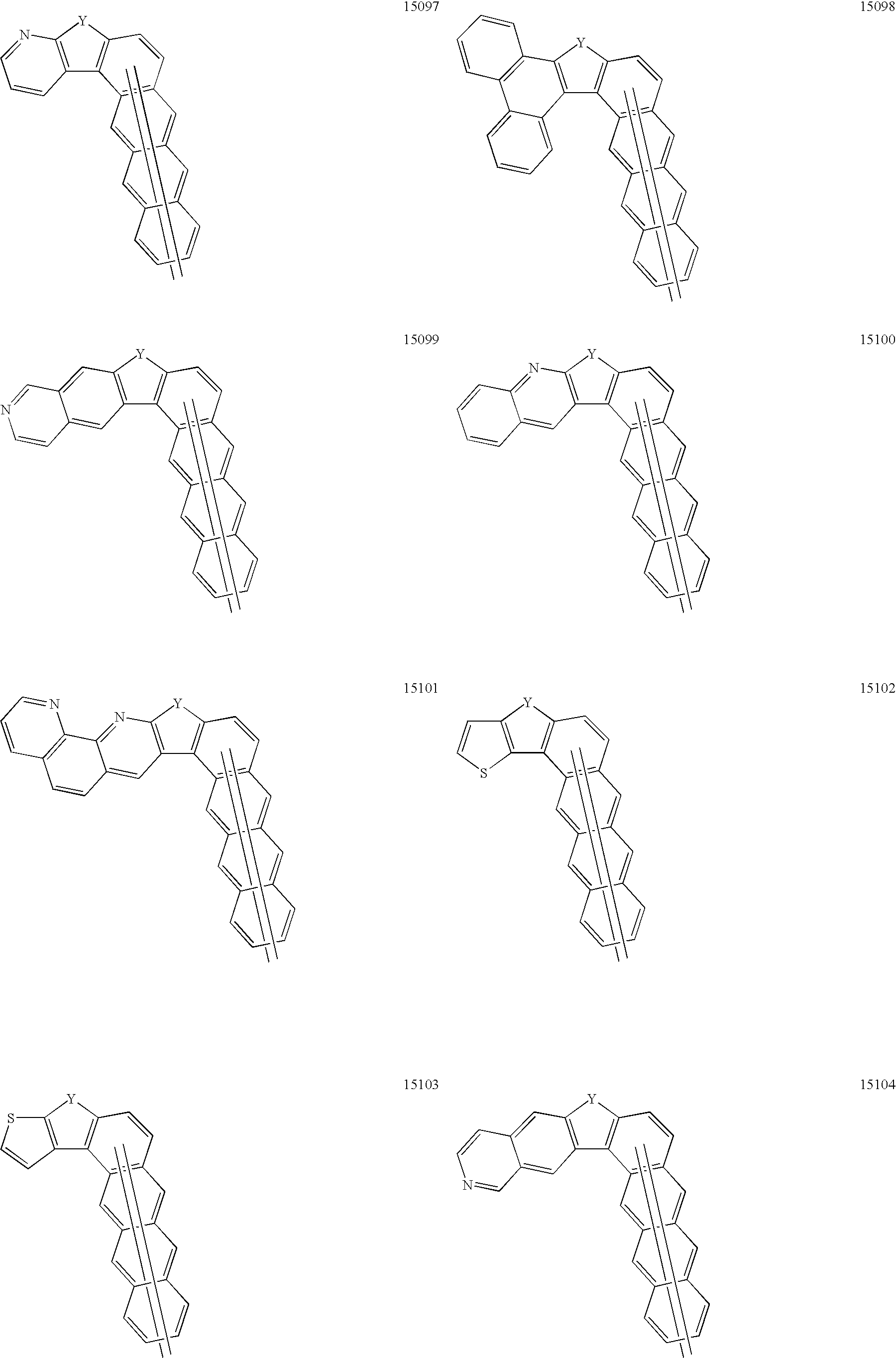

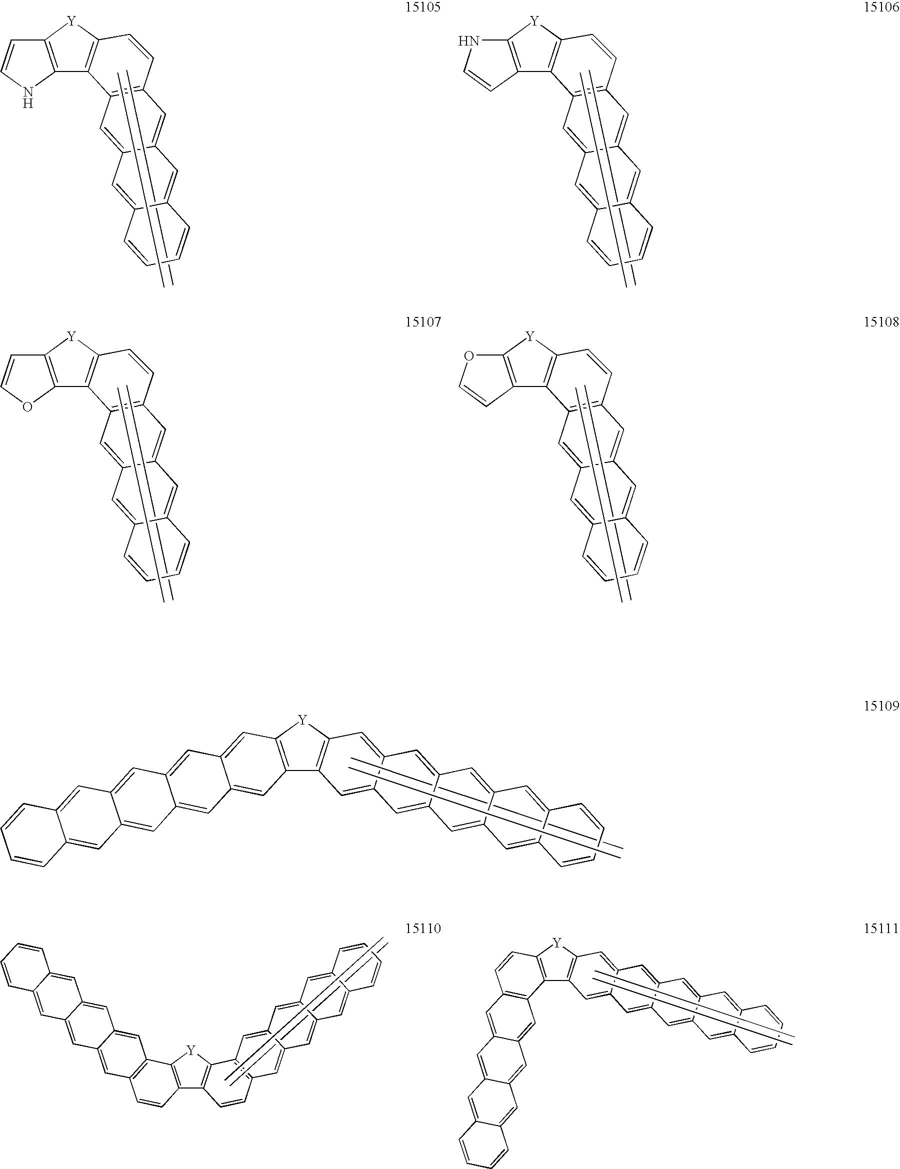

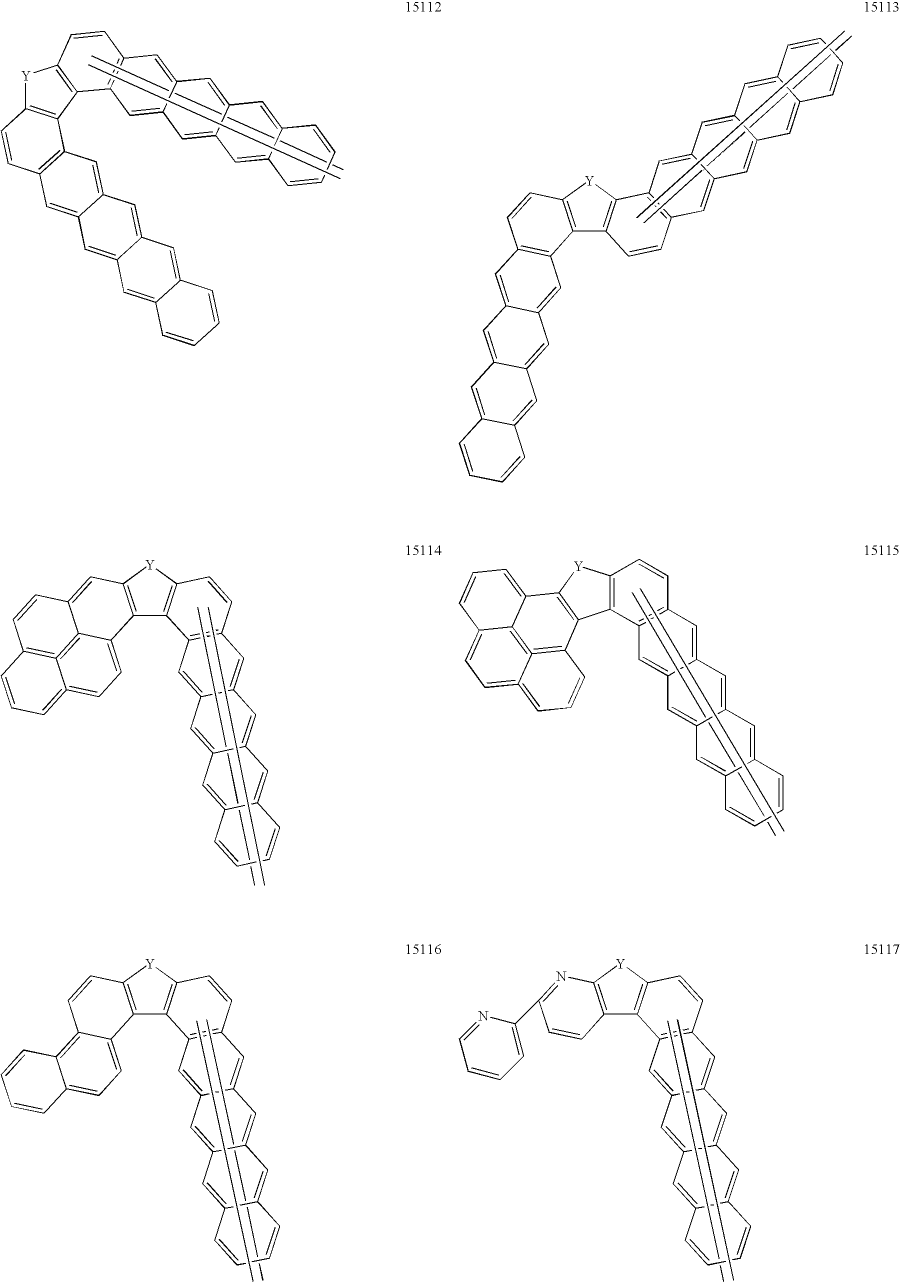

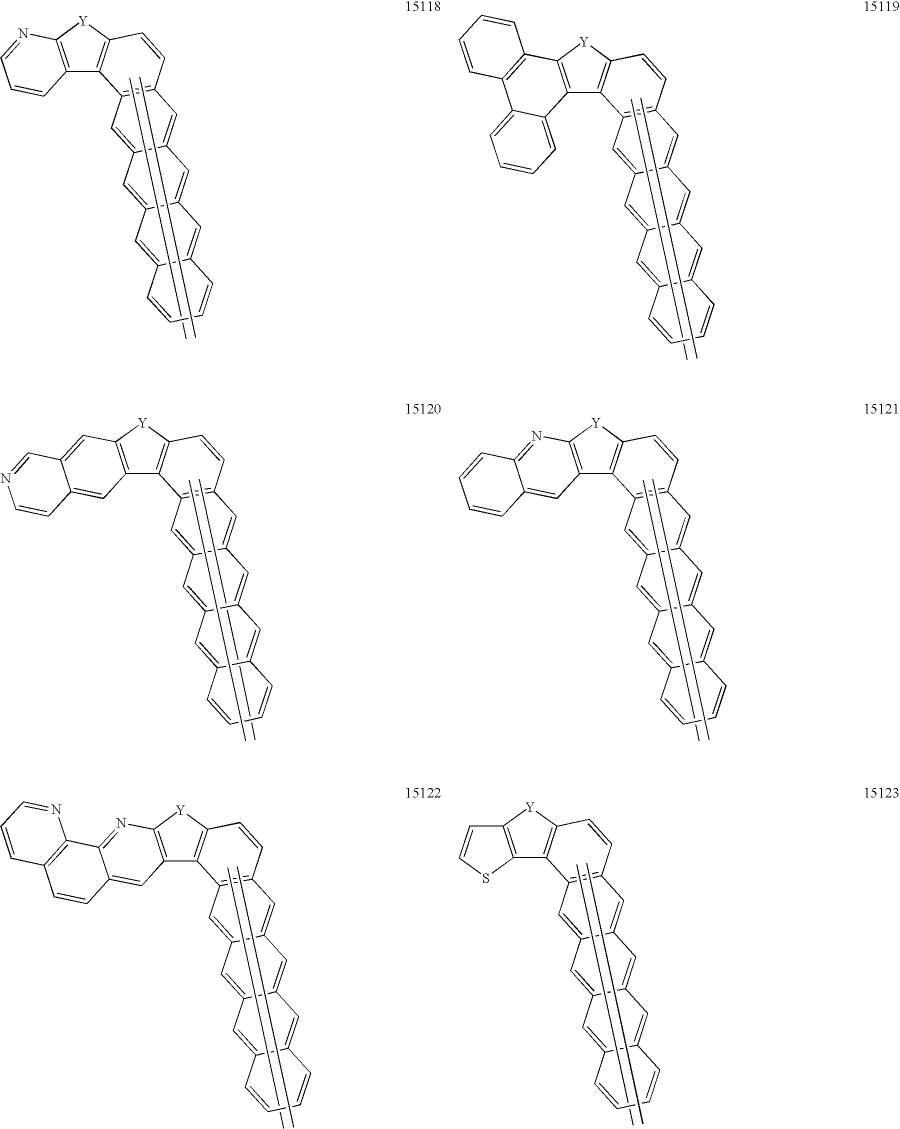

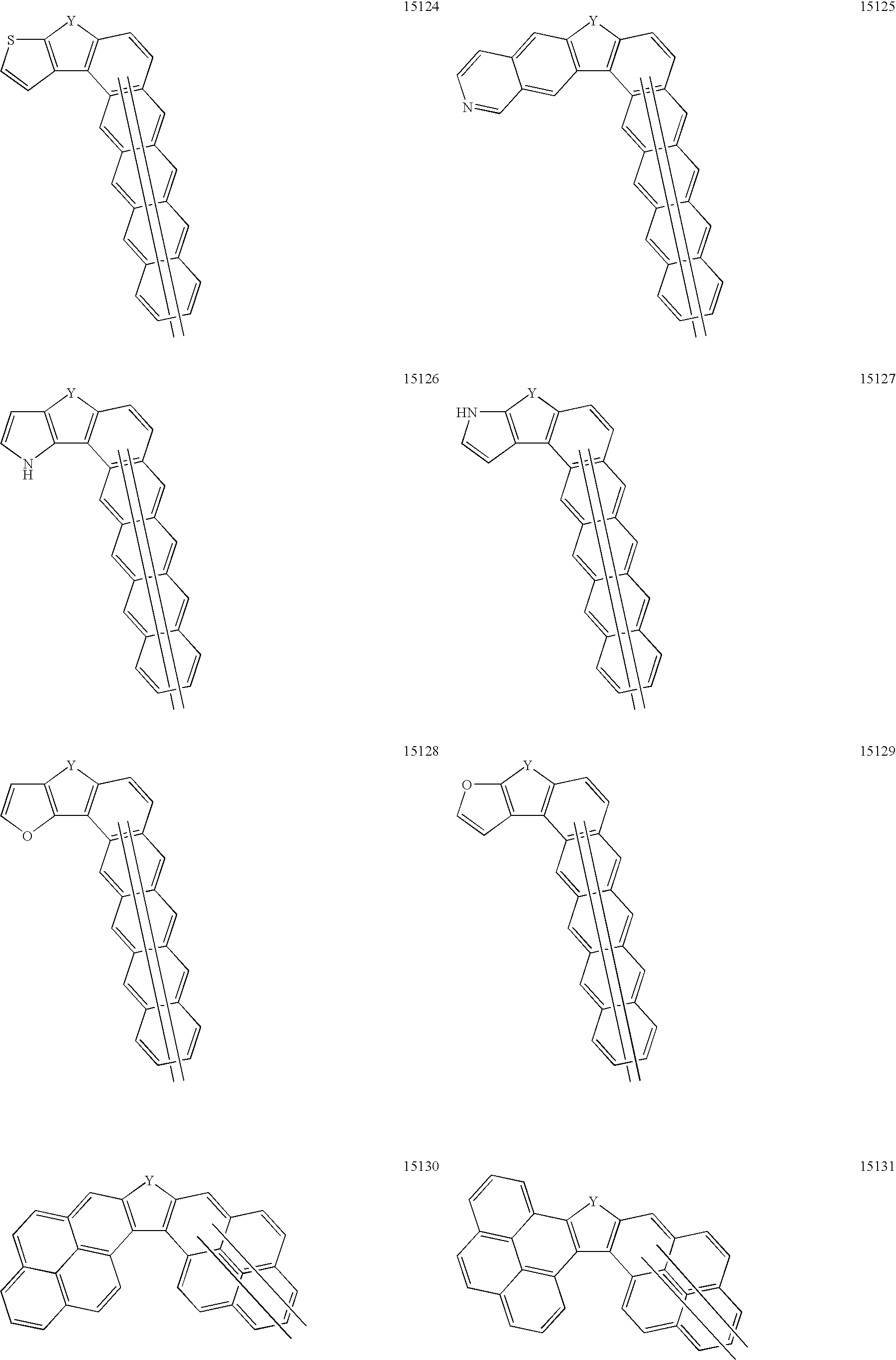

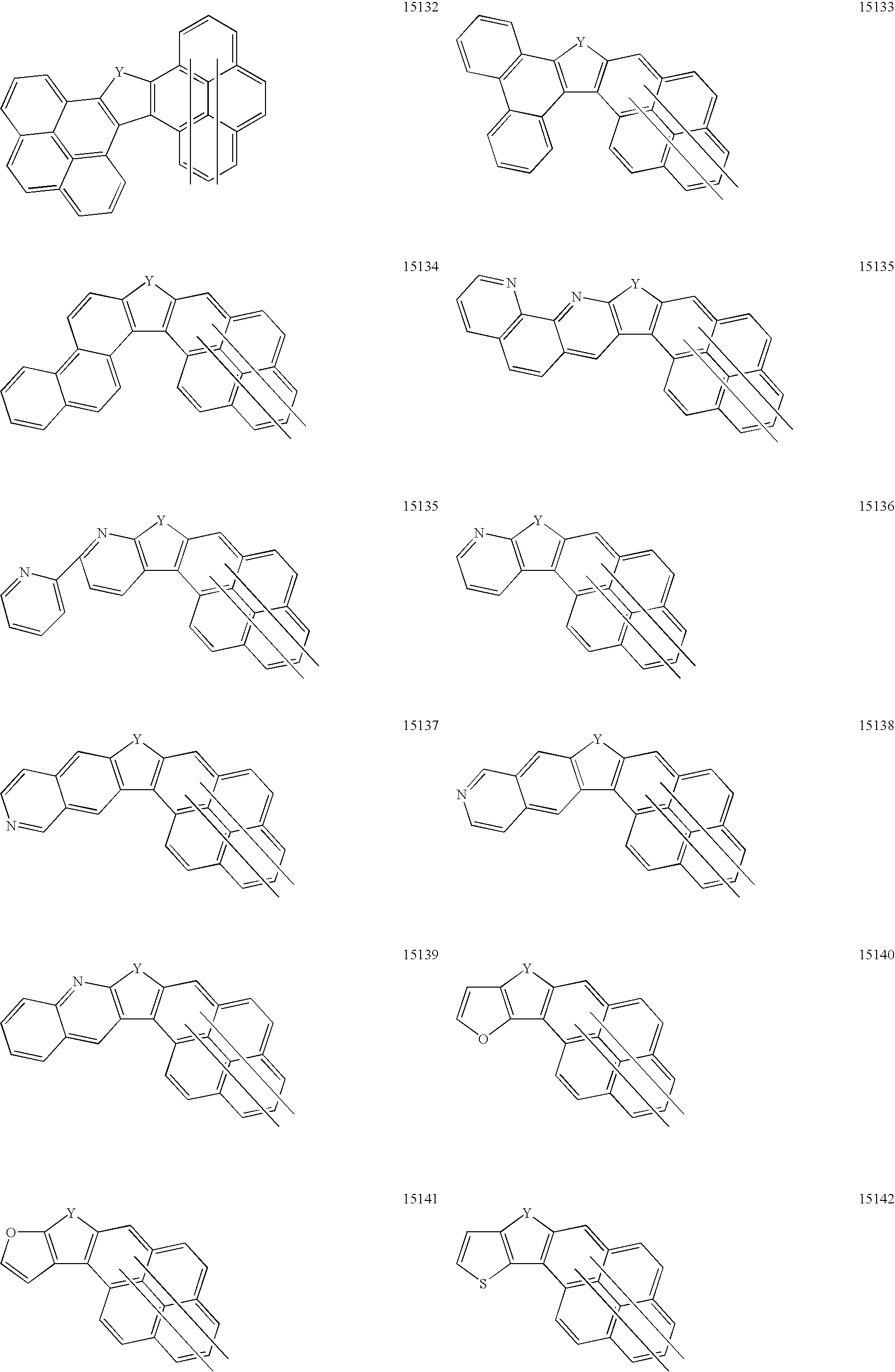

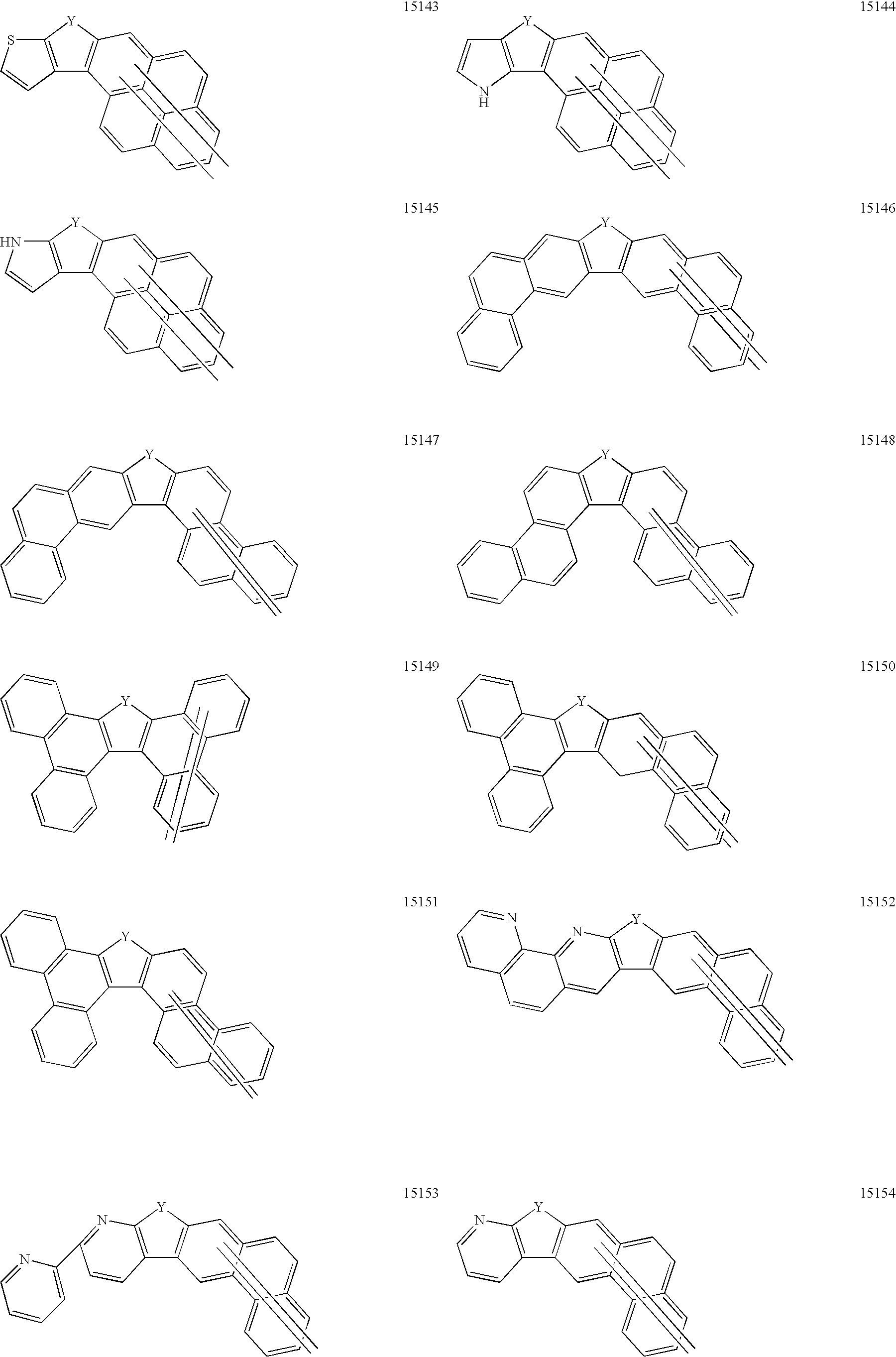

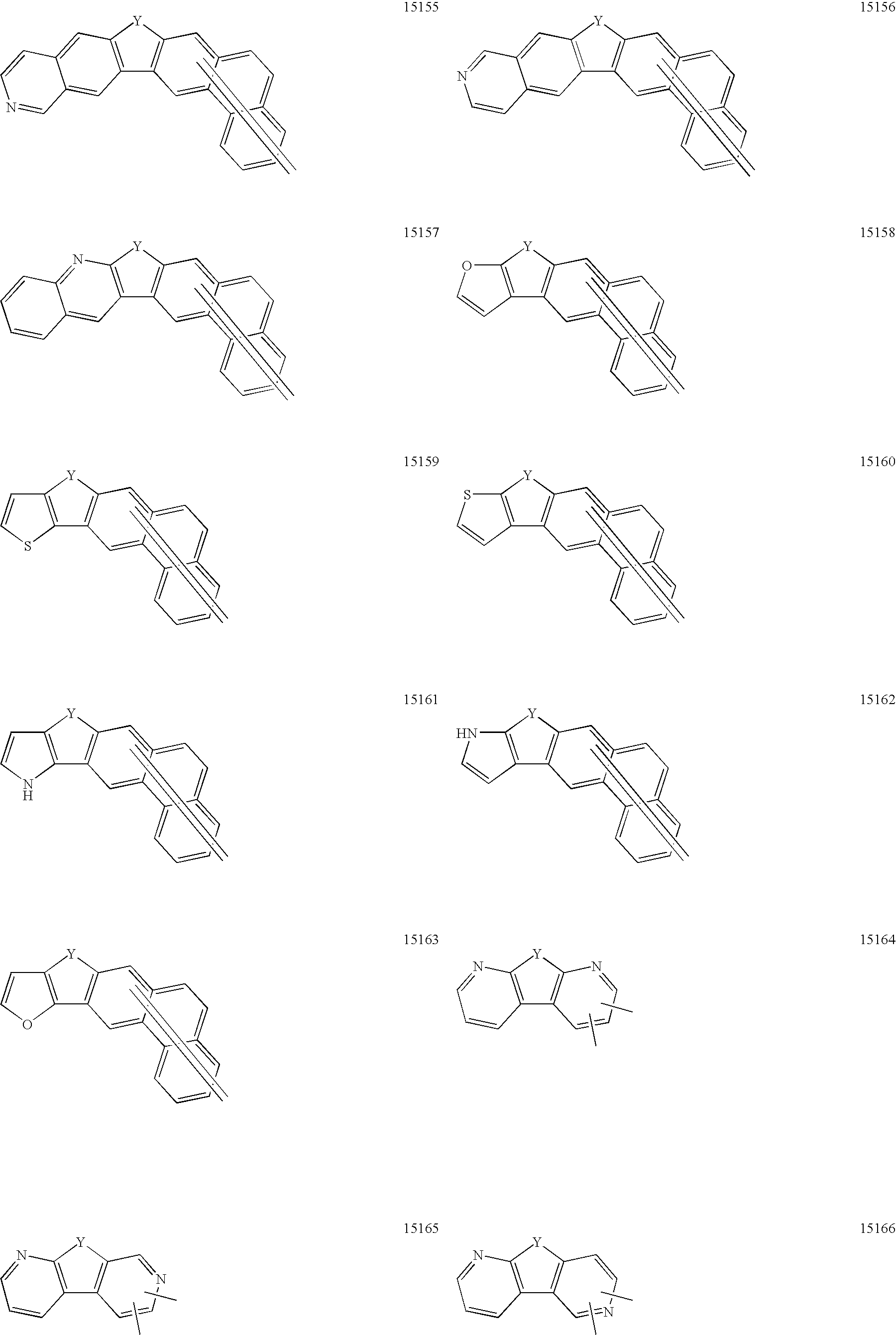

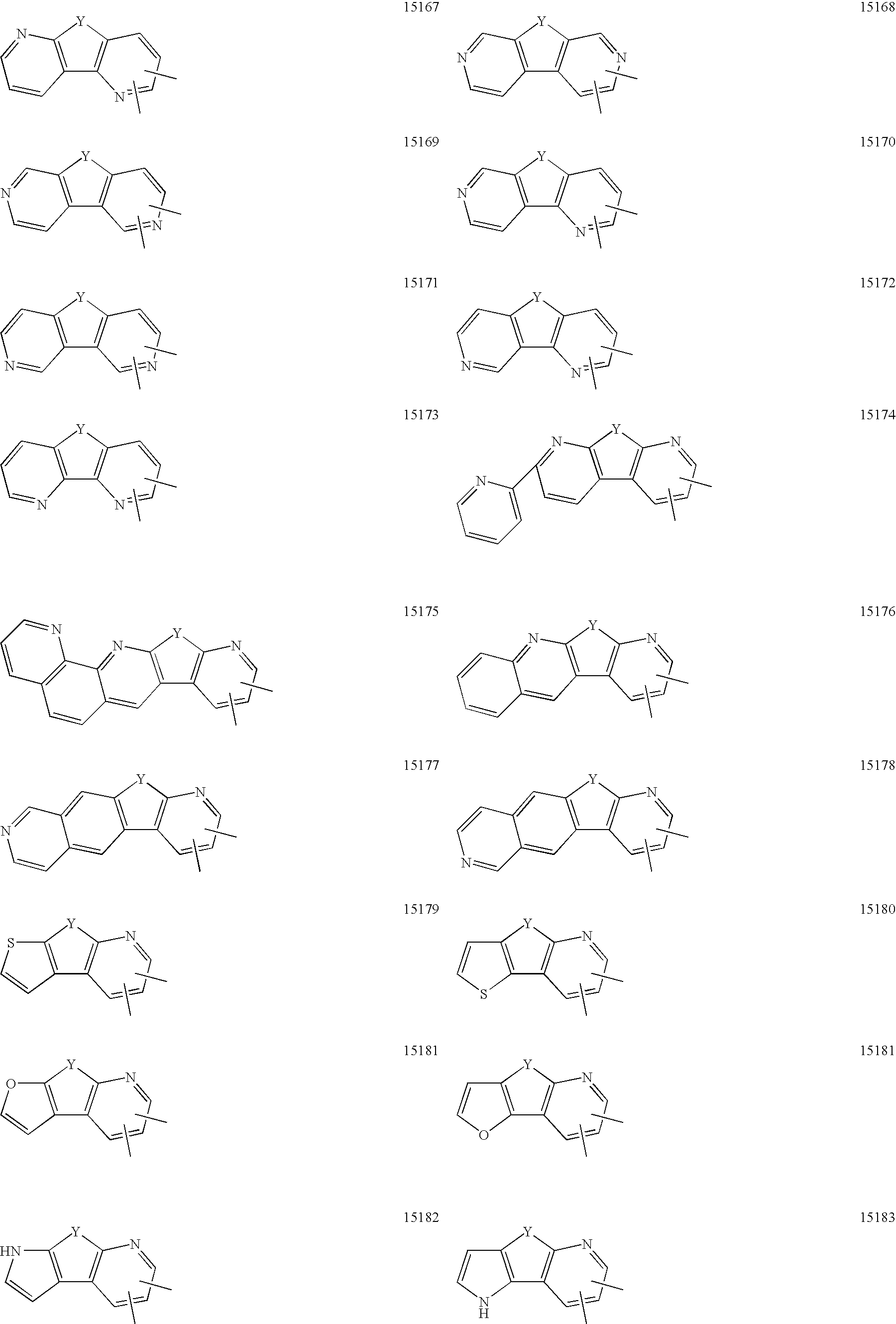

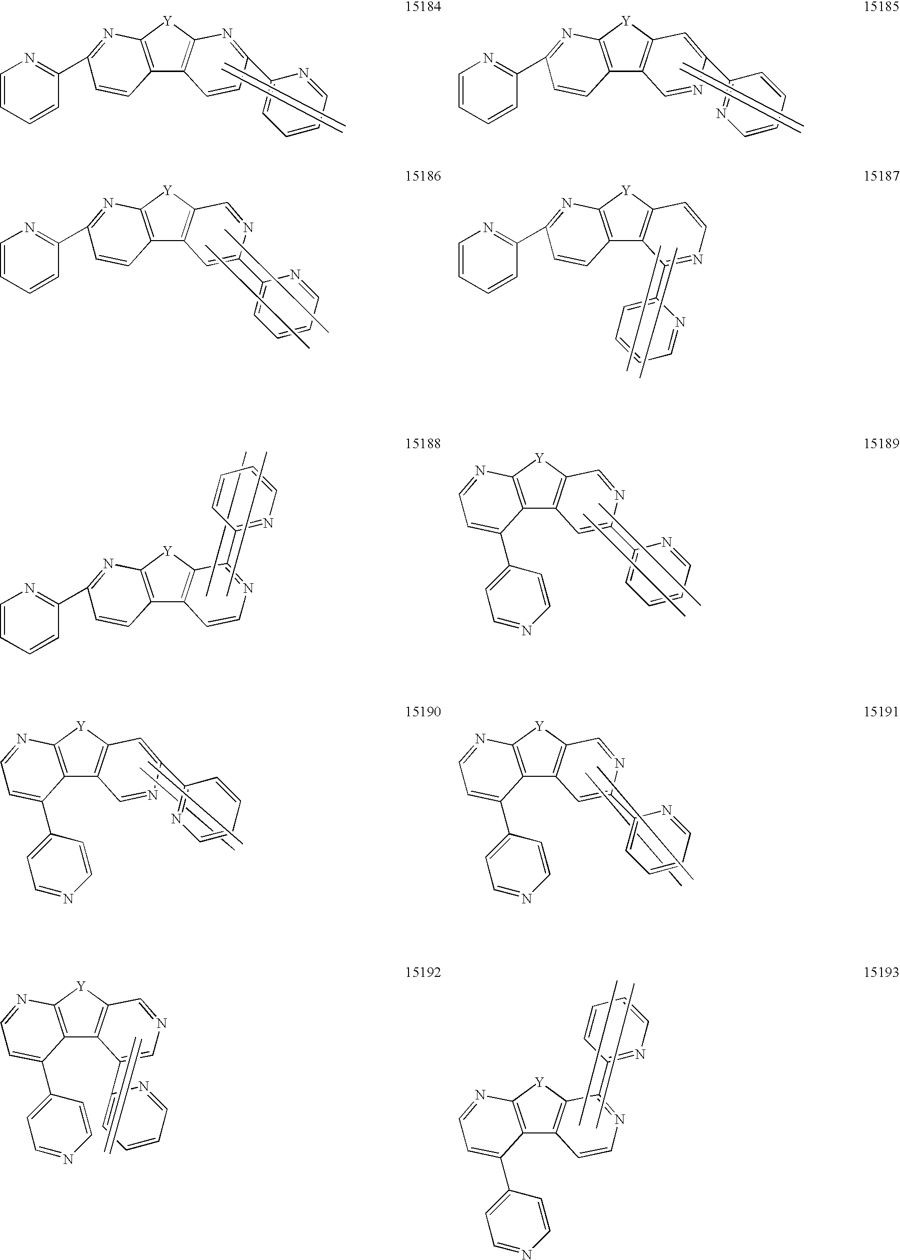

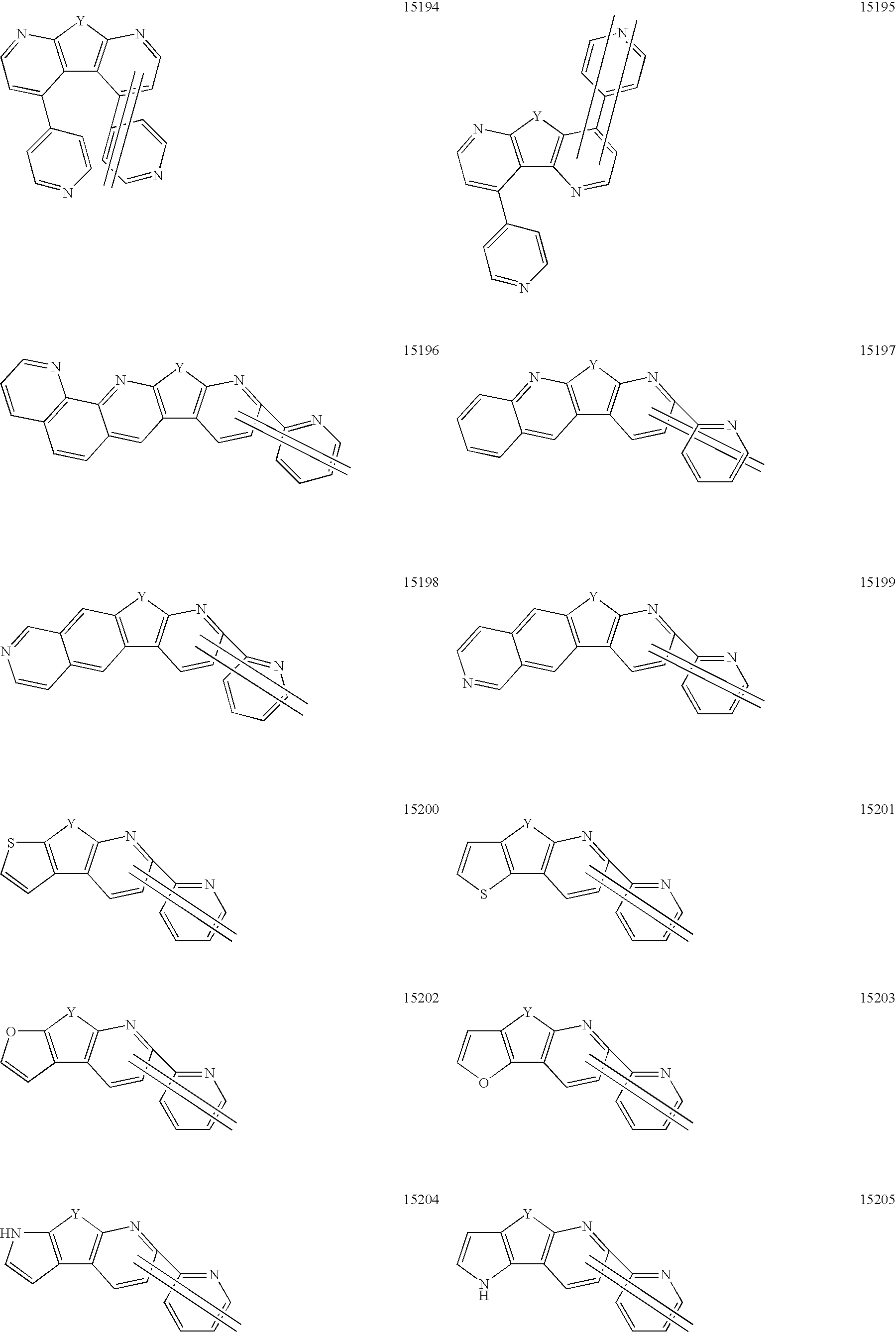

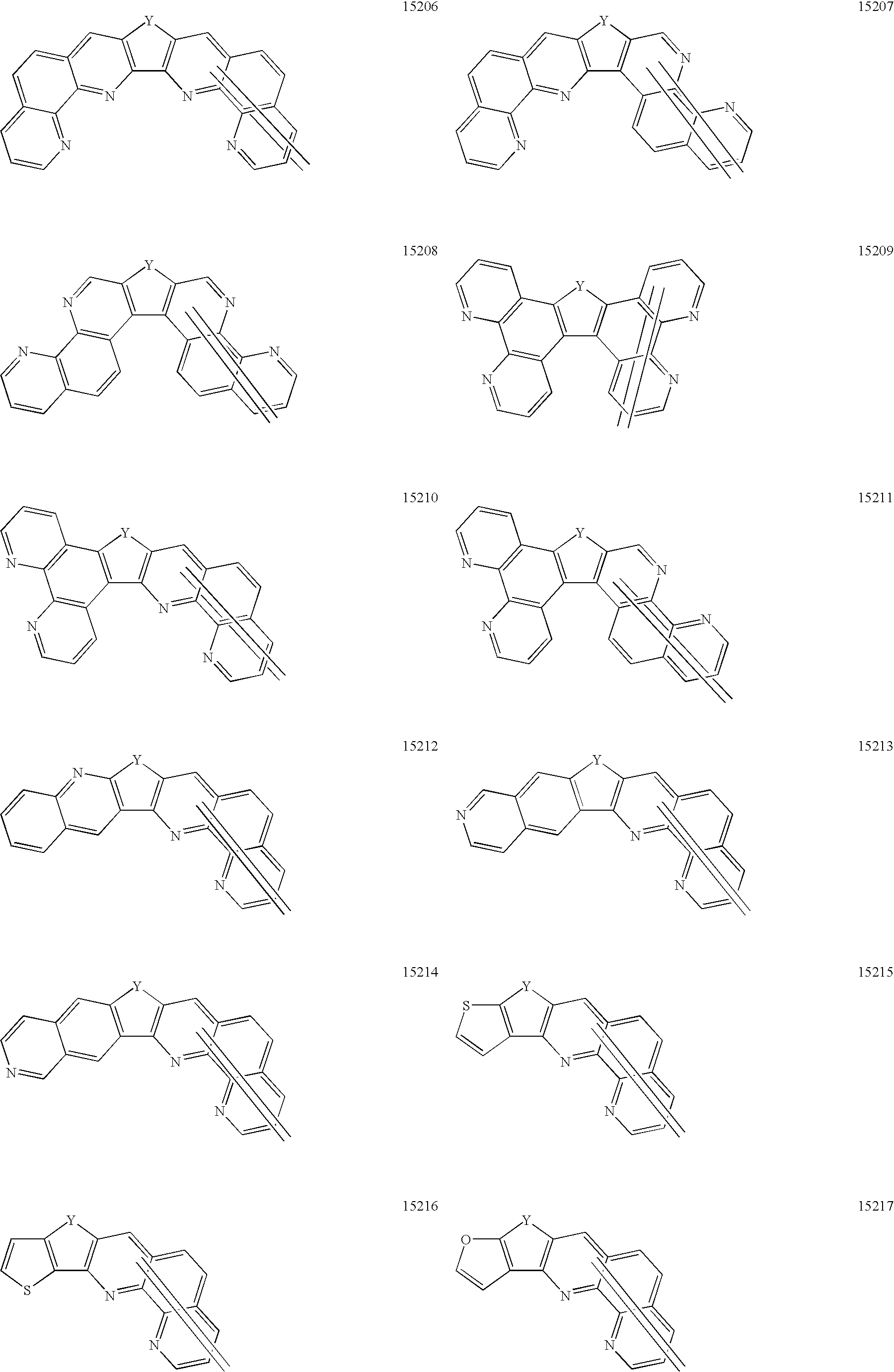

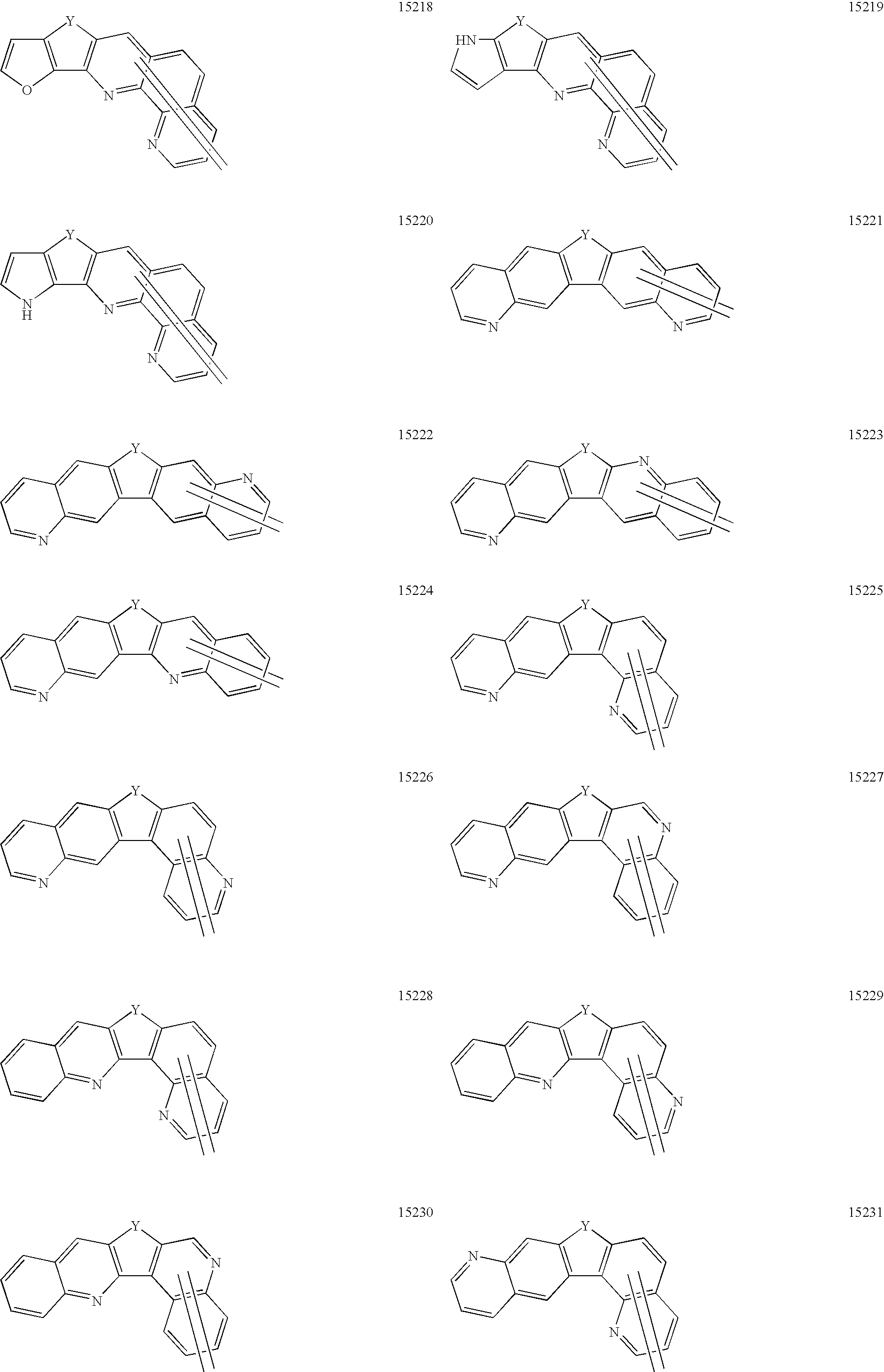

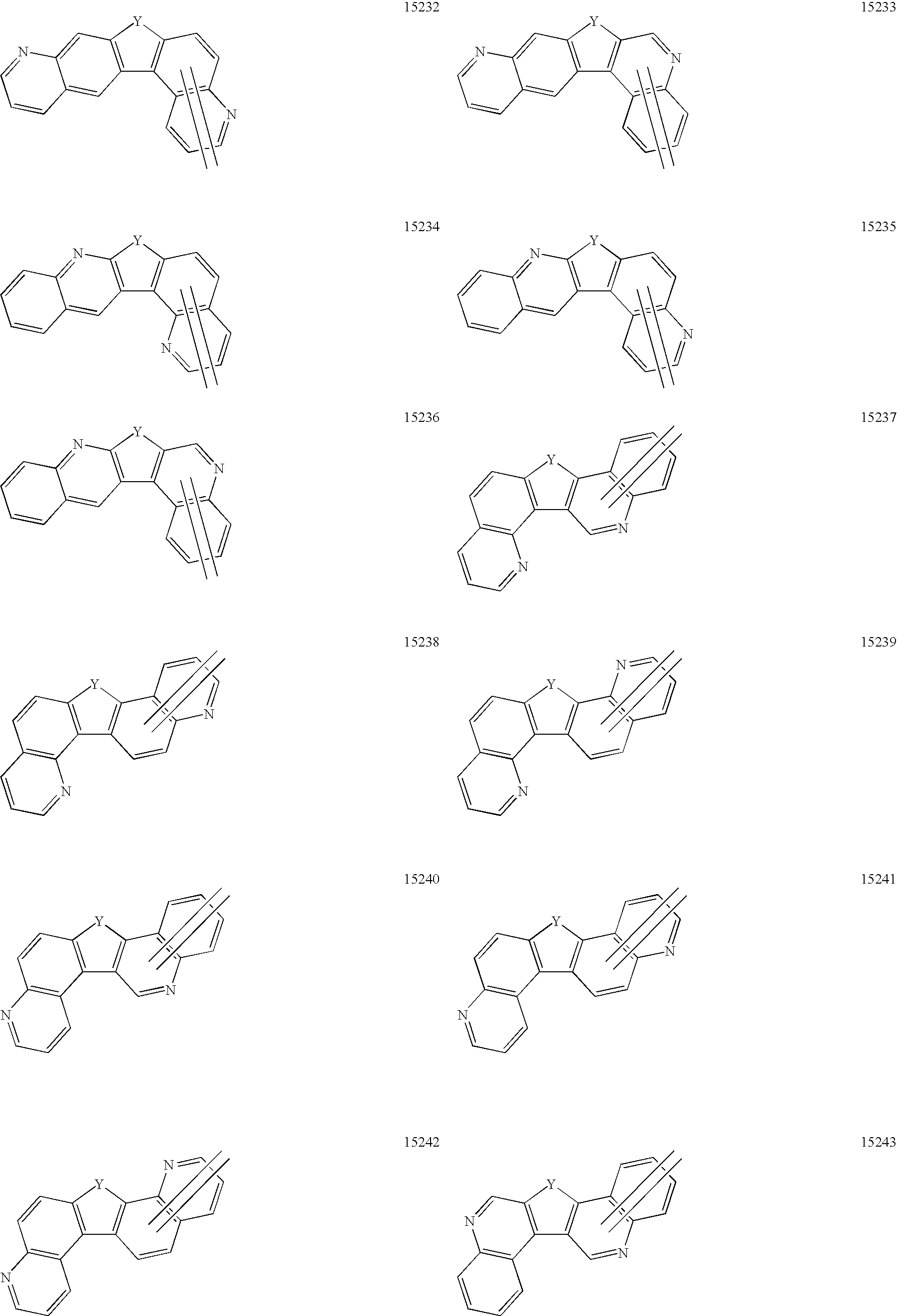

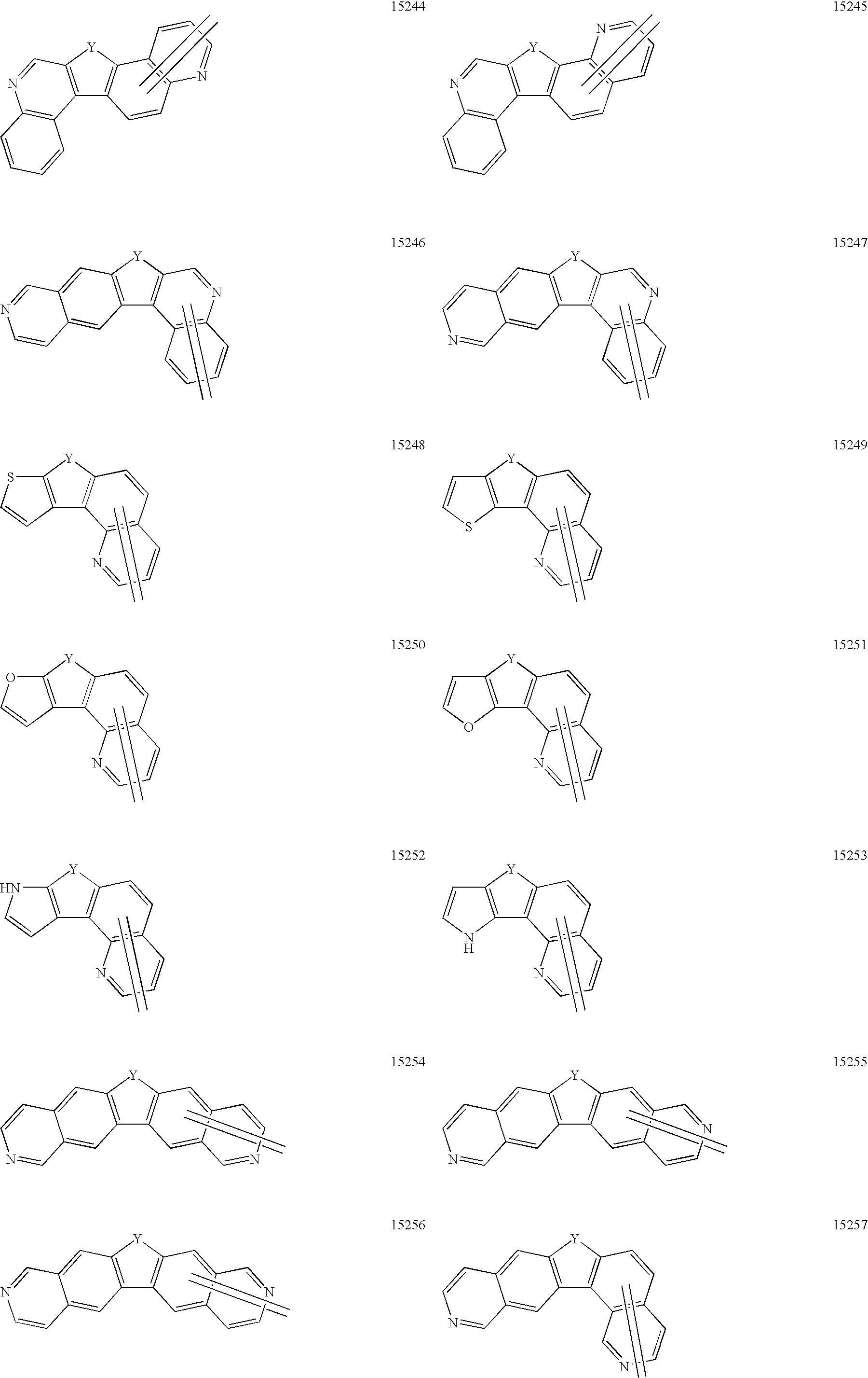

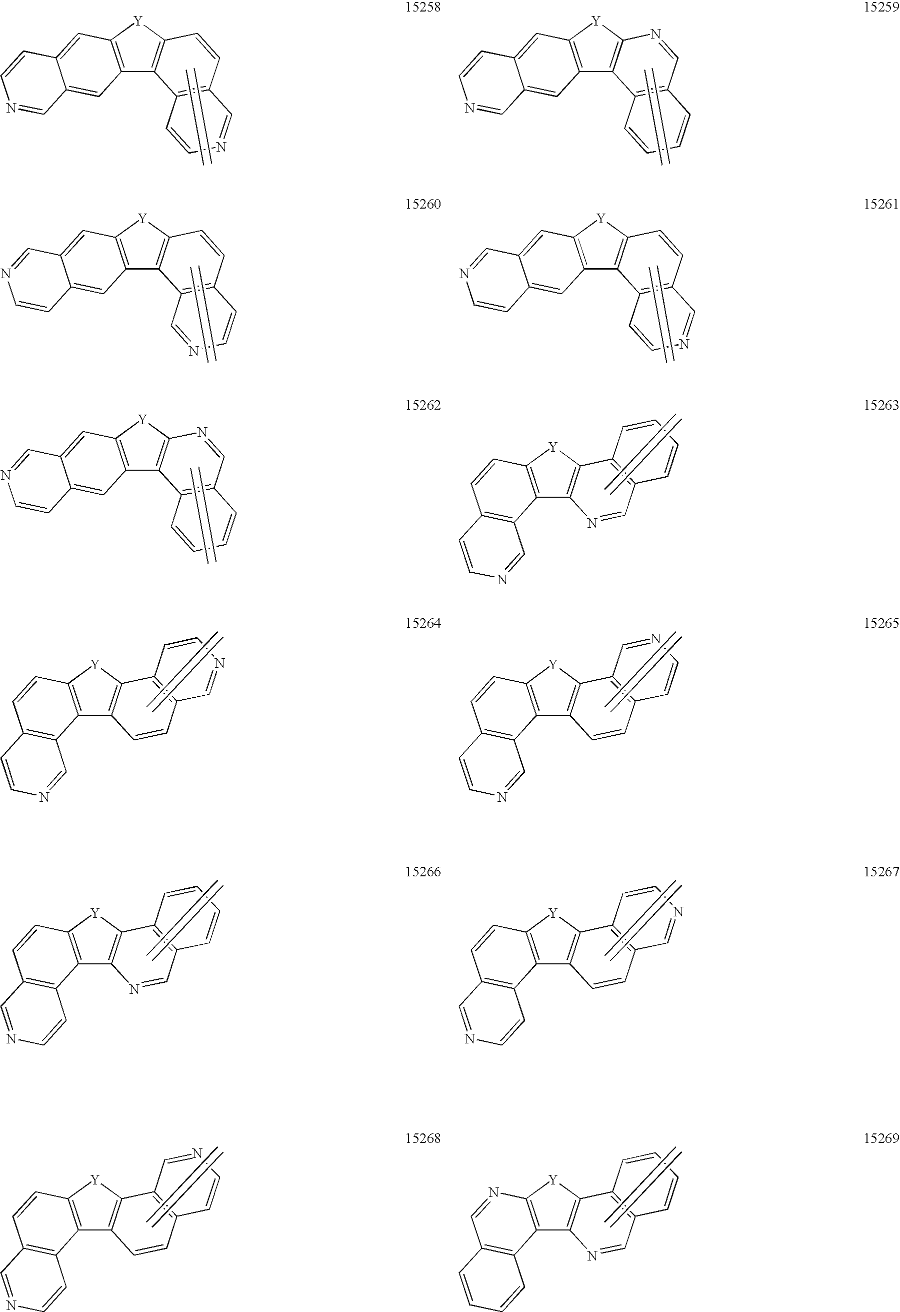

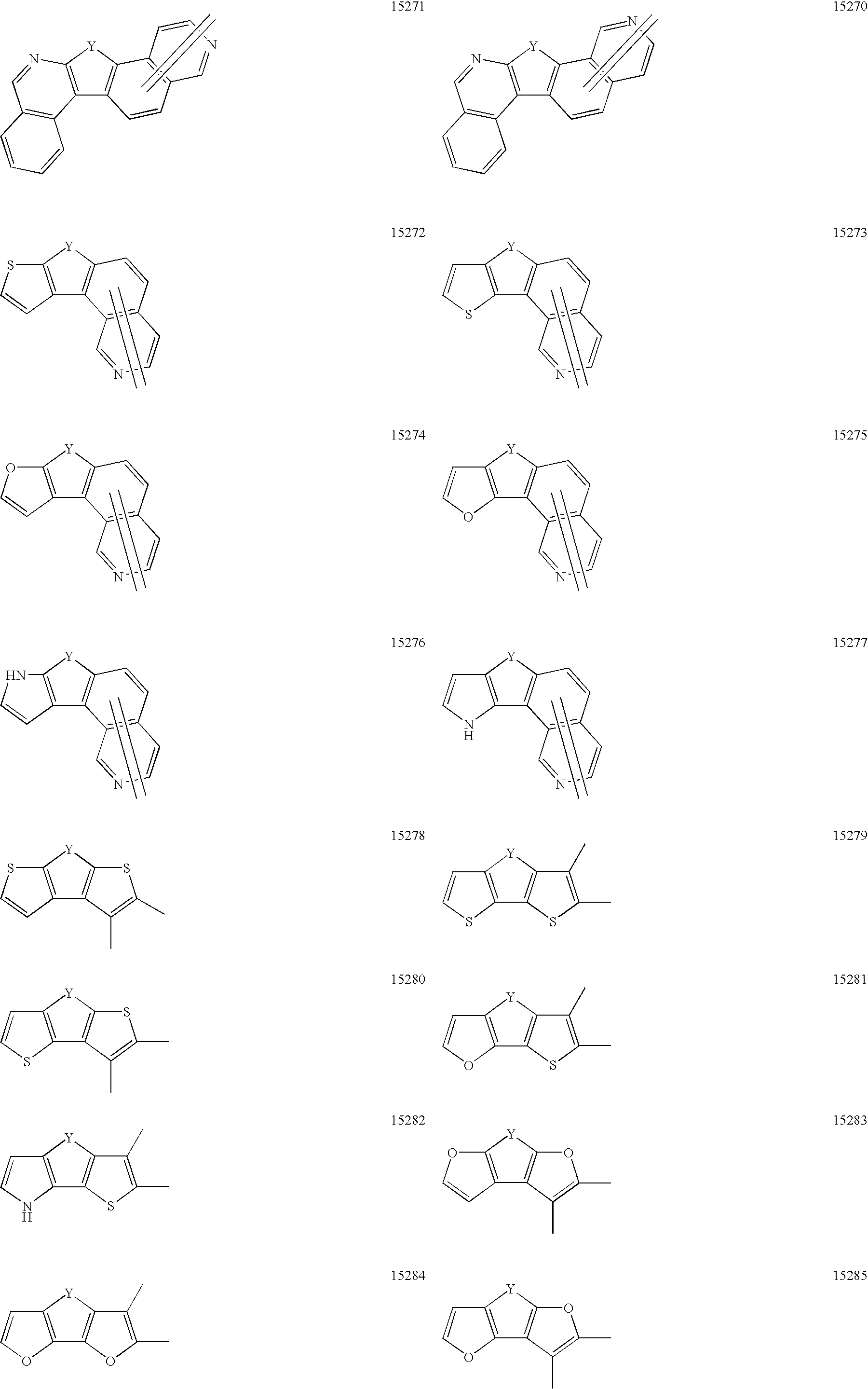

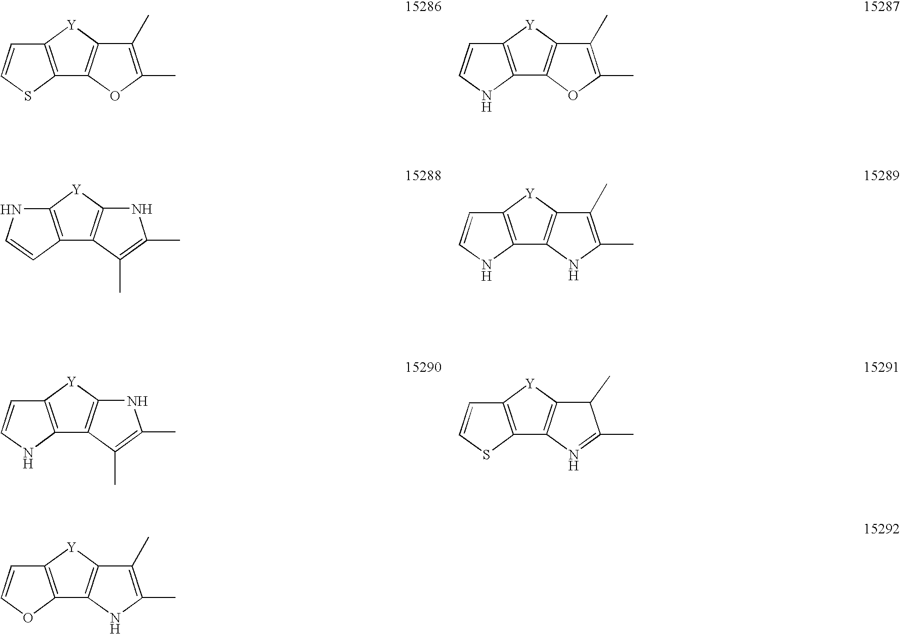

In the above formula (1), formulae (1-4) and (1-5) are preferable, and the structure represented by the above formula (1-4) is more preferable.

Specific examples of formula (1-4) include the followings.

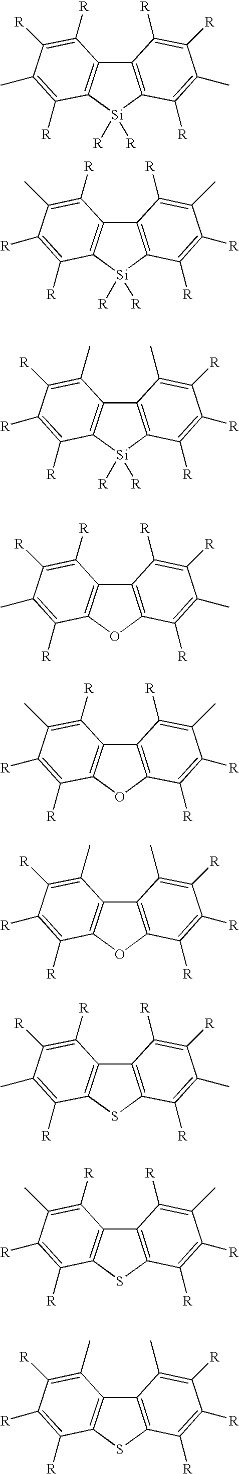

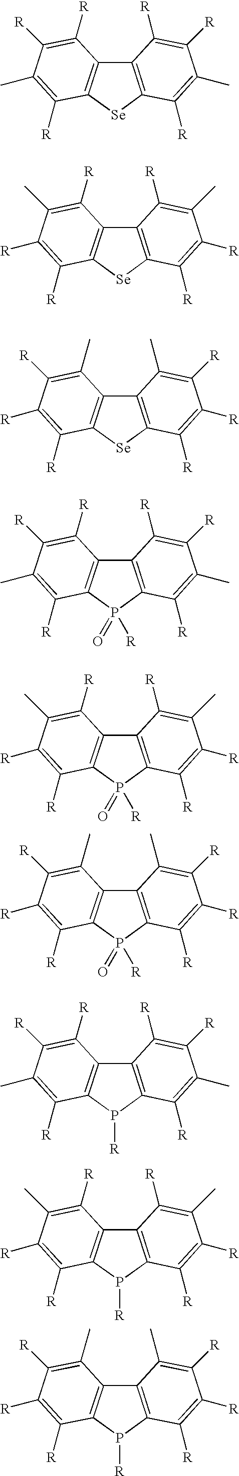

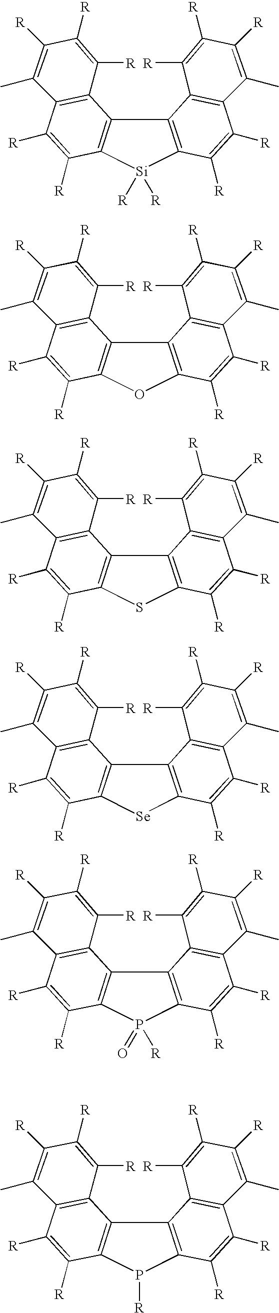

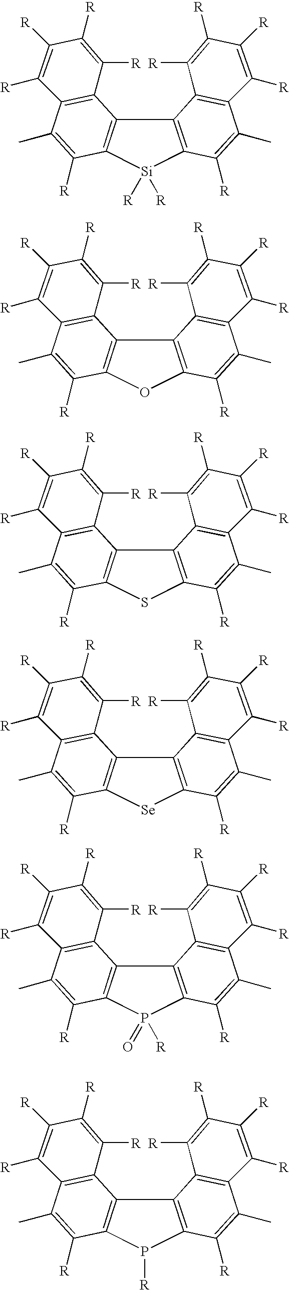

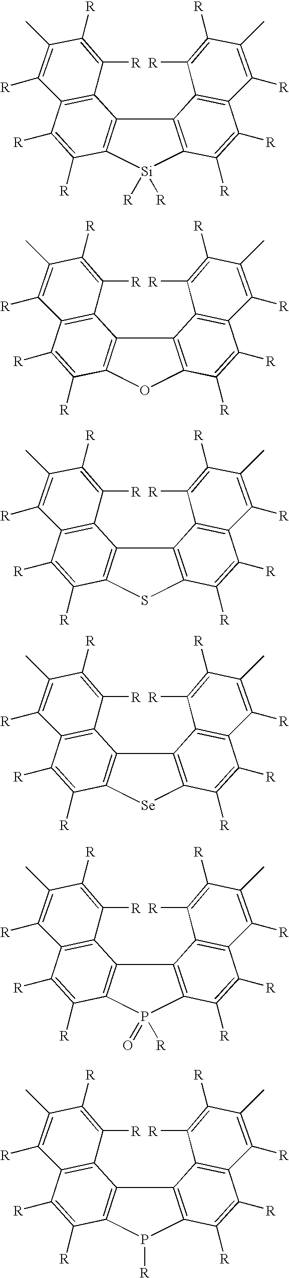

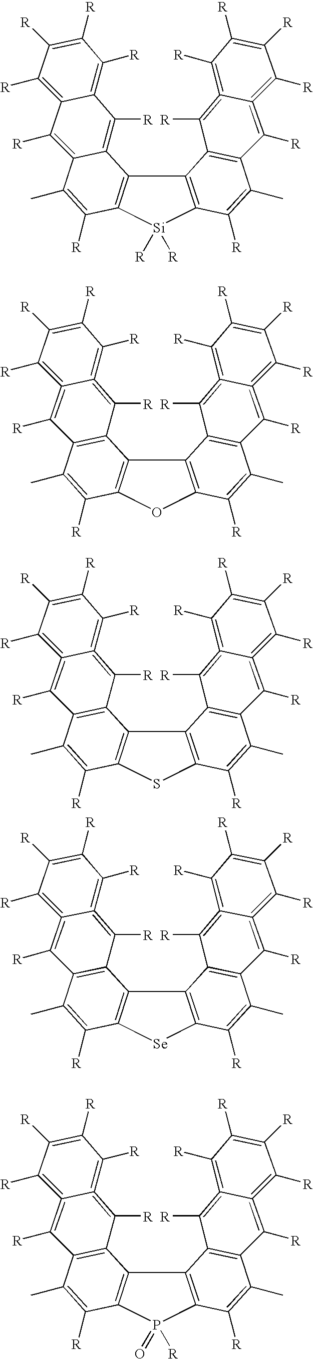

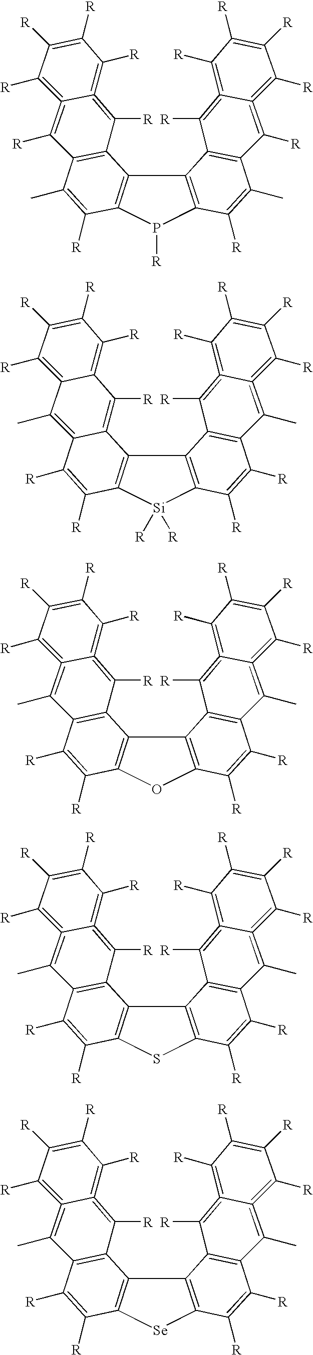

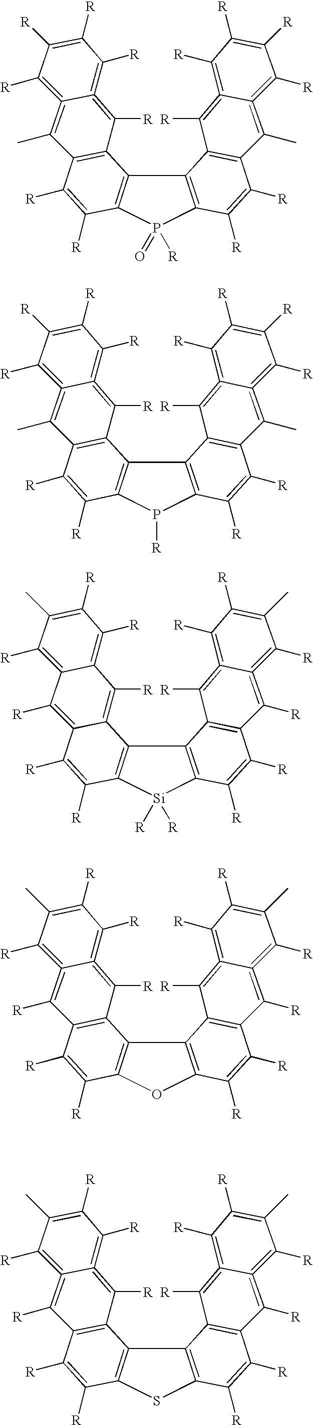

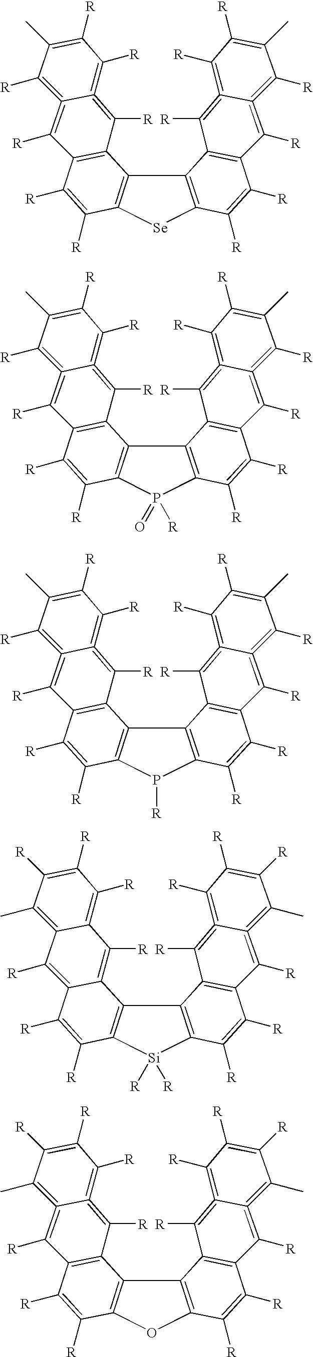

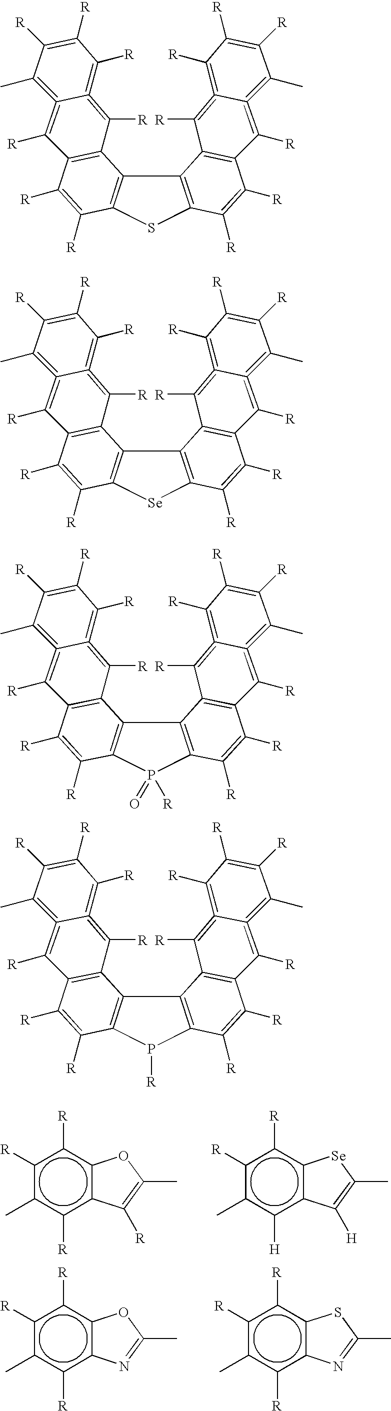

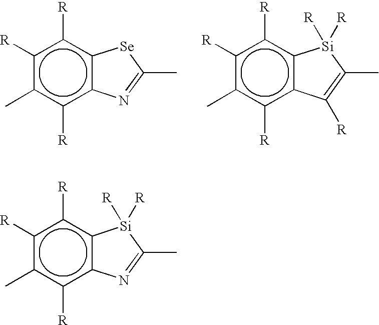

Wherein R's each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, cyano group, etc. In the above specific examples, a plurality of Rs contained in one structural formula may be the same or different, and may be selected each independently.

The alkyl group may be any of linear, branched or cyclic. The number of carbon atoms is usually about 1 to 20, preferably 3 to 20, and specific examples thereof include methyl group, ethyl group, propyl group, i-propyl group, butyl group, i-butyl group, t-butyl group, pentyl group, hexyl group, cyclohexyl group, heptyl group, octyl group, 2-ethylhexyl group, nonyl group, decyl group, 3,7-dimethyl octyl group, lauryl group, trifluoromethyl group, pentafluoroethyl group, perfluorobutyl group, perfluorohexyl group, perfluorooctyl group, etc.; and pentyl group, hexyl group, octyl group, 2-ethylhexyl group, decyl group, and 3,7-dimethyl octyl group are preferable.

The alkoxy group may be any of linear, branched or cyclic. The number of carbon atoms is usually about 1 to 20, preferably 3 to 20, and specific examples thereof include methoxy group, ethoxy group, propyloxy group, i-propyloxy group, butoxy group, i-butoxy group, t-butoxy group, pentyloxy group, hexyloxy group, heptyloxy group, octyloxy group, 2-ethylhexyloxy group, nonyloxy group, decyloxy group, 3,7-dimethyloctyloxy group, lauryloxy group, etc.; and pentyloxy group, hexyloxy group, octyloxy group, 2-ethylhexyloxy group, decyloxy group, 3,7-dimethyloctyloxy group are preferable.

The alkylthio group may be any of linear, branched or cyclic. The number of carbon atoms is usually about 1 to 20, preferably 3 to 20, and specific examples thereof include methylthio group, ethylthio group, propylthio group, i-propylthio group, butylthio group, i-butylthio group, t-butylthio group, pentylthio group, hexylthio group, heptylthio group, octylthio group, 2-ethylhexylthio group, nonylthio group, decylthio group, 3,7-dimethyloctylthio group, laurylthio group, trifluoromethylthio group, etc.; and pentylthio group, hexylthio group, octylthio group, 2-ethylhexylthio group, decylthio group, 3,7-dimethyloctylthio group are preferable.

The aryl group has usually about 6 to 60 carbon atoms, preferably 7 to 48, and specific examples thereof include phenyl group, C₁-C₁₂ alkoxyphenyl group (C₁-C₁₂ represents the number of carbon atoms 1-12. Hereafter the same), C₁-C₁₂ alkylphenyl group, 1-naphtyl group, 2-naphtyl group, 1-anthracenyl group, 2-anthracenyl group, 9-anthracenyl group, pentafluorophenyl group, etc., and C₁-C₁₂ alkoxyphenyl group and C₁-C₁₂ alkylphenyl group are preferable. The aryl group is an atomic group in which one hydrogen atom is removed from an aromatic hydrocarbon. The aromatic hydrocarbon includes those having a condensed ring, an independent benzene ring, or two or more condensed rings bonded through groups, such as a direct bond or a vinylene group.

Concrete examples of C₁-C₁₂ alkoxyphenyl include methoxyphenyl, ethoxyphenyl, propyloxyphenyl, i-propyloxyphenyl, butoxyphenyl, i-butoxyphenyl, t-butoxyphenyl, pentyloxyphenyl, hexyloxyphenyl, cyclohexyloxyphenyl, heptyloxyphenyl, octyloxyphenyl, 2-ethylhexyloxyphenyl, nonyloxyphenyl, decyloxyphenyl, 3,7-dimethyloctyloxyphenyl, lauryloxyphenyl, etc.

Concrete examples of C₁-C₁₂ alkylphenyl group include methylphenyl group, ethylphenyl group, dimethylphenyl group, propylphenyl group, mesityl group, methylethylphenyl group, i-propylphenyl group, butylphenyl group, i-butylphenyl group, t-butylphenyl group, pentylphenyl group, isoamylphenyl group, hexylphenyl group, heptylphenyl group, octylphenyl group, nonylphenyl group, decylphenyl group, dodecylphenyl group, etc.

The aryloxy group has the number of carbon atoms of usually about 6 to 60, preferably 7 to 48, and concrete examples thereof include phenoxy group, C₁-C₁₂ alkoxyphenoxy group, C₁-C₁₂ alkyl phenoxy group, 1-naphtyloxy group, 2-naphtyloxy group, pentafluorophenyloxy group, etc.; and C₁-C₁₂ alkoxyphenoxy group and C₁-C₁₂ alkylphenoxy group are preferable.

Concrete examples of C₁-C₁₂ alkylphenoxy group include methylphenoxy group, ethylphenoxy group, dimethylphenoxy group, propylphenoxy group, 1,3,5-trimethylphenoxy group, methylethylphenoxy group, i-propylphenoxy group, butyl phenoxy group, i-butylphenoxy group, t-butylphenoxy group, pentylphenoxy group, isoamylphenoxy group, hexylphenoxy group, heptylphenoxy group, octylphenoxy group, nonylphenoxy group, decylphenoxy group, dodecylphenoxy group, etc.

The arylthio group has the number of carbon atoms of usually about 6 to 60, preferably 7 to 48, and concrete examples thereof include phenylthio group, C₁-C₁₂ alkoxyphenylthio group, C₁-C₁₂ alkylphenylthio group, 1-naphthylthio group, 2-naphthylthio group, pentafluorophenylthio group, etc.; C₁-C₁₂ alkoxy phenylthio group and C₁-C₁₂ alkyl phenylthio group are preferable.

The arylalkyl group has the number of carbon atoms of usually about 7 to 60, preferably 7 to 48, and concrete examples thereof include phenyl-C₁-C₁₂alkyl group, C₁-C₁₂alkoxy phenyl-C₁-C₁₂ alkyl group, C₁-C₁₂ alkylphenyl-C₁-C₁₂ alkyl group, 1-naphtyl-C₁-C₁₂ alkyl group, 2-naphtyl-C₁-C₁₂ alkyl group etc.; and C₁-C₁₂ alkoxyphenyl-C₁-C₁₂ alkyl group and C₁-C₁₂ alkyl phenyl-C₁-C₁₂ alkyl group are preferable.

The arylalkoxy group has the number of carbon atoms of usually about 7 to 60, preferably 7 to 48, and concrete examples thereof include: phenyl-C₁-C₁₂alkoxy groups, such as phenylmethoxy group, phenylethoxy group, phenylbutoxy group, phenylpentyloxy group, phenylhexyloxy group, phenylheptyloxy group, and phenyloctyloxy group; C₁-C₁₂alkoxyphenyl-C₁-C₁₂ alkoxy group, C₁-C₁₂alkylphenyl-C₁-C₁₂alkoxy group, 1-naphtyl-C₁-C₁₂ alkoxy group, 2-naphtyl-C₁-C₁₂ alkoxy group etc.; and C₁-C₁₂ alkoxyphenyl-C₁-C₁₂ alkoxy group and C₁-C₁₂ alkylphenyl-C₁-C₁₂ alkoxy group are preferable.

The arylalkylthio group has the number of carbon atoms of usually about 7 to 60, preferably 7 to 48, and concrete examples thereof include: phenyl-C₁-C₁₂ alkylthio group, C₁-C₁₂ alkoxy phenyl-C₁-C₁₂ alkylthio group, C₁-C₁₂ alkylphenyl-C₁-C₁₂ alkylthio group, 1-naphtyl-C₁-C₁₂ alkylthio group, 2-naphtyl-C₁-C₁₂ alkylthio group, etc.; and C₁-C₁₂ alkoxy phenyl-C₁-C₁₂ alkylthio group and C₁-C₁₂ alkylphenyl-C₁-C₁₂ alkylthio group are preferable.

The arylalkenyl group has the number of carbon atoms of usually about 7 to 60, preferably 7 to 48, and concrete examples thereof include: phenyl-C₂-C₁₂ alkenyl group, C₁-C₁₂ alkoxy phenyl-C₂-C₁₂ alkenyl group, C₁-C₁₂ alkyl phenyl-C₂-C₁₂ alkenyl group, 1-naphtyl-C₂-C₁₂ alkenyl group, 2-naphtyl-C₂-C₁₂alkenyl group, etc.; and C₁-C₁₂ alkoxy phenyl-C₂-C₁₂alkenyl group, and C₂-C₁₂alkyl phenyl-C₁-C₁₂ alkenyl group are preferable.

The arylalkynyl group has the number of carbon atoms of usually about 7 to 60, preferably 7 to 48, and concrete examples thereof include: phenyl-C₂-C₁₂ alkynyl group, C₁-C₁₂ alkoxy phenyl-C₂-C₁₂ alkynyl group, C₁-C₁₂ alkylphenyl-C₂-C₁₂ alkynyl group, 1-naphtyl-C₂-C₁₂ alkynyl group, 2-naphtyl-C₂-C₁₂ alkynyl group, etc.; and C₁-C₁₂ alkoxyphenyl-C₂-C₁₂ alkynyl group, and C₁-C₁₂ alkylphenyl-C₂-C₁₂ alkynyl group are preferable.

The substituted amino group includes an amino group substituted by 1 or 2 groups selected from an alkyl group, aryl group, arylalkyl group, or monovalent heterocyclic group. Alkylamino group may be any of linear, branched or cyclic, and may be a monoalkylamino group or a dialkylamino group. Said alkyl group, aryl group, arylalkyl group, or monovalent heterocyclic group may have a substituent. The substituted amino group has usually about 1 to 60, preferably 2 to 48 carbon atoms, without including the number of carbon atoms of said substituent.

Concrete examples thereof include methylamino group, dimethylamino group, ethylamino group, diethylamino group, propylamino group, dipropylamino group, i-propylamino group, diisopropylamino group, butylamino group, i-butyl amino group, t-butylamino group, pentylamino group, hexyl amino group, cyclohexylamino group, heptylamino group, octyl amino group, 2-ethylhexylamino group, nonylamino group, decyl amino group, 3,7-dimethyloctylamino group, laurylamino group, cyclopentylamino group, dicyclopentyl amino group, cyclohexyl amino group, dicyclohexylamino group, pyrrolidyl group, piperidyl group, ditrifluoromethylamino group, phenylamino group, diphenylamino group, C₁-C₁₂ alkoxyphenylamino group, di(C₁-C₁₂ alkoxyphenyl)amino group, di(C₁-C₁₂ alkylphenyl) amino group, 1-naphtylamino group, 2-naphtylamino group, pentafluorophenylamino group, pyridylamino group, pyridazinylamino group, pyrimidylamino group, pyrazylamino group, triazylamino group phenyl-C₁-C₁₂ alkylamino group, C₁-C₁₂ alkoxyphenyl-C₁-C₁₂alkylamino group, C₁-C₁₂ alkyl phenyl-C₁-C₁₂ alkylamino group, di(C₁-C₁₂ alkoxyphenyl-C₁-C₁₂ alkyl)amino group, di(C₁-C₁₂ alkylphenyl-C₁-C₁₂ alkyl)amino group, 1-naphtyl-C₁-C₁₂ alkylamino group, 2-naphtyl-C₁-C₁₂ alkylamino group, etc.

The substituted silyl group means a silyl group substituted by 1, 2 or 3 groups selected from an alkyl group, aryl group, arylalkyl group, or monovalent heterocyclic group. The substituted silyl group has usually about 1 to 60, preferably 3 to 48 carbon atoms. Alkylsilyl group may be any of linear, branched or cyclic, and said alkyl group, aryl group, arylalkyl group, or monovalent heterocyclic group may have substituents.

Concrete examples of the substituted silyl group include trimethylsilyl group, triethylsilyl group, tripropylsilyl group, tri-1-propylsilyl group, dimethyl-1-propylsilyl group, diethyl-1-propylsilyl group, t-butylsilyldimethylsilyl group, pentyldimethylsilyl group, hexyldimethylsilyl group, heptyl dimethylsilyl group, octyldimethylsilyl group, 2-ethyl hexyl-dimethylsilyl group, nonyldimethylsilyl group, decyl dimethylsilyl group, 3,7-dimethyloctyl-dimethylsilyl group, lauryldimethylsilyl group, phenyl-C₁-C₁₂ alkylsilyl group, C₁-C₁₂ alkoxyphenyl-C₁-C₁₂ alkylsilyl group, C₁-C₁₂ alkyl phenyl-C₁-C₁₂ alkylsilyl group, 1-naphtyl-C₁-C₁₂ alkylsilyl group, 2-naphtyl-C₁-C₁₂ alkylsilyl group, phenyl-C₁-C₁₂ alkyl dimethylsilyl group, triphenylsilyl group, tri-p-xylylsilyl group, tribenzylsilyl group, diphenylmethylsilyl group, t-butyldiphenylsilyl group, dimethylphenylsilyl group, etc.

As the halogen atom, a fluorine atom, a chlorine atom, a bromine atom, and an iodine atom are exemplified.

The acyl group has usually about 2 to 20 carbon atoms, preferably 2 to 18 carbon atoms, and concrete examples thereof include acetyl group, propionyl group, butyryl group, isobutyryl group, pivaloyl group, benzoyl group, trifluoro acetyl group, pentafluorobenzoyl group, etc.

The acyloxy group has usually about 2 to 20 carbon atoms, preferably 2 to 18 carbon atoms, and concrete examples thereof include acetoxy group, propionyloxy group, butyryloxy group, isobutyryloxy group, pivaloyloxy group, benzoyloxy group, trifluoroacetyloxy group, pentafluorobenzoyl oxy group, etc.

Imine residue is a residue in which a hydrogen atom is removed from an imine compound (an organic compound having —N═C— is in the molecule. Examples thereof include aldimine, ketimine, and compounds whose hydrogen atom on N is substituted with an alkyl group etc.), and usually has about 2 to 20 carbon atoms, preferably 2 to 18 carbon atoms. As the concrete examples, groups represented by below structural formulas are exemplified.

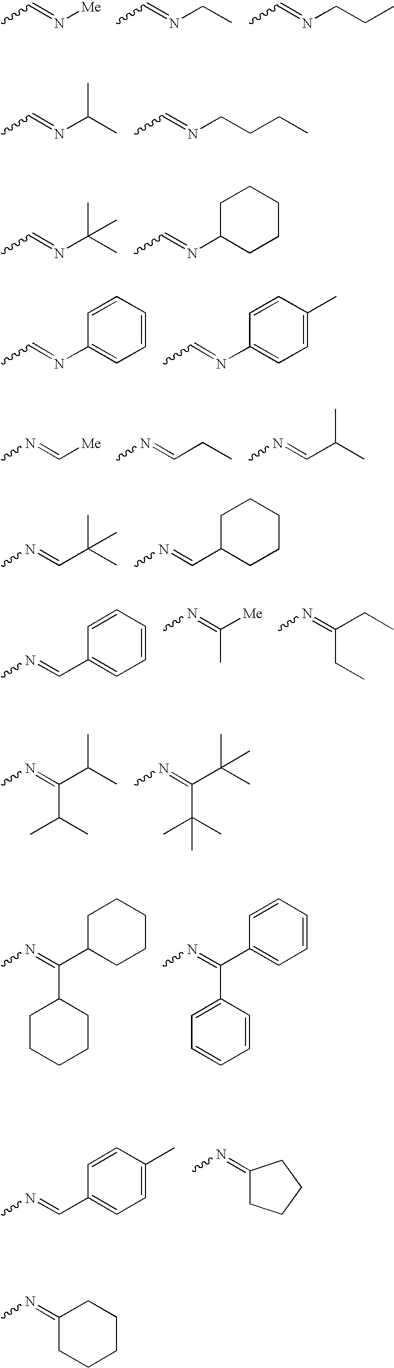

The amide group has usually about 2 to 20 carbon atoms, preferably 2 to 18 carbon atoms, and specific examples thereof include formamide group, acetamide group, propioamide group, butyroamide group, benzamide group, trifluoroacetamide group, pentafluoro benzamide group, diformamide group, diacetoamide group, dipropioamide group, dibutyroamide group, dibenzamide group, ditrifluoro acetamide group, dipentafluorobenzamide group, etc.

Examples of the acid imide group include residual groups in which a hydrogen atom connected with nitrogen atom is removed, and have usually about 2 to 60 carbon atoms, preferably 2 to 48 carbon atoms. As the concrete examples of acid imide group, the following groups are exemplified.

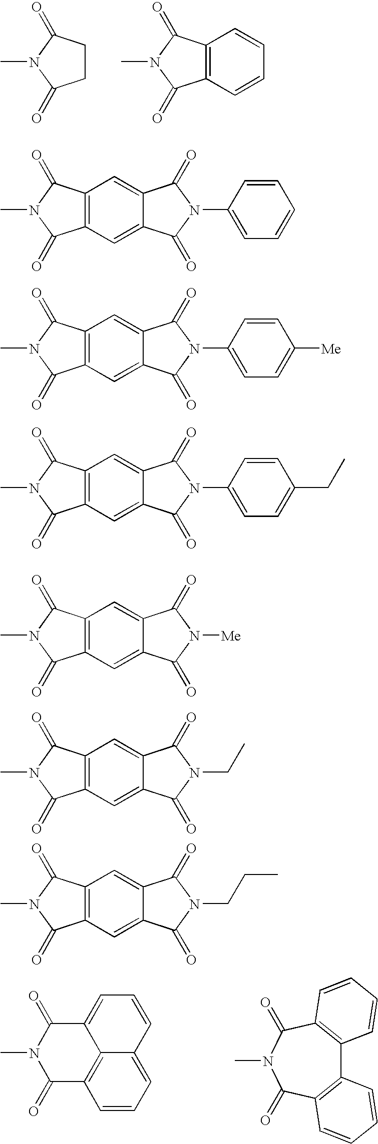

The monovalent heterocyclic group means an atomic group in which a hydrogen atom is removed from a heterocyclic compound, and the number of carbon atoms is usually about 4 to 60, preferably 4 to 20. The number of carbon atoms of the substituent is not contained in the number of carbon atoms of a heterocyclic group. The heterocyclic compound means an organic compound having a cyclic structure in which at least one heteroatom such as oxygen, sulfur, nitrogen, phosphorus, boron, etc. is contained in the cyclic structure as the element other than carbon atoms. Concrete examples thereof include thienyl group, C₁-C₁₂ alkylthienyl group, pyroryl group, furyl group, pyridyl group, C₁-C₁₂ alkylpyridyl group, piperidyl group, quinolyl group, isoquinolyl group, etc.; and thienyl group, C₁-C₁₂ alkylthienyl group, pyridyl group, and C₁-C₁₂ alkylpyridyl group are preferable.

The substituted carboxyl group means a carboxyl group substituted by alkyl group, aryl group, arylalkyl group, or monovalent heterocyclic group, and has usually about 2 to 60, preferably 2 to 48 carbon atoms. Concrete examples thereof include methoxy carbonyl group, ethoxycarbonyl group, propoxycarbonyl group, i-propoxycarbonyl group, butoxycarbonyl group, i-butoxy carbonyl group, t-butoxycarbonyl group, pentyloxycarbonyl group, hexyloxycarbonyl group, cyclohexyloxycarbonyl group, heptyloxycarbonyl group, octyloxycarbonyl group, 2-ethylhexyloxycarbonyl group, nonyloxycarbonyl group, decyloxycarbonyl group, 3,7-dimethyloctyloxycarbonyl group, dodecyloxycarbonyl group, trifluoromethoxycarbonyl group, pentafluoroethoxycarbonyl group, perfluorobutoxycarbonyl group, perfluorohexyloxycarbonyl group, perfluorooctyloxy carbonyl group, phenoxycarbonyl group, naphtoxycarbonyl group, pyridyloxycarbonyl group, etc. Said alkyl group, aryl group, arylalkyl group, or monovalent heterocyclic group may have substituent. The number of carbon atoms of said substituent is not contained in the number of carbon atoms of the substituted carboxyl group.

Among the above examples, in the groups containing an alkyl, they may be any of linear, branched or cyclic, or may be the combination thereof. In case of not linear, isoamyl group, 2-ethylhexyl group, 3,7-dimethyloctyl group, cyclohexyl group, 4-C₁-C₁₂ alkylcyclohexyl group, etc., are exemplified. Moreover, the tips of two alkyl chains may be connected to form a ring. Furthermore, a part of methyl groups and methylene groups of alkyl, may be replaced by a group containing hetero atom, or a methyl or methylene group substituted by one or more fluorine. As the hetero atoms, an oxygen atom, a sulfur atom, a nitrogen atom, etc., are exemplified.

Furthermore, in the examples of the substituents, when an aryl group or a heterocyclic group is included in the part thereof, they may have one or more substituents.

In the examples of substituent Rs, alkyloxy group, alkylthio group, aryl group, aryloxy group and arylthio group are more preferable.

Furthermore, among the structures shown by the above formula (1-4), structures shown by the below formula (1-6), (1-7), (1-8), (1-9) or (1-10) are preferable, structures shown by (1-6), (1-7) or (1-8) are more preferable, and structures shown by (1-6) are further preferable. 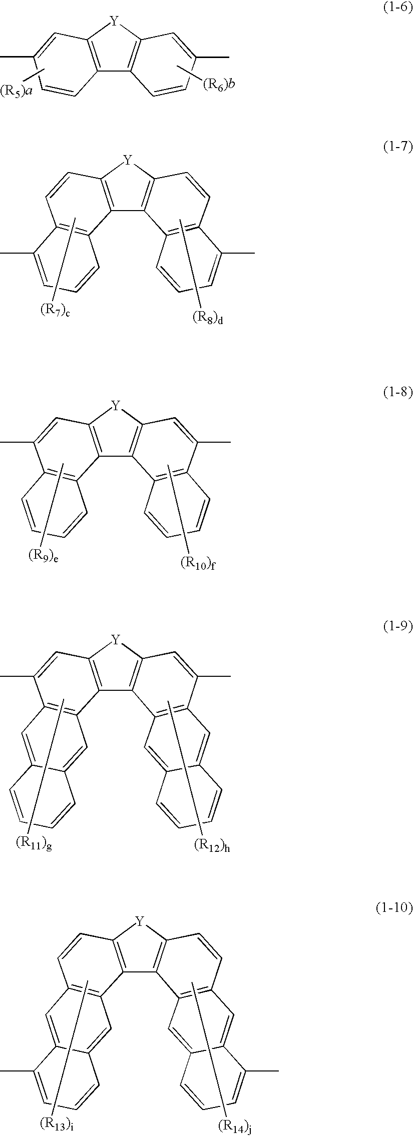
(Wherein, R₅, R₆, R₇, R₈, R₉, R₁₀, R₁₁, R₁₂, R₁₃, and R₁₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, acyloxy group, imine residue, amide group, acid imide group, monovalent heterocyclic group, carboxyl group, or substituted carboxyl group. a and b each independently represent an integer of 0 to 3. c, d, e and f each independently represent an integer of 0 to 5. g, h, i and j each independently represent an integer of 0 to 7. A plurality of R₅, R₆, R₇, R₈, R₉, R₁₀, R₁₁, R₁₂, R₁₃, and R₁₄ are independently exist, they may be the same or different. Y represents the same meaning as above.)

In view of the solubility in a solvent, a+b, c+d, e+f, and i+j are preferably 1 or more.

In the above specific examples, Y is preferably a structure of O atom or S atom.

Next, the metal complex structure showing light-emission from triplet excited state will be explained. The metal complex structure showing light-emission from triplet excited state is a structure derived from a metal complex showing light-emission from triplet excited state, and usually exists in a molecule as a form of a residue in which one or two hydrogens are removed from the ligand of the complex.

The metal complex showing light-emission from triplet excited state includes, for example, a complex in which phosphorescence light-emission is observed, and a complex in which fluorescence light-emission is observed in addition to the phosphorescence light-emission. For example, a metal complex compound which has been used as a low molecular weight EL light-emission material from the former is exemplified. These are disclosed by, for example, Nature, (1998) 395, 151; Appl. Phys. Lett. (1999), 75(1), 4; Proc. SPIE-Int. Soc. Opt. Eng. (2001), 4105 (Organic Light-Emitting Materials and Devices IV, 119; J. Am. Chem. Soc., (2001), 123, 4304; Appl. Phys. Lett., (1997), 71(18), 2596; Syn. Met., (1998), 94(1), 103; Syn. Met., (1999), 99(2), 1361; Adv. Mater., (1999), 11 (10), 852, etc.

The center metal of a complex emitting triplet light-emission is usually an atom having an atomic number of 50 or more, and is a metal manifesting a spin-orbital mutual action on this complex and showing a possibility of the intersystem crossing between the singlet state and the triplet state.

For example, gold, platinum, iridium, osmium, rhenium, tungsten, europium, terbium, thulium, dysprosium, samarium, praseodymium, gadolinium, a ytterbium atom are preferable; gold, platinum, iridium, osmium, rhenium, tungsten atom are more preferable; gold, platinum, iridium, osmium, rhenium atom are further preferable; and gold, platinum, iridium, and rhenium atom are most preferable.

As the ligand of a triplet light-emitting complex compound, for example, 8-quinolinol and derivatives thereof, benzoquinolinol and derivatives thereof, 2-phenyl-pyridine and derivatives thereof, 2-phenyl-benzothiazole and derivatives thereof, 2-phenyl-benzoxazole and derivatives thereof, porphyrin and derivatives thereof, and the like are exemplified.

Examples of the metal complex structure showing light-emission from triplet excited state include the residues in which one or more R's in the following triplet light-emitting complex compound are removed

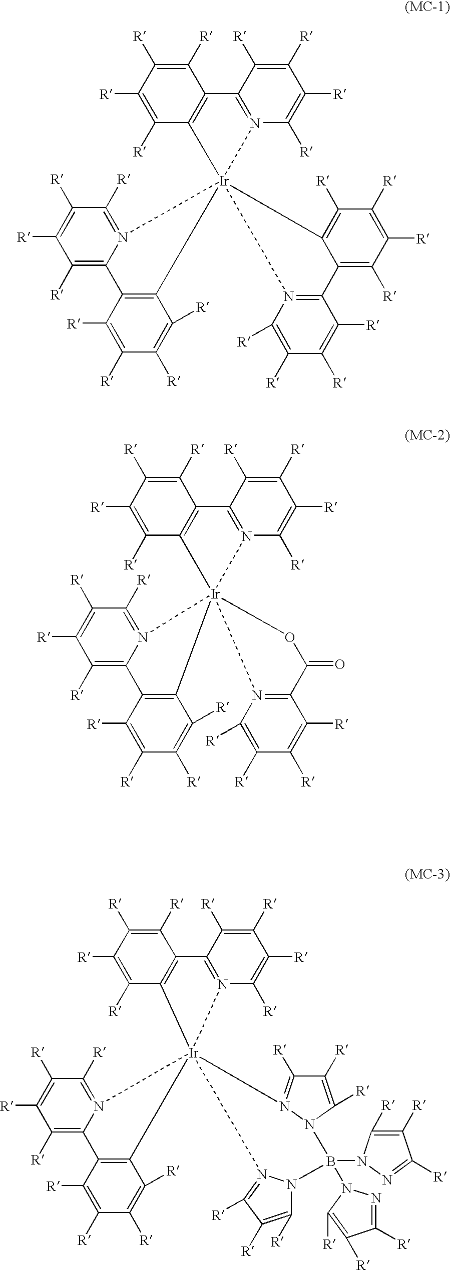

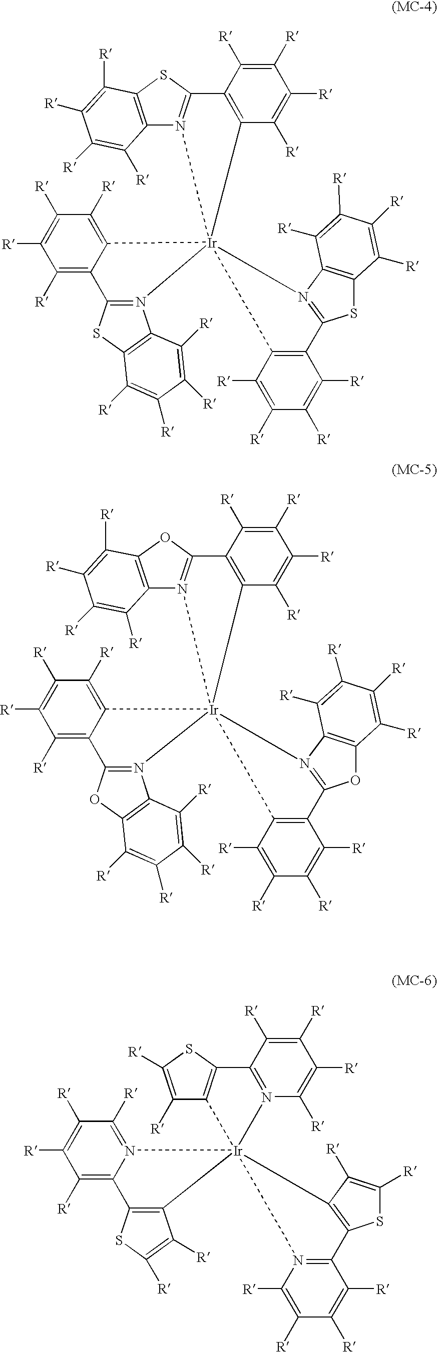

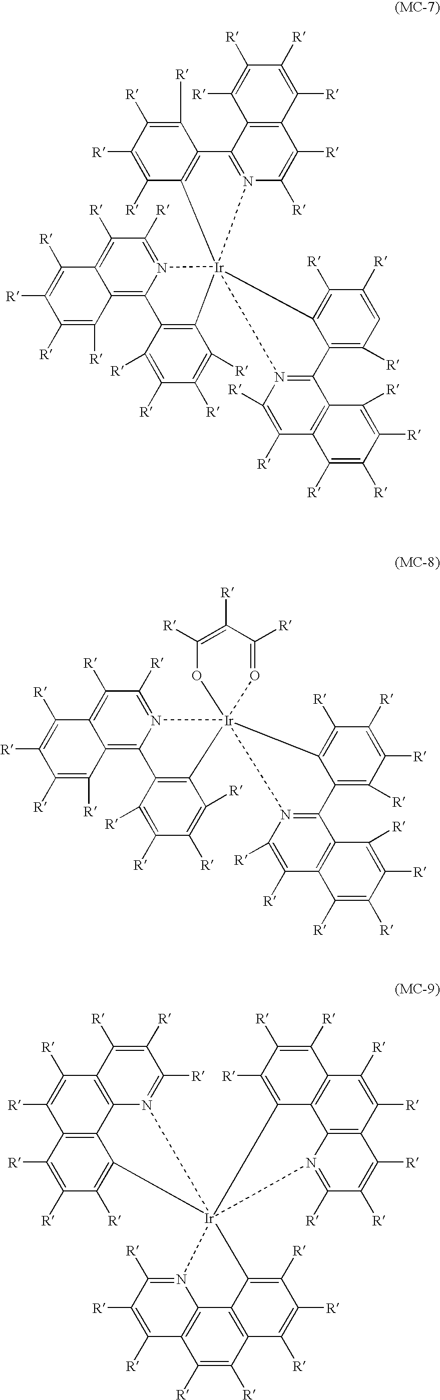

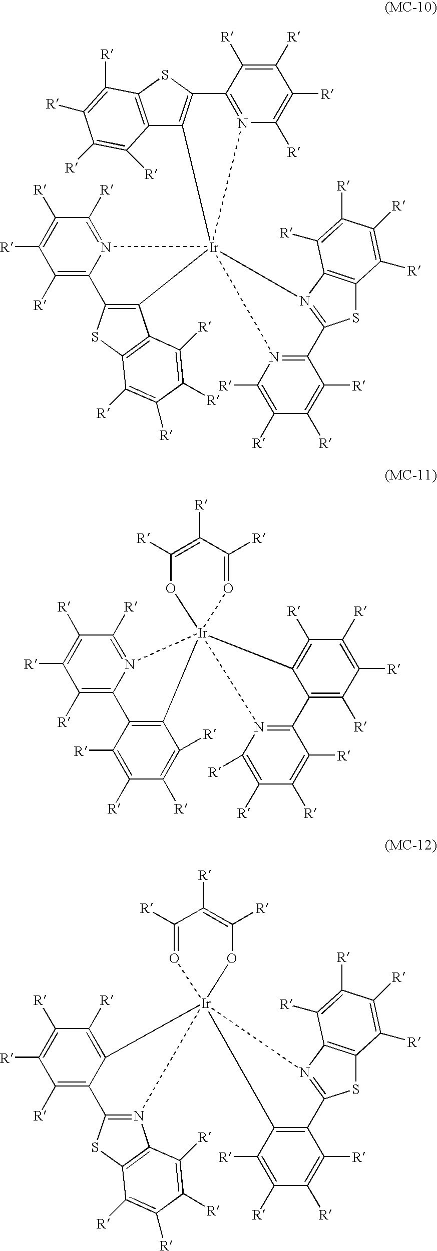

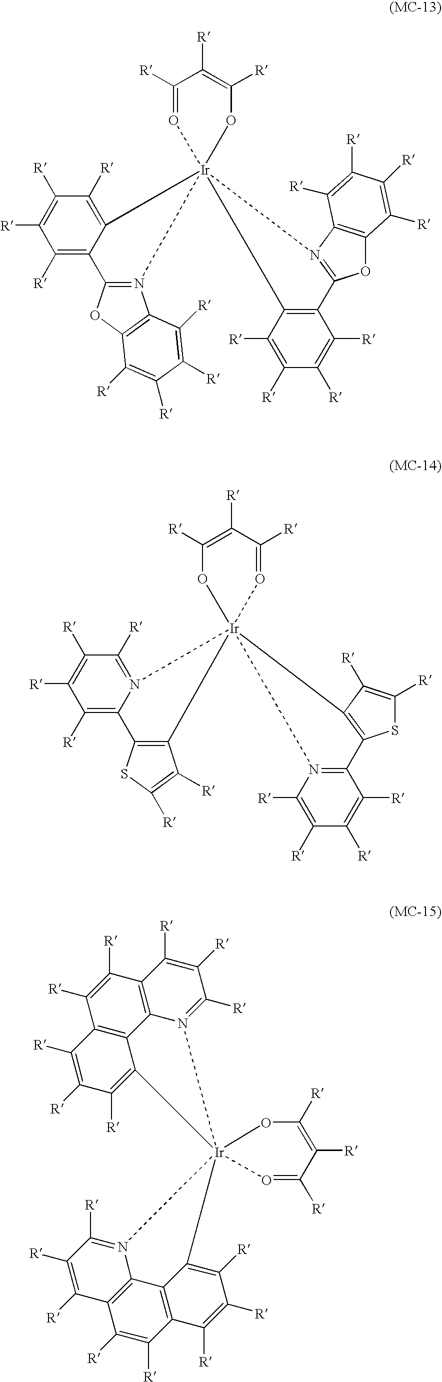

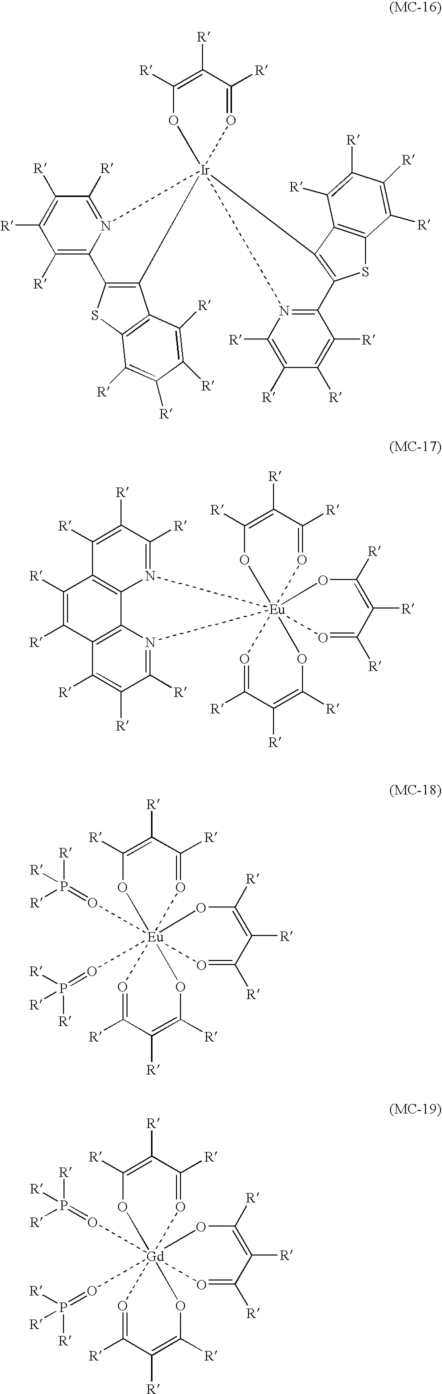

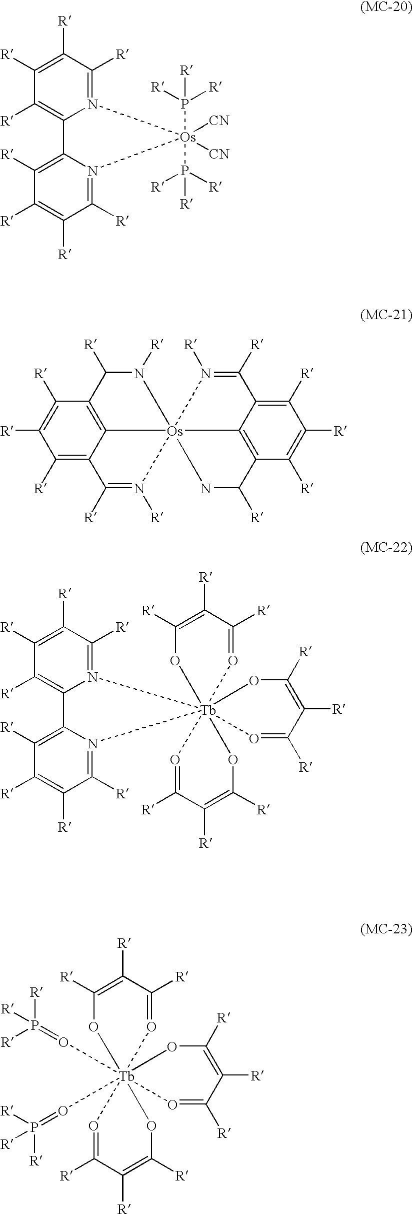

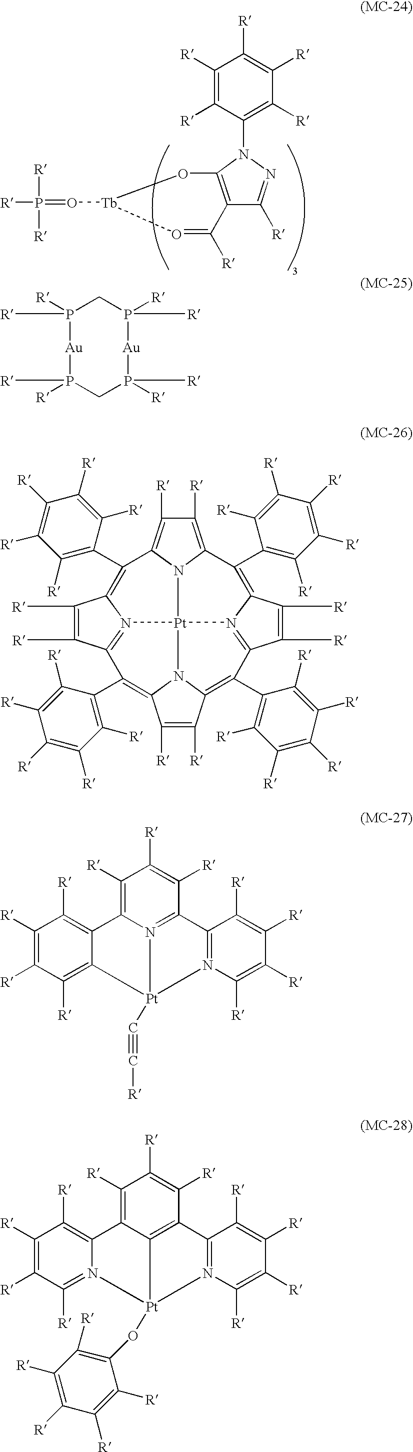

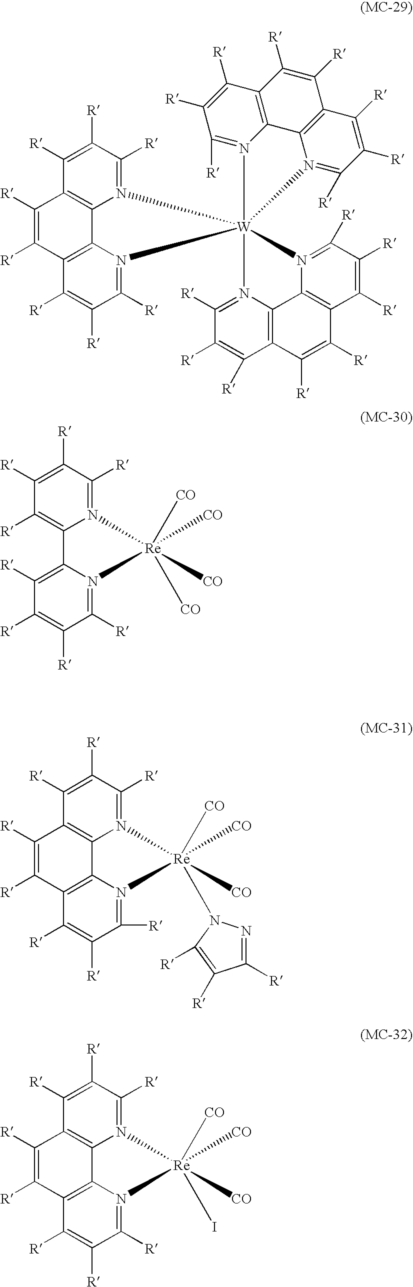

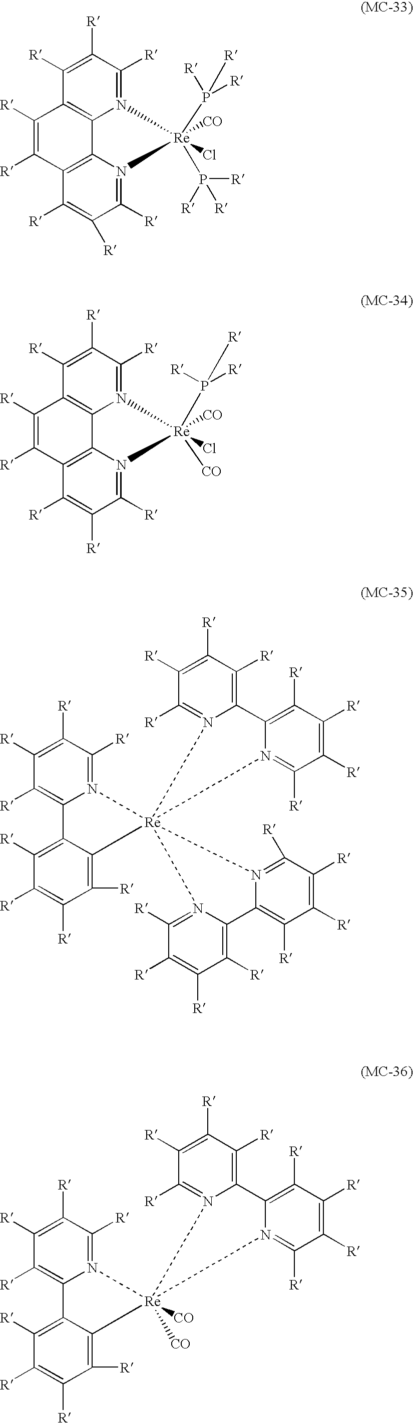

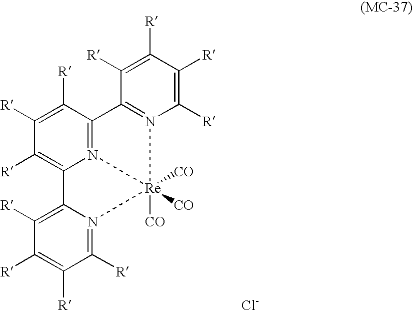

Wherein, R′s each independently represent hydrogen atom, halogen atom, alkyl group, alkoxy group, alkylthio group, aryl group, aryloxy group, arylthio group, arylalkyl group, arylalkoxy group, arylalkylthio group, amino group, substituted amino group, silyl group, substituted silyl group, acyl group, acyloxy group, imine residue, amide group, arylalkenyl group, arylalkynyl group, cyano group, a monovalent heterocyclic group. In order to improve the solubility in a solvent, alkyl group and alkoxy group are preferable, and it is preferable that the repeating unit including substituent has a form of little symmetry.

Concrete examples of R′ include the same as those shown by the above R.

In case where the metal complex structure showing light-emission from triplet excited state is included as a repeating unit in a polymer chain in the present invention, the repeating unit is represented, for example, by the below formula (14), (15), (16) or (16-1). 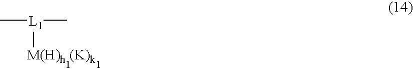
(Wherein, K represents a ligand containing one or more atoms, as an atom which bonds with M, selected from a nitrogen atom, oxygen atom, carbon atom, sulfur atom, and phosphorus atom; a halogen atom, or a hydrogen atom. M represents an atom having an atomic number of 50 or more, and showing a possibility of the intersystem crossing between the singlet state and the triplet state by spin-orbital mutual action on this compound. H represents a ligand containing one or more atoms, as an atom which bonds with M, selected from a nitrogen atom, oxygen atom, carbon atom, sulfur atom, and phosphorus atom. h₁ represents an integer of 1-3, k₁ represents an integer of 0-3, and h₁+k₁ is an integer of 1-5. L₁ represents a residue in which two hydrogen atoms are removed from the ligand containing one or more atoms, as an atom which bonds with M, selected from a nitrogen atom, an oxygen atom, a carbon atom, a sulfur atom, and a phosphorus atom.) 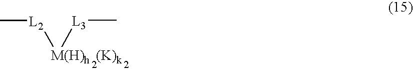
(Wherein, M, H, and K represent the same meaning as the above. L₂ and L₃ each independently represent a residue in which one hydrogen atom is removed from the ligand containing one or more atoms, as an atom which bonds with M, selected from a nitrogen atom, an oxygen atom, a carbon atom, a sulfur atom, and a phosphorus atom. h₂ represents an integer of 1-3, k₂ represents an integer of 0-3, and h₂+k₂ is an integer of 1-3.)

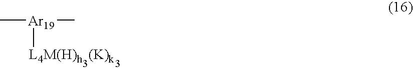

(Wherein, M, H, and K represent the same meaning as the above. Ar₁₉ represents a trivalent aromatic group or a trivalent heterocyclic group.

L₄ represents a residue in which one hydrogen atom is removed from the ligand containing one or more atoms, as an atom which bonds with M, selected from a nitrogen atom, an oxygen atom, a carbon atom, a sulfur atom, and a phosphorus atom. h₃ represents an integer of 1-3, k₃ represents an integer of 0-3, and h₃+k₃ is an integer of 1-4.)

The trivalent aromatic group is an atomic group in which three hydrogen atoms are removed from an aromatic hydrocarbon, and has usually 4 to 60 carbon atoms, preferably 4 to 20 carbon atoms. The number of carbon atoms of the substituent is not contained in the number of carbon atoms of the trivalent aromatic group. Specifically, exemplified are the groups in which a hydrogen atom is removed from the group represented as the arylene group described in Ar₁.

The trivalent aromatic group is an atomic group in which three hydrogen atoms are removed from an aromatic hydrocarbon, and has usually 4 to 60 carbon atoms, preferably 4 to 20 carbon atoms. The number of carbon atoms of the substituent is not contained in the number of carbon atoms of the trivalent aromatic group. Specifically, exemplified are the groups in which a hydrogen atom is removed from the group represented as the arylene group described in Ar₁.

The trivalent heterocyclic group is an atomic group in which three hydrogen atoms are removed from a heterocyclic compound, and has usually 4 to 60 carbon atoms, preferably 4 to 20 carbon atoms. The number of carbon atoms of the substituent is not contained in the number of carbon atoms of the trivalent heterocyclic group. Specifically, exemplified are the groups in which a hydrogen atom is removed from the group represented as the divalent heterocyclic group described in Ar₁.

In the present invention, the metal complex structure showing light-emission from triplet excited state may be those represented by the structure containing groups of -L-X in the repeating unit, for example, the below formula (16-1). 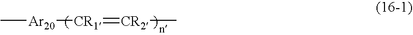
(Wherein, Ar₂₀ represents a divalent heterocyclic group which contains one or more atoms selected from the group consisting of an oxygen atom, a silicon atom, and a germanium atom, a tin atom, a phosphorus atom, a boron atom, a sulfur atom, a selenium atom, and a tellurium atom. Said Ar₂₀ has 1 to 4 groups represented by -L-X.

X represents a monovalent group containing a metal complex structure showing light-emission from triplet excited state. L represents a single bond, —O—, —S—, —CO—, —CO₂—, and —SO—, —SO₂—, —SiR_{3′}R_{4′}—, NR_{5′}—, —BR_{6′}—, —PR_{7′}—, —P(═O)(R_{8′})—, alkylene group which may be substituted, alkenylene group which may be substituted, alkynylene group which may be substituted, arylene group which may be substituted, or divalent heterocyclic group which may be substituted. When this alkylene group, alkenylene group and alkynylene group contain —CH₂-group, one or more of —CH₂— groups contained in the alkylene group, and one or more of —CH₂— groups contained in the alkenylene group and one or more of —CH₂-groups contained in the alkynylene group, respectively may be replaced with the group selected from the group consisting of —O—, —S—, —CO—, —CO₂—, —SO—, —SO₂—, and —SiR_{9′}R_{10′}—, NR_{11′}—, —BR_{12′}—, —PR_{13′}—, and —P(═O)(R_{14′}). R_{1′}, R_{2′}, R_{3′}, R_{4′}, R_{5′}, R_{6′}, R_{7′}, R_{8′}, R_{9′}, R_{10′}, R_{11′}, R_{12′}, R_{13′}, R_{14′} each independently represent a group selected from the group consisting of a hydrogen atom, alkyl group, aryl group, monovalent heterocyclic group and cyano group.

Ar₂₀ may contain substituents, other than a group represented by -L-X, selected from the group consisting of alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, and cyano group. When Ar₂₀ contains a plurality of substituents, they may be the same or different respectively. n′ is 0 or 1.)

As X, those represented by the below formula (X-1) are exemplified.
[(H₁)_{h3′}-M-(K₁)_{k3′} [symbol] * (X-1)

Wherein, M represents the same meaning as the above. H₁ is a ligand which contains one or more of nitrogen atom, oxygen atom, carbon atom, sulfur atom, and phosphorus atoms, and bonds with M through one or more said atoms. When K₁ does not have connecting bond with L, it has a connecting bond with L in an arbitrary position of H₁ which does not bond with M.

As H₁, the ligands represented by H are exemplified.

K₁ represents a hydrogen atom, halogen atom, alkyl group, alkoxy group, acyloxy group, alkylthio group, aryl group, aryloxy group, arylthio group, arylalkyl group, arylalkoxy group, arylalkylthio group, substituted amino group, alkene, alkyne, amine, imine, amide group, acid imide group, isonitril ligand, cyano group, phosphine, phosphine oxide ligand, phosphite, sulfone ligand, sulfoxide ligand, sulfonate group, sulfide, heterocyclic ligand, carboxyl group, carbonyl compound, or ether; and may be a polydentate ligand of combination thereof.

When H₁ does not have connecting bond with L, K₁ has a connecting bond with L in an arbitrary position of H₁ which does not bond with M. In this case, K₁ is an atomic group in which a hydrogen atom is removed from those selected from the above concrete examples. Accordingly, when L¹ has a connecting bond with L, L¹ is not a hydrogen atom and a halogen atom.

As K₁, the ligands represented by K are exemplified. h_{3′} represents an integer of 0-5, k_{3′} represents an integer of 1-5, and h3′+k3′ is an integer of 1-5.

L in -L-X represents a single-bond, —O—, —S—, —CO—, —CO₂—, —SO—, —SO₂—, —SiR_{3′}R_{4′}—, —NR_{5′}, —BR_{6′}, —PR_{7′}, —P(═O)(R_{8′})—, alkylene group which may be substituted, alkenylene group which may be substituted, alkynylene group which may be substituted, arylene group which may be substituted, or divalent heterocyclic group. When this alkylene group, alkenylene group and alkynylene group contain —CH₂— groups, one or more of —CH₂— groups contained in the alkylene group, one or more of —CH₂— groups contained in the alkenylene group or one or more of —CH₂— groups contained in the alkynylene group, respectively may be replaced with the group selected from the group consisting of —O—, —S—, —CO—, —CO₂—, —SO—, —SO₂—, and —SiR_{3′}R_{4′}—, NR_{5′}, —BR_{6′}, —PR_{7′}, and —P(═O)(R_{8′}). R_{3′}, R_{4′}, R_{5′}, R_{6′}, R_{7′}, R_{8′}, R_{9′}, R_{10′}, R_{11′}, R_{12′}, R_{13′}, and R_{14′} each independently represent a group selected from groups consisting of a hydrogen atom, alkyl group, aryl group, monovalent heterocyclic group, and cyano group. Concrete examples of R_{3′} to R_{14′} include the same as those shown in the above R′.

In the case that L is an alkylene group which may be substituted, the number of carbon atoms is usually about 1 to 12. Examples of the substituents include an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, acid imide group, monovalent heterocyclic group, carboxyl group, substituted carboxyl group, cyano group, etc.

When this alkylene group contains two or more —CH₂— groups, one or more of —CH₂— groups contained in the alkylene group may be replaced with the group selected from the group consisting of —O—, —S—, —CO—, —CO₂—, —SO—, —SO₂—, and —SiR_{15′}R_{16′}—, NR_{17′—, —BR}_{18′}—, —PR_{19′}—, and —P(═O)(R_{20′}). Concrete examples of R_{15′} to R_{20′} include the same as those shown in R_{3′} to R_{14′}. Preferable examples of alkylene group include —C₃H₆—, —C₄H₈—, —C₅H₁₀—, —C₆H₁₂—, —C₈H₁₆—, —C₁₀H₂₀—, etc.

When L is an alkenylene group which may be substituted, the number of carbon atoms is usually 1 to 12, and examples of the substituents include an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, a halogen atom, acyl group, acyloxy group, imino group, amide group, acid imide group, a monovalent heterocyclic group, carboxyl group, substituted carboxyl group, cyano group, etc.

When this alkenylene group contains —CH₂— group, one or more of —CH₂— groups contained in the alkenylene group may be replaced with the group selected from the group consisting of —O—, —S—, —CO—, —CO₂—, —SO—, —SO₂—, —SiR_{15′}R_{16′}—, NR_{17′}—, —BR_{18′}—, —PR_{19′}—, and —P(═O)(R_{20′})—.

Concrete examples of R_{15′} to R_{20′} include the same as those of R_{3′} to R_{14′} in the above R′. As the preferable example of alkenylene group, —CH═CH—, —CH═CH—CH₂—, etc. are exemplified.

When L is an alkynylene group, the number of carbon atoms is usually 1 to 12, and examples of the substituents include an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, acid imide group, a monovalent heterocyclic group, carboxyl group, substituted carboxyl group, cyano group, etc.

When this alkynylene group contains —CH₂— group, one or more of —CH₂— groups contained in the alkenylene group may be replaced with the group selected from the group consisting of —O—, —S—, —CO—, —CO₂—, —SO—, —SO₂—, —SiR_{15′}R_{16′—, NR}_{17′}—, —BR_{18′}—, —PR_{19′}—, and —P(═O)(R_{20′})—. Concrete examples of R_{15′} to R_{20′} include the same as those of R_{3′} to R_{14′} in the above R′. As the preferable example of alkynylene group, —C≡C—, —CH₂—C≡C—CH₂—, etc. are exemplified.

When L is an arylene group which may be substituted, the concrete examples of this arylene group include an atomic group in which two hydrogen atoms are removed from an aromatic ring of the aromatic hydrocarbon containing 6-60 carbon atoms, preferably an atomic group in which two hydrogen atoms are removed from a benzene ring, and as the substituent which may be substituted to an aromatic ring, C₁-C₁₂ alkyl group, and C₁-C₁₂ alkoxy group are preferable.

When L is a divalent heterocyclic group which may be substituted, as the substituent which may be substituted to said heterocyclic group, C₁-C₁₂ alkyl group, and C₁-C₁₂ alkoxy group are preferable. The number of carbon atoms is usually about 4 to 60, and preferably 4 to 20. The number of carbon atoms of the substituent is not counted as the number of carbon atoms of the heterocyclic compound group. The heterocyclic compound means an organic compound having a cyclic structure in which at least one heteroatom such as oxygen, sulfur, nitrogen, phosphorus, boron, etc. is contained in the cyclic structure as the element other than carbon atoms.

Concrete examples thereof include thienyl group, C₁-C₁₂ alkylthienyl group, pyroryl group, furyl group, pyridyl group, C₁-C₁₂ alkyl pyridyl group, piperidyl group, quinolyl group, isoquinolyl group, etc., and thienyl group, C₁-C₁₂ alkylthienyl group, pyridyl group, and C₁-C₁₂ alkylpyridyl group are preferable.

Moreover, among L, a single bond, —O— and —S— are preferable.

As Ar₂₀, structures represented by the below formula (1-1′), (1-2′) or (1-3′) are exemplified

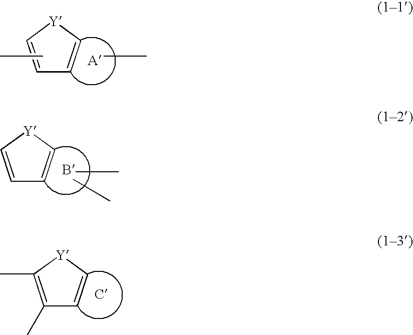

Wherein, ring A′ and ring B′ and ring C′ each independently represent an aromatic ring. Formulae (1-1′), (1-2′) and (1-3′) respectively have 1 to 4 substituents represented by -L-X. L and X represent the same meaning as the above. Y′ represents O atom, S atom, Se atom, Te atom, the below formula (1-A), (1-B), (1-C), (1-D), (1-E) or (1-F).
As Ar₂₀, structures represented by the below formula (1-4′) or (1-5′) are exemplified. 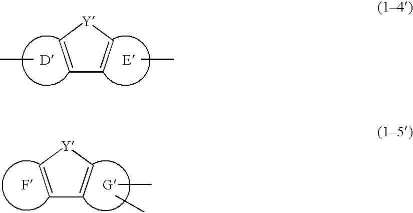
Wherein, ring D′, ring E′ and ring F′ and ring G′ each independently represent an aromatic ring, formulae (1-4′) and (1-5′) respectively have 1 to 4 substituents represented by -L-X. L, X and X′ represent the same meaning as the above. 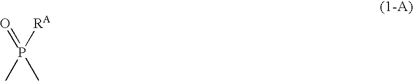
(Wherein, R^{A} shows a hydrogen atom, alkyl group, cycloalkyl group, arylalkyl group, aryl group, alkyloxy group, cycloalkyl oxy group, arylalkyloxy group, aryloxy group, or a group represented by -L-X.) 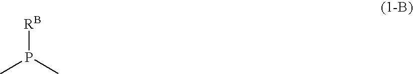
(Wherein, R^{B} shows an alkyl group, alkyloxy group, alkylthio group, aryl group, aryloxy group, arylthio group, arylalkyl group, arylalkyloxy group, arylalkylthio group, substituted amino group, acyl group, acyloxy group, amide group, monovalent heterocyclic group, or a group represented by -L-X.) 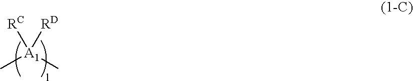
(Wherein, A₁ represents Si, Ge and Sn, and R^{C} and R^{D} each independently represent an alkyl group, alkyloxy group, alkylthio group, aryl group, aryloxy group, arylthio group, arylalkyl group, arylalkyloxy group, arylalkylthio group, substituted amino group, acyloxy group, amide group, monovalent heterocyclic group, or a group represented by -L-X. l represents 1 or 2.) 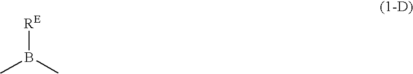
(Wherein, R^{E} represents a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group, halogen atom, or a group represented by -L-X.) 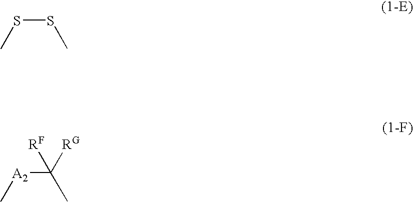
(Wherein, A₂ represents O or S, and R^{F} and R^{G} each independently represent an alkyl group, alkyloxy group, alkylthio group, aryl group, aryloxy group, arylthio group, arylalkyl group, arylalkyloxy group, arylalkylthio group, substituted amino group, acyloxy group, amide group, monovalent heterocyclic group, or a group represented by -L-X.)

Concrete examples of a formula (1-1′) include those in which Y of the group shown by the concrete examples of (1-1) is Y′, and 1 to 4-L-X are substituted to the aromatic ring of the group shown by the concrete examples.

Concrete examples of a formula (1-2′) include those in which Y of the group shown by the concrete examples of (1-2) is Y′, and 1 to 4-L-X are substituted to the aromatic ring of the group shown by the concrete examples.

Concrete examples of a formula (1-3′) include those in which Y of the group shown by the concrete examples of (1-3) is Y′, and 1 to 4 -L-X are substituted to the aromatic ring of the group shown by the concrete examples.

Concrete examples of a formula (1-4′) include those in which Y of the group shown by the concrete examples of (1-4) is Y′, and 1 to 4-L-X are substituted to the aromatic ring of the group shown by the concrete examples.

Concrete examples of a formula (1-5′) include those in which Y of the group shown by the concrete examples of (1-5) is Y′, and 1 to 4-L-X are substituted to the aromatic ring of the group shown by the concrete examples.

Repeating units containing the structures represented by the above formula (16-1), (1-1′), (1-2′), (1-3′), (1-4′), (1-5′) may contain, in addition to a group represented by -L-X, a substituent selected from the group consisting of alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group, and cyano group.

a plurality of substituent exist, they may be the same or different.

Concrete examples of the substituents R^{A} to R^{G} in (1-A), (1-B), (1-C), (1-D), and (1-F) include the same with those described in the above R′.

As Ar₂₀ in the above formula (16-1), (1-4′) is preferable. The below formula (1-4′A), (1-4′B), (1-4′C) (1-4′D) or (1-4′E) is preferable, structures represented by the below formula (1-4′A), (1-4′B) or (1-4° C.) are further preferable and structures represented by (1-4′A) is the most preferable.

Concrete examples of a formula (1-4′) include, in the example shown as the concrete examples of (1-4), those whose 1 to 4 of respective Rs are represented by -L-X.

Concrete examples of other structures include, in the below formulae, those whose 1 to 4 of respective Rs are represented by -L-X.

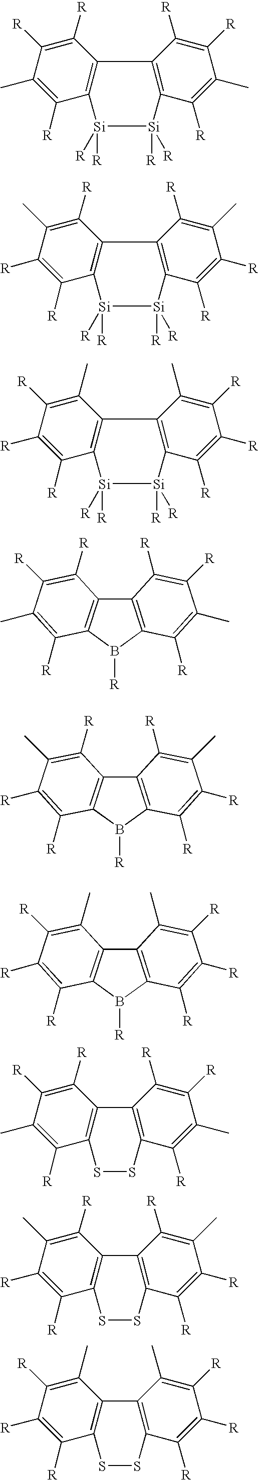

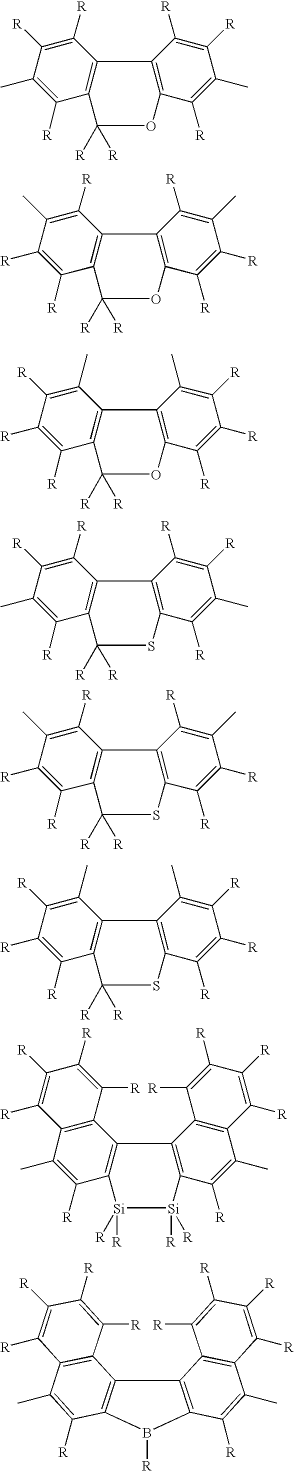

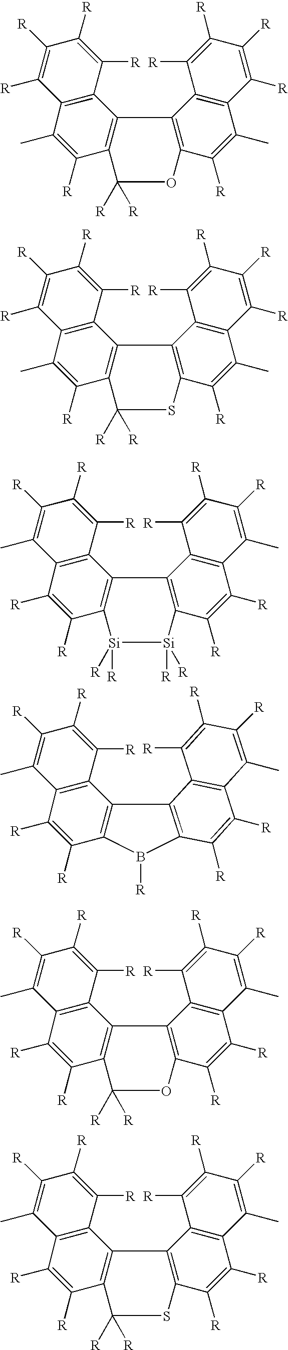

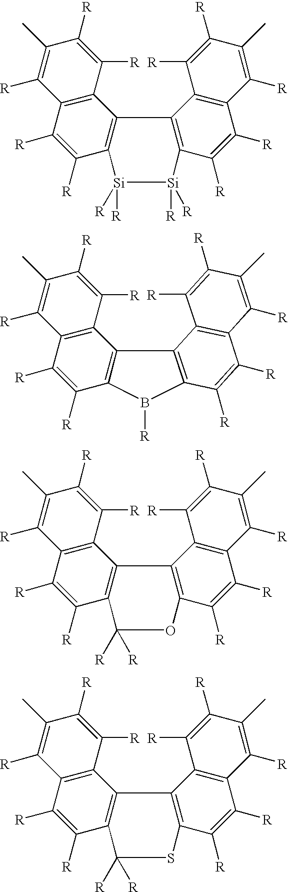

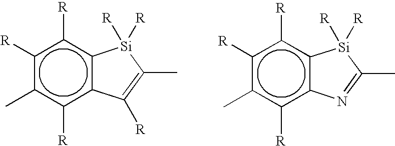

Concrete examples of Ar₂₀ include, in addition to those belongs to the above formulae (1-1′) to (1-5′), those whose 1 to 4 of respective Rs are represented by -L-X.

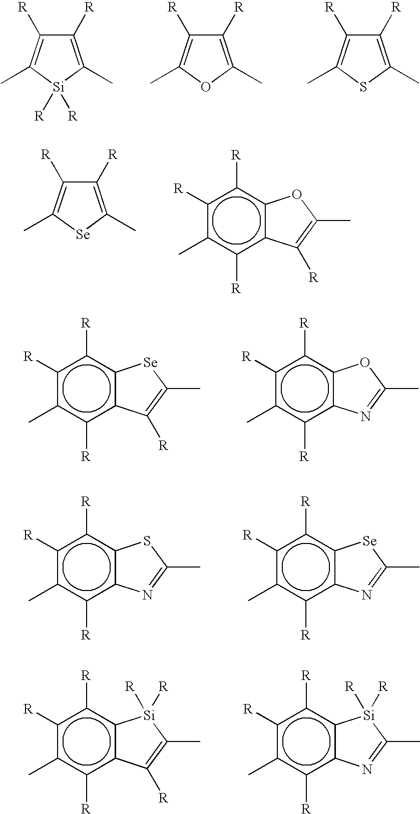

In the above formula (1-1′), (1-2′), (1-3′), (1-4′) or (1-5′), it is preferable that ring A′, ring B′, ring C′, ring D′, ring E′, ring F′ and ring G′, are aromatic hydrocarbon rings.

The repeating unit represented by the above formula (1-1′) is preferably a repeating unit selected from the below formula (1-1′A) to (1-1′E), and more preferably a structure represented by (1-1′A), (1-1′B) or (1-1′C). 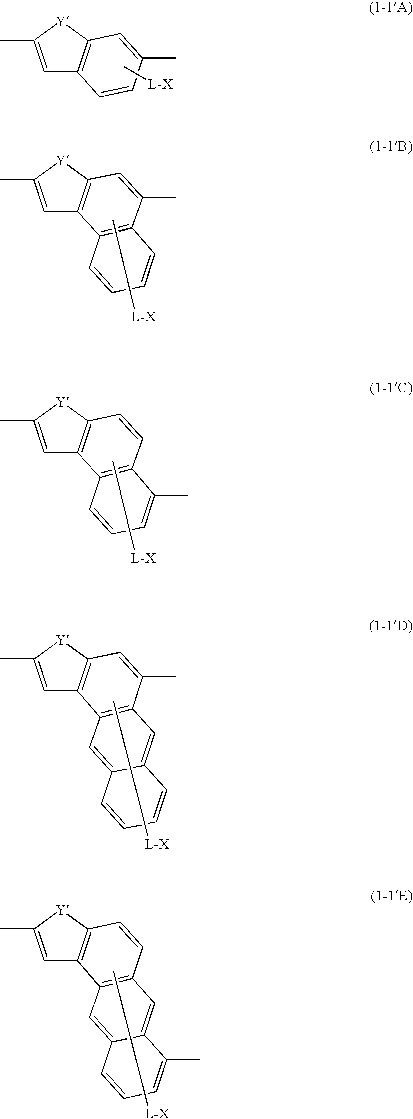
(Wherein, L, X, and Y′ represent the same meaning as the above.)

The repeating unit represented by the above formula (1-4′) is preferably a repeating unit selected from the below formula (1-4′A) to (1-4′E), more preferably (1-4′A), (1-4′B) or (1-4′C), and the most preferably (1-4′A).

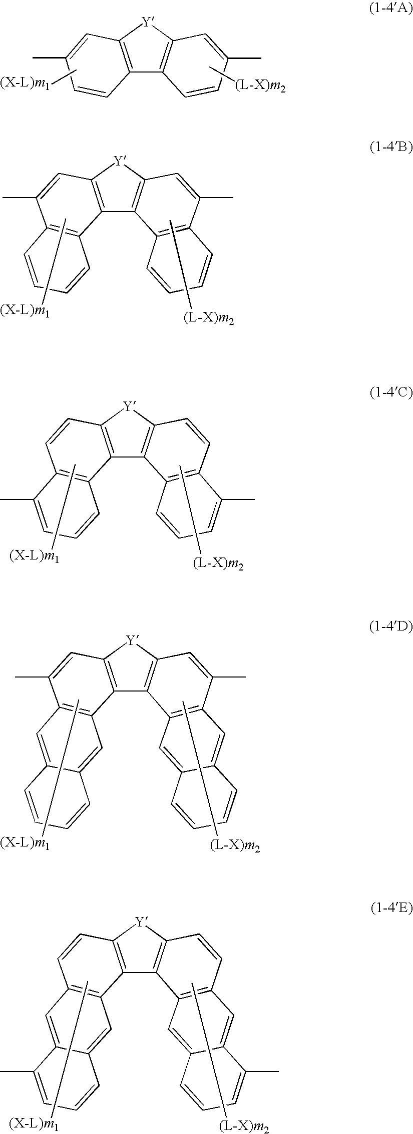

(Wherein, L, X, and Y′ represent the same meaning as the above. m₁ and m₂ are 0 or 1, and either of them is 1.)

In the above concrete examples, it is preferable that Y′ is O atom or S atom.

In the above formula (16-1), X is preferably a complex structure containing gold, platinum, iridium, osmium, rhenium, tungsten, europium, terbium, thulium, dysprosium, samarium, praseodymium, gadolinium, and ytterbium atom, more preferably a complex structure containing gold, platinum, iridium, osmium, rhenium, and tungsten atom, further preferably a complex structure containing gold, platinum, iridium, osmium, and rhenium atom, and especially preferably a complex structure containing platinum, iridium, and rhenium atom.

In the above formula (16-1), n′ is 0 or 1.

In the above formula (16-1), R1′ and R2′ each independently represent a hydrogen atom, alkyl group, aryl group, monovalent heterocyclic group, or cyano group.

Here, concrete examples of alkyl group, aryl group, and monovalent heterocyclic group in R_{1′} and R_{2′}, include the same those represented in the above R′.

The total amount of the repeating units represented by the above formula (14) to (16) and (16-1) based on the total moles of all the repeating units in the polymer compound of the present invention is usually 0.01-50% by mole, and preferably 0.1-10% by mole.

Moreover, when the metal complex structure showing light-emission from triplet excited state of the present invention is contained in the terminal of a polymer chain, the terminal structure is represented, for example, by the below formula (17).
-L₅M(H)ₕ_{₄}(K)ₖ_{₄} (17)
(Wherein, M, H, and K represent the same meaning as the above. L₅ represents a residue in which one hydrogen atom is removed from the ligand containing one or more atoms, as an atom which bonds with M, selected from a nitrogen atom, an oxygen atom, a carbon atom, a sulfur atom, and a phosphorus atom. h₄ represents an integer of 1-3, k₄ represents an integer of 0-3, and h₄+k₄ is an integer of 1-4.)

In the above formula (14)-(16), (16-1) and (17), examples of the ligand containing one or more atoms as an atom which bonds with M, selected from a nitrogen atom, oxygen atom, carbon atom, sulfur atom, and phosphorus atom, include an alkyl group, alkoxy group, acyloxy group, alkylthio group, aryl group, aryloxy group, arylthio group, arylalkyl group, arylalkoxy group, arylalkylthio group, amino group, substituted amino group, alkene ligand, alkyne ligand, amine ligand, imine ligand, amide group, acid imide group, isonitril ligand, cyano group, phosphine ligand, phosphine oxide ligand, phosphite ligand, sulfone ligand, sulfoxide ligand, sulfonate group, sulfide ligand, heterocyclic ligand, carboxyl group, carbonyl ligand, and ether ligand; and may also include polydentate ligands derived from the combination thereof.

As the alkene ligand, ethylene, propylene, butene, hexene, and decene are exemplified.

As the alkyne ligand, acetylene, phenyl acetylene, and diphenyl acetylene are exemplified, without being limited especially.

As the isonitril ligand, t-butyl isonitril and phenyl isonitril are exemplified, without being limited especially.

As the phosphine ligand, exemplified are those having a coordinate bond at the phosphorus atom with M, such as triphenyl phosphine, tri-o-tolyl phosphine, tri-t-butyl phosphine, tricyclohexyl phosphine, 1,2-bis(diphenyl phosphino) ethane, and 1,3-bis(diphenyl phosphino) propane.

As the phosphine oxide ligand, tributylphosphine oxide and triphenylphosphine oxide are exemplified, without being limited especially.

As the phosphite ligand, exemplified are those having a coordinate bond at the phosphorus atom with M, such as trimethyl phosphite, triethyl phosphite, triphenyl phosphite, and tri benzyl phosphite.

As the sulfone ligand, dimethylsulfone and dibutylsulfone are exemplified, without being limited especially.

As the sulfoxide ligand, dimethyl sulfoxide and dibutyl sulfoxide are exemplified, without being limited especially.

As the sulfonate group, benzene sulfonate group, p-toluene sulfonate group, methane sulfonate group, ethane sulfonate group, and trifluoromethane sulfonate group are exemplified.

As the sulfide ligand, exemplified are those having a coordinate bond at the sulfur atom with M, such as dimethyl sulfide, diphenyl sulfide and thioanisole.

The heterocyclic ligand may be either zerovalent or monovalent, and as the zerovalent ligand, exemplified are atomic groups in which a hydrogen atom is removed from 2,2′-bipyridyl, 1,10-phenanthroline, 2-(4-thiophene-2-yl)pyridine, 2-(benzothiophene-2-yl)pyridine etc. As the monovalent ligand, exemplified are atomic groups in which a hydrogen atom is removed from phenyl pyridine, 2-(paraphenyl phenyl)pyridine, 7-bromobenzo[h]quinoline, 2-(4-phenylthiophene-2-yl)pyridine, 2-phenylbenzoxazole, 2-(paraphenyl phenyl)benzoxazole, 2-phenylbenzothiazole, and 2-(para phenylphenyl)benzothiazole, etc.

As the carboxyl group, acetoxy group, naphthenate group, and 2-ethylhexanoate group are exemplified, without being limited especially.

As the carbonyl ligand, exemplified are those having a coordinate bond at the oxygen atom with M, and example thereof include ketones such as carbon monoxide, acetone and benzophenone, and diketones such as acetyl acetone and acenaphtho quinone.

As the ether ligand, exemplified are those having a coordinate bond at the oxygen atom with M, and example thereof include dimethyl ether, diethyl ether, tetrahydrofuran, 1,2-dimethoxy ethane, etc.

The polydentate ligands (bi- or more-dentate ligand) derived from the combination of these include: groups where a heterocyclic ring and a benzene ring are bonded, such as, phenylpyridine, 2-(paraphenylphenyl)pyridine, 2-phenyl benzoxazole, 2-(paraphenylphenyl)benzoxazole, 2-phenyl benzothiazole, 2-(paraphenylphenyl)benzothiazole, 1,3-di(2-pyridyl)benzene, etc.; groups where two or more hetero cyclic rings are bonded, such as, 2-(4-thiophene-2-yl)pyridine, 2-(4-phenyl thiophene-2-yl)pyridine, 2-(benzothiophene-2-yl)pyridine, 2,2′:6′,2″-terpyridine, 2,3,7,8,12,13,17,18-octa ethyl-21H,23H-porphyrin, etc.; and acetonates, such as acetylacetonate, dibenzomethylate, and thenoyltrifluoro acetonate, etc.

As the polydentate ligands derived from the combination of alkyl group, alkoxy group, acyloxy group, alkylthio group, aryl group, aryloxy group, arylthio group, arylalkyl group, arylalkoxy group, arylalkylthio group, substituted amino group, sulfonate group, cyano group, heterocyclic ligand, carbonyl ligand, ether ligand, amine ligand, imine ligand, phosphine ligand, phosphite ligand, and sulfide ligand, exemplified are acetylacetonates such as acetylacetonate, dibenzomethylate, thenoylrifluoroacetonate, etc.

M is a metal atom which has an atomic number of 50 or more, and intersystem crossing between a singlet state and a triplet state in this compound can occur by the spin-orbital interaction.

Examples of the atom represented by M include a rhenium atom, osmium atom, iridium atom, platinum atom, gold atom, lanthanum atom, cerium atom, praseodymium atom, neodymium atom, promethium atom, samarium atom, europium atom, gadolinium atom, terbium atom, dysprosium atom, etc. A rhenium atom, osmium atom, iridium atom, platinum atom, gold atom, samarium atom, europium atom, gadolinium atom, terbium atom, and dysprosium atom are preferable; and an iridium atom, platinum atom, gold atom, and europium atom is more preferable in respect of light emitting efficiency.

H represents a ligand containing one or more atoms selected from a nitrogen atom, oxygen atom, carbon atom, sulfur atom, and phosphorus atom, as the atom which bonds with M.

The ligand containing one or more atoms selected from a nitrogen atom, oxygen atom, carbon atom, sulfur atom, and phosphorus atom, as the atom which bonds with M is the same as those exemplified as K.

Examples of H include a ligand composed by combining heterocycles, such as pyridine ring, thiophene ring and benzoxazole ring, and a benzene ring.

Preferable examples are as follows.

When H is a bidentate ligand which bonds with M at two atoms selected from a nitrogen atom, an oxygen atom, a carbon atom, a sulfur atom, and a phosphorus atom, and forms 5 membered ring: phenylpyridine, 2-(paraphenylphenyl)pyridine, 7-bromobenzo [h]quinoline, 2-(4-thiophene-2-yl)pyridine, 2-(4-phenyl thiophene-2-yl)pyridine, 2-phenylbenzoxazole, 2-(paraphenyl phenyl)benzoxazole, 2-phenylbenzothiazole, 2-(paraphenyl phenyl)benzothiazole, 2-(benzothiophene-2-yl)pyridine, etc.

When H is a tridentate ligand which bonds with M at any three atoms selected from a nitrogen atom, an oxygen atom, a carbon atom, a sulfur atom, and a phosphorus atom: 2,2′:6′,2″-terpyridine, 1,3-di(2-pyridyl)benzene, etc.

When H is a tetradentate ligand which bonds with M at any four atoms selected from a nitrogen atom, an oxygen atom, a carbon atom, a sulfur atom, and a phosphorus atom:

7,8,12,13,17,18-hexakis ethyl-21H,23H-porphyrin which is a ligand in which four pyrrole rings are connected in cyclic form.

H may have a substituent and examples thereof include halogen atom, alkyl group, alkoxy group, alkylthio group, aryl group, aryloxy group, arylthio group, arylalkyl group, arylalkoxy group, arylalkylthio group, amino group, substituted amino group, silyl group, substituted silyl group, acyl group, acyloxy group, imine residue, amide group, arylalkenyl group, arylalkynyl group, cyano group, and monovalent heterocyclic group.

As H, followings are exemplified.

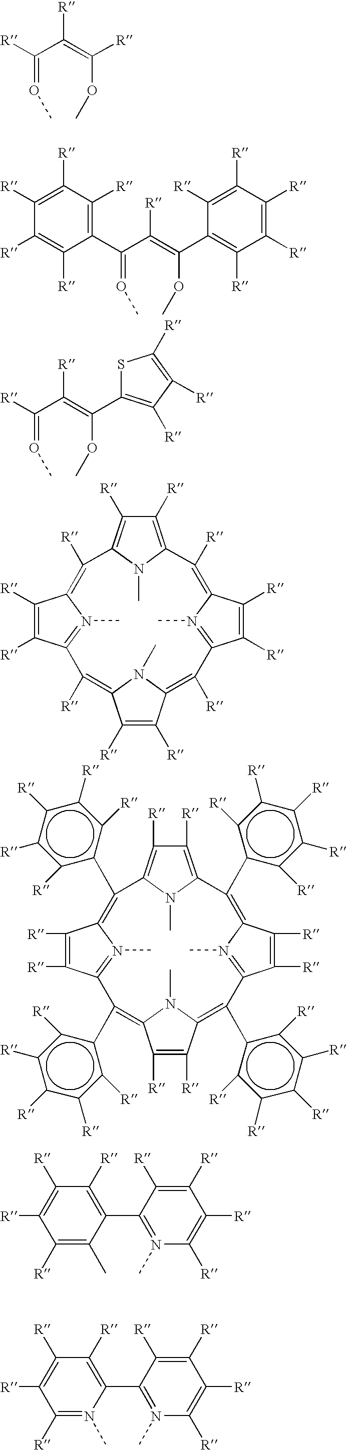

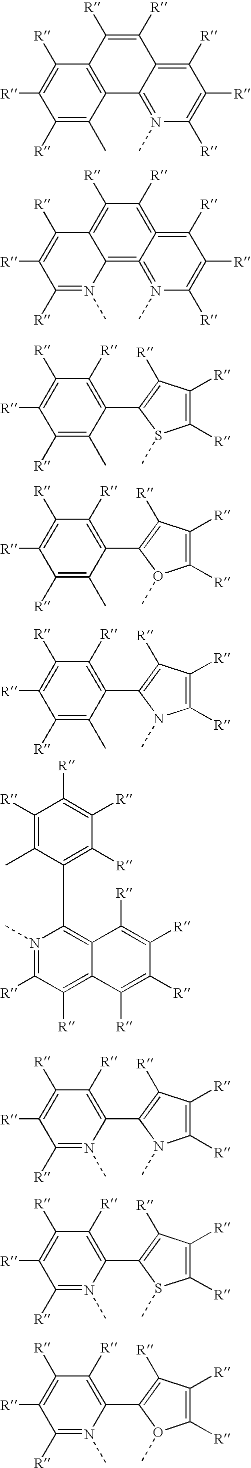

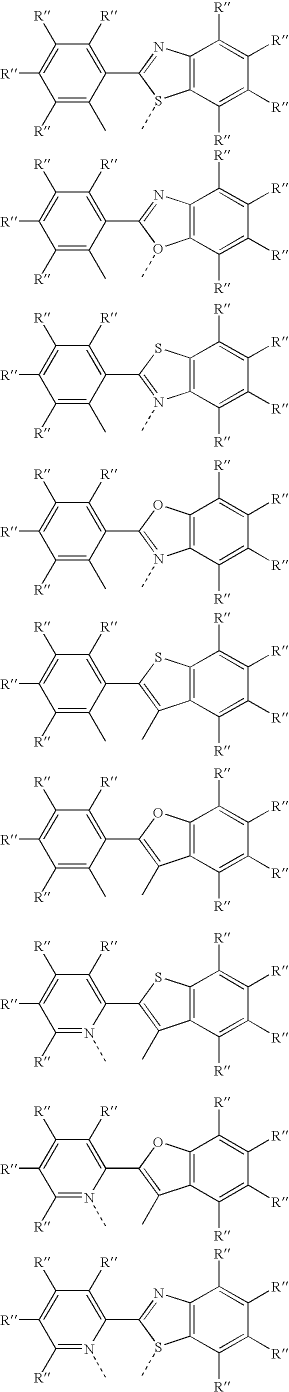

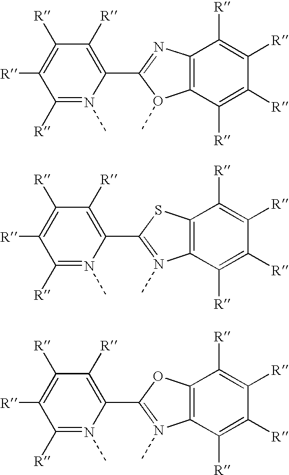

Here, R″ each independently represent a hydrogen atom, halogen atom, alkyl group, alkoxy group, alkylthio group, aryl group, aryloxy group, arylthio group, arylalkyl group, arylalkoxy group, arylalkylthio group, amino group, substituted amino group, silyl group, substituted silyl group, acyl group, acyloxy group, imino group, amide group, arylalkenyl group, arylalkynyl group, cyano group, and monovalent heterocyclic group. Concretely, the group in the above R are exemplified. R″ may be mutually bonded to form a ring. In order to improve the solubility in a solvent, it is preferable that at least one of R″ contains an alkyl group of long chain.

As a concrete examples of R″, those as the same groups shown in the above R and R′ are exemplified.

It is preferable that H bonds with M at the at least one nitrogen or carbon atom in respect of the stability, and it is more preferable that H bonds with M at polydentate.

When H is a bidentate ligand which bonds with M at two atoms selected from a nitrogen atom, an oxygen atom, a carbon atom, a sulfur atom, and a phosphorus atom, to form a 5 membered ring, and it is more preferable that M bonds with at least one carbon atom, and H is a bidentate ligand represented by (H-1), (H-2), (H-3) or (H-4). 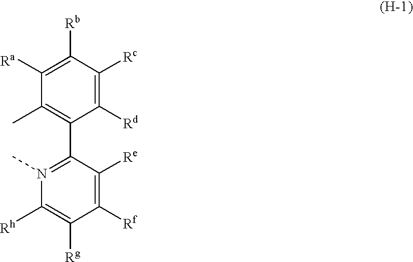
In formula (H-1), R^{a} to R^{h} each independently represent a hydrogen atom, halogen atom, alkyl group, alkoxy group, alkylthio group, aryl group, aryloxy group, arylthio group, arylalkyl group, arylalkoxy group, arylalkylthio group, amino group, substituted amino group, silyl group, substituted silyl group, acyl group, acyloxy group, imine residue, amide group, arylalkenyl group, arylalkynyl group, cyano group, and monovalent heterocyclic group.

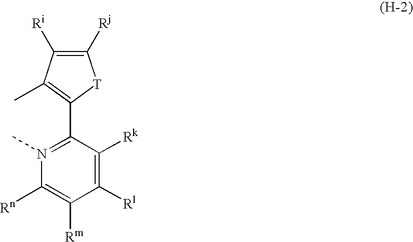

In formula (H-2), T is S or O, and Rⁱ to Rⁿ each independently represent a hydrogen atom, halogen atom, alkyl group, alkoxy group, alkylthio group, aryl group, aryloxy group, arylthio group, arylalkyl group, arylalkoxy group, arylalkylthio group, amino group, substituted amino group, silyl group, substituted silyl group, acyl group, acyloxy group, imine residue, amide group, arylalkenyl group, arylalkynyl group, cyano group, and monovalent heterocyclic group.
Rᵢ and R^{j} may form a ring, and in that case, it may be a condensed benzene ring. 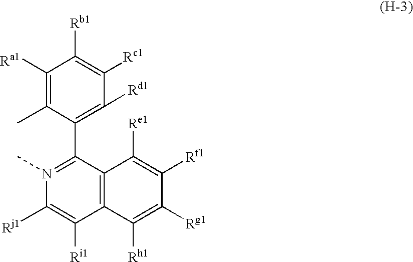
In formula (H-3), R^{a1} to R^{j1} each independently represent a hydrogen atom, halogen atom, alkyl group, alkoxy group, alkylthio group, aryl group, aryloxy group, arylthio group, arylalkyl group, arylalkoxy group, arylalkylthio group, substituted amino group, substituted silyl group, acyl group, acyloxy group, imine residue, amide group, arylalkenyl group, arylalkynyl group, cyano group, and monovalent heterocyclic group. 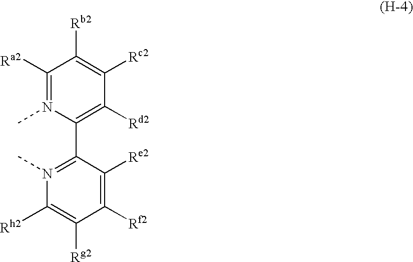
In formula (H-4), R^{a2} to R^{j2} each independently represent a hydrogen atom, halogen atom, alkyl group, alkoxy group, alkylthio group, aryl group, aryloxy group, arylthio group, arylalkyl group, arylalkoxy group, arylalkylthio group, substituted amino group, substituted silyl group, acyl group, acyloxy group, imine residue, amide group, arylalkenyl group, arylalkynyl group, cyano group, and monovalent heterocyclic group.

When H is a tridentate ligand which bonds with M at three atoms selected from a nitrogen atom, an oxygen atom, a carbon atom, a sulfur atom, and a phosphorus atom, it is more preferable that H is a tridentate ligand represented by the below formula (H-5) or (H-6).

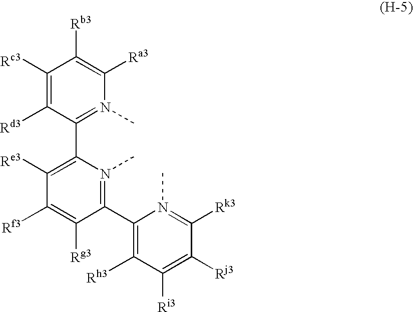

In formula (H-5), R^{a3} to R^{k3} each independently represent a hydrogen atom, halogen atom, alkyl group, alkoxy group, alkylthio group, aryl group, aryloxy group, arylthio group, arylalkyl group, arylalkoxy group, arylalkylthio group, substituted amino group, substituted silyl group, acyl group, acyloxy group, imine residue, amide group, arylalkenyl group, arylalkynyl group, cyano group, and monovalent heterocyclic group. 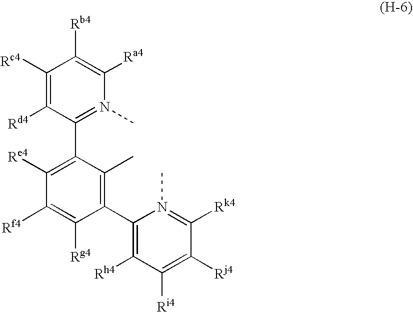
In formula (H-6), R^{a4}-R^{k4} each independently represent a hydrogen atom, halogen atom, alkyl group, alkoxy group, alkylthio group, aryl group, aryloxy group, arylthio group, arylalkyl group, arylalkoxy group, arylalkylthio group, substituted amino group, substituted silyl group, acyl group, acyloxy group, imine residue, amide group, arylalkenyl group, arylalkynyl group, cyano group, and monovalent heterocyclic group.

Concrete examples of R^{a} to Rⁿ, R^{a1} to R^{j1}, R^{a2} to R^{j2}, R^{a3} to R^{k3} and R^{a4} to R^{k4} include the same as shown by the above R and R′.

As L₁, L₂, L₃, L₄, or L₅, exemplified are residues in which hydrogen atoms, corresponding to the connecting bond number to the polymer chain, on R″ or R″ are removed from the group described in the above H. Concretely, exemplified are residues in which hydrogen atoms, corresponding to the connecting bond number to the polymer chain, on R″ or R″ are removed respectively from the concrete examples of the above structural formula.

In case of L₁, the number of connecting bonds to a polymer chain is 2, and, in case of L₂, L₃, L₄ and L₅, the number of connecting bonds to a polymer chain is 1.

From the viewpoint of improving light-emission strength, besides the metal complex structure showing light-emission from triplet excited state, the polymer complex compound of the present invention is preferably a copolymer comprising those having the structures of the same formula (1) but having a different substituent; or a copolymer comprising a repeating unit of formula (1) and one or more kinds of other repeating units. Examples of such a repeating unit include preferably a repeating unit represented by the a below formula (3), formula (4), formula (5), or formula (6).
-Ar₁- (3)
-(Ar₂-X₁)_{ff}-Ar₃- (4)
-Ar₄-X₂- (5)
-X₃- (6)

Wherein, Ar₁, Ar₂, Ar₃ and Ar₄ each independently represent an arylene group, or divalent heterocyclic group. X₁, X₂ and X₃ each independently represent —CR₁₅═CR₁₆—, —C≡C—, —N(R₁₇)—, or —(SiR₁₈R₁₉)ₘ—. R₁₅ and R₁₆ each independently represent a hydrogen atom, alkyl group, aryl group, monovalent heterocyclic group, carboxyl group, substituted carboxyl group, or cyano group. R₁₇, R₁₈ and R₁₉ each independently represent a hydrogen atom, alkyl group, aryl group, monovalent heterocyclic group, arylalkyl group, or substituted amino group. ff represents an integer of 0 to 2. m represents an integer of 1 to 12. When R₁₅, R₁₆, R₁₇, R₁₈ and R₁₉ respectively exist in plural, they may be the same or different.

The arylene group is an atomic group in which two hydrogen atoms of an aromatic hydrocarbon are removed, and usually, the number of carbon atoms is about 6 to 60, and preferably 6 to 20. The aromatic hydrocarbon includes those having a condensed ring, an independent benzene ring, or two or more condensed rings bonded through groups, such as a direct bond or a vinylene group.

Examples of the arylene group include phenylene group (for example, following formulas 1-3), naphthalenediyl group (following formulas 4-13), anthracenylene group (following formulas 14-19), biphenylene group (following formulas 20-25), fluorene-diyl group (following formulas 36-38), terphenyl-diyl group (following formulas 26-28), stilbene-diyl (following formulas A-D), distilbene-diyl (following formulas E, F), condensed ring compound group (following formulas 29-38), etc. Among them, phenylene group, biphenylene group, fluorene-diyl group and stilbene-diyl group are preferable.

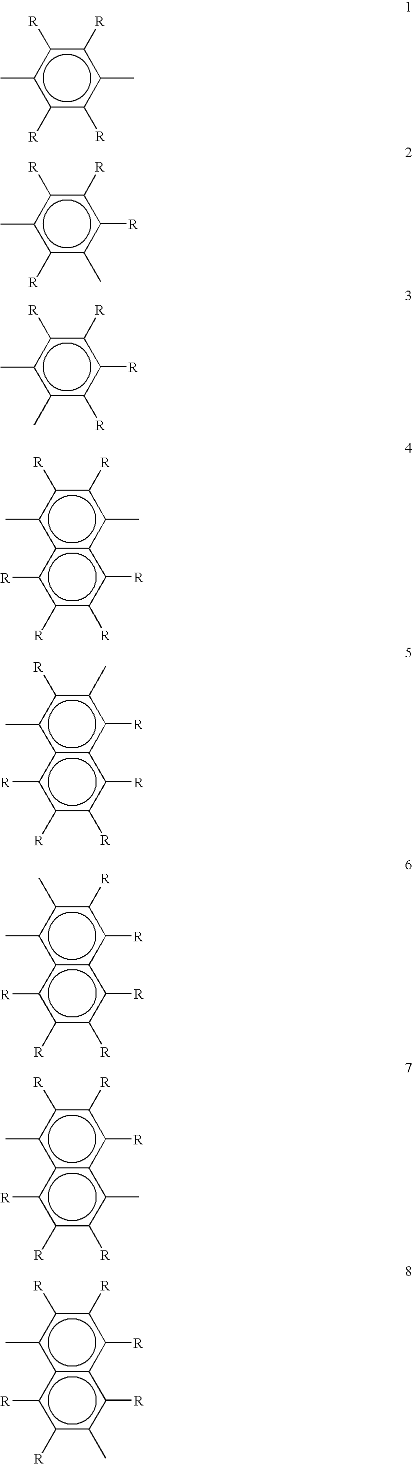

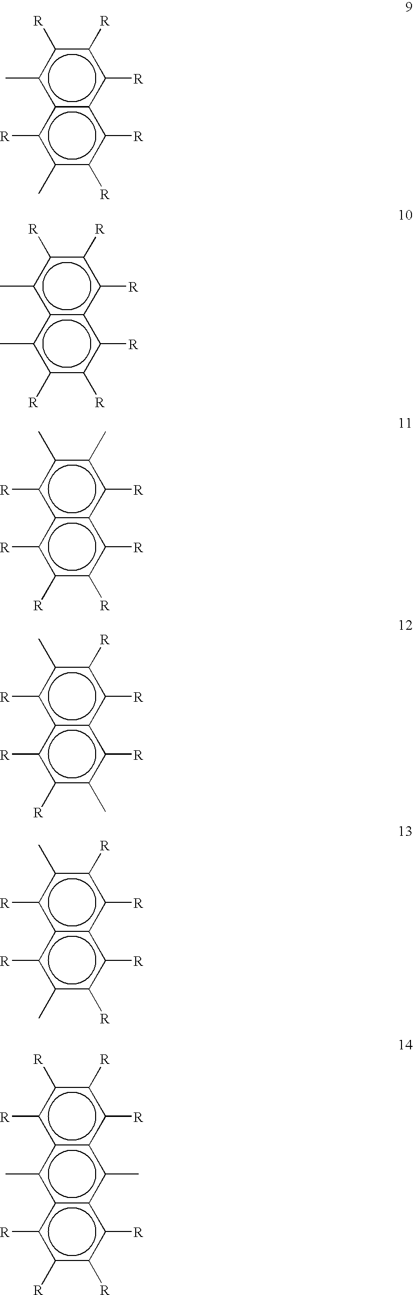

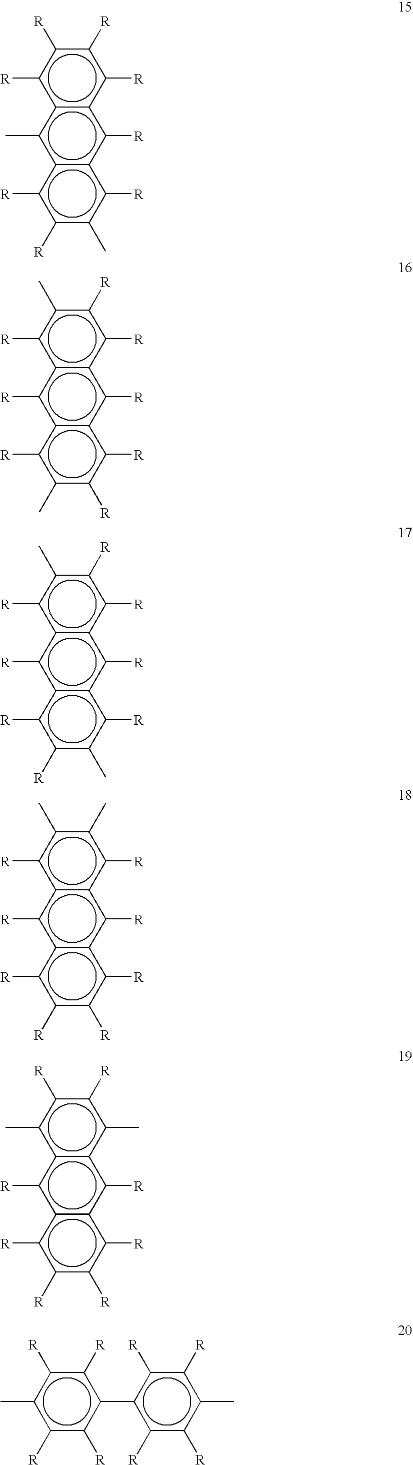

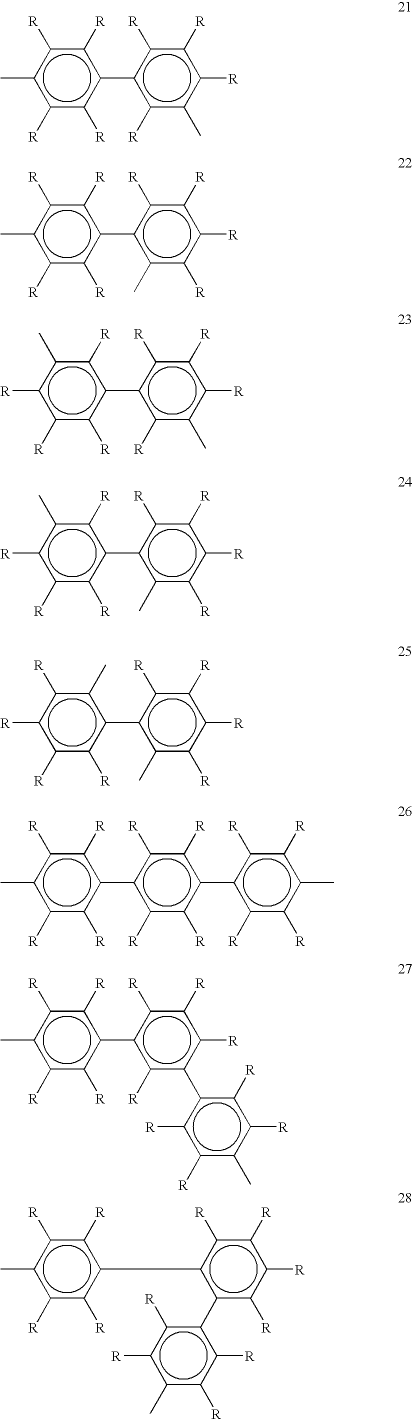

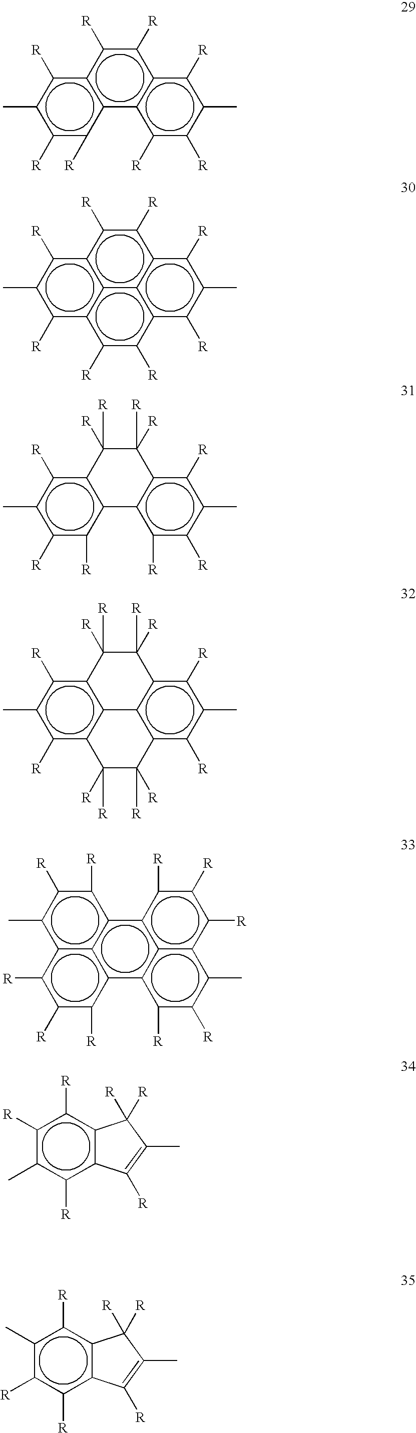

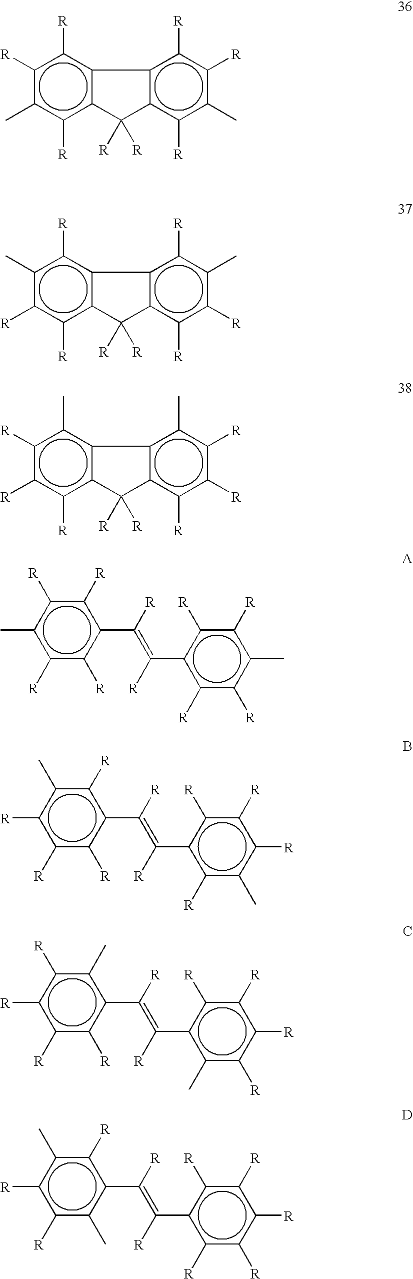

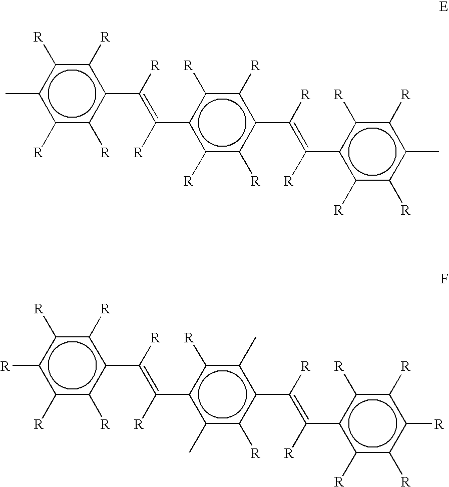

The divalent heterocyclic group means an atomic group in which two hydrogen atoms are removed from a heterocyclic compound, and the number of carbon atoms is usually about 3 to 60.

The heterocyclic compound means an organic compound having a cyclic structure in which at least one heteroatom such as oxygen, sulfur, nitrogen, phosphorus, boron, etc. is contained in the cyclic structure as the element other than carbon atoms.

Examples of the divalent heterocyclic groups include the followings.

Divalent heterocyclic groups containing nitrogen as a hetero atom; pyridine-diyl group (following formulas 39-44), diaza phenylene group (following formulas 45-48), quinolinediyl group (following formulas 49-63), quinoxalinediyl group (following formulas 64-68), acridinediyl group (following formulas 69-72), bipyridyldiyl group (following formulas 73-75), phenanthrolinediyl group (following formulas 76-78), etc.

Groups having a fluorene structure containing silicon, nitrogen, selenium, etc. as a hetero atom (following formulas 79-93).

5 membered heterocyclic groups containing silicon, nitrogen, sulfur, selenium, etc. as a hetero atom: (following formulas 94-98).

Condensed 5 membered heterocyclic groups containing silicon, nitrogen, selenium, etc. as a hetero atom: (following formulas 99-108),

5 membered heterocyclic groups containing silicon, nitrogen, sulfur, selenium, etc. as a hetero atom, which are connected at the a position of the hetero atom to form a dimer or an oligomer (following formulas 109-113);

5 membered ring heterocyclic groups containing silicon, nitrogen, sulfur, selenium, as a hetero atom is connected with a phenyl group at the a position of the hetero atom (following formulas 113-119); and

Groups of 5 membered ring heterocyclic groups containing nitrogen, oxygen, sulfur, as a hetero atom on which a phenyl group, furyl group, or thienyl group is substituted (following formulas 120-125).

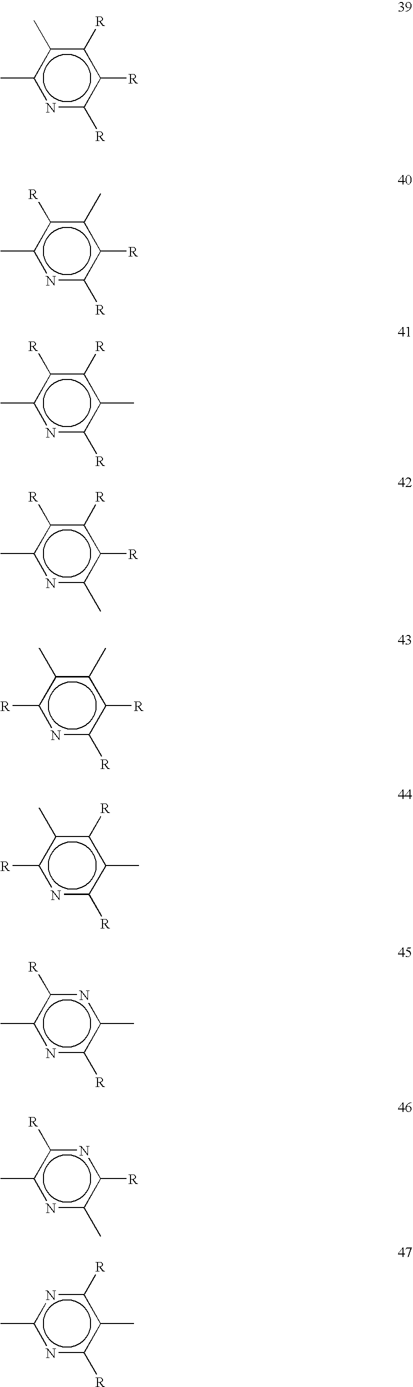

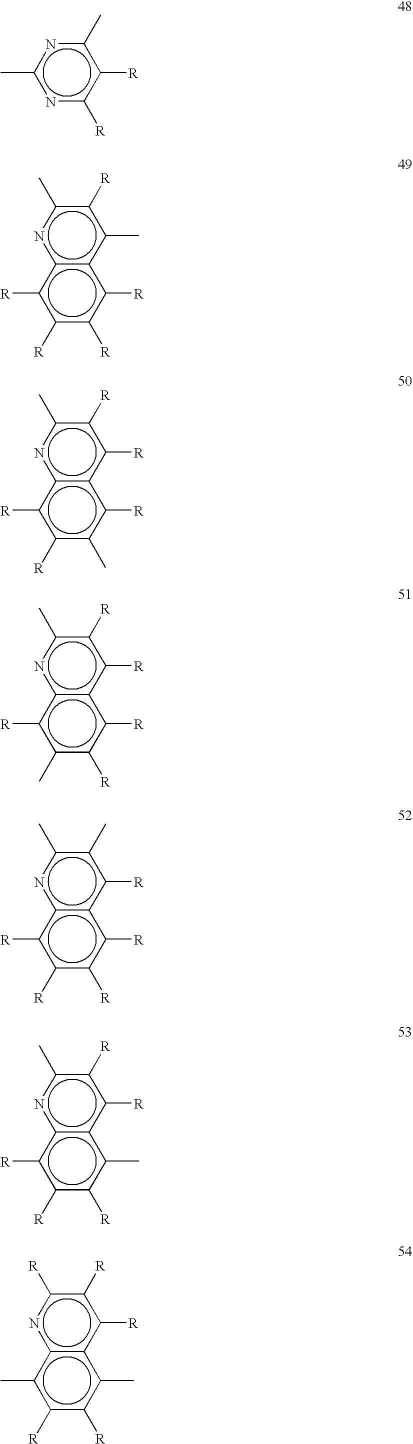

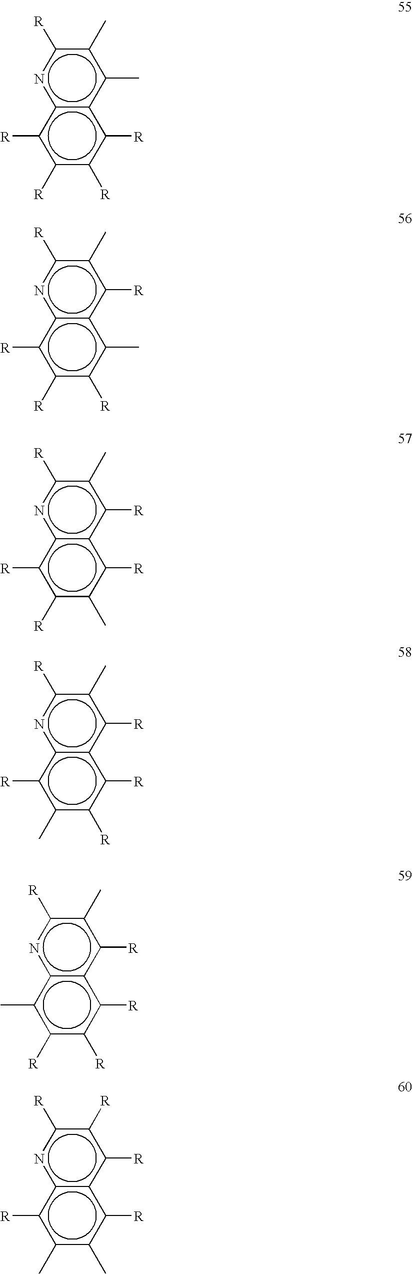

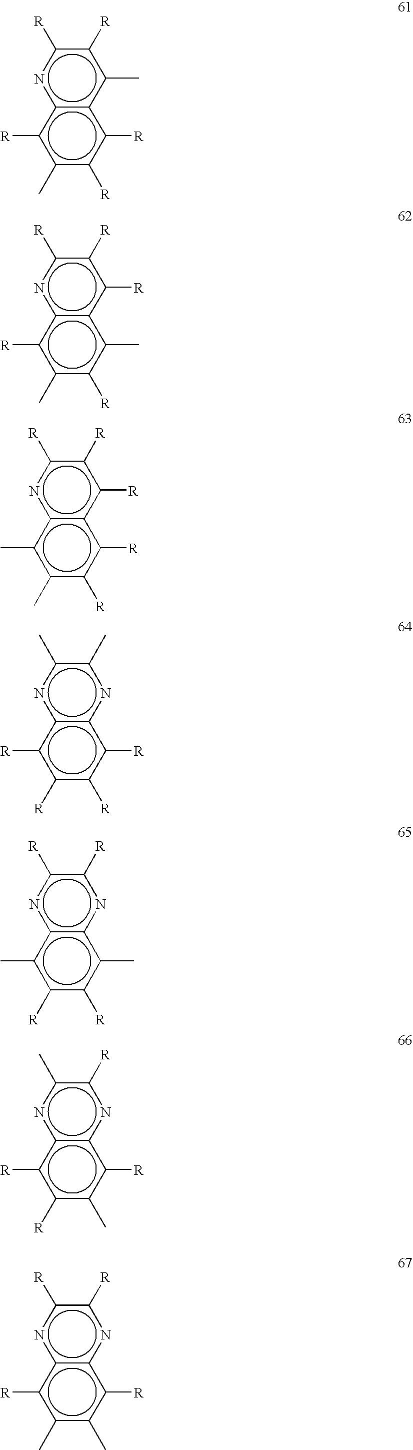

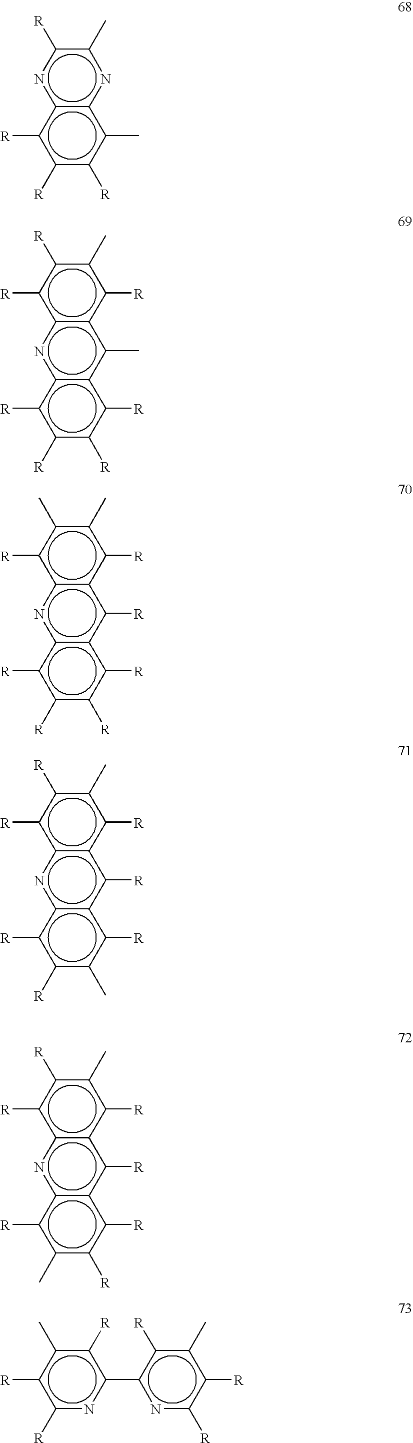

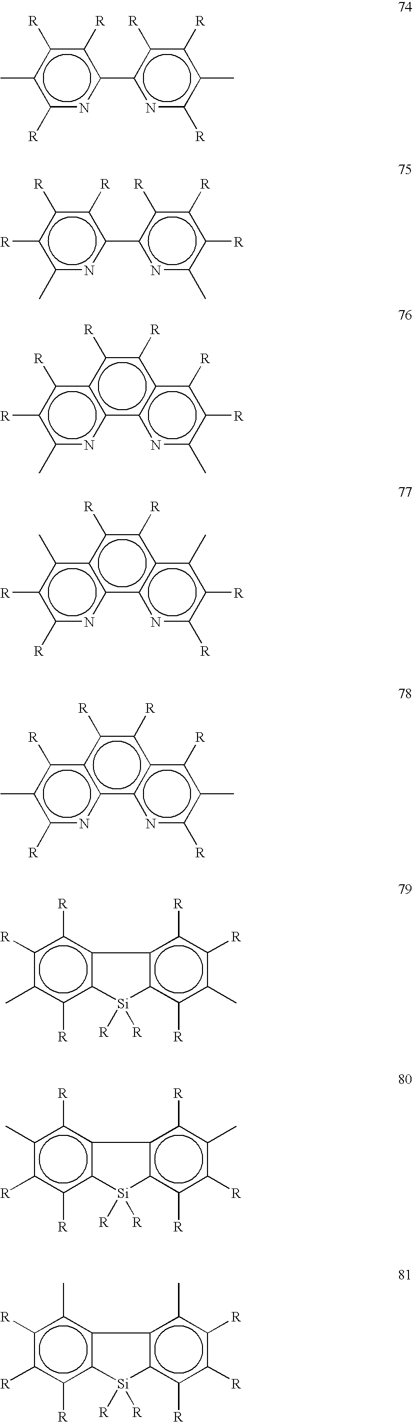

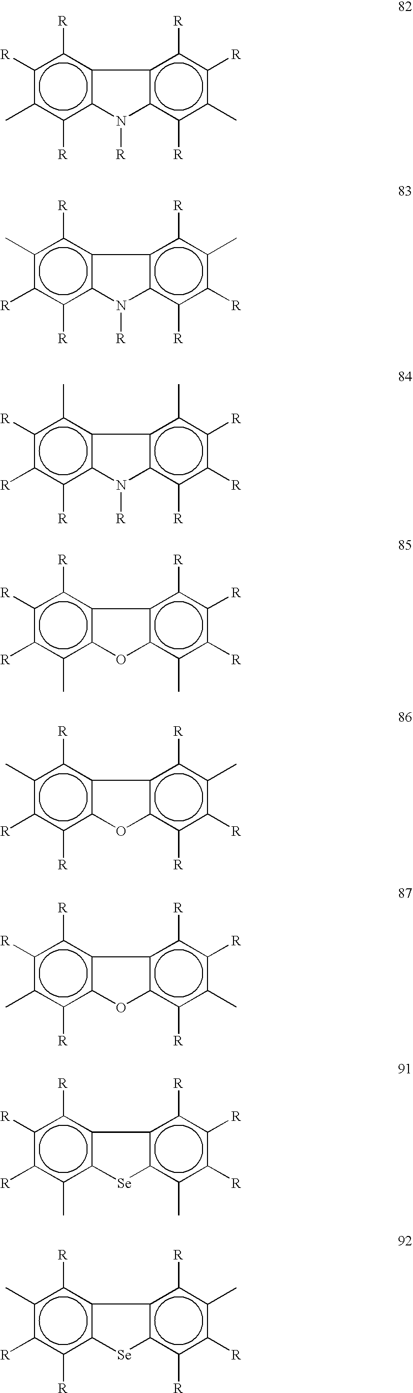

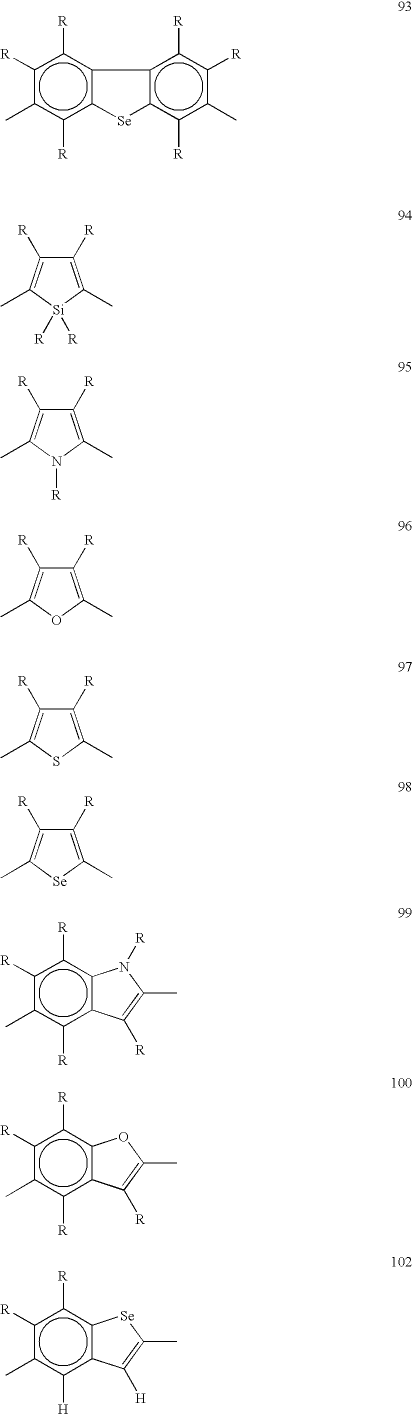

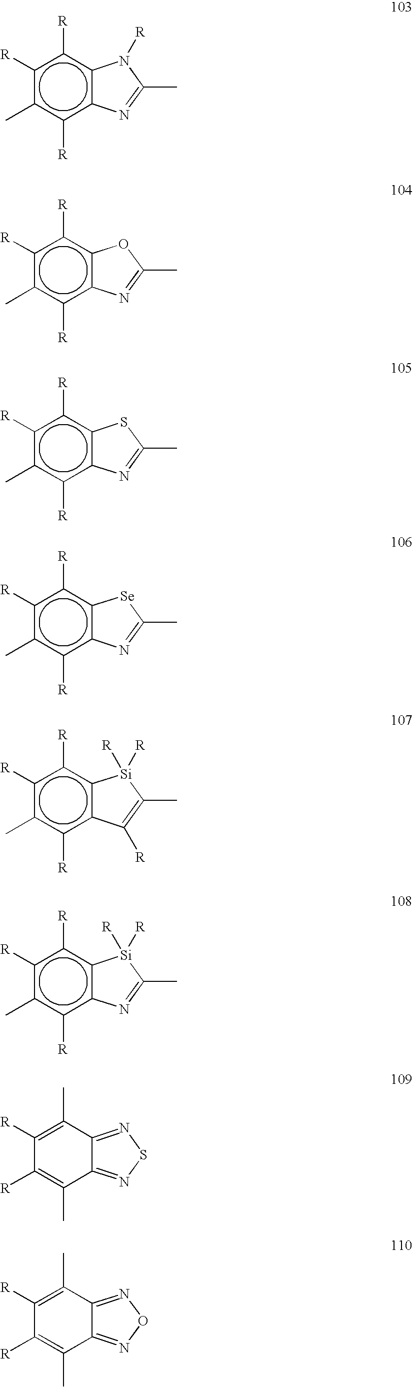

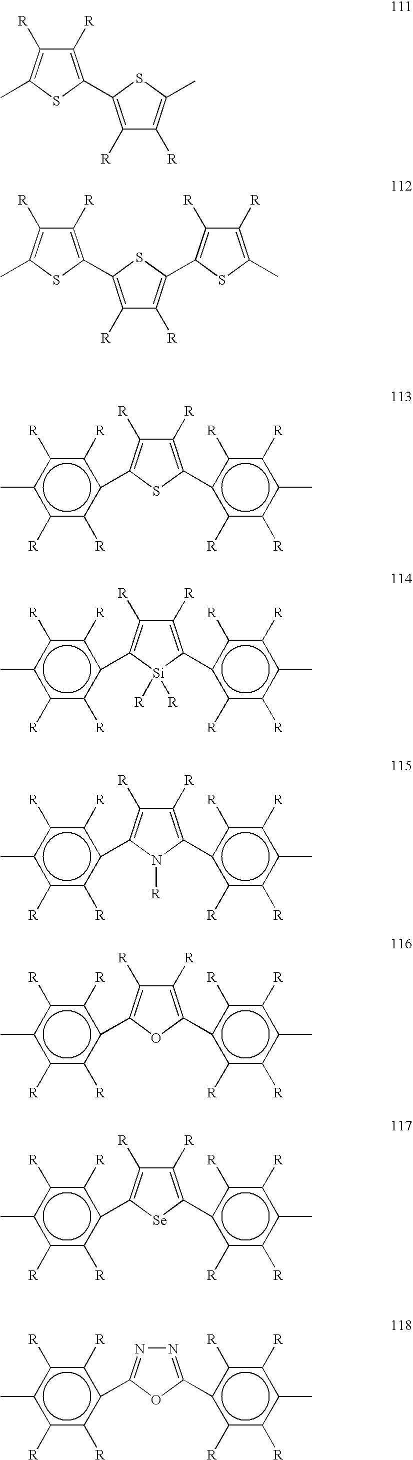

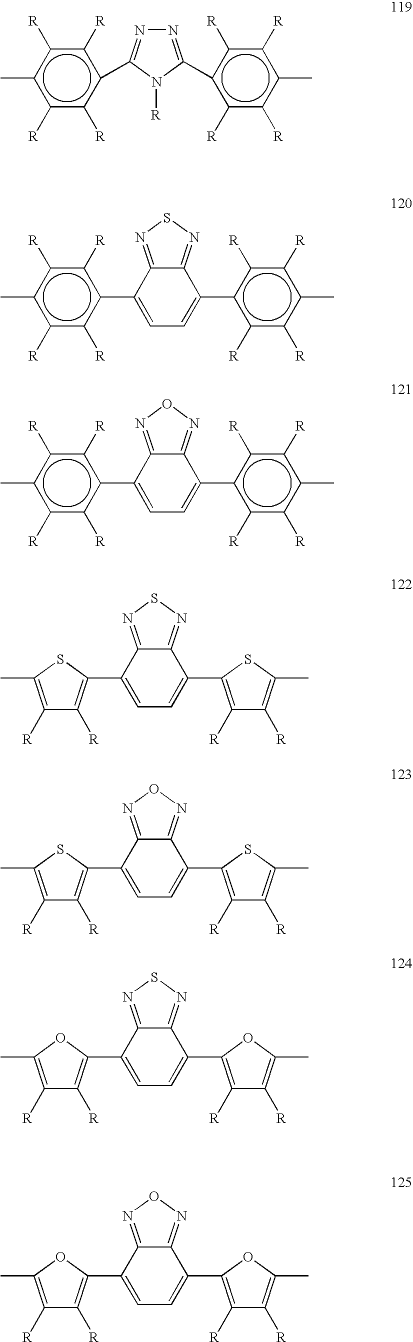

In the examples of the above formulae 1-125, Rs each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom (for example, chlorine, bromine, iodine), acyl group, acyloxy group, imine residue, amide group, acid imide group, monovalent heterocyclic group, carboxyl group, substituted carboxyl group, or cyano group. Carbon atom contained in the groups of formulas 1-125 may be substituted by a nitrogen atom, oxygen atom, or sulfur atom, and a hydrogen atom may be substituted by a fluorine atom.

Of the repeating unit represented by the above formula (3), the repeating unit represented by the below formula (7), formula (8), formula (9), formula (10), formula (11), and formula (12) are preferable. 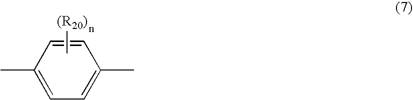
(Wherein, R₂₀ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. n represents an integer of 0 to 4. When a plurality of R₂₀ exist, they may be the same or different.)

As the concrete examples of formula (7), followings are exemplified. 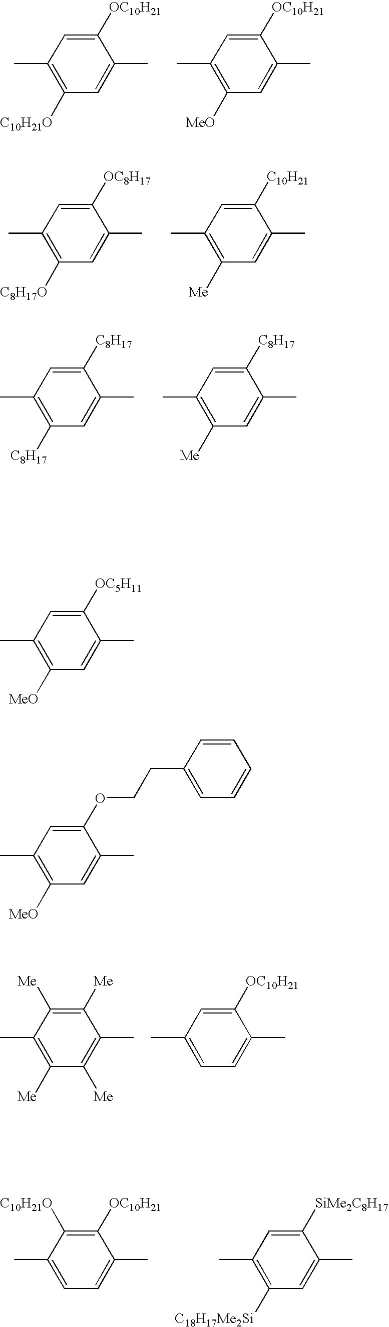 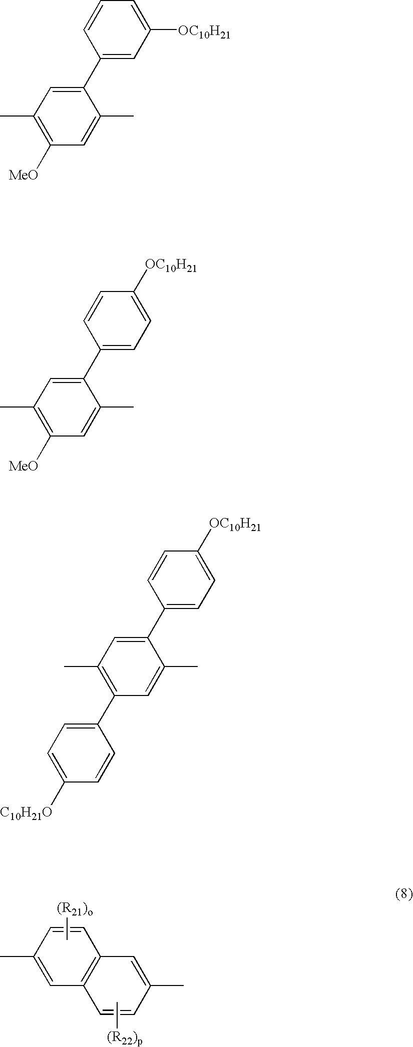
(Wherein, R₂₁ and R₂₂ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. o and p each independently represent an integer of 0 to 3. When a plurality of R₂₁ and R₂₂ exist, they may be respectively the same or different.)

As the concrete example of formula (8), followings are exemplified. 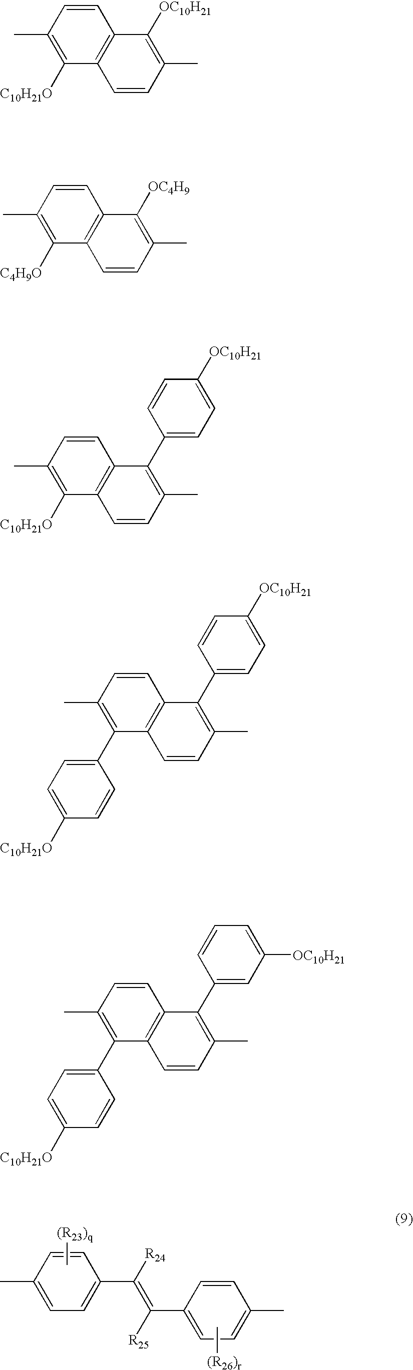
(Wherein, R₂₃ and R₂₆ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. q and r each independently represent an integer of 0 to 4. R₂₄ and R₂₅ each independently represent a hydrogen atom, alkyl group, aryl group, monovalent heterocyclic group, carboxyl group, substituted carboxyl group, or cyano group. When a plurality of R₂₃ and R₂₆ exist, they may be the same or different.)

As the concrete example of a formula (9), followings are exemplified. 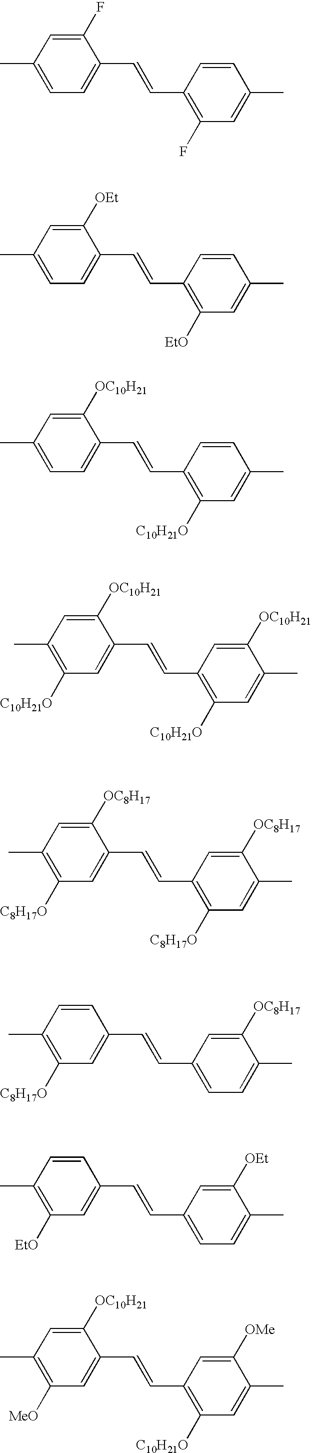 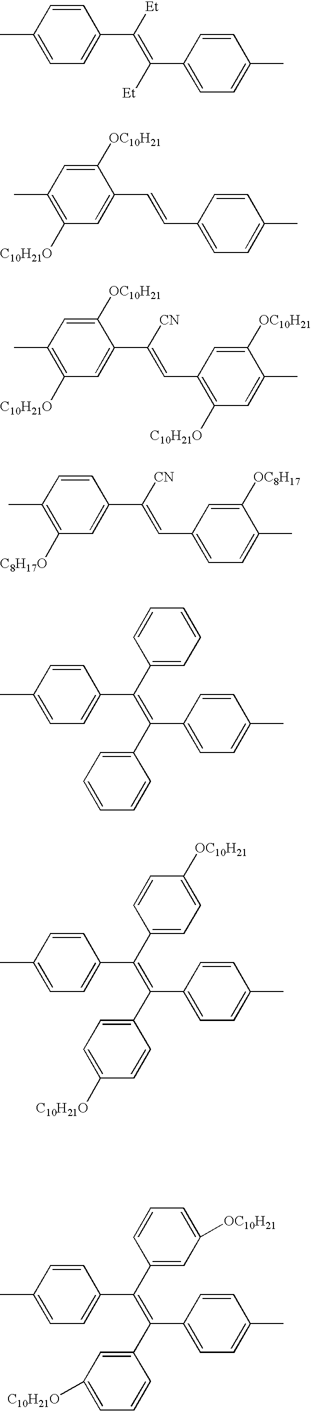 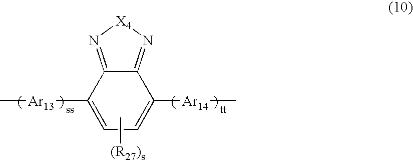
(Wherein, R₂₇ represents an alkyl group, alkoxy group, alkylthio
group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. s shows an integer of 0 to 2. Ar₁₃ and Ar₁₄ each independently represent an arylene group, divalent heterocyclic group, or a divalent group having metal complex structure. ss and tt each independently represent 0 or 1. X₄ represents O, S, SO, SO₂, Se, or Te. When a plurality of R₂₇ exists, they may be the same or different.)

As the concrete example of formula (10), followings are exemplified. 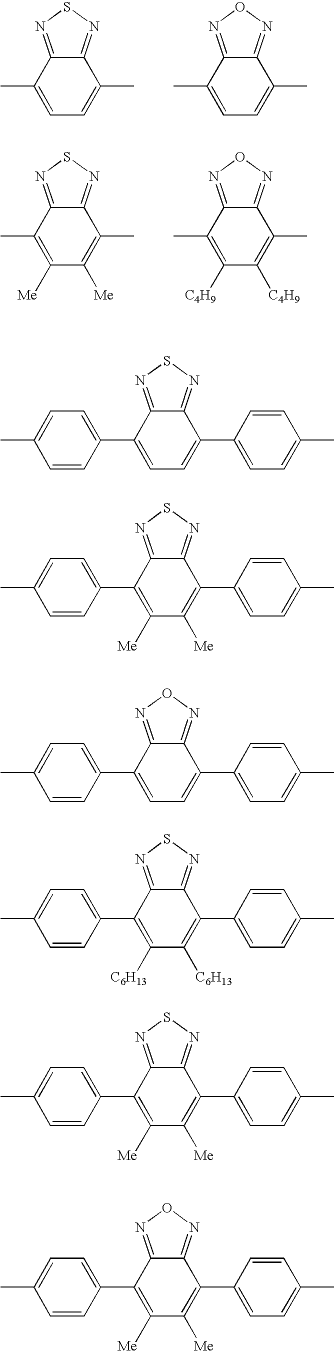 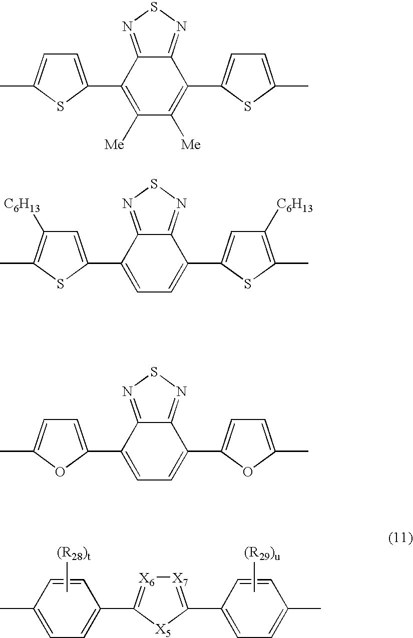
(Wherein, R₂₈ and R₂₉ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. t and u each independently represent an integer of 0 to 4. X₅ represents O, S, SO₂, Se, Te, N—R₃₀, or SiR₃₁R₃₂. X₆ and X₇ each independently represent N or C—R₃₃. R₃₀, R₃₁, R₃₂, and R₃₃ each independently represent a hydrogen atom, alkyl group, aryl group, arylalkyl group, or monovalent heterocyclic group. When a plurality of R₂₈, R₂₉ and R₃₃ exist, they may be the same or different.)

As the examples of central 5 membered ring in the repeating unit represented by formula (11), thiadiazole, oxadiazole, triazole, thiophene, furan, silole, etc. are exemplified.

As the concrete example of formula (11), followings are exemplified. 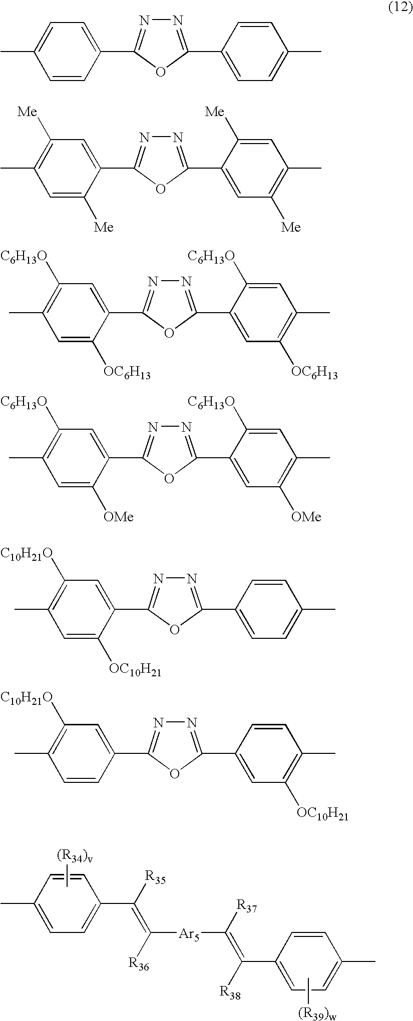
(Wherein, R₃₄ and R₃₉ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. v and w each independently represent an integer of 0 to 4. R₃₅, R₃₆, R₃₇ and R₃₈ each independently represent a hydrogen atom, alkyl group, aryl group, monovalent heterocyclic group, carboxyl group, substituted carboxyl group, or cyano group. Ar₅ represents an arylene group, divalent heterocyclic group, or a divalent group having metal complex structure. When a plurality of R₃₄ and R₃₉ exist, they may be the same or different.)

As the concrete example of a formula (12), followings are exemplified.

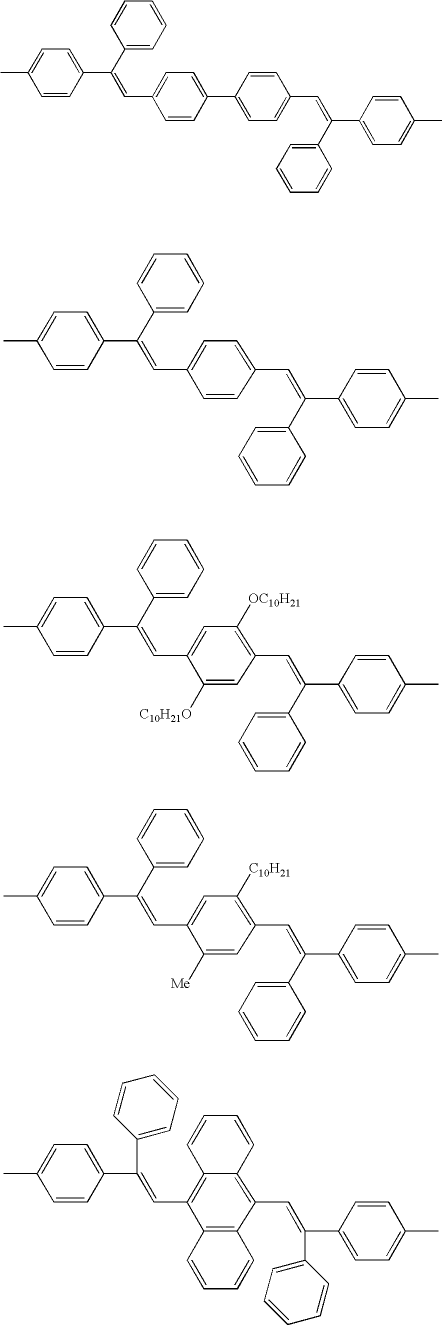

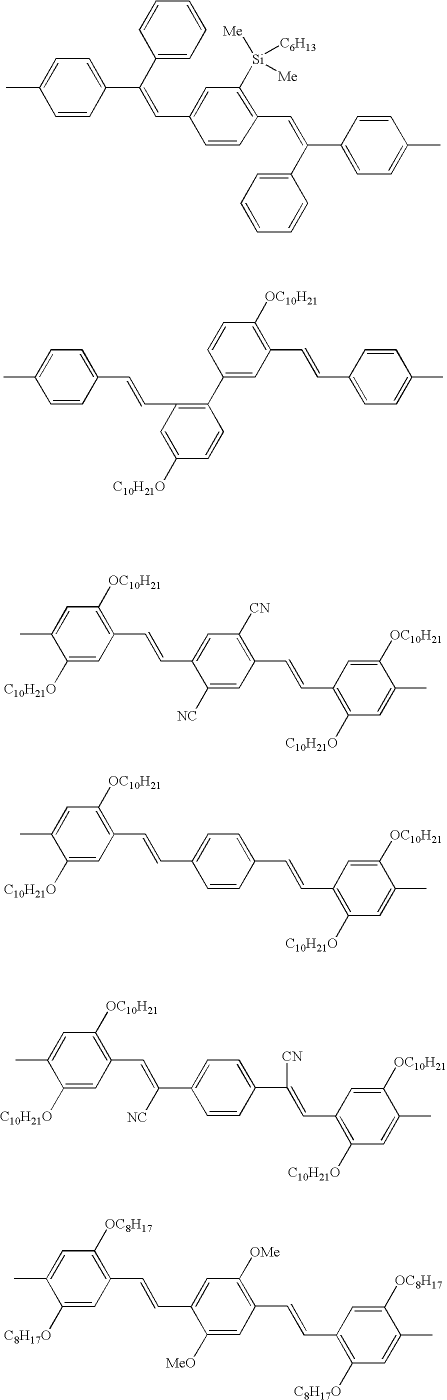

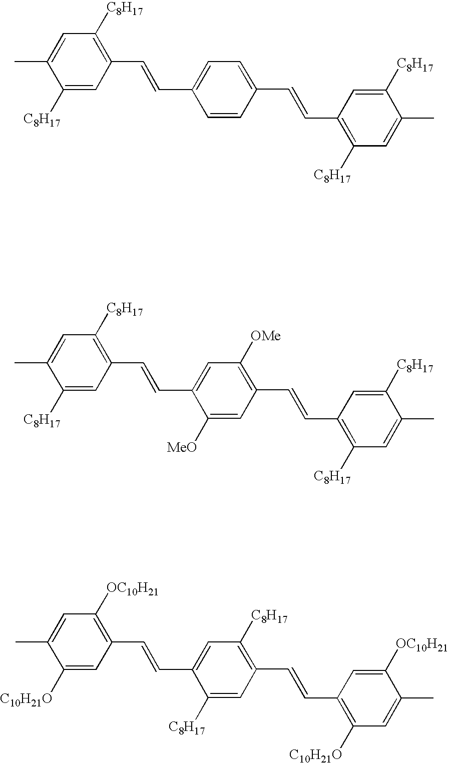

As the structures represented by the above formula (3), the structures the below formula (12-1) are exemplified. 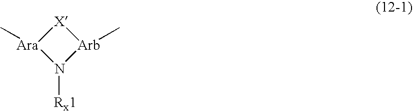
[Wherein, Arₐ and Ar_{b} each independently represent a trivalent aromatic hydrocarbon group or a trivalent heterocyclic group. Rₓ₁ represents an aryl group or monovalent heterocyclic group which may here an alkyl group, alkoxy group, alkylthio group, alkylsilyl group, alkylamino group, and a substituent. X′ represents a single bond or 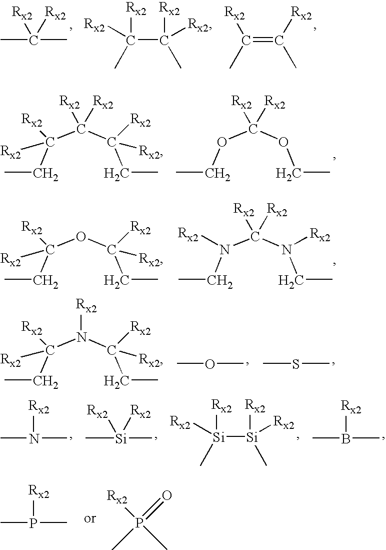
(Wherein, R₁₂ each independently represents a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group, or cyano group.) When a plurality of Rₓ₂ exist, they may be the same or different.]

Wherein, Arₐ and Ar_{b} each independently represent a trivalent aromatic hydrocarbon group or a trivalent heterocyclic group.

The trivalent aromatic hydrocarbon group means an atomic group in which three hydrogen atoms are removed from a benzene ring or a condensed ring. In the following exemplified formulae, among the three connecting bonds, bonds in vicinal ortho position are respectively connected to X′ and N represented by formula (12-1), (12-1A), (12-1C) and (12-1D).

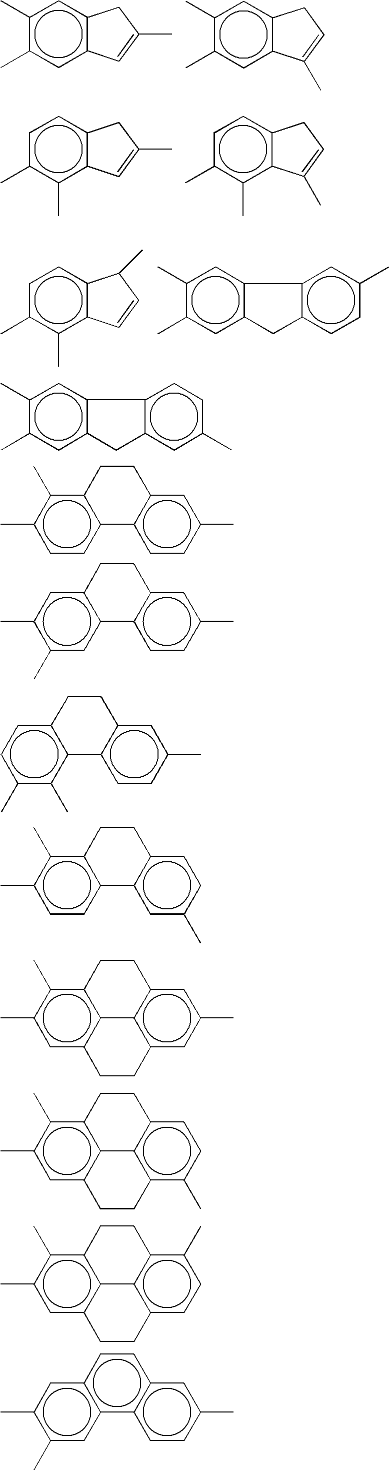

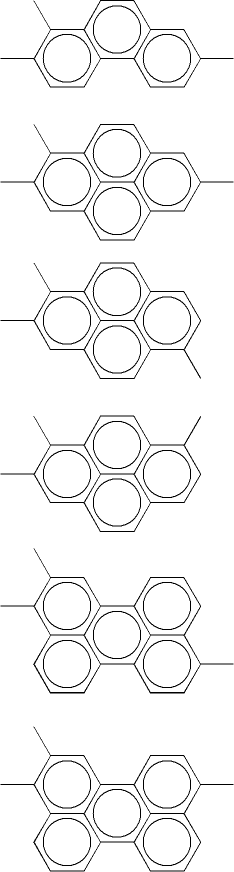

The above trivalent aromatic hydrocarbon group may have one or more substituents on the aromatic ring. As the substituents, exemplified are a halogen atom, alkyl group, alkyloxy group, alkylthio group, alkylamino group, aryl group, aryloxy group, arylthio group, arylamino group, arylalkyl group, arylalkyloxy group, arylalkylthio group, arylalkylamino group, acyl group, acyloxy group, amide group, imino group, substituted silyl group, substituted silyl oxy group, substituted silylthio group, the substituted silylamino group, monovalent heterocyclic group, arylalkenyl group, arylalkynyl group, or cyano group.

The number of carbon atoms which constitute the ring of trivalent aromatic hydrocarbon group is usually 6 to 60, and preferably 6 to 20.

The trivalent heterocyclic group means an atomic group in which three hydrogen atoms are removed from a heterocyclic compound.

The heterocyclic compound means a cyclic organic compound in which a hetero atom such as oxygen, sulfur, nitrogen, phosphorus, boron, etc. is contained in the ring, in addition to carbon atom, as the elements constituting the ring.

As the trivalent heterocyclic group, followings are exemplified. In the following exemplified formulae, among the three connecting bonds, bonds in vicinal ortho position are respectively connected to X and N represented by formula (12-1), (12-1A), (12-1C) and (12-1D).

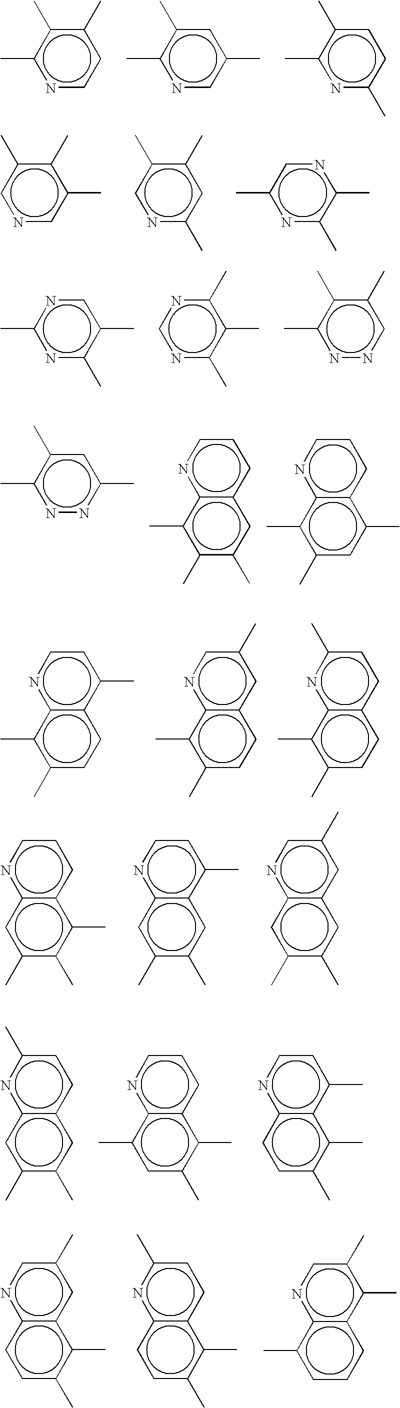

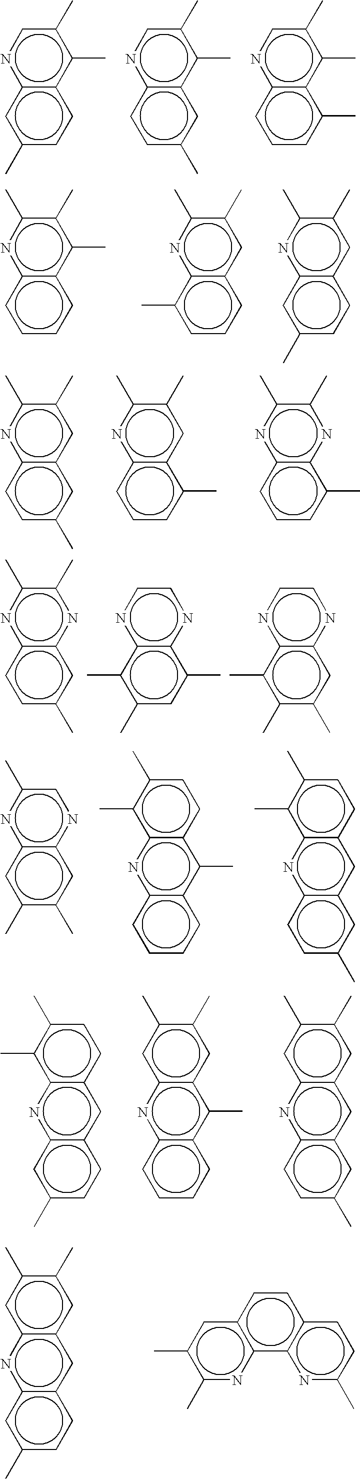

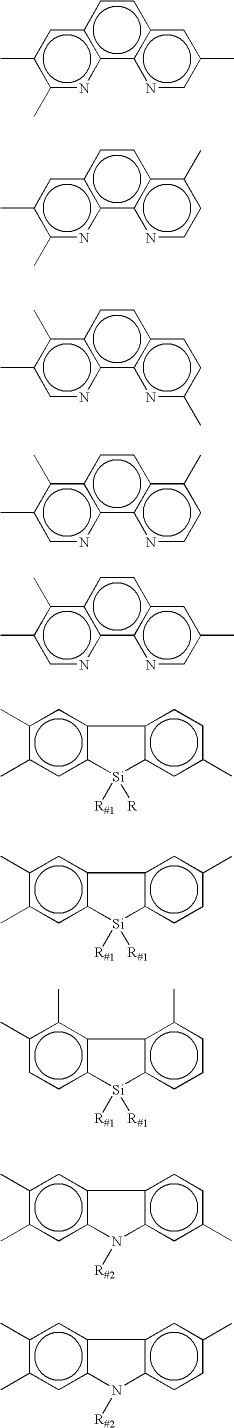

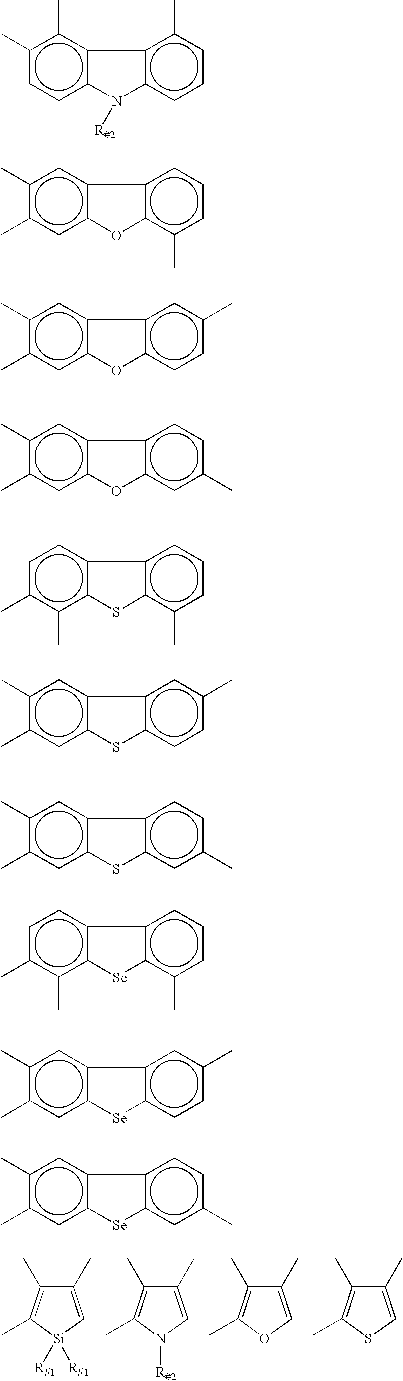

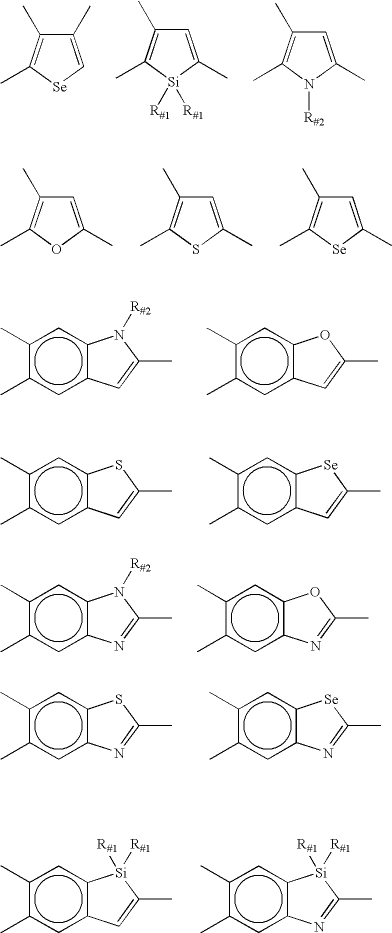

The above trivalent heterocyclic group may have one or more substituents on the ring. Examples of the substituent include an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group, or cyano group.

The number of carbon atoms constituting the ring of trivalent heterocyclic group is, usually 4 to 60, and preferably 4 to 20.

In the above formula, R_{#1}s are each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom (for example, chlorine, bromine, iodine), acyl group, acyloxy group, imino group, amide group, imide group, monovalent heterocyclic group, carboxyl group, substituted carboxyl group, or cyano group.

R_{#2}s each independently represent a hydrogen atom, alkyl group, aryl group, arylalkyl group, substituted silyl group, acyl group, or monovalent heterocyclic group.

In formula (12-1), X′ represents a single bond, or 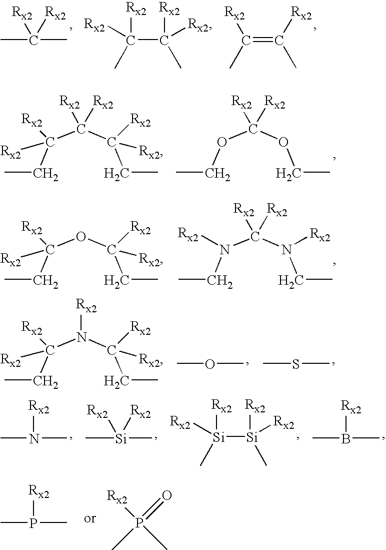
(Wherein, R₁₂ each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group, or cyano group. When a plurality of R₁₂s exist, they may be the same or different.)

Among them, preferables are a single bond, and 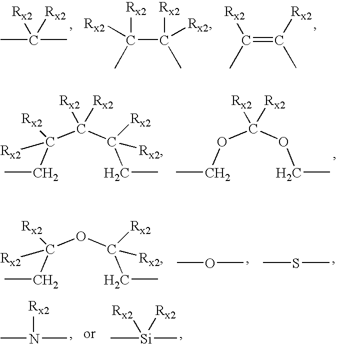
and a single bond is more preferable

Among the repeating units represented by the above formula, (12-1), formula (12-1A), (12-1B), (12-1C), (12-1D), (12-1E), and (12-1F) are preferable, (12-1A), (12-1D), (12-1E) and (12-1F) are more preferable, and formula (12-1F) is still more preferable. 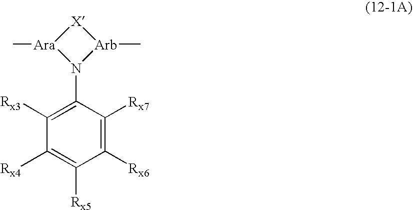
[Wherein, X′, Arₐ and Ar_{b} represent the same meaning as the above. Rₓ₃, Rₓ₄, Rₓ₅, Rₓ₆ and Rₓ₇ each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group, or cyano group.] 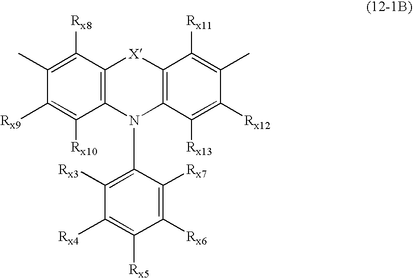
[Wherein, Rₓ₃, Rₓ₄, Rₓ₅, Rₓ₆, Rₓ₇ and X′ represent the same meaning as the above. Rₓ₈, Rₓ₉, Rₓ₁₀, Rₓ₁₁, Rₓ₁₂ and Rₓ₁₃ represent the same meaning as Rₓ₃, Rₓ₄, Rₓ₅, Rₓ₆ and Rₓ₇.] 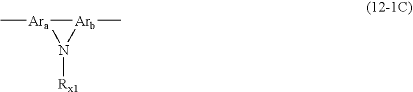
[Wherein, Rₓ₁, Arₐ and Ar_{b} represent the same meaning as the above.] 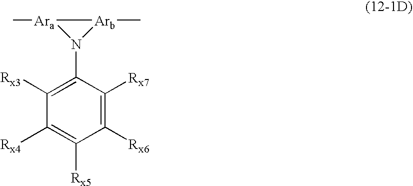
[Wherein, Rₓ₃, Rₓ₄, Rₓ₅, Rₓ₆, Rₓ₇, Arₐ and Ar_{b} represent the same meaning as the above.] 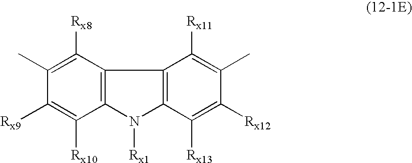
[Wherein, Rₓ₁, Rₓ₈, Rₓ₉, Rₓ₁₀, Rₓ₁₁, Rₓ₁₂ and Rₓ₁₃ represent the same meaning as the above.] 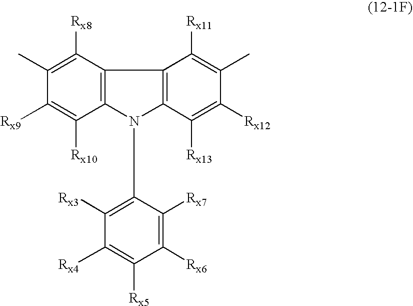
[Wherein, Rₓ₃, Rₓ₄, Rₓ₅, Rₓ₆, Rₓ₇, Rₓ₈, Rₓ₉, Rₓ₁₀, Rₓ₁₁, Rₓ₁₂ and Rₓ₁₃ represent the same meaning as the above.]

Of the repeating units represented by the above formula (4), repeating unit represented by the below formula (13) is preferable. 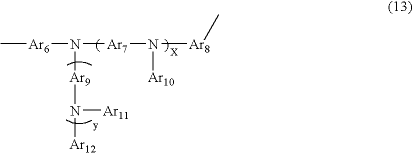
[Wherein, Ar₆, Ar₇, Ar₈ and Arg each independently represent an arylene group or a divalent heterocyclic group. Ar₁₀, Ar₁₁, and Ar₁₂ each independently represent an aryl group or monovalent heterocyclic group. Ar₆, Ar₇, Ar₈, Ar₉ and Ar₁₀ may have a substituent. x and y each independently represent 0 or 1, and are 0≦x+y≦1.]

As the concrete examples of the repeating unit represented by the above formula (13), the followings (represented by formula 126 to 133) are exemplified.

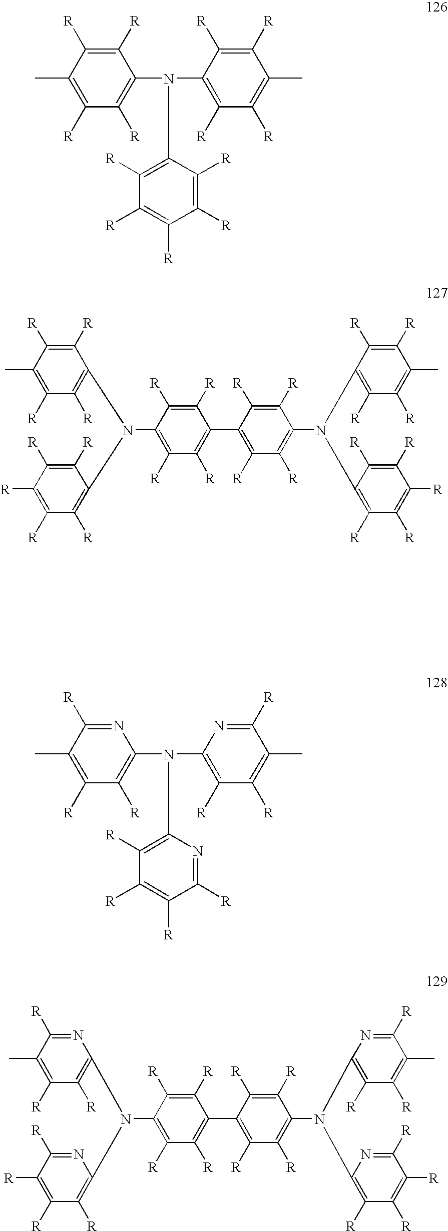

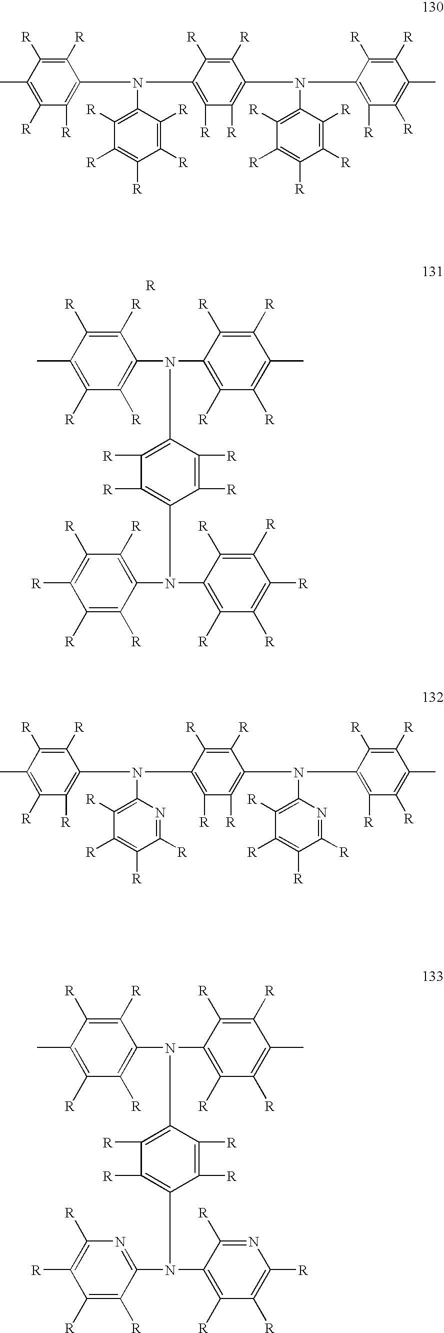

In the above formula, R is the same as those of the above formulas 1-125. In the above examples, a plurality of Rs are contained in one structural formula, they may be the same or different groups. In order to improve the solubility in a solvent, it is preferable to have one or more other than a hydrogen atom, and it is preferable that there is little symmetry in the form of the repeating unit including the substituent.

When R contains an aryl group or a heterocyclic group as a part thereof in the above formula, they may have one or more substituents.

In the substituent in which R contains an alkyl chain in the above formula, they may be any of linear, branched or cyclic, or the combination thereof, and when it is not linear, isoamyl group, 2-ethylhexyl group, 3,7-dimethyloctyl group, cyclohexyl group, 4-C₁-C₁₂ alkylcyclohexyl group, etc. are exemplified. In order to improve the solubility of a polymer compound in a solvent, it is preferable that one or more cyclic or branched alkyl chain is contained.

Moreover, a plurality of Rs may be connected to form a ring. Furthermore, when R is a group containing an alkyl chain, said alkyl chain may be interrupted by a group containing a hetero atom. Here, as the hetero atom, an oxygen atom, a sulfur atom, a nitrogen atom, etc. are exemplified.

Of them, the repeating unit represented by the below formula (13-2) is preferable. 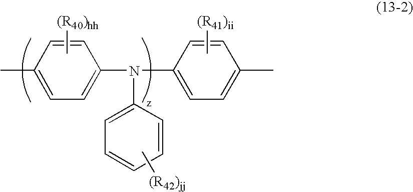
[Wherein, R₄₀, R₄₁ and R₄₂ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, the acyloxy group, imine residue, amide group, acid imide group, monovalent heterocyclic group, carboxyl group, substituted carboxyl group, or cyano group. hh, ii and jj each independently represent an integer of 0 to 4. z represents an integer of 1 to 2. When R₄₀, R₄₁ and R₄₂ are exist in plural, they may be the same or different.]

The polymer complex compound of the present invention may contain a repeating units other than the repeating unit represented by the above formula (1), and the repeating unit represented by formula (3) to formula (13) within a range of not injuring the fluorescence characteristic or the charge transportation characteristic. Moreover, these repeating unit and other repeating units may be connected through a non-conjugated unit, and the non-conjugated portions may be contained in the repeating unit. Examples of the bonding structure include those shown below, and the combinations of two or more of those shown below. Here, R is a group selected from the same substituent as the above, and Ar₁₅ represents a hydrocarbon group having 6 to 60 carbon atoms.

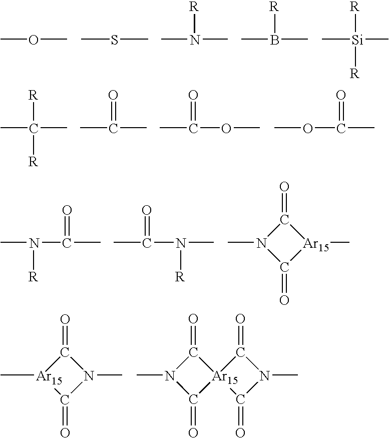

The polymer complex compound of the present invention may have two or more kinds of metal complex structures showing light-emission from triplet excited state. Each metal complex structure may have the same metal each other, and may have a different metal. Moreover, each metal complex structure may have a mutually different ligand, and may have a mutually different light-emission color. For example, exemplified is a case where both of a metal complex structure which emits green light, and a metal complex structure which emits red light are contained in one polymer complex compound. In this case, since a light-emission color is controllable by designing so that an appropriate amount of the metal complex structure may be included, it is preferable.

The polymer compound used for the present invention may also be a random, block or graft copolymer, or a polymer having an intermediate structure thereof, for example, a random copolymer having block property. From the viewpoint for obtaining a polymer compound having high fluorescent quantum yield, random copolymers having block property and block or graft copolymers are preferable than complete random copolymers. Further, a polymer having a branched main chain and more than three terminals may also be included.

Furthermore, the end group of polymer compound used for the present invention may also be protected with a stable group since if a polymerization active group remains intact, there is a possibility of reduction in light emitting property and life-time when made into an device. Those having a conjugated bond continuing to a conjugated structure of the main chain are preferable, and there are exemplified structures connected to an aryl group or heterocyclic compound group via a carbon-carbon bond. Specifically, substituents described as Chemical Formula 10 in JP-A-9-45478 are exemplified.

The polystyrene reduced number-average molecular weight of the polymer complex compound is usually 10³ to 10⁸, and preferably 10⁴ to 10⁶. The polystyrene reduced weight-average molecular weight of the polymer complex compound is usually 10³ to 10⁸, and preferably 5×10⁴ to 5×10⁶.

As the good solvent to the polymer complex compound of the present invention, exemplified are chloroform, methylene chloride, dichloroethane, tetrahydrofuran, toluene, xylene, mesitylene, tetralin, decalin, n-butyl benzene, etc. Although it depends on the structure and the molecular weight of the polymer complex compound, usually the complex compound can be dissolved in these solvents in 0.1% by weight or more.

Next, the manufacture method of the polymer complex compound of the present invention is explained.

In case of the case having vinylene group in the main chain, for example, a method described in JP-A-5-202355 is exemplified. That is, exemplified are: a polymerization by Wittig reaction of a compound having formyl group and a compound having phosphonium-methyl group, or a compound having formyl group and phosphonium-methyl group; polymerization by Heck reaction of a compound having vinyl group and a compound having halogen atom; polycondensation by dehydrohalogenation method of a compound having two or more monohalogenated-methyl groups; polycondensation by sulfonium-salt decomposition method of a compound having two or more sulfonium-methyl groups; polymerization by Knoevenagel reaction of a compound having formyl group and a compound having cyano group; and polymerization by McMurry reaction of a compound having two or more formyl groups.

When a polymer complex compound of the present invention has a triple bond in the main chain, for example, Heck reaction can be used.

In case of neither a double bond nor a triple bond is contained in the main chain, exemplified are: a method of polymerization by Suzuki coupling reaction from corresponding monomer; a method of polymerization by Grignard reaction; a method of polymerization by Ni(0) catalyst; a method of polymerization by by oxidizers, such as FeCl₃; a method of electrochemical oxidization polymerization; and a method by decomposition of an intermediate polymer having a suitable leaving group.

Among these, a polymerization by Wittig reaction, a polymerization by Heck reaction, a polymerization by Knoevenagel reaction, a method of polymerization by Suzuki coupling reaction, a method of polymerization by Grignard reaction, and a method of polymerization by Ni(0) catalyst are preferable, since it is easy to control the structure.

Specifically, a compound, as a monomer, having a plurality of polymerization active groups is dissolved in an organic solvent according to necessity, and can be reacted using alkali or appropriate catalyst, at a temperature between the boiling point and the melting point of the organic solvent.

For example, known methods which can be used are described in: Organic Reactions, volume 14, page 270-490, John Wiley & Sons, Inc., 1965; Organic Reactions, Volume 27, page 345-390, John Wiley & Sons, Inc., 1982; Organic Syntheses, Collective Volume VI, page 407-411, John Wiley & Sons, Inc., 1988; Chemical Review (Chem. Rev.), Volume 95, page 2457 (1995); Journal of Organometallic Chemistry (J. Organomet. Chem.), Volume 576, page 147 (1999); Journal of Praktical Chemistry, Vol. 336th, page 247 (1994); and Macromolecular Chemistry, Macromolecular Symposium (Makromol. Chem., Macromol. Symp.), Volume 12th, page 229 (1987).

It is preferable that the organic solvent used is subjected to a deoxygenation treatment sufficiently and the reaction is progressed under an inert atmosphere, generally for suppressing a side reaction, though the treatment differs depending on compounds and reactions used. Further, it is preferable to conduct a dehydration treatment likewise. However, this is not applicable in the case of a reaction in a two-phase system with water, such as a Suzuki coupling reaction.

For the reaction, alkali or a suitable catalyst is added. It can be selected according to the reaction to be used. It is preferable that the alkali or the catalyst can be dissolved in a solvent used for a reaction. Example of the method for mixing the alkali or the catalyst, include a method of adding a solution of alkali or a catalyst slowly, to the reaction solution with stirring under an inert atmosphere of argon, nitrogen, etc. or conversely, a method of adding the reaction solution to the solution of alkali or a catalyst slowly.

For example, a polymer complex compound containing the above formula (14) as a repeating unit is preferably produced by conducting condensation polymerization of the monomer represented by the below formula (18), in existence of a monomer of formula (1), or one or more of monomers selected from formula (1) and formulae (3), (4), (5) and (6). 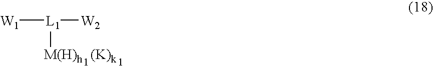
[Wherein, M, H, K, L₁, h₁ and k₁ represent the same meaning as the above. W₁ and W₂ each independently represent a halogen atom, sulfonate group, —B(OH)₂, boric ester group, sulfonium-methyl group, phosphonium-methyl group, phosphonate-methyl group, monohalogenated-methyl group, formyl group, cyano group or vinyl group.]

A polymer complex compound containing the above formula (15) as a repeating unit is preferably produced by conducting condensation polymerization of the monomer represented by the below formula (19), in existence of a monomer of formula (1), or one or more of monomers selected from formula (1) and formulae (3), (4), (5) and (6). 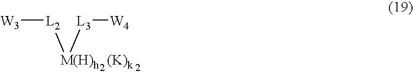
(Wherein, M, H, K, L₂, L₃, h₃ and k₂ represent the same meaning as the above. W₃ and W₄ each independently represent a halogen atom, sulfonate group, —B(OH)₂, boric ester group, sulfonium-methyl group, phosphonium-methyl group, phosphonate-methyl group, monohalogenated-methyl group, formyl group, cyano group or vinyl group.)
Here, as W₃ and W₄, halogen atom, —B(OH)₂, and boric ester group are preferable, and halogen atom is more preferable.

As the monomer represented by the above formula (19), for example, those in which two R's contained respectively in the compounds of the above formulae MC-1 to MC-37 are replaced with W₃ and W₄, and as the examples, those represented by the below formulae (19-a) to (19-h) are exemplified.

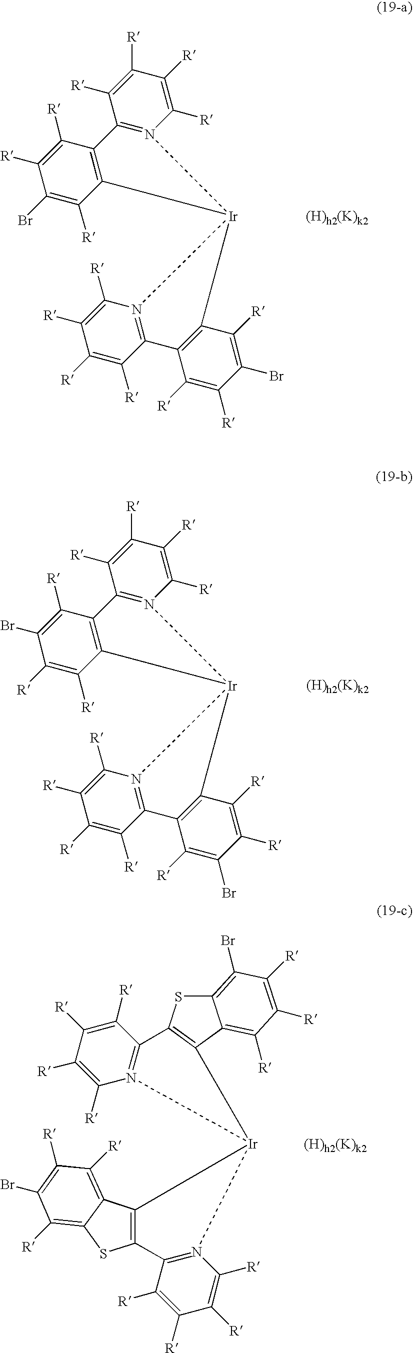

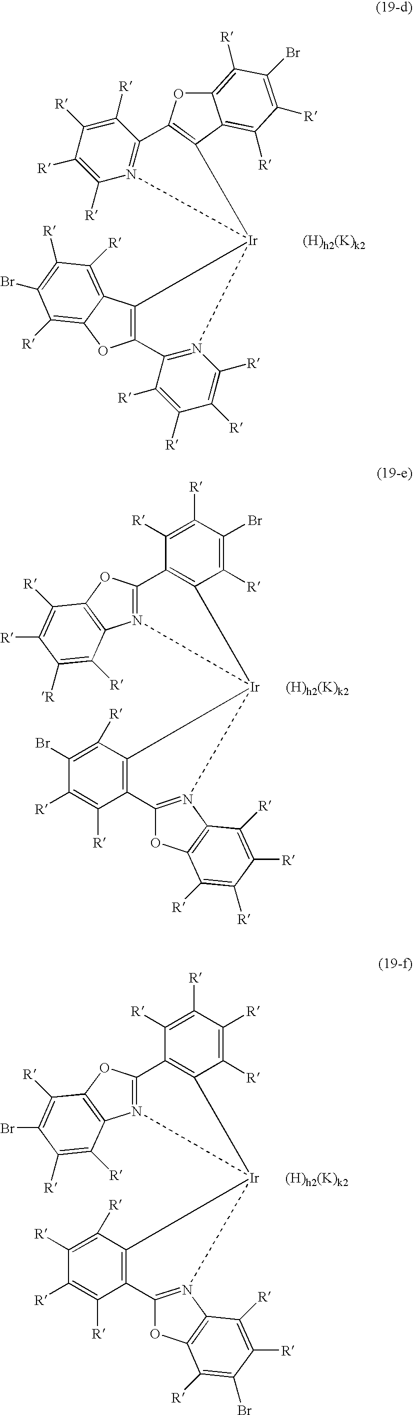

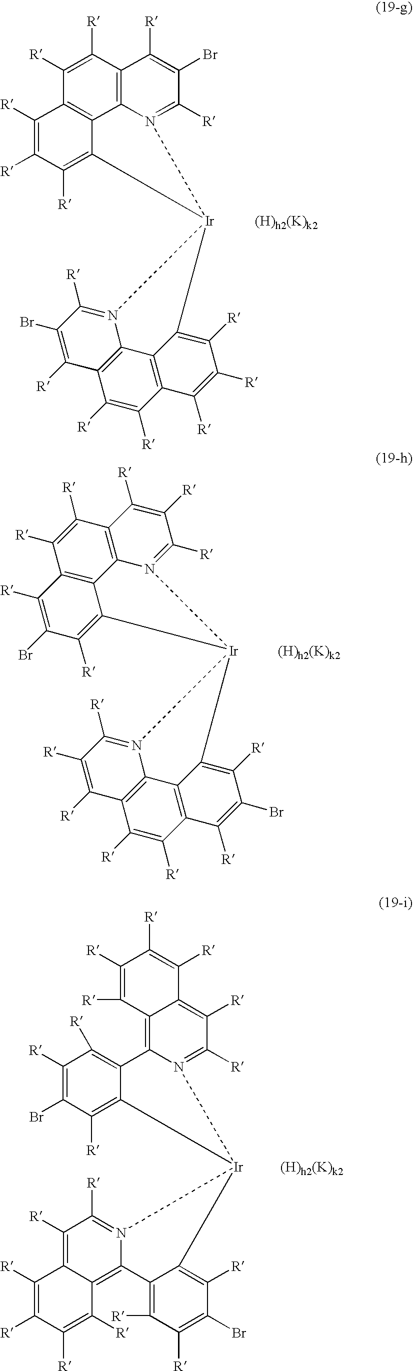

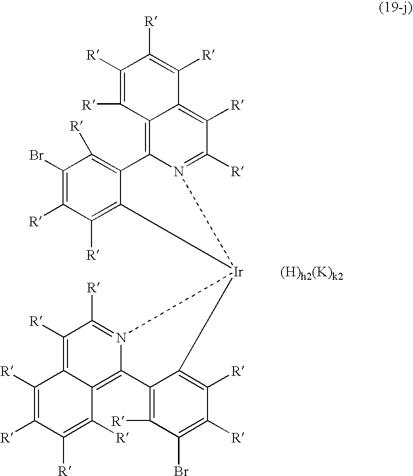

As the concrete examples of the monomers represented by the above formula (19), those in which the position of a bromine atom is exchanged to R′ on the same ligand in each of (19-a) to (19-j), and those in which the central metal Ir is changed to other metal, are also exemplified.

A polymer complex compound containing the above formula (16) as a repeating unit is preferably produced by conducting condensation polymerization of the monomer represented by the below formula (20), in existence of a monomer of formula (1), or one or more of monomers selected from formula (1) and formulae (3), (4), (5) and (6). 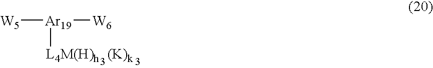
(Wherein, M, H, K, Ar₁₉, L₄, h₃ and k₃ represent the same meaning as the above. W₅ and W₆ each independently represent a halogen atom, sulfonate group, —B(OH)₂, boric ester group, sulfonium-methyl group, phosphonium-methyl group, phosphonate-methyl group, monohalogenated-methyl group, formyl group, cyano group or vinyl group.)

Moreover, a polymer complex compound containing the above formula (16-1) as a repeating unit is preferably produced by conducting condensation polymerization of the monomer represented by the below formula (20-1), in existence of a monomer of formula (1), or one or more of monomers selected from formula (1) and formulae (3), (4), (5) and (6).
W₇-Ar₂₀ [symbol] CR_{1′}═CR2′ [symbol] _{n′}W₈ (20-1)
(Wherein, Ar₂₀, R_{1′}, R_{2′} and n′ represent the same meaning as the above. W₇ and W₈ each independently represent a halogen atom, sulfonate group, —B(OH)₂, boric ester group, sulfonium-methyl group, phosphonium-methyl group, phosphonate-methyl group, monohalogenated-methyl group, formyl group, cyano group or vinyl group.)

As the repeating unit represented by the above formula (20-1), for example, followings are exemplified.

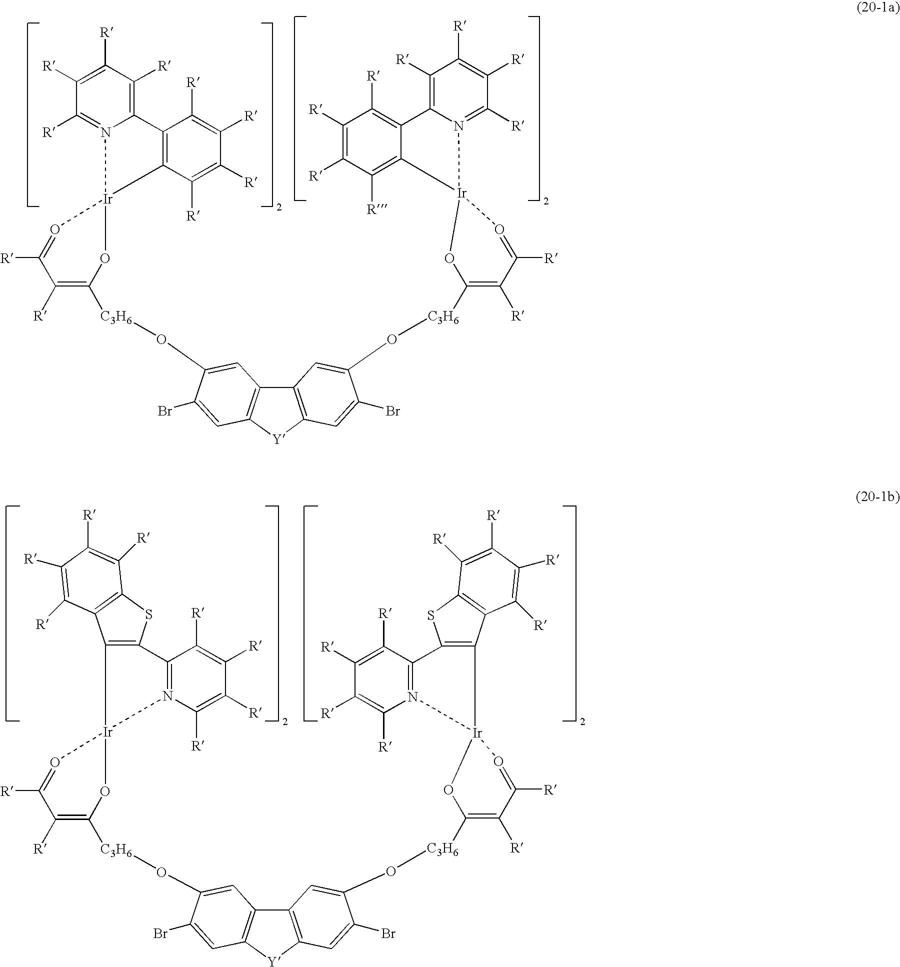

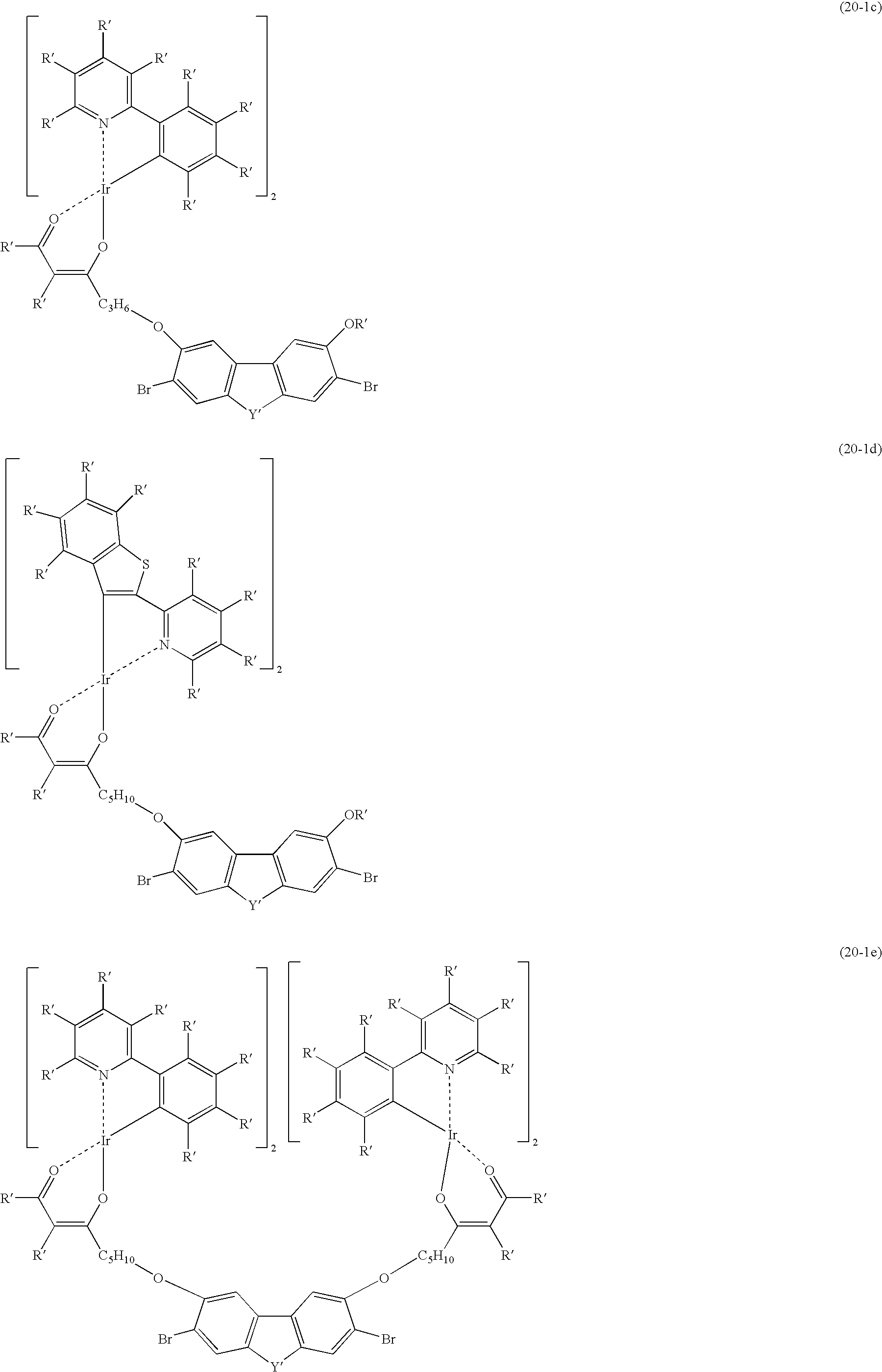

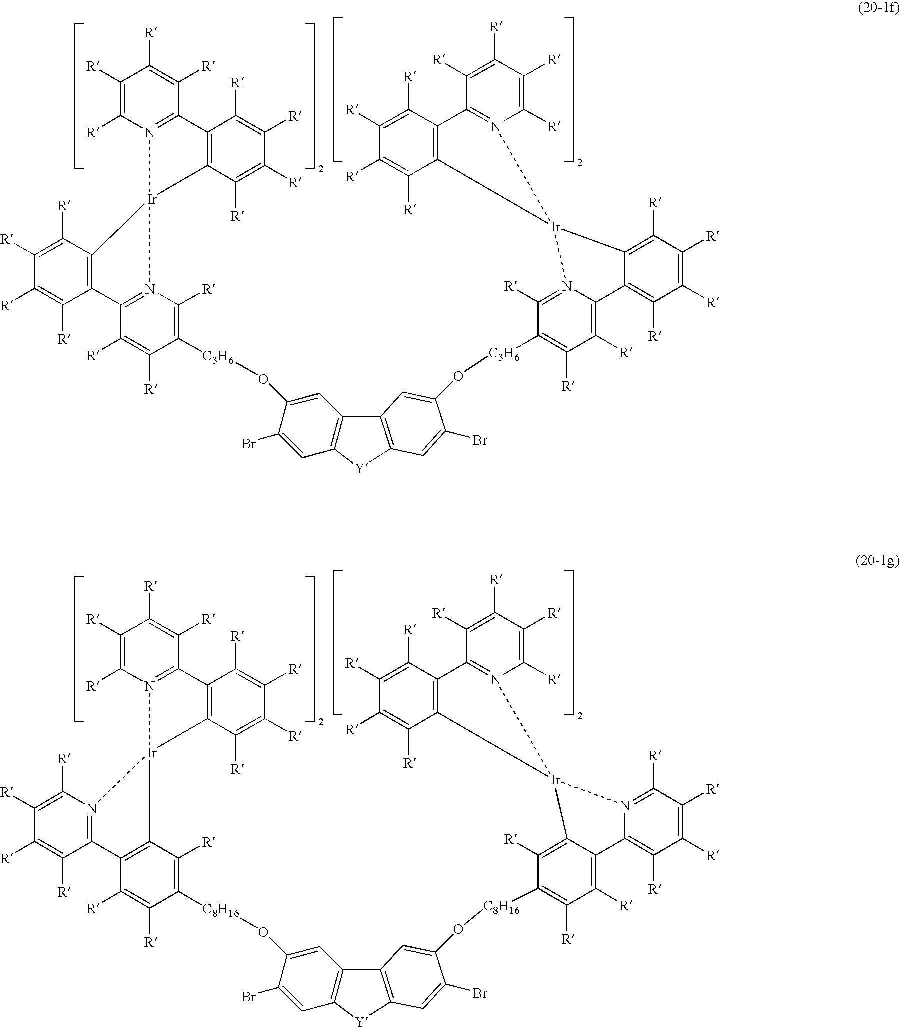

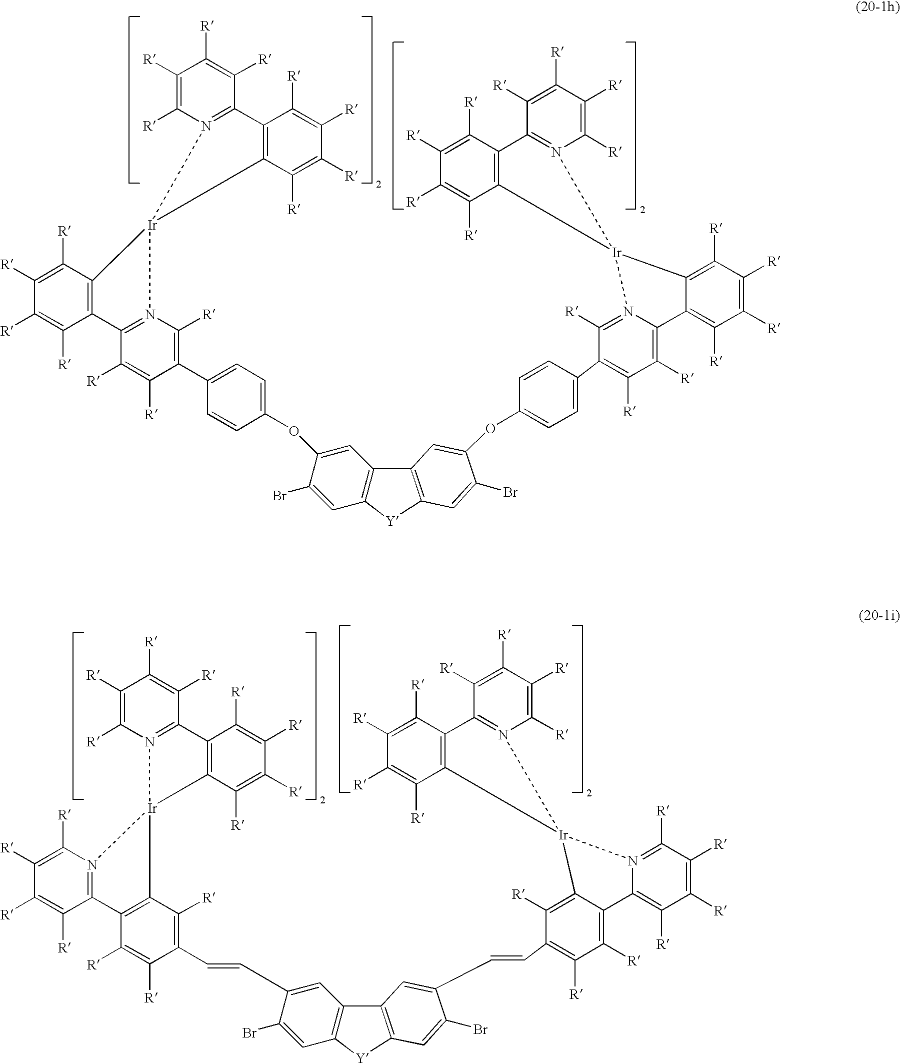

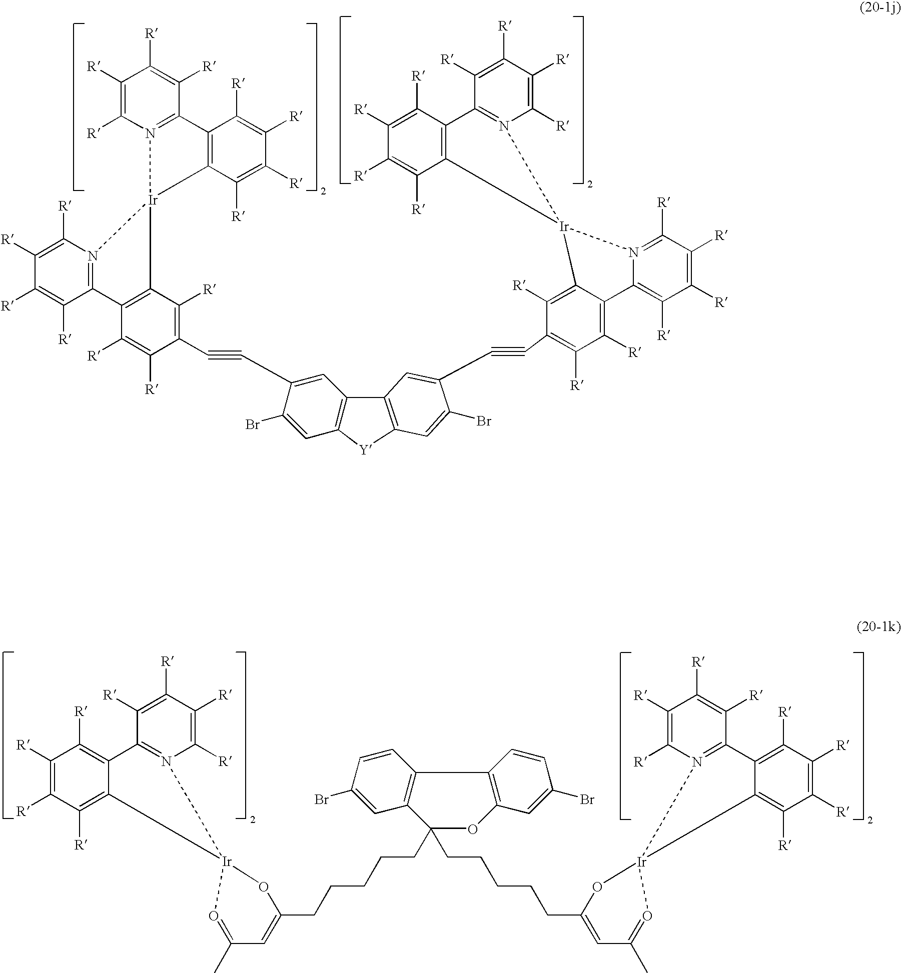

In the above concrete examples, Y′ represents the same meaning as shown by the above, and concrete examples of R′ include the same as those shown by the above R′.

Among the group represented by the above W₁ to W₈, as the halogen atom, sulfonate group, boric ester group, sulfonium-methyl group, phosphonium-methyl group, phosphonate-methyl group, and monohalogenated-methyl group, the following groups are exemplified.

As the halogen atom, chlorine, bromine, and iodine are exemplified.

Examples of the sulfonate group include benzenesulfonate group, p-toluenesulfonate group, methanesulfonate group, ethanesulfonate group, and trifluoromethanesulfonate group.

As the boric ester group, the groups represented by the below formulae are exemplified.

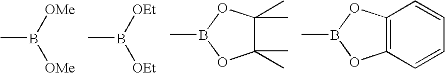

As the sulfonium-methyl group, the groups represented by the below formulae are exemplified.
—CH₂S⁺Me₂X″-, —CH₂S⁺Ph₂X″-

(X″ represents a halogen atom.)

As the phosphonium-methyl group, the groups represented by the below formulae are exemplified.

—CH₂P⁺Ph₃X″- (X″ represents a halogen atom.)

As the phosphonate-methyl group, the groups represented by the below formulae are exemplified.

—CH₂P(═O)(OR′″)₂ (R′″ represents an alkyl group, aryl group, or arylalkyl group.)

As the monohalogenated-methyl group, chloromethyl group, bromomethyl group, and iodomethyl group are exemplified.

When the polymer complex compound of the present invention comprises a repeating unit other than the repeating unit of formula (14) to (16-1), it can be prepared by copolymerizing a monomer used as the repeating unit other than the repeating unit of formula (14) to (16-1).

As the monomer used as the repeating unit other than the repeating unit of formula (14) to (16-1), compounds of the below formulae (21) and (22) are exemplified.
X₅-Ar₁₆-(CR₄₃═CR₄₄)₁-X₆ (21)
Wherein, Ar₁₆, R₄₃, R₄₄, and 1 are the same as those of the above. X₅ and X₆ each independently represent a halogen atom, sulfonate group, —B(OH)₂, boric ester group, sulfonium-methyl group, phosphonium-methyl group, phosphonate-methyl group, monohalogenated-methyl group, formyl group, cyano group or vinyl group. 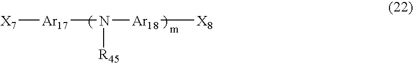
Wherein, Ar₁₇, Ar₁₈, R₄₅, and m are the same as those of the above. X₇ and X₈ each independently represent halogen atom, sulfonate group, —B(OH)₂, boric ester group, sulfonium-methyl group, phosphonium-methyl group, phosphonate-methyl group, monohalogenated-methyl group, formyl group, cyano group or vinyl group.

In the group represented by X₅ to X₈, as the halogen atom, boric ester group, sulfonium-methyl group, sulfonate methyl group, phosphonium-methyl group, phosphonate-methyl group, and monohalogenated-methyl group, the groups described in the above W₁ and W₂ are exemplified.

The polymer complex compound of the present invention can be prepared by copolymerizing the monomer represented by the below formula (23) in coexistence of, for example, a monomer of formula (1) or one or more monomers selected from formula (3), (4), (5), and (6).
X₉-L₅M(H)ₕ_{₄}(K)ₖ_{₄} (23)
[Wherein, M, H, K, L₅, h₄ and k₄ represent the same meaning as the above. X₉ represents a halogen atom, —B(OH)₂, boric ester group, sulfonium-methyl group, sulfonate methyl group, phosphonium-methyl group, phosphonate-methyl group, monohalogenated-methyl group, formyl group, cyano group, or vinyl group.]

In the group represented by X_{g}, as the halogen atom, boric ester group, sulfonium-methyl group, sulfonate methyl group, phosphonium-methyl group, phosphonate-methyl group, and monohalogenated-methyl group, the groups described in the above W₁ and W₂ are exemplified.

Here, as X₉, a halogen atom, —B(OH)₂ and boric ester group are preferable, and halogen atom is more preferable.

As the monomer represented by the above formula (23), for example, those in which one of R's contained respectively in the compounds of the above formulae MC-1 to MC-37 are replaced with X₉, and as the examples, those represented by the below formulae (23-a) to (23-j) are exemplified.

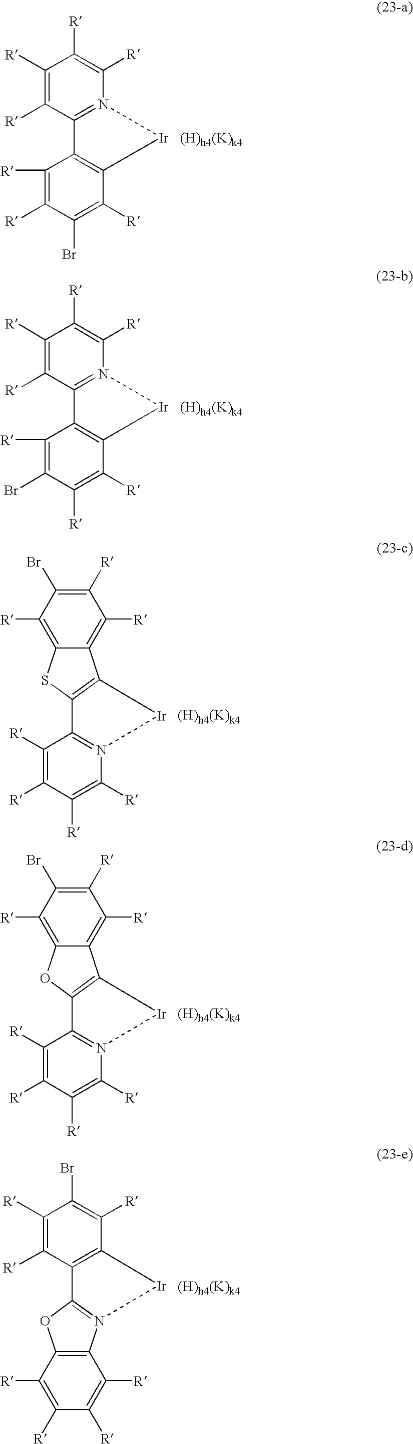

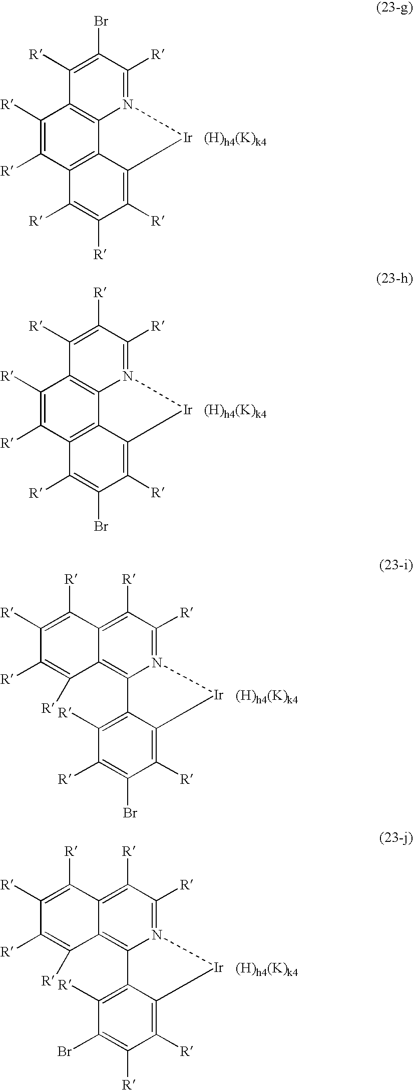

As the concrete examples of the monomer represented by the above formula (23), those in which the position of a bromine atom is exchanged to R′ on the same ligand in each of (23-a) to (23-j), and those in which the central metal Ir is changed to other metal, are also exemplified.

When a light-emitting material comprising the polymer complex compound of the present invention is used for an organic electroluminescence device, the purity thereof exerts an influence on light emitting property, therefore, it is preferable that a monomer is purified by a method such as distillation, sublimation purification, re-crystallization and the like before being polymerized. Further, it is preferable to conduct a purification treatment such as re-precipitation purification, chromatographic separation and the like after the polymerization.

As the manufacture method of the polymer complex compound of the present invention, as mentioned above, it can be manufactured by polymerizing, as raw materials, using a group of the triplet light-emitting complex and a monomer having a polymerizable group.

Moreover, by polymerizing, as raw materials, using a group of legends represented by the above H, K, L₁, L₄ or L₅ and a monomer having a polymerizable group to obtain a polymer, and reacting said polymer with a central metal of the triplet light-emitting complex.

Next, the use of the polymer complex compound of the present invention is explained.

The polymer complex compound of the present invention has fluorescence or phosphorescence in the solid state, and it can be used as a light emitting polymer (high molecular weight light-emitting material). Moreover, the polymer complex compound has excellent electronic transportating property, and can use it suitably as a polymer-LED material, and a charge transporting material. The polymer LED comprising the light emitting polymer is a polymer LED of high performance which can be driven at low-voltage and at high efficiency. Therefore, the polymer LED can be preferably used for apparatus, such as a liquid crystal display as a back light, a flat or curved light source for lighting, a segment display, a dot matrix flat-panel display, etc.

Moreover, the polymer complex compound of the present invention can be used also as laser dye, organic solar-cell material, organic semiconductor for organic transistors, and conductive thin film material, such as conductive thin-film, or organic semiconductor thin film Furthermore, it can be used also as a light-emitting thin-film material which emits fluorescence and phosphorescence.

Next, the polymer LED of the present invention is explained.

The polymer LED of the present invention is characterized by having a layer which contains an organic layer between the electrodes consisting of an anode and a cathode, and the organic layer comprises the polymer complex compound of the present invention.

The organic layer may be any of a light emitting layer, a hole transporting layer, and an electron transporting layer, but preferably the organic layer is a light emitting layer.

Herein, the light emitting layer is a layer having function to emit a light, the hole transporting layer is a layer having function to transport a hole, and the electron transporting layer is a layer having function to transport an electron. Herein, the electron transporting layer and the hole transporting layer are generically called a charge transporting layer. The light emitting layer, hole transporting layer, and electron transporting layer, may be each independently used as two or more layers.

When the organic layer is a light emitting layer, the light emitting layer which is an organic layer may contain further a hole transporting material, an electron transporting material, or fluorescent material.

A composition comprising one or more kinds of compounds selected from a hole transporting material, an electron transporting material, and fluorescent material, and the polymer complex compound of the present invention can be used as a light-emitting material or a charge transporting material.

When the polymer complex compound of the present invention, and a hole transporting material are mixed, the mixing ratio of the hole transporting material to whole of the mixture is lwt % to 80 wt %, and preferably 5 wt % to 60 wt %. When the polymer material of the present invention, and an electron transporting material are mixed, the mixing ratio of the electron transporting material to whole of the mixture is 1 wt % to 80 wt %, and preferably 5 wt % to 60 wt %. Moreover, when the polymer complex compound of the present invention, and a fluorescent material are mixed, the mixing ratio of the fluorescent material to whole of the mixture is 1 wt % to 80 wt %, and preferably 5 wt % to 60 wt %.

When the polymer complex compound of the present invention is mixed with a fluorescent material, a hole transporting material, and/or an electron transporting material, the mixing ratio of the fluorescent material to whole of the mixture is 1 wt % to 50 wt %, preferably 5 wt %-40 wt %, the ratio of the hole transporting material, and the electron transporting material in totals thereof is 1 wt % to 50 wt %, preferably 5 wt % to 40 wt %, and the content of the polymer complex compound of the present invention is 99 wt % to 20 wt %.

As the hole transporting material, electron transporting material, and fluorescent material to be mixed, known low molecular weight compounds and known polymer compounds can be used, and it is preferable to use a polymer compound.

As for the hole transporting material, electron transporting material and fluorescent material of polymer compound; exemplified are polyfluorene, derivative and copolymer thereof; polyarylene, derivative and copolymer thereof; polyarylene vinylene, derivative and copolymer thereof; and aromatic amine, derivative and copolymer thereof; and they are disclosed in WO 99/13692, WO99/48160, GB2340304A, WO00/53656, WO01/19834, WO00/55927, GB2348316 and WO00/46321, WO00/06665, WO99/54943, WO99/54385, U.S. Pat. No. 5,777,070 and WO98/06773, WO97/05184, WO00/35987, WO00/53655, WO01/34722, WO99/24526, WO00/22027, WO00/22026, WO98/27136, US573636, WO 98/21262, U.S. Pat. No. 5,741,921, WO 97/09394, WO 96/29356, WO 96/10617, EP0707020, WO95/07955, JP-A-2001-181618, JP-A-2001-123156, JP-A-2001-3045, JP-A-2000-351967, JP-A-2000-303066, JP-A-2000-299189, JP-A-2000-252065, JP-A-2000-136379, JP-A-2000-104057, JP-A-2000-80167, JP-A-10-324870, JP-A-10-114891, JP-A-9-111233, JP-A-9-45478 etc.

As the low molecular weight fluorescent material, there can be used, for example, naphthalene derivatives, anthracene or derivatives thereof, perylene or derivatives thereof; dyes such as polymethine dyes, xanthene dyes, coumarine dyes, cyanine dyes; metal complexes of 8-hydroxyquinoline or derivatives thereof, aromatic amine, tetraphenylcyclopentane or derivatives thereof, or tetraphenylbutadiene or derivatives thereof, and the like.

Specifically, there can be used known compounds such as those described in JP-A Nos. 57-51781, 59-195393 and the like, for example.

Regarding the thickness of the light emitting layer of the polymer LED of the present invention, the optimum value differs depending on material used, and may properly be selected so that the driving voltage and the light emitting efficiency become optimum values, and for example, it is from 1 nm to 1 μm, preferably from 2 nm to 500 nm, further preferably from 5 nm to 200 nm.

As the forming method of the light emitting layer, film forming method from a solution is exemplified. As the film forming method from a solution, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like. At the point that a pattern forming and multicolored printing are easy, printing methods, such as a screen-stenciling method, flexography method, offset-printing method, and ink-jet printing method are preferable.

As the ink composition used by the printing method etc., at least one kind of the polymer compound of the present invention is contained, and a hole transporting material, an electron transporting material, a fluorescent material, a solvent, and additive such as a stabilizing agent, may be contained in addition to the polymer complex compound of the present invention.

The rate of the polymer complex compound of the present invention in the ink composition is 20 wt % to 100 wt % to the total weight of the composition excluding the solvent, and preferably 40 wt % to 100 wt %.

In case a solvent is furthermore contained in the ink composition, the rate of the solvent is 1 wt % to 99.9 wt % to the total weight of a composition, preferably 60 wt % to 99.5 wt %, and more preferably 80 wt % to 99.0 wt %.

Viscosity of the ink composition changes according to a printing method,

in case that the ink composition goes through a discharging apparatus, such as ink-jet printing method, it is preferable that the viscosity is in a range of 1 to 100 mPa·s at 25° C. in order to prevent clogging and flight bending at the time of discharging.

Although the solvent used for ink composition is not especially limited, those which can dissolve or disperse uniformly the materials constituting the composition other than solvent are preferable.

When the material constituting the ink composition is soluble in a non-polar solvent, as the solvent, there are exemplified chlorine solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethylcellosolve acetate and the like.

Moreover, as the polymer LED of the present invention, there are exemplified: a polymer LED having an electron transporting layer between a cathode and a light emitting layer; a polymer LED having a hole transporting layer between an anode and a light emitting layer; and a polymer LED having an electron transporting layer between a cathode and a light emitting layers, and a hole transporting layer between an anode and a light emitting layer.

For example, the following structures of a-d are specifically exemplified.

a) anode/light emitting layer/cathode

b) anode/hole transporting layer/light emitting layer/cathode

c) anode/light emitting layer/electron transporting layer/cathode

d) anode/hole transporting layer/light emitting layer/electron transporting layer/cathode

(wherein, “/” indicates adjacent lamination of layers. Hereinafter, the same).

When the polymer LED of the present invention has a hole transporting layer, as the hole transporting materials used, there are exemplified polyvinylcarbazole or derivatives thereof, polysilane or derivatives thereof, polysiloxane derivatives having an aromatic amine in the side chain or the main chain, pyrazoline derivatives, arylamine derivatives, stilbene derivatives, triphenyldiamine derivatives, polyaniline or derivatives thereof, polythiophene or derivatives thereof, polypyrrole or derivatives thereof, poly(p-phenylenevinylene) or derivatives thereof, poly(2,5-thienylenevinylene) or derivatives thereof, or the like.

Specific examples of the hole transporting material include those described in JP-A Nos. 63-70257, 63-175860, 2-135359, 2-135361, 2-209988, 3-37992 and 3-152184.

Among them, as the hole transporting materials used in the hole transporting layer, preferable are polymer hole transporting materials such as polyvinylcarbazole or derivatives thereof, polysilane or derivatives thereof, polysiloxane derivatives having an aromatic amine compound group in the side chain or the main chain, polyaniline or derivatives thereof, polythiophene or derivatives thereof, poly(p-phenylenevinylene) or derivatives thereof, poly(2,5-thienylenevinylene) or derivatives thereof, or the like, and further preferable are polyvinylcarbazole or derivatives thereof, polysilane or derivatives thereof and polysiloxane derivatives having an aromatic amine compound group in the side chain or the main chain.

As the hole transporting material of low molecular weight compound, a pyrazoline derivative, an arylamine derivative, a stilbene derivative, and a triphenyldiamine derivative are exemplified. In the case of the hole transporting material of low molecular weight compound, it is preferable to use it with dispersing a polymer binder.

The polymer binder mixed is preferably that does not disturb charge transport extremely, and that does not have strong absorption of a visible light is suitably used. As such polymer binder, polycarbonate, polyacrylate, poly(methyl acrylate), poly(methyl methacrylate), polystyrene, poly(vinyl chloride), polysiloxane and the like are exemplified.

Polyvinylcarbazole or derivatives thereof are obtained, for example, by cation polymerization or radical polymerization from a vinyl monomer.

As the polysilane or derivatives thereof, there are exemplified compounds described in Chem. Rev., 89, 1359 (1989) and GB 2300196 published specification, and the like. For synthesis, methods described in them can be used, and a Kipping method can be suitably used particularly.

As the polysiloxane or derivatives thereof, those having the structure of the above-described hole transporting material having lower molecular weight in the side chain or main chain, since the siloxane skeleton structure has poor hole transporting property. Particularly, there are exemplified those having an aromatic amine having hole transporting property in the side chain or main chain.

The method for forming a hole transporting layer is not restricted, and in the case of a hole transporting layer having lower molecular weight, a method in which the layer is formed from a mixed solution with a polymer binder is exemplified. In the case of a polymer hole transporting material, a method in which the layer is formed from a solution is exemplified.

The solvent used for the film forming from a solution is not particularly restricted providing it can dissolve a hole transporting material. As the solvent, there are exemplified chlorine solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethylcellosolve acetate and the like.

As the film forming method from a solution, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like, from a solution.

Regarding the thickness of the hole transporting layer, the optimum value differs depending on material used, and may properly be selected so that the driving voltage and the light emitting efficiency become optimum values, and at least a thickness at which no pin hole is produced is necessary, and too large thickness is not preferable since the driving voltage of the device increases. Therefore, the thickness of the hole transporting layer is, for example, from 1 nm to 1 μm, preferably from 2 nm to 500 nm, further preferably from 5 nm to 200 nm.

When the polymer LED of the present invention has an electron transporting layer, known compounds are used as the electron transporting materials, and there are exemplified oxadiazole derivatives, anthraquinonedimethane or derivatives thereof, benzoquinone or derivatives thereof, naphthoquinone or derivatives thereof, anthraquinone or derivatives thereof, tetracyanoanthraquinodimethane or derivatives thereof, fluorenone derivatives, diphenyldicyanoethylene or derivatives thereof, diphenoquinone derivatives, or metal complexes of 8-hydroxyquinoline or derivatives thereof, polyquinoline and derivatives thereof, polyquinoxaline and derivatives thereof, polyfluorene or derivatives thereof, and the like.

Specifically, there are exemplified those described in JP-A Nos. 63-70257, 63-175860, 2-135359, 2-135361, 2-209988, 3-37992 and 3-152184.

Among them, oxadiazole derivatives, benzoquinone or derivatives thereof, anthraquinone or derivatives thereof, or metal complexes of 8-hydroxyquinoline or derivatives thereof, polyquinoline and derivatives thereof, polyquinoxaline and derivatives thereof, polyfluorene or derivatives thereof are preferable, and 2-(4-biphenyl)-5-(4-t-butylphenyl)-1,3,4-oxadiazole, benzoquinone, anthraquinone, tris(8-quinolinol) aluminum and polyquinoline are further preferable.

The method for forming the electron transporting layer is not particularly restricted, and in the case of an electron transporting material having lower molecular weight, a vapor deposition method from a powder, or a method of film-forming from a solution or melted state is exemplified, and in the case of a polymer electron transporting material, a method of film-forming from a solution or melted state is exemplified, respectively.

The solvent used in the film-forming from a solution is not particularly restricted provided it can dissolve electron transporting materials and/or polymer binders. As the solvent, there are exemplified chlorine solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethylcellosolve acetate and the like.

As the film-forming method from a solution or melted state, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like.

Regarding the thickness of the electron transporting layer, the optimum value differs depending on material used, and may properly be selected so that the driving voltage and the light emitting efficiency become optimum values, and at least a thickness at which no pin hole is produced is necessary, and too large thickness is not preferable since the driving voltage of the device increases. Therefore, the thickness of the electron transporting layer is, for example, from 1 nm to 1 μm, preferably from 2 nm to 500 nm, further preferably from 5 nm to 200 nm.

Moreover, among the charge transporting layers provided adjacent to an electrode, those having a function to improve the charge injection efficiency from an electrode, and having the effect of lowering driving voltage of a device, are generally just called a charge injection layer (a hole injection layer, electron injection layer).

Further, for the improvement of adhesion and charge injection from the electrode, the above charge injection layer or an insulating layer 2 nm of film thickness may be adjacently prepared to the electrode, and for the improvement of adhesion of the interface and prevention of mixing, a thin buffer layer may be inserted into the interface of a charge transporting layer and a light emitting layer.

The order and number of layers laminated and the thickness of each layer can be appropriately applied while considering light emitting efficiency and life of the device.

In the present invention, as the polymer LED having a charge injecting layer (electron injecting layer, hole injecting layer) provided, there are listed a polymer LED having a charge injecting layer provided adjacent to a cathode and a polymer LED having a charge injecting layer provided adjacent to an anode.

For example, the following structures e) to p) are specifically exemplified.

e) anode/charge injecting layer/light emitting layer/cathode

f) anode/light emitting layer/charge injecting layer/cathode

g) anode/charge injecting layer/light emitting layer/charge injecting layer/cathode

h) anode/charge injecting layer/hole transporting layer/light emitting layer/cathode

i) anode/hole transporting layer/light emitting layer/charge injecting layer/cathode

j) anode/charge injecting layer/hole transporting layer/light emitting layer/charge injecting layer/cathode

k) anode/charge injecting layer/light emitting layer/electron transporting layer/cathode

l) anode/light emitting layer/electron transporting layer/charge injecting layer/cathode

m) anode/charge injecting layer/light emitting layer/electron transporting layer/charge injecting layer/cathode

n) anode/charge injecting layer/hole transporting layer/light emitting layer/electron transporting layer/cathode

o) anode/hole transporting layer/light emitting layer/electron transporting layer/charge injecting layer/cathode

p) anode/charge injecting layer/hole transporting layer/light emitting layer/electron transporting layer/charge injecting layer/cathode

As the specific examples of the charge injecting layer, there are exemplified layers containing an conducting polymer, layers which are disposed between an anode and a hole transporting layer and contain a material having an ionization potential between the ionization potential of an anode material and the ionization potential of a hole transporting material contained in the hole transporting layer, layers which are disposed between a cathode and an electron transporting layer and contain a material having an electron affinity between the electron affinity of a cathode material and the electron affinity of an electron transporting material contained in the electron transporting layer, and the like.

When the above-described charge injecting layer is a layer containing an conducting polymer, the electric conductivity of the conducting polymer is preferably 10⁻⁵ S/cm or more and 10³ S/cm or less, and for decreasing the leak current between light emitting pixels, more preferably 10⁻⁵ S/cm or more and 10² S/cm or less, further preferably 10⁻⁵ S/cm or more and 10¹ S/cm or less.

Usually, to provide an electric conductivity of the conducting polymer of 10⁻⁵ S/cm or more and 10³ S/cm or less, a suitable amount of ions are doped into the conducting polymer.

Regarding the kind of an ion doped, an anion is used in a hole injecting layer and a cation is used in an electron injecting layer.

As examples of the anion, a polystyrene sulfonate ion, alkylbenzene sulfonate ion, camphor sulfonate ion and the like are exemplified, and as examples of the cation, a lithium ion, sodium ion, potassium ion, tetrabutyl ammonium ion and the like are exemplified.

The thickness of the charge injecting layer is for example, from 1 nm to 100 nm, preferably from 2 nm to 50 nm.

Materials used in the charge injecting layer may properly be selected in view of relation with the materials of electrode and adjacent layers, and there are exemplified conducting polymers such as polyaniline and derivatives thereof, polythiophene and derivatives thereof, polypyrrole and derivatives thereof, poly(phenylene vinylene) and derivatives thereof, poly(thienylene vinylene) and derivatives thereof, polyquinoline and derivatives thereof, polyquinoxaline and derivatives thereof, polymers containing aromatic amine structures in the main chain or the side chain, and the like, and metal phthalocyanine (copper phthalocyanine and the like), carbon and the like.

The insulation layer having a thickness of 2 nm or less has function to make charge injection easy. As the material of the above-described insulation layer, metal fluoride, metal oxide, organic insulation materials and the like are listed. As the polymer LED having an insulation layer having a thickness of 2 nm or less, there are listed polymer LEDs having an insulation layer having a thickness of 2 nm or less provided adjacent to a cathode, and polymer LEDs having an insulation layer having a thickness of 2 nm or less provided adjacent to an anode.

Specifically, there are listed the following structures q) to ab) for example.

q) anode/insulation layer having a thickness of 2 nm or less/light emitting layer/cathode

r) anode/light emitting layer/insulation layer having a thickness of 2 nm or less/cathode

s) anode/insulation layer having a thickness of 2 nm or less/light emitting layer/insulation layer having a thickness of 2 nm or less/cathode

t) anode/insulation layer having a thickness of 2 nm or less/hole transporting layer/light emitting layer/cathode

u) anode/hole transporting layer/light emitting layer/insulation layer having a thickness of 2 nm or less/cathode

v) anode/insulation layer having a thickness of 2 nm or less/hole transporting layer/light emitting layer/insulation layer having a thickness of 2 nm or less/cathode

w) anode/insulation layer having a thickness of 2 nm or less/light emitting layer/electron transporting layer/cathode

x) anode/light emitting layer/electron transporting layer/insulation layer having a thickness of 2 nm or less/cathode

y) anode/insulation layer having a thickness of 2 nm or less/light emitting layer/electron transporting layer/insulation layer having a thickness of 2 nm or less/cathode

z) anode/insulation layer having a thickness of 2 nm or less/hole transporting layer/light emitting layer/electron transporting layer/cathode

aa) anode/hole transporting layer/light emitting layer/electron transporting layer/insulation layer having a thickness of 2 nm or less/cathode

ab) anode/insulation layer having a thickness of 2 nm or less/hole transporting layer/light emitting layer/electron transporting layer/insulation layer having a thickness of 2 nm or less/cathode

The substrate forming the polymer LED of the present invention may preferably be that does not change in forming an electrode and layers of organic materials, and there are exemplified glass, plastics, polymer film, silicon substrates and the like. In the case of a opaque substrate, it is preferable that the opposite electrode is transparent or semitransparent.

Usually, at least one of the electrodes consisting of an anode and a cathode, is transparent or semitransparent. It is preferable that the anode is transparent or semitransparent.

As the material of this anode, electron conductive metal oxide films, semitransparent metal thin films and the like are used.

Specifically, there are used indium oxide, zinc oxide, tin oxide, and composition thereof, i.e. indium/tin/oxide (ITO), and films (NESA and the like) fabricated by using an electron conductive glass composed of indium/zinc/oxide, and the like, and gold, platinum, silver, copper and the like. Among them, ITO, indium/zinc/oxide, tin oxide are preferable. As the fabricating method, a vacuum vapor deposition method, sputtering method, ion plating method, plating method and the like are used. As the anode, there may also be used organic transparent conducting films such as polyaniline or derivatives thereof, polythiophene or derivatives thereof and the like.

The thickness of the anode can be appropriately selected while considering transmission of a light and electric conductivity, and for example, from 10 nm to 10 μm, preferably from 20 nm to 1 μm, further preferably from 50 nm to 500 nm.

Further, for easy charge injection, there may be provided on the anode a layer comprising a phthalocyanine derivative conducting polymers, carbon and the like, or a layer having an average film thickness of 2 nm or less comprising a metal oxide, metal fluoride, organic insulating material and the like.

As the material of a cathode used in the polymer LED of the present invention, that having lower work function is preferable. For example, there are used metals such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium and the like, or alloys comprising two of more of them, or alloys comprising one or more of them with one or more of gold, silver, platinum, copper, manganese, titanium, cobalt, nickel, tungsten and tin, graphite or graphite intercalation compounds and the like. Examples of alloys include a magnesium-silver alloy, magnesium-indium alloy, magnesium-aluminum alloy, indium-silver alloy, lithium-aluminum alloy, lithium-magnesium alloy, lithium-indium alloy, calcium-aluminum alloy and the like. The cathode may be formed into a laminated structure of two or more layers.

The thickness of the cathode can be appropriately selected while considering transmission of a light and electric conductivity, and for example, from 10 nm to 10 μm, preferably from 20 nm to 1 μm, further preferably from 50 nm to 500 nm.

As the method for fabricating a cathode, there are used a vacuum vapor deposition method, sputtering method, lamination method in which a metal thin film is adhered under heat and pressure, and the like. Further, there may also be provided, between a cathode and an organic layer, a layer comprising an conducting polymer, or a layer having an average film thickness of 2 nm or less comprising a metal oxide, metal fluoride, organic insulation material and the like, and after fabrication of the cathode, a protective layer may also be provided which protects the polymer LED. For stable use of the polymer LED for a long period of time, it is preferable to provide a protective layer and/or protective cover for protection of the device in order to prevent it from outside damage.

As the protective layer, there can be used a polymeric compound, metal oxide, metal fluoride, metal borate and the like. As the protective cover, there can be used a glass plate, a plastic plate the surface of which has been subjected to lower-water-permeation treatment, and the like, and there is suitably used a method in which the cover is pasted with an device substrate by a thermosetting resin or light-curing resin for sealing. If space is maintained using a spacer, it is easy to prevent an device from being injured. If an inner gas such as nitrogen and argon is sealed in this space, it is possible to prevent oxidation of a cathode, and further, by placing a desiccant such as barium oxide and the like in the above-described space, it is easy to suppress the damage of an device by moisture adhered in the production process. Among them, any one means or more are preferably adopted.

The polymer LED of the present invention can be used for a flat light source, a segment display, a dot matrix display, and a liquid crystal display as a back light, lighting, etc.

For obtaining light emission in plane form using the polymer LED of the present invention, an anode and a cathode in the plane form may properly be placed so that they are laminated each other. Further, for obtaining light emission in pattern form, there is a method in which a mask with a window in pattern form is placed on the above-described plane light emitting device, a method in which an organic layer in non-light emission part is formed to obtain extremely large thickness providing substantial non-light emission, and a method in which any one of an anode or a cathode, or both of them are formed in the pattern. By forming a pattern by any of these methods and by placing some electrodes so that independent on/off is possible, there is obtained a display device of segment type which can display digits, letters, simple marks and the like. Further, for forming a dot matrix device, it may be advantageous that anodes and cathodes are made in the form of stripes and placed so that they cross at right angles. By a method in which a plurality of kinds of polymeric compounds emitting different colors of lights are placed separately or a method in which a color filter or luminescence converting filter is used, area color displays and multi color displays are obtained. A dot matrix display can be driven by passive driving, or by active driving combined with TFT and the like. These display devices can be used as a display of a computer, television, portable terminal, portable telephone, car navigation, view finder of a video camera, and the like.

Further, the above-described light emitting device in plane form is a thin self-light-emitting one, and can be suitably used as a flat light source for back-light of a liquid crystal display, or as a flat light source for illumination. Further, if a flexible plate is used, it can also be used as a curved light source or a display.

The following examples will illustrate the present invention further in detail, but the scope of the invention is not limited to them.

Here, regarding the number-average molecular weight, a polystyrene reduced number-average molecular weight was measured by gel permeation chromatography (GPC) using tetrahydrofuran as a solvent.

### EXAMPLE 1

### Synthesis of Compound (a-1)

A 100 ml four-necked flask was purged with argon, then, into the flask was charged 0.49 g (1.4 mmol) of iridium chloride hydrate and 0.97 g (2.8 mmol) of 5-bromo-2-(4-octylphenyl)pyridine, and 21 ml of 2-ethoxyethanol and 7 ml of water were added. The mixture was stirred at a bath temperature of 120° C. for 6 hours, then, allowed to cool, and the deposited orange solid was filtrated and washed with water. The resultant solid was re-crystallized from a mixed solvent of 10 ml of toluene and 4 ml of hexane, to obtain 0.80 g of orange solid.

A 100 ml four-necked flask was purged with argon, then, into the flask was charged 0.46 g of the resultant orange solid, 0.20 g (2.0 mmol) of acetylacetone and 0.20 g (2.0 mmol) triethylamine, and 100 ml of dehydrated methanol was added. The mixture was refluxed at a bath temperature of 80° C. for 13 hours, then, allowed to cool, and concentrated to dryness, purified by silica gel column chromatography using toluene as a solvent, and the solvent was distilled off to obtain 0.30 g of a compound (a-1).

¹H-NMR(CDCl₃, 300 MHz) d8.51 (2H, s), 7.81 (2H, dd), 7.67 (2H, d), 7.40 (2H, d), 6.64 (2H, d), 6.00 (2H, s), 5.25 (1H, s), 2.31 (4H, t), 1.82 (6H, s), 1.15-1.42 (24H, m), 0.87 (6H, t).

MS (ESI-positive, KCl addition)m/z: 1021.3 ([M+K]⁺).

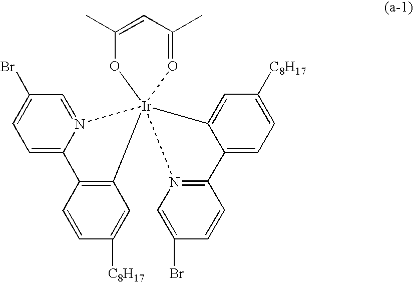

### EXAMPLE 2

### Synthesis of Polymer Complex Compound (a-2)

82 mg (0.08 mmol) of the above-mentioned compound (a-1), 1.9 g (2.9 mmol) of 2,7-dibromo-3,6-octyloxydibenzofuran and 1.15 g of 2,2′-bipydiryl were charged into a reaction vessel, then, an atmosphere in the reaction system was purged with a nitrogen gas. To this was added 70 ml of tetrahydrofuran deaerated previously by bubbling with an argon gas (dehydrated solvent). Next, to this mixed solution was added 2.0 g of bis(1,5-cyclooctadiene)nickel(0) {Ni(COD)₂}, the mixture was stirred at room temperature for 30 minutes, then, reacted at 60° C. for 3.3 hours. The reaction was conducted in a nitrogen gas atmosphere. After the reaction, this solution was cooled, then, poured into a mixed solution of methanol 30 ml/ion exchanged water 30 ml/25% ammonia water 5 ml, and the mixture was stirred for about 2 hours. Next, the generated precipitate was recovered by filtration. This precipitate was dried under reduced pressure, then, dissolved in toluene. This solution was filtrated to remove insoluble materials, then, this solution was purified by passing through a column filled with alumina. Next, this solution was washed with 1 N hydrochloric acid, 2.5% ammonia water and ion exchanged water, and poured into methanol to cause re-precipitation, and the generated precipitate was recovered. This precipitate was dried under reduced pressure, to obtain 0.57 g of a polymer (a-2).

This polymer had a polystyrene-reduced number-average molecular weight of 7.2×10⁴ and a polystyrene-reduced weight-average molecular weight of 2.2×10⁵.

2,7-dibromo-3,6-octyloxydibenzofuran was synthesized by a method described in EP1344788.

### EXAMPLE 3

### Synthesis of Compound (b-1)

A 100 ml four-necked flask was purged with argon, then, into the flask was charged 1.06 g (3.0 mmol) of iridium chloride hydrate, 1.04 g (3.0 mmol) of 5-bromo-2-(4-octylphenyl)pyridine and 0.80 g (3.0 mmol) of 2-(4-octylphenyl)pyridine, and 42 ml of 2-ethoxyethanol and 14 ml of water were added. The mixture was stirred at a bath temperature of 120° C. for 9 hours, then, allowed to cool, and the deposited orange solid was filtrated and washed with water. The resultant solid was dissolved in chloroform, filtrated through silica gel, then, the solvent was distilled off to obtain orange solid.

A 100 ml four-necked flask was purged with argon, then, into the flask was charged 2.58 mg (3.0 mmol) of the resultant orange solid, 1.2 g (12 mmol) of acetylacetone and 1.2 g (12 mmol) triethylamine, and 150 ml of dehydrated methanol was added. The mixture was refluxed at a bath temperature of 80° C. for 18 hours, then, allowed to cool, and concentrated to dryness, purified by silica gel column chromatography using toluene as a solvent, and the solvent was distilled off to obtain 0.42 g of a compound (b-1).

¹H-NMR(CDCl₃, 300 MHz)d8.55 (1H, s), 8.45 (1H, d), 7.80 (1H, d), 7.79 (1H, d), 7.69 (2H, m), 7.42 (2H, m), 7.09 (2H, m), 6.01 (2H, d), 5.22 (1H, s), 2.30 (4H, m), 1.80 (6H, S), 1.03-1.41 (24H, m), 0.88 (6H, t).

MS (ESI-positive, KCl addition) m/z: 941.2([M+K]⁺).

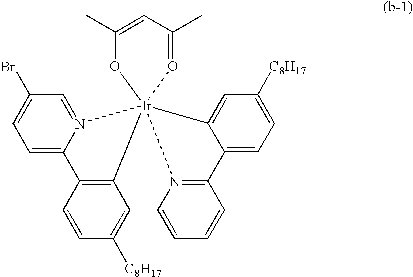

### EXAMPLE 4

### Synthesis of Polymer Complex Compound (b-2)

77 mg (0.08 mmol) of the above-mentioned compound (b-1), 1.9 g (2.9 mmol) of 2,7-dibromo-3,6-octyloxydibenzofuran and 1.16 g of 2,2′-bipydiryl were charged into a reaction vessel, then, an atmosphere in the reaction system was purged with a nitrogen gas. To this was added 70 ml of tetrahydrofuran deaerated previously by bubbling with an argon gas (dehydrated solvent). Next, to this mixed solution was added 2.0 g of bis(1,5-cyclooctadiene)nickel(0) {Ni(COD)₂}, the mixture was stirred at room temperature for 30 minutes, then, reacted at 60° C. for 3.3 hours. The reaction was conducted in a nitrogen gas atmosphere. After the reaction, this solution was cooled, then, poured into a mixed solution of methanol 30 ml/ion exchanged water 30 ml/25% ammonia water 5 ml, and the mixture was stirred for about 2 hours. Next, the generated precipitate was recovered by filtration. This precipitate was dried under reduced pressure, then, dissolved in toluene. This solution was filtrated to remove insoluble materials, then, this solution was purified by passing through a column filled with alumina. Next, this solution was washed with 1 N hydrochloric acid, 2.5% ammonia water and ion exchanged water, and poured into methanol to cause re-precipitation, and the generated precipitate was recovered. This precipitate was dried under reduced pressure, to obtain 0.57 g of a polymer (b-2).

This polymer had a polystyrene-reduced number-average molecular weight of 5.8×10⁴ and a polystyrene-reduced weight-average molecular weight of 1.5×10⁵.

<Light Emitting Property>

### EXAMPLES 5 AND 6

Toluene solutions of the polymer complex compounds (a-2, b-2) synthesized above each having a concentration of 0.8 wt % were spin-coated on quartz to produce thin film. Measurement of the emission spectrum of this thin film using a spectrophotometer confirmed intense light emission from triplet excited state, showing peaks around 551 nm (a-2) and around 554 nm (b-2). The excitation wavelength was 350 nm.

<Measurement of EL Light Emission>

### EXAMPLE 7

On a glass substrate carrying thereon an ITO film having a thickness of 150 nm formed by a sputtering method, a film having a thickness of 70 nm was formed by spin coating using a solution of poly(ethylenedioxythiophene)/polystyrenesulfonic acid (Baytron P manufactured by Bayer), and the film was dried at 200° C. on a hot plate for 10 minutes. Next, a film was formed by spin coating at a rotational speed of 1500 rpm using a toluene solution of the polymer complex compound (a-2) so prepared that the concentration thereof was 1.5 wt %. Further, this was dried under reduced pressure at 80° C. for 1 hour, then, lithium fluoride was vapor-deposited at a thickness of about 4 nm, and calcium was vapor-deposited at a thickness of about 5 nm and aluminum was vapor-deposited at a thickness of about 80 nm each as a cathode, to produce an EL device. After the degree of vacuum reached 1×10⁻⁴ Pa or less, vapor deposition of a metal was initiated. By applying voltage on the resultant device, EL light emission showing a peak at 560 nm was obtained. The device showed light emission of 100 cd/m² at about 14.7 V. The maximum light emission efficiency was 12.06 cd/A.

### EXAMPLE 8

A device was produced in the same manner as in Example 12 except that the polymer complex compound (b-2) was used instead of the polymer complex compound (a-2). Membrane formation was conducted by spin coating at 1100 rpm using a 1.5 wt % toluene solution. By applying voltage on the resultant device, EL light emission showing a peak at 564 nm was obtained. The device showed light emission of 100 cd/m² at about 8.3 V. The maximum light emission efficiency was 17.35 cd/A.

### EXAMPLE 9

### Synthesis of Compound c-1

Under an argon atmosphere, 1.73 g (72 mmol) of NaH was charged, and this was cooled in an ice bath. A solution of 7.96 g (40 mmol) of 4-bromoacetophenone in 60 ml of ethyl acetate was dropped over a period of 1 hour under ice cooling. The mixture was heated under reflux to react for 4.5 hours. The mixture was cooled to room temperature, and washed with 1 N hydrochloric acid and ion exchanged water, and liquid separation was performed. The organic layer was dried over anhydrous mirabilite, and concentrated to obtain 7.35 g of a pale orange coarse product. The product was re-crystallized from ethanol, to obtain 3.37 g of a white needle-shaped crystal (yield: 35%).

¹H-NMR (300 MHz/CDCl_{3′}): d2.20(s, 3H), 6.14(s, 1H), 7.60(d, 2H), 7.74(d, 2H), 16.1 (bs, 1H),

MS (APCI(+)): (M+H)⁺ 241

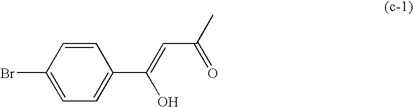

### EXAMPLE 10

### Synthesis of Compound c-2

15.9 g (61.1 mmol) of pinacol 4-tert-butylphenylboronate, 10.0 g (61.1 mmol) of 1-chloroquinoline and 150 ml of dehydrated toluene were charged, and bubbling with nitrogen was performed. 106 mg (0.092 mmol) of Pd(PPh₃)₄ was charged, further, bubbling with nitrogen was performed. 97 ml (137.5 mmol) of 20% Et4NOH aq. was charged, and the mixture was heated under reflux for 21 hours. The reaction mass was cooled down to room temperature, charged into ion exchanged water, and extracted with diethyl ether. The organic layer was dried over anhydrous magnesium sulfate, filtrated and concentrated to obtain 19.3 g of an oil. The crystal was dissolved with 50 ml of dichloromethane/hexane=1/1, and charged on a silica gel column, and dichloromethane/hexane=1/1, dichloromethane, and dichloromethane/methanol=9/1 were passed through this. The filtrate was concentrated to obtain 20 g of a yellow oil. Re-crystallization from 200 ml of hexane gave 8.2 g of a white plate-shaped crystal (yield: 51.3%).

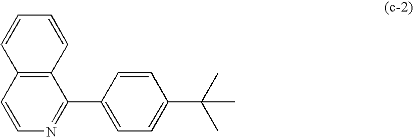

### EXAMPLE 10

### Synthesis of Compound c-3

4.89 g (14 mmol) of IrCl₃.3H₂O, 27.97 g (31 mmol) of ligand, 36 ml of 2-ethoxyethanol and 12 ml of ion exchanged water were charged, and bubbling with nitrogen was performed. Under a nitrogen atmosphere, the mixture was heated under reflux for 17 hours, then, cooled down to room temperature, and the reaction mass was filtrated under suction. The resultant red brown powder was washed with ion exchanged water and methanol, to obtain 9.3 g of a red brown powder (yield: 89.8%).

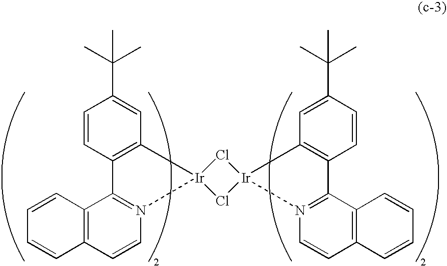

### EXAMPLE 11

### Synthesis of Compound c-4

Under an argon atmosphere, 1.05 g (0.7 mmol) of p-complex, 10.84 g (3.5 mmol) of ligand, 0.74 g (7.0 mmol) of sodium carbonate and 20 ml of 2-ethoxyethanol were charged, and reacted at room temperature for 4 hours. The reaction mass was filtrated under suction, to obtain a red brown powder. The red brown powder was dissolved in chloroform, charged on a silica gel column, and chloroform was passed through this. The filtrate was concentrated to obtain a red brown powder. The resultant powder was washed with ethanol to obtain 0.37 g of the intended substance (yield: 27.8 g).

¹H-NMR (300 MHz/THF-d₄) d0.97(d, 18H), 1.90(s, 3H), 6.04(s, 1H), 6.36 (dd, 2H), 6.89-6.97(m, 2H), 7.41(d, 2H), 7.58 (dd, 2H), 7.65 (dd, 2H), 7.74-7.78(m, 4H), 8.01-8.04(m, 2H), 8.11 (dd, 2H), 8.56 (dd, 2H), 9.04(m, 2H)

MS (ESI-positive, KCl addition: (M+K)⁺ 991

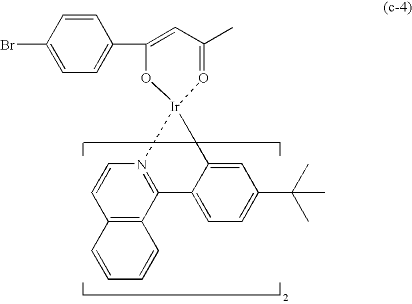

### EXAMPLE 12

### Synthesis of Polymer Complex Compound c-5

24 mg (0.025 mmol) of the above-mentioned compound, 568 mg (0.975 mmol) of 2,7-dibromo-3,6-octyloxydibenzofuran and 375 mg of 2,2′-bipyridyl were charged in a reaction vessel, then, an atmosphere in the reaction system was purged with a nitrogen gas. To this was 30 ml of tetrahydrofuran deaerated previously by bubbling with an argon gas (dehydrated solvent). Next, to this mixed solution was added 660 mg of bis(1,5-cyclooctadiene)nickel(0) {Ni(COD)₂}, the mixture was stirred at room temperature for 30 minutes, then, reacted at 60° C. for 3.3 hours. The reaction was conducted in a nitrogen gas atmosphere. After the reaction, this solution was cooled, then, poured into a mixed solution of methanol 30 ml/ion exchanged water 30 ml/25% ammonia water 3.6 ml, and the mixture was stirred for about 2 hours. Next, the generated precipitate was recovered by filtration. This precipitate was dried under reduced pressure, then, dissolved in toluene. This solution was filtrated to remove insoluble materials, then, this solution was purified by passing through a column filled with alumina. Next, this solution was washed with 1 N hydrochloric acid, 2.5% ammonia water and ion exchanged water, and poured into methanol to cause re-precipitation, and the generated precipitate was recovered. This precipitate was dried under reduced pressure, to obtain 110 mg of a polymer complex compound (c-5).

This polymer had a polystyrene-reduced number-average molecular weight of 4.8×10⁴ and a polystyrene-reduced weight-average molecular weight of 8.1×10⁴

<Light Emitting Property>

### EXAMPLE 13

A toluene solution of the polymer complex compound (c-5) synthesized above having a concentration of 0.8 wt % was spin-coated on quartz to produce a thin film. Measurement of the emission spectrum of this thin film using a spectrophotometer confirmed intense light emission from triplet excited state, showing a peak around 618 nm. The excitation wavelength was 350 nm.

<Measurement of EL Light Emission>

### EXAMPLE 14

On a glass substrate carrying thereon an ITO film having a thickness of 150 nm formed by a sputtering method, a film having a thickness of 70 nm was formed by spin coating using a solution of poly(ethylenedioxythiophene)/polystyrenesulfonic acid (Baytron P manufactured by Bayer), and the film was dried at 200° C. on a hot plate for 10 minutes. Next, a film was formed by spin coating at a rotational speed of 900 rpm using a toluene solution of the polymer complex compound (c-5) so prepared that the concentration thereof was 1.7 wt %. Further, this was dried under reduced pressure at 80° C. for 1 hour, then, lithium fluoride was vapor-deposited at a thickness of about 4 nm, and calcium was vapor-deposited at a thickness of about 5 nm and aluminum was vapor-deposited at a thickness of about 80 nm each as a cathode, to produce an EL device. After the degree of vacuum reached 1×10⁻⁴ Pa or less, vapor deposition of a metal was initiated. By applying voltage on the resultant device, EL light emission showing a peak at 625 nm was obtained. The device showed light emission of 100 cd/m² at about 13 V. The maximum light emission efficiency was 0.78 cd/A.

### EXAMPLE 15

### Synthesis of Compound d-2

The iridium complex (d-1) was brominated by a general aromatic organic compound bromination method, and the brominated complex was purified by silica gel column chromatography using toluene:hexane=1:1 as a solvent to have the following formula (d-2).

¹H-NMR(CDCl₃, 300 MHz)d7.81-7.72 (4H, m), 7.54-7.42 (7H, m), 6.88-6.78 (3H, m), 6.75-6.60 (5H, m), 2.36-2.19 (6H, m), 1.56-1.40 (6H, m), 1.05-1.39 (30H, m), 0.90-0.85 (9H, m).

MS (ESI-positive, KCl addition m/z: 1070.4 ([M+H]⁺)

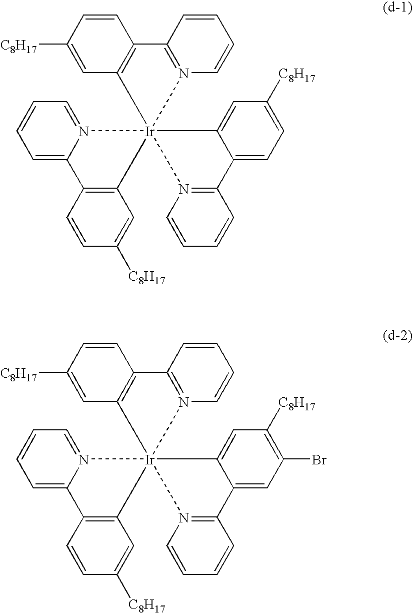

### EXAMPLE 16

### Synthesis of Polymer Complex Compound d-3

43 mg (0.040 mmol) of the above-mentioned compound (d-2), 1.142 g (1.960 mmol) of 2,7-dibromo-3,6-octyloxydibenzofuran and 750 mg of 2,2-bipydiryl were charged into a reaction vessel, then, an atmosphere in the reaction system was purged with a nitrogen gas. To this was added 42 ml of tetrahydrofuran deaerated previously by bubbling with an argon gas (dehydrated solvent). Next, to this mixed solution was added 1.320 g of bis(1,5-cyclooctadiene)nickel(0) {Ni(COD)₂}, the mixture was stirred at room temperature for 30 minutes, then, reacted at 60° C. for 3.3 hours. The reaction was conducted in a nitrogen gas atmosphere. After the reaction, this solution was cooled, then, poured into a mixed solution of methanol 30 ml/ion exchanged water 30 ml/25% ammonia water 3.6 ml, and the mixture was stirred for about 2 hours. Next, the generated precipitate was recovered by filtration. This precipitate was dried under reduced pressure, then, dissolved in toluene. This solution was filtrated to remove insoluble materials, then, this solution was purified by passing through a column filled with alumina. Next, this solution was washed with 1 N hydrochloric acid, 2.5% ammonia water and ion exchanged water, and poured into methanol to cause re-precipitation, and the generated precipitate was recovered. This precipitate was dried under reduced pressure, to obtain 610 mg of a polymer complex compound (d-3).

This polymer had a polystyrene-reduced number-average molecular weight of 4.8×10⁴ and a polystyrene-reduced weight-average molecular weight of 1.2×10⁵.

### EXAMPLE 17

<Light Emitting Property>

A toluene solution of the polymer complex compound (d-3) synthesized above having a concentration of 0.8 wt % was spin-coated on quartz to produce a thin film. Measurement of the emission spectrum of this thin film using a spectrophotometer confirmed intense light emission from triplet excited state, showing a peak around 516 nm. The excitation wavelength was 350 nm.

<Measurement of EL Light Emission>

### EXAMPLE 18

On a glass substrate carrying thereon an ITO film having a thickness of 150 nm formed by a sputtering method, a film having a thickness of 70 nm was formed by spin coating using a solution of poly(ethylenedioxythiophene)/polystyrenesulfonic acid (Baytron P manufactured by Bayer), and the film was dried at 200° C. on a hot plate for 10 minutes. Next, a film was formed by spin coating at a rotational speed of 1400 rpm using a toluene solution of the polymer complex compound (d-3) so prepared that the concentration thereof was 2.0 wt %. Further, this was dried under reduced pressure at 80° C. for 1 hour, then, lithium fluoride was vapor-deposited at a thickness of about 4 nm, and calcium was vapor-deposited at a thickness of about 5 nm and aluminum was vapor-deposited at a thickness of about 80 nm each as a cathode, to produce an EL device. After the degree of vacuum reached 1×10⁻⁴ Pa or less, vapor deposition of a metal was initiated. By applying voltage on the resultant device, EL light emission showing a peak at 520 nm was obtained. The device showed light emission of 100 cd/m² at about 11 V. The maximum light emission efficiency was 3.8 cd/A.

### EXAMPLE 19

### Synthesis of Compound (e-1)

A 100 ml four-necked flask was purged with argon, then, into the flask was charged 0.30 g (0.1 mmol) of a compound (e-3) described below, 0.13 g (0.2 mmol) of a compound (e-2) described below and 0.20 g (2.0 mmol) of triethylamine, and 30 ml of dehydrated methanol was added to this. The mixture was stirred at a bath temperature of 80° C. for 9 hours, then, allowed to cool, concentrated to dryness, then, purified by silica gel column chromatography using toluene as a solvent, and the solvent was distilled off to obtain 0.35 g of a compound (e-1).

The compound (e-3) was synthesized by methods described in EP1344788 and J. Am. Chem. Soc. 2003, 125, 636-637.

¹H-NMR(CDCl₃, 300 MHz)d8.47 (4H, d), 7.79-7.02 (20H, m), 6.56 (4H, m), 6.08 (2H, s), 6.02 (2H, s), 5.20 (2H, s), 3.91 (4H, m), 2.26 (6H, m), 2.04 (4H, t), 1.69 (4H, t), 1.05-1.45 (64H, m), 0.88 (12H, m).

MS (ESI-positive, KCl addition: m/: 2153.7 ([M+K]⁺)

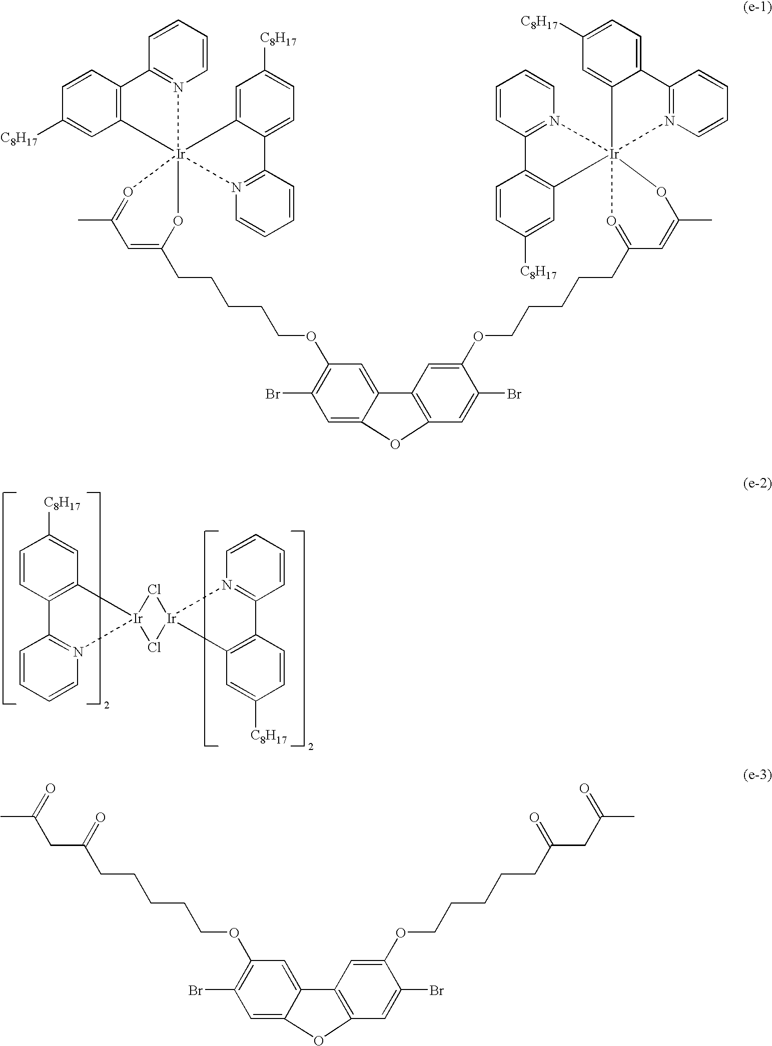

### EXAMPLE 20

### Synthesis of Polymer Complex Compound (e-4)

93 mg (0.08 mmol) of the above-mentioned compound (e-1), 1.9 g (2.9 mmol) of 2,7-dibromo-3,6-octyloxydibenzofuran and 1.25 g of 2,2′-bipyridyl were charged into a reaction vessel, then, an atmosphere in the reaction system was purged with a nitrogen gas. To this was added 70 ml of tetrahydrofuran deaerated previously by bubbling with an argon gas (dehydrated solvent). Next, to this mixed solution was added 2.2 g of bis(1,5-cyclooctadiene)nickel(0) {Ni(COD)₂}, the mixture was stirred at room temperature for 30 minutes, then, reacted at 60° C. for 3.3 hours. The reaction was conducted in a nitrogen gas atmosphere. After the reaction, this solution was cooled, then, poured into a mixed solution of methanol 30 ml/ion exchanged water 30 ml/25% ammonia water 5 ml, and the mixture was stirred for about 2 hours. Next, the generated precipitate was recovered by filtration. This precipitate was dried under reduced pressure, then, dissolved in toluene. This solution was filtrated to remove insoluble materials, then, this solution was purified by passing through a column filled with alumina. Next, this solution was washed with 1 N hydrochloric acid, 2.5% ammonia water and ion exchanged water, and poured into methanol to cause re-precipitation, and the generated precipitate was recovered. This precipitate was dried under reduced pressure, to obtain 0.57 g of a polymer complex compound (e-4).

This polymer had a polystyrene-reduced number-average molecular weight of 4.4×10⁴ and a polystyrene-reduced weight-average molecular weight of 2.2×10⁵.

2,7-dibromo-3,6-octyloxydibenzofuran was synthesized by a method described in EP1344788.

### EXAMPLE 21

<Light Emitting Property>

A toluene solution of the polymer complex compound (e-4) synthesized above having a concentration of 0.8 wt % was spin-coated on quartz to produce a thin film. Measurement of the emission spectrum of this thin film using a spectrophotometer confirmed intense light emission from triplet excited state, showing a peak around 517 nm. The excitation wavelength was 350 nm.

<Measurement of EL Light Emission>

### EXAMPLE 22

On a glass substrate carrying thereon an ITO film having a thickness of 150 nm formed by a sputtering method, a film having a thickness of 70 nm was formed by spin coating using a solution of poly(ethylenedioxythiophene)/polystyrenesulfonic acid (Baytron P manufactured by Bayer), and the film was dried at 200° C. on a hot plate for 10 minutes. Next, a film was formed by spin coating at a rotational speed of 600 rpm using a toluene solution of the polymer complex compound (e-4) so prepared that the concentration thereof was 1.5 wt %. Further, this was dried under reduced pressure at 80° C. for 1 hour, then, lithium fluoride was vapor-deposited at a thickness of about 4 nm, and calcium was vapor-deposited at a thickness of about 5 nm and aluminum was vapor-deposited at a thickness of about 80 nm each as a cathode, to produce an EL device. After the degree of vacuum reached 1×10⁻⁴ Pa or less, vapor deposition of a metal was initiated. By applying voltage on the resultant device, EL light emission showing a peak at 517 nm was obtained. The device showed light emission of 100 cd/m² at about 6.0 V. The maximum light emission efficiency was as high as 5.04 cd/A.

### INDUSTRIAL APPLICABILITY

The complex compound of the present invention containing a structure of a triplet light emitting complex in a polymer gives, when used in a light emitting layer of a light emitting device, excellent properties of the device.

1. A polymer complex compound comprising a repeating unit of the following formula (1) and a metal complex structure showing light emission from triplet excited state, having visible light emission in the solid state, and having a polystyrene reduced number-average molecular weight of 10³ to 10⁸: 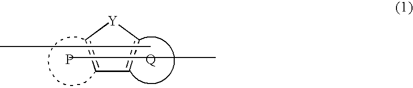
(wherein, Ring P and Ring Q each independently represent an aromatic ring, but Ring P may be either existent or non-existent;
when Ring P is existent, two connecting bonds respectively are on Ring P and/or Ring Q, and when Ring P is non-existent, two connecting bonds respectively are on 5 membered ring containing Y, and/or Ring Q;
the aromatic ring and/or the 5-membered ring containing Y may carry substituents selected from the group consisting of alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atoms, acyl group, acyloxy group, imine residues, amide group, acid imide group, monovalent heterocyclic group, carboxyl group, substituted carboxyl group and cyano group; and
Y represents —O—, —S—, —Se—, —Si(R₁)(R₂)—, —P(R₃)— or —PR₄ (═O)—, and R₁, R₂, R₃ and R₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group or halogen atom).

2. The polymer complex compound according to claim 1, wherein the repeating unit of the above-mentioned formula (1) is a repeating unit of the following formula (1-1), (1-2) or (1-3): 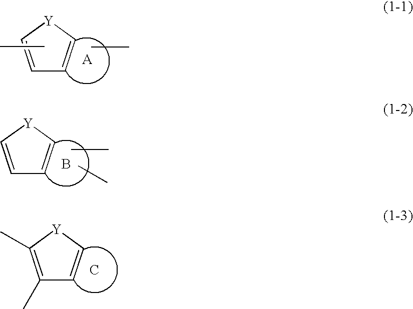
(wherein, Ring A, Ring B and Ring C each independently represent an aromatic ring;
the formulae (1-1), (1-2) and (1-3) may each carry substituents selected from the group consisting of alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atoms, acyl group, acyloxy group, imine residues, amide group, acid imide group, monovalent heterocyclic group, carboxyl group, substituted carboxyl group and cyano group; and
Y represents the same meaning as described above).

3. The polymer complex compound according to claim 1, wherein the repeating unit of the above-mentioned formula (I) is a repeating unit of the following formula (1-4) or (1-5): 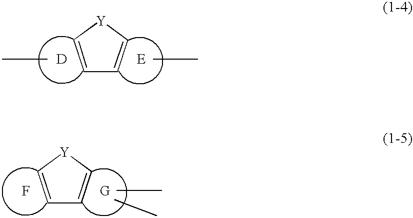
(wherein, Ring D, Ring E, Ring F and Ring G each independently represent an aromatic ring optionally carrying substituents selected from the group consisting of alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atoms, acyl group, acyloxy group, imine residues, amide group, acid imide group, monovalent heterocyclic group, carboxyl group, substituted carboxyl group and cyano group; and
Y represents the same meaning as described above).

4. The polymer complex compound according to claim 1, wherein the Ring P, Ring Q, Ring A, Ring B, Ring C, Ring D, Ring E, Ring F and Ring G represent an aromatic hydrocarbon ring.

5. The polymer complex compound according to claim 3, wherein the repeating unit of the above-mentioned formula (1-4) is a repeating unit selected from the following formulae (1-6), (1-7), (1-8), (1-9) and (1-10): 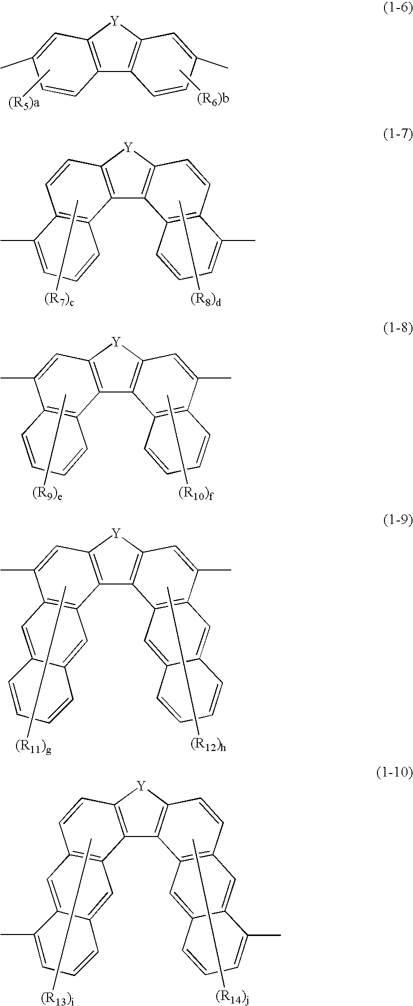
(wherein, R₅, R₆, R₇, R₈, R₉, R₁₀, R₁₁, R₁₂, R₁₃ and R₁₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, acyloxy group, imine residue, amide group, acid imide group, monovalent heterocyclic group, carboxyl group or substituted carboxyl group;
a and b each independently represent an integer of 0 to 3. c, d, e and f each independently represent an integer of 0 to 5;
g, h, i and j each independently represent an integer of 0 to 7;
when R₅, R₆, R₇, R₈, R₉, R₁₀, R₁₁, R₁₂, R₁₃ and R₁₄ exist each in plural number, they may the same or different; and
Y represents the same meaning as described above).

6. The polymer complex compound according to claim 1, wherein Y represents an O atom or a S atom.

7. The polymer complex compound according to claim 1, further having a repeating unit of the following formula (3), formula (4), formula (5) or formula (6):
-Ar₁- (3) [symbol]
Ar₂—X₁ [symbol] _{ff}Ar₃— (4)
-Ar₄-X₂- (5)
-X₃- (6
(wherein, Ar₁, Ar₂, Ar₃ and Ar₄ each independently represent an arylene group, divalent heterocyclic group or divalent group having a metal complex structure;
X₁, X₂ and X₃ each independently represent —CR₁₃═CR₁₄—, —C≡C—, —N(R₁₅)— or —(SiR₁₆R₁₇)ₘ;
R₁₃ and R₁₄ each independently represent a hydrogen atom, alkyl group, aryl group, monovalent heterocyclic group, carboxyl group, substituted carboxyl group or cyano group;
R₁₅, R₁₆ and R₁₇ each independently represent a hydrogen atom, alkyl group, aryl group, monovalent heterocyclic group, arylalkyl group or substituted amino group;
ff represents an integer of 0 to 2. m represents an integer of 1 to 12; and
when R₁₃, R₁₄, R₁₅, R₁₆ and R₁₇ exist each in plural number, they may be the same or different).

8. The polymer complex compound according to claim 7, wherein the repeating unit of the above-mentioned formula (3) is a repeating unit of the following formula (7), (8), (9), (10), (11), (12) or (12-1): 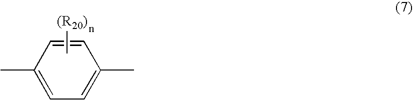
(wherein, R₂₀ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group;
n represents an integer of 0 to 4; and
when a plurality of R₂₀s exist, they may be the same or different) 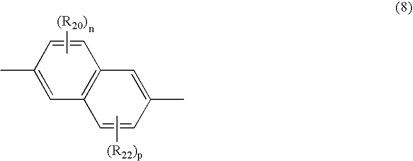
(wherein, R₂₁ and R₂₂ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group;
o and p each independently represent an integer of 0 to 3;
when R₂₁ and R₂₂ exist each in plural number, they may be the same or different) 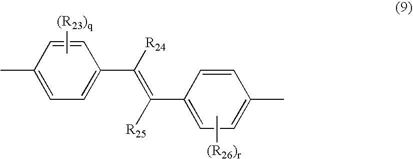
(wherein, R₂₃ and R₂₆ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group;
q and r each independently represent an integer of 0 to 4;
R₂₄ and R₂₅ each independently represent a hydrogen atom, alkyl group, aryl group, monovalent heterocyclic group, carboxyl group, substituted carboxyl group or cyano group;
when R₂₃ and R₂₆ exist in plural number, they may be the same or different) 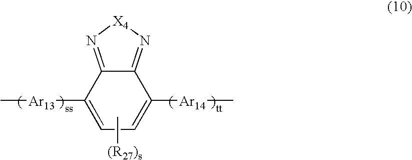
(wherein, R₂₇ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. s represents an integer of 0 to 2;
Ar₁₃ and Ar₁₄ each independently represent an arylene group, divalent heterocyclic group or divalent group having a metal complex structure. ss and tt each independently represent 0 or 1;
X₄ represents O, S, SO, SO₂, Se or Te;
when a plurality of R₂₇s exist, they may be the same or different) 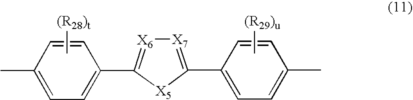
(wherein, R₂₈ and R₂₉ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group;
t and u each independently represent an integer of 0 to 4;
X₅ represents O, S, SO₂, Se, Te, N—R₃₀ or SiR₃₁R₃₂;
X₆ and X₇ each independently represent N or C—R₃₃. R₃₀, R₃₁, R₃₂ and R₃₃ each independently represent a hydrogen atom, alkyl group, aryl group, arylalkyl group or monovalent heterocyclic group;
when R₂₈, R₂₉ and R₃₃ exist in plural number, they may be the same or different) 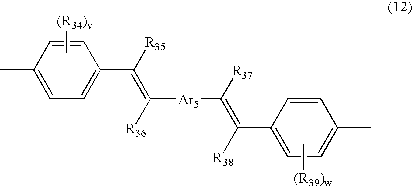
(wherein, R₃₄ and R₃₉ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group;
v and w each independently represent an integer of 0 to 4. R₃₅, R₃₆, R₃₇ and R₃₈ each independently represent a hydrogen atom, alkyl group, aryl group, monovalent heterocyclic group, carboxyl group, substituted carboxyl group or cyano group;
Ar₅ represents an arylene group, divalent heterocyclic group or divalent group having a metal complex structure;
when R₃₄ and R₃₉ exist in plural number, they may be the same or different) 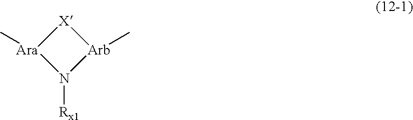
(wherein, Arₐ and Ar_{b} each independently represent a trivalent aromatic hydrocarbon group or a trivalent heterocyclic group, Rₓ₁ represents an alkyl group, alkoxy group, alkylthio group, alkyksilyl group, alkylamino group, aryl group optionally having a substituent, or monovalent heterocyclic group, X′ represents a single bond, 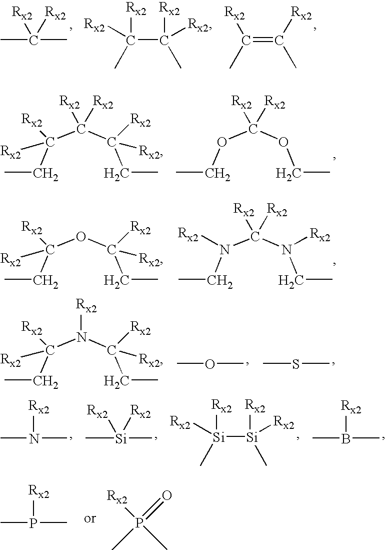
(wherein, Rₓ₂s each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group or cyano group; and
when a plurality of Rₓ₂s exist, they may be the same or different).

9. The polymer complex compound according to claim 7, wherein the repeating unit of the above-mentioned formula (4) is a repeating unit of the following formula (13): 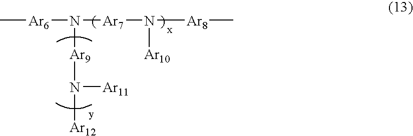
(wherein, Ar₆, Ar₇, Ar₈ and Ar₉ each independently represent an arylene group or divalent heterocyclic group;
Ar₁₀, Ar₁₁, and Ar₁₂ each independently represent an aryl group or monovalent heterocyclic group; and
Ar₆, Ar₇, Ar₈, Ar₉ and Ar₁₀ may have a substituent. x and y each independently represent 0 or 1, and 0≦x+y≦1).

10. An ink composition comprising at least one polymer complex compound according to claim 1.

11. The ink composition according to claim 10, wherein the viscosity at 25° C. is 1 to 100 mPa·s.

12. A light emitting thin film comprising the polymer complex compound according to claim 1.

13. An electrically conductive thin film comprising the polymer complex compound according to claim 1.

14. An organic semiconductor thin film comprising the polymer complex compound according to claim 1.

15. A polymer light emitting device having an organic layer between electrodes composed of an anode and a cathode wherein the organic layer contains the polymer complex compound according to claim 1.

16. The polymer light emitting device according to claim 15, wherein the organic layer is a light emitting layer.

17. The polymer light emitting device according to claim 16, wherein the light emitting layer further comprises a hole transporting material, electron transporting material or fluorescent material.

18. A sheet light source using the polymer light emitting device according to claim 15.

19. A segment display using the polymer light emitting device according to claim 15.

20. A dot matrix display using the polymer light emitting device according to claim 15.

21. A liquid crystal display using the polymer light emitting device according to claim 15 as back light.

22. An illumination using the polymer light emitting device according to claim 15.
